(19) United States
(12) Patent Application Publication
(10) Pub. No.: US 2024/0086588 A1
(43) Pub. Date: Mar. 14, 2024

(54) Systems and Methods for Managing Energy Storage Devices

(71) Applicant: BATTELLE ENERGY ALLIANCE, LLC, Idaho Falls, ID (US)

(72) Inventor: Kevin L. Gering, Idaho Falls, ID (US)

(73) Assignee: BATTELLE ENERGY ALLIANCE, LLC, Idaho Falls, ID (US)

(21) Appl. No.: 18/504,028

(22) Filed: Nov. 7, 2023

Related U.S. Application Data
(63) Continuation-in-part of application No. 17/015,369, filed on Sep. 9, 2020, now Pat. No. 11,815,557.
(60) Provisional application No. 62/897,877, filed on Sep. 9, 2019.

(51) Int. Cl. G06F 30/20

(52) U.S. Cl. CPC G06F 30/20

(57) ABSTRACT

An energy storage device (ESD) manager may be configured to utilize and/or develop aging models configured to model age-related performance degradation predicted to be incurred by an ESD under respective operating conditions. The aging model of an ESD may be used to determine operating conditions that satisfy the performance and/or endurance requirements of an application. The ESD manager may generate a policy to manage operation of the ESD in accordance with the determined operating conditions. For example, the aging model may be used to determine discharge conditions predicted to ensure that performance degradation incurred by the ESD remains below a threshold for a specified usage period. The discharge conditions may be used to determine a discharge configuration adapted to configure the application to utilize the ESD in accordance with the determined discharge conditions.

### CROSS-REFERENCE TO RELATED APPLICATIONS

This application is a continuation-in-part of U.S. patent application Ser. No. 17/015,369 filed Sep. 9, 2020, which claims priority to U.S. Provisional Patent Application No. 62/897,877 filed Sep. 9, 2019, each of which is incorporated by reference herein.

### STATEMENT REGARDING FEDERALLY SPONSORED RESEARCH OR DEVELOPMENT

This invention was made with government support under Contract Number DE-AC07-05-ID12517 awarded by the United States Department of Energy. The government has certain rights in the invention.

### BACKGROUND

Unless otherwise explicitly indicated herein, the approaches and other subject matter of this section are not prior art to the claims in this disclosure and are not admitted to be prior art by inclusion in this section.

An energy storage device (ESD) such as a battery can age over time. As used herein, “aging” or “ESD aging” refers to a process by which performance of an ESD deteriorates. ESD aging may result in performance degradation, such as decreased capacity, faster temperature rise, lower charge acceptance, higher internal impedance, lower voltage, self-discharge, and so on. ESD aging can be impacted by, inter alia, the conditions to which the ESD is subjected. For example, subjecting an ESD to charge rates that exceed predetermined limits can result in rapid ESD aging, or even unsafe conditions. Therefore, charging ESD at higher charge rates can advantageously reduce charge time but may significantly shorten the useful life of the ESD. These adverse effects can be exacerbated by other conditions, such as discharge rate, state of charge, and so on. As such, it can be difficult to accurately predict ESD aging. For example, the use of a particular charge rate may not result in premature aging under normal circumstances but may result in rapid aging (or unsafe conditions) when the ESD is subjected to strenuous discharge conditions (or vice versa). Therefore, what is needed are systems, methods, and devices for modeling ESD aging and using such models to determine ESD utilization policies configured to ensure satisfactory performance of the ESD over a specified usage period.

### SUMMARY

Disclosed herein are systems, methods, and apparatus for managing ESD. The disclosed systems and methods may be configured to model ESD aging, which may comprise developing aging models for respective ESD (and/or respective types of ESD). As used herein, “aging” or “ESD aging” refers to a process by which performance of an ESD deteriorates over time. An “aging model” determined for an ESD may comprise and/or refer to a model configured to predict performance loss to be incurred by the ESD under specified operating conditions.

In some implementations, the disclosed systems and methods may be configured to utilize ESD aging models to manage ESD utilization by an application. For example, the disclosed systems and methods may be configured to manage ESD charge operations, which may comprise determining charge policy for the ESD, the charge policy configured to limit aging incurred by the ESD. The charge policy may be configured such that performance loss predicted to be incurred by the ESD by the aging model remains below a threshold for specified usage period, e.g., a target usage period or target usable life. As used herein, a “target usage period” or “target usable life” of an ESD may comprise and/or refer to a period during which performance loss predicted to be incurred by the ESD remains below a performance loss threshold of the application (and/or a time during which performance of the ESD is predicted to satisfy specified performance requirements). A usage period may correspond to usage time, e.g., may comprise and/or refer to a time, timespan, time window, time period, time range, and/or the like. Alternatively, or in addition, aspects of a usage period may be defined with respect to ESD utilization. For example, the target usage period of an ESD may be defined in terms of duty cycle, e.g., may specify a number of duty cycles the ESD is required to endure while satisfying specified performance requirements.

In some implementations, the disclosed the aging models may be utilized to determine discharge policies for ESD. The discharge policy determined for an ESD may be configured such that performance loss to be incurred by the ESD due to, inter alia, discharge conditions is predicted to remain below a performance loss threshold over a specified usage period.

The disclosed systems and methods may be configured to manage ESD duty cycles, e.g., manage charge, discharge, and/or other conditions pertaining to operation and/or storage of the ESD. The aging model may be utilized to determine an operation policy for an ESD, the operation policy comprising a charge policy configured to control charge conditions of the ESD within the application and a discharge policy configured to control discharge conditions of the ESD within the application. The operation policy may be configured such that performance loss predicted to be incurred by the ESD due to target charge and/or discharge conditions of the ESD are maintained below a threshold for a specified usage period.

Disclosed herein are systems and methods configured to manage implementation of applications by respective ESD (and/or ESD types). The disclosed system, apparatus, and/or instructions stored on non-transitory, computer-readable storage medium may be configured to implement a method comprising retrieving an aging model for an ESD, the aging model configured to predict discharge-related performance loss to be incurred by the ESD under respective discharge conditions and distinguish the discharge-related performance loss from charge-related performance loss, utilizing the aging model to determine an operation policy for the ESD within an application, the operation policy comprising a discharge policy specifying target discharge conditions for the ESD within the application, the operation policy configured such that performance loss predicted to be incurred by the ESD satisfies a performance requirement of the application, and configuring the application to implement the discharge policy. Configuring the application to implement the discharge policy may comprise generating instructions to control aspects of discharge operations implemented by a discharge module of the application such that discharge conditions of the ESD within the application correspond with the target discharge conditions of the discharge policy.

In some implementations, the method may further comprise configuring the discharge policy to maintain the performance loss predicted to be incurred by the ESD under a threshold for a specified usage period. Alternatively, or in addition, method may further comprise configuring the discharge policy to maintain the performance loss predicted to be incurred by the ESD under a threshold of a secondary application for a secondary usage period extending beyond the specified usage period.

The disclosed method for ESD management may further include utilizing the aging model to determine predicted charge-related performance loss to be incurred by the ESD over the specified usage period, wherein the discharge policy is configured such that a sum of the predicted charge-related performance loss and predicted discharge-related performance loss under the discharge policy satisfies the threshold for the specified usage period.

In some examples, utilizing the aging model to determine the operation policy for the ESD may further comprise determining a charge policy of the operation policy, the charge policy pertaining to charge operations to be performed on the ESD within the application, and configuring the operation policy such that a sum of the predicted charge-related performance loss to be incurred by the ESD under the charge policy and the predicted discharge-related performance loss to be incurred by the ESD under the discharge policy satisfies the threshold for a specified usage period. Utilizing the aging model to determine the operation policy for the ESD may further comprise configuring the operation policy to satisfy one or more of a discharge requirement of the application and a charge requirement of the application while maintaining predicted performance loss to be incurred by the ESD under the threshold for the specified usage period.

Alternatively, or in addition, utilizing the aging model to determine the operation policy for the ESD may further comprise determining a candidate operation policy for the ESD, the candidate operation policy comprising a candidate discharge policy and a candidate charge policy, evaluating aging predicted to be incurred by the ESD under the candidate operation policy, the evaluating comprising predicting discharge-related aging to be incurred by the ESD under target discharge conditions of the candidate discharge policy and predicting charge-related aging to be incurred by the ESD under target charge conditions of the candidate charge policy, and modifying the candidate operation policy based on the evaluating, the modifying based on one or more of an aging prediction determined for the candidate policy, aging metrics of the candidate operation policy, operating condition sensitivity data determined for the ESD, a discharge constraint of the application, and a charge constraint of the application. The method may further include configuring the application to implement charge operations in accordance with the charge policy of the operation policy.

In some embodiments, utilizing the aging model to determine the operation policy for the ESD further comprises evaluating aging predicted to be incurred by the ESD under a plurality of candidate operation policies, each candidate operation policy comprising a respective discharge policy and respective charge policy, and selecting the operation policy from the plurality of candidate operation policies based, at least in part, on one or more of aging predictions determined for the candidate policies, aging metrics of the candidate policies, and cost metrics of the candidate policies, the cost metrics based, at least in part, on optimization criteria of the application. In some implementations, each candidate operation policy of the plurality of operation policies may comprise a same charge policy configured to model predicted charge conditions of the application, and modifying respective candidate operation policies of the plurality of operation policies may comprise modifying discharge policies of the respective candidate operation policies.

The disclosed method may further comprise determining a modified operation policy for the ESD in response to detecting a prediction deviation. The prediction deviation may comprise one or more of a deviation between performance loss predicted to be incurred by the ESD under the operation policy and measured performance loss observed in the ESD within the application, and a deviation between target operating conditions of the operation policy and measured operating conditions of the ESD within the application. The method may further include configuring the application to implement the modified operation policy. Determining the modified operation policy may comprise determining a modified discharge policy, the modified discharge policy configured to reduce discharge-related aging to be incurred by the ESD within the application. The prediction deviation may be detected in response to comparing predicted charge conditions of the ESD used to determine the operation policy for the ESD within the application and measured charge conditions of the ESD within the application.

In some implementations, the method may further comprise retrieving aging models for a plurality of ESD types, displaying aging predictions determined for selected ESD types of the plurality of ESD types on a graphical user interface, the aging predictions indicating performance degradation to be incurred by ESD of the selected ESD types under operating policies configured to satisfy performance requirements of the application, and receiving user selection of an ESD type of the plurality of ESD types in response to the displaying.

In some implementations, the disclosed system, apparatus, and/or instructions stored on non-transitory, computer-readable storage medium may be configured to implement a method comprising retrieving an aging model for an ESD, the aging model configured to predict charge-related performance loss to be incurred by the ESD under respective charge conditions and distinguish the charge-related performance loss from discharge-related performance loss, utilizing the aging model to determine an operation policy for the ESD within an application, the operation policy comprising a charge policy specifying target charge conditions for the ESD within the application, the operation policy configured such that performance loss predicted to be incurred by the ESD satisfies a performance requirement of the application, and configuring the application to implement the charge policy. Configuring the application to implement the charge policy may comprise generating instructions to control aspects of charge operations implemented by a charge module of the application such that charge conditions of the ESD within the application correspond with the target discharge conditions of the discharge policy.

In some implementations, the method may further comprise configuring the charge policy to maintain the performance loss predicted to be incurred by the ESD under a threshold for a specified usage period. Alternatively, or in addition, the method may comprise configuring the charge policy to maintain the performance loss predicted to be incurred by the ESD under a threshold of a secondary application for a secondary usage period extending beyond the specified usage period.

The disclosed method for ESD management may further include utilizing the aging model to determine predicted discharge-related performance loss to be incurred by the ESD over the specified usage period, wherein the charge policy is configured such that a sum of the predicted discharge-related performance loss and predicted charge-related performance loss under the charge policy satisfies the threshold for the specified usage period.

In some examples, utilizing the aging model to determine the operation policy for the ESD may further comprise determining a discharge policy of the operation policy, the discharge policy pertaining to discharge operations to be performed on the ESD within the application, and configuring the operation policy such that a sum of the predicted discharge-related performance loss to be incurred by the ESD under the discharge policy and the predicted charge-related performance loss to be incurred by the ESD under the charge policy satisfies the threshold. Utilizing the aging model to determine the operation policy for the ESD may further comprise configuring the operation policy to satisfy one or more of a discharge requirement of the application and a charge requirement of the application while maintaining predicted performance loss to be incurred by the ESD under the threshold for the specified usage period.

Alternatively, or in addition, utilizing the aging model to determine the operation policy for the ESD may further comprise determining a candidate operation policy for the ESD, the candidate operation policy comprising a candidate charge policy and a candidate discharge policy, evaluating aging predicted to be incurred by the ESD under the candidate operation policy, the evaluating comprising predicting charge-related aging to be incurred by the ESD under target charge conditions of the candidate charge policy and predicting discharge-related aging to be incurred by the ESD under target discharge conditions of the candidate discharge policy, and modifying the candidate operation policy based on the evaluating, the modifying based on one or more of an aging prediction determined for the candidate policy, aging metrics of the candidate operation policy, operating condition sensitivity data determined for the ESD, a discharge constraint of the application, and a charge constraint of the application. The method may further include configuring the application to implement discharge operations in accordance with the discharge policy of the operation policy.

In some embodiments, utilizing the aging model to determine the operation policy for the ESD may further comprise evaluating aging predicted to be incurred by the ESD under a plurality of candidate operation policies, each candidate operation policy comprising a respective charge policy and respective discharge policy, and selecting the operation policy from the plurality of candidate operation policies based, at least in part, on one or more of aging predictions determined for the candidate policies, aging metrics of the candidate policies, and cost metrics of the candidate policies, the cost metrics based, at least in part, on optimization criteria of the application. In some implementations, each candidate operation policy of the plurality of operation policies may comprise a same discharge policy configured to model predicted discharge conditions of the application, and wherein modifying respective candidate operation policies of the plurality of operation policies comprises modifying charge policies of the respective candidate operation policies.

The disclosed method may further comprise determining a modified operation policy for the ESD in response to detecting a prediction deviation, the prediction deviation comprising one or more of a deviation between performance loss predicted to be incurred by the ESD under the operation policy and measured performance loss observed in the ESD within the application, and a deviation between target operating conditions of the operation policy and measured operating conditions of the ESD within the application. The method may further include configuring the application to implement the modified operation policy. Determining the modified operation policy may comprise determining a modified charge policy, the modified charge policy configured to reduce charge-related aging to be incurred by the ESD within the application. The prediction deviation may be detected in response to comparing predicted discharge conditions of the ESD used to determine the operation policy for the ESD within the application and measured discharge conditions of the ESD within the application.

In some implementations, the method may further comprise retrieving aging models for a plurality of ESD types, displaying aging predictions determined for selected ESD types of the plurality of ESD types on a graphical user interface, the aging predictions indicating performance degradation to be incurred by ESD of the selected ESD types under operating policies configured to satisfy performance requirements of the application, and receiving user selection of an ESD type of the plurality of ESD types in response to the displaying.

### BRIEF DESCRIPTION OF DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements and have been solely selected for ease of recognition in the drawings.

FIG. 1A is a schematic block diagram illustrating an example of a system for managing energy storage devices.

FIG. 1B comprises a plot illustrating an example of an aging model.

FIG. 1C comprises a plot illustrating another example of an aging model.

FIG. 1D is a schematic block diagram illustrating examples of charge policies and corresponding charge configurations.

FIG. 1E is a schematic block diagram illustrating examples of discharge policies and corresponding discharge configurations.

FIG. 1F is a schematic block diagram illustrating examples of operating models configured to characterize operating conditions of respective usage periods.

FIG. 1G comprises a plot illustrating examples of aging predictions configured to model performance degradation of an ESD over time under respective operating conditions.

FIG. 2A is a schematic block diagram illustrating an example of an ESD manager.

FIG. 2B is a schematic block diagram illustrating examples of ESD aging data.

FIG. 2C is a schematic block diagram illustrating an example of an age modeling engine.

FIG. 3 is a schematic block diagram illustrating another example of a system for managing energy storage devices.

FIG. 4 comprises a plot illustrating examples of relationships between charge conditions and aging predictions of an ESD aging model.

FIG. 5A comprises a plot illustrating examples of aging models configured predict charge-related aging incurred by ESD under a range of charge rates.

FIG. 5B comprises a plot illustrating an example of an aging model configured to predict charge-related aging incurred by an ESD under a range of charge rates and charge temperatures.

FIG. 5C comprises a plot illustrating examples of aging models configured to predict charge-related aging under a range of charge rates and end charge voltages.

FIG. 5D comprises a plot illustrating further examples of aging models configured to predict charge-related aging under a range of charge rates and end charge voltages.

FIG. 6 comprises a plot illustrating examples of charge-related aging predictions.

FIG. 7A comprises a plot illustrating an example of a multi-period aging model.

FIG. 7B comprises a plot illustrating an example of a multi-period aging model configured to satisfy a usage guarantee.

FIG. 8 is a schematic block diagram illustrating an example of an ESD manager.

FIG. 9 comprises a plot illustrating examples of deviations between aging predictions and observed aging incurred by an ESD.

FIG. 10 is a schematic block diagram illustrating another example of a system for managing energy storage devices.

FIG. 11A comprises a plot illustrating an example an of ESD discharge model.

FIG. 11B comprises a plot illustrating another example of an ESD discharge model.

FIG. 11C comprises a plot illustrating another example of an ESD discharge model.

FIG. 12 comprises a plot illustrating further examples of ESD aging predictions.

FIG. 13 is a schematic block diagram of another example of an ESD manager.

FIG. 14 is a schematic block diagram of another example of a system for managing energy storage devices.

FIG. 15 comprises a plot illustrating additional examples of ESD aging predictions.

FIG. 16A comprises a plot illustrating further examples of aging predictions.

FIG. 16B comprises a plot illustrating examples of multi-application aging predictions.

FIG. 17 is a schematic block diagram illustrating another example of an ESD manager.

FIG. 18 is a schematic block diagram illustrating an example of a design interface.

FIG. 19 comprises a flowchart illustrating an example of a method for managing implementation of an application by an ESD.

FIG. 20 comprises a flowchart illustrating an example of a method for managing ESD prediction deviations.

FIG. 21 comprises a flowchart illustrating another example of a method for managing implementation of an application by an ESD.

FIG. 22 comprises a flowchart illustrating another example of a method for managing ESD prediction deviations.

FIG. 23 comprises a flowchart illustrating another example of a method for managing implementation of an application by an ESD.

FIG. 24 comprises a flowchart illustrating another example of a method for managing ESD prediction deviations.

FIG. 25 comprises a flowchart illustrating an example of a method for learning an aging model of an ESD (and/or ESD type).

### DETAILED DESCRIPTION OF THE INVENTION

As used herein, unless context requires otherwise, an ESD refers to a physical structure, component, system, apparatus, and/or device capable of storing and discharging energy. An ESD may refer to a device capable of maintaining a potential differential between two or more terminals (e.g., a voltage differential AV). An ESD may include one or more of a cell, an electrochemical cell, a collection of one or more cells, a collection of one or more electrochemical cells, a battery comprising one or more cells, an electrochemical battery comprising one or more electrochemical cells, an aluminum-ion battery, a carbon battery, a flow battery, a vanadium redox battery, a zinc-bromide battery, a zinc-cerium battery, a lead-acid battery, a glass battery, a lithium-ion battery, a lithium cobalt oxide battery, a lithium ion manganese oxide battery, a lithium ion polymer battery, a lithium iron phosphate battery, a lithium-sulfur battery, a thin film lithium-ion battery, a lithium ceramic battery, a magnesium-ion battery, a metal-air electrochemical battery, a lithium-air battery, an aluminum-air battery, a germanium-air battery, a calcium-air battery, an iron air battery, a potassium-ion battery, a silicon-air battery, a zinc-air battery, a tin-air battery, a sodium-air battery, a beryllium-air battery, a molten salt battery, a nickel-cadmium battery, a nickel-hydrogen battery, a nickel-iron battery, a nickel metal hydride battery, a nickel-zinc battery, a polymer-based battery, a rechargeable alkaline battery, a silver-zinc battery, a silver-cadmium battery, a sodium-sulfur battery, a super iron battery, a zinc-ion battery, and/or the like.

As used herein, the “capacity” or “maximum capacity” of an ESD (capacity C) refers to a quantity of energy capable of being stored by the ESD and/or discharged therefrom. The capacity of an ESD may be expressed in terms of electrical energy, such as watt-hours (Wh), kilowatt-hours (kWh), ampere-hours (Ahr), or the like. As used herein, the State of Charge (SoC) of an ESD may refer to the level of charge stored within the ESD relative to the capacity of the ESD (e.g., as a percentage of the maximum capacity C). The SoC of an ESD may indicate an amount of electrical energy capable of being discharged from the ESD at a given magnitude of discharge current. The rate at which electrical energy may be discharged from an ESD may be referred to the discharge rate of the ESD. The discharge rate may be expressed in terms of ESD capacity. The discharge rate of an ESD may be expressed in terms of a C-rate (Amps/hr), relative to a specified C 1 discharge rate of the ESD. The C 1 discharge rate may indicate a current output of the ESD to discharge the ESD from a full SoC over an hour (e.g., may correspond to the ESD capacity expressed as Ahr).

As used herein, unless context requires otherwise, charging an ESD refers to storing energy within the ESD and discharging refers to extracting energy from the ESD (e.g., configuring the ESD to supply power to a load or the like). Charging an ESD may, therefore, comprise supplying electrical power to the ESD, e.g., driving an electrical current into the ESD at a particular voltage potential (and/or range of potentials). Discharging an ESD may comprise extracting power from the ESD, e.g., coupling terminals of the ESD to a load or the like.

As disclosed herein, an ESD may comprise one or more electrochemical cells, each capable of storing energy in the form of chemical potential energy. The electrochemical cells of the ESD may be capable of discharging stored potential energy as electrical power. Charging an ESD may comprise supplying electrical power to the ESD and configuring the ESD to store the supplied electrical power as chemical potential energy (e.g., within one or more electrochemical cells). The time required to charge an ESD may be a function of the rate at which electrical power is supplied to the ESD (and/or the rate at which the ESD is capable of accepting and storing electrical power as chemical potential energy). The charge rate of an ESD may be expressed in terms of a rated capacity (C-rate) and may differ from the discharge rate (C₁). The charge rate of an ESD may be expressed in terms of a C-rate (Amps/hr) related to a specified discharge rate.

As disclosed herein, ESD may age over time, e.g., as the ESD endures charge/discharge cycles (duty cycles). The rate at which an ESD ages can be significantly impacted by the operating conditions of the ESD. ESD aging may result in degradation of one or more ESD performance characteristics, which may include, but are not limited to: decreased capacity, faster temperature rise during operation, less charge acceptance, higher internal impedance, lower voltage, more frequent self-discharge, and/or the like.

The operating conditions of an ESD can significantly impact the degree of aging incurred by the ESD and/or the rate at which such aging is incurred over time. For example, the use of excessively high charge rates may result in shortened ESD life or even unsafe conditions (e.g., catastrophic ESD failure such as a short-circuit). These adverse effects can be exacerbated when high charge rates are used in conjunction with other strenuous conditions, such as high SoC, high discharge rates, and/or the like. ESD aging can be impacted by other operating conditions, such as temperature. For example, charging lithium-ion batteries at low temperatures can result in lithium dendrite growth, which can lead to reduced energy capacity or even ESD failure.

ESD aging can result in performance loss and/or degradation. As used herein, “performance loss” or “performance degradation” incurred by an ESD may comprise and/or refer to a change to one or more performance characteristics of the ESD. A “performance characteristic” or “ESD characteristic” may relate to any aspect of the ESR functionality of the ESD including, but not limited to: energy storage capacity, charge acceptance, charge retention, power delivery, discharge rate, internal impedance, voltage potential (e.g., ΔV the ESD is capable of maintaining), ΔV under load, cell voltage, frequency of self-discharge, temperature rise during operation, temperature rise during charge operations, temperature rise during discharge operations, and/or the like.

The performance loss incurred by an ESD may render the ESD unsuitable for its intended application. For example, the performance degradation incurred by an ESD due to aging may render the ESD incapable of storing the amount of energy required by the application, satisfying power requirements of the application, or the like. As used herein, an ESD that is “suitable” for a particular application refers to an ESD capable of satisfying performance requirements of the application. A performance requirement may refer to any suitable performance characteristic of an ESD, e.g., capacity, discharge rate, and/or the like, as disclosed herein. An ESD that is incapable of satisfying the performance requirements of an application (e.g., due to, inter alia, ESD aging) may be referred to as “unsuitable” for the application.

ESD aging may shorten the usable life of the ESD. As used herein, the “usable life” of an ESD in a particular application refers to a time during which the ESD satisfies ESR requirements of the application. Accordingly, the usable life of an ESD in an application may be a function of, inter alia, the operating conditions of the ESD within the application. For example, ESD that are charged at higher rates may age more quickly than ESD charged at lower rates. Therefore, although the use of higher charge rates may advantageously reduce charge time, they may adversely impact the useful life of the ESD. Similarly, ESD discharged at higher rates (and/or under more strenuous conditions, such as higher temperatures) may age more quickly and to a greater extent than ESD discharged at lower rates. Again, although use at higher discharge rates may be advantageous in some scenarios, such use may significantly decrease the usable life of the ESD.

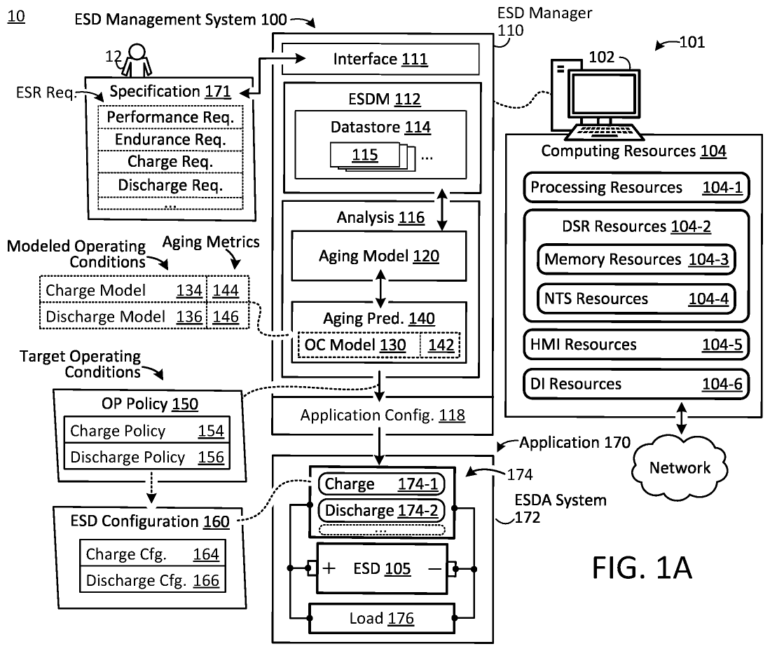

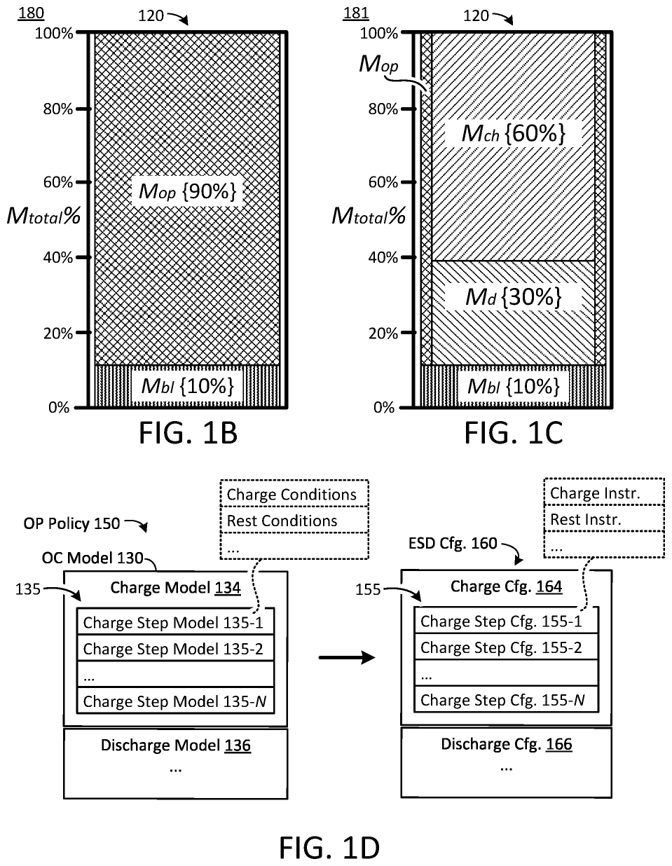

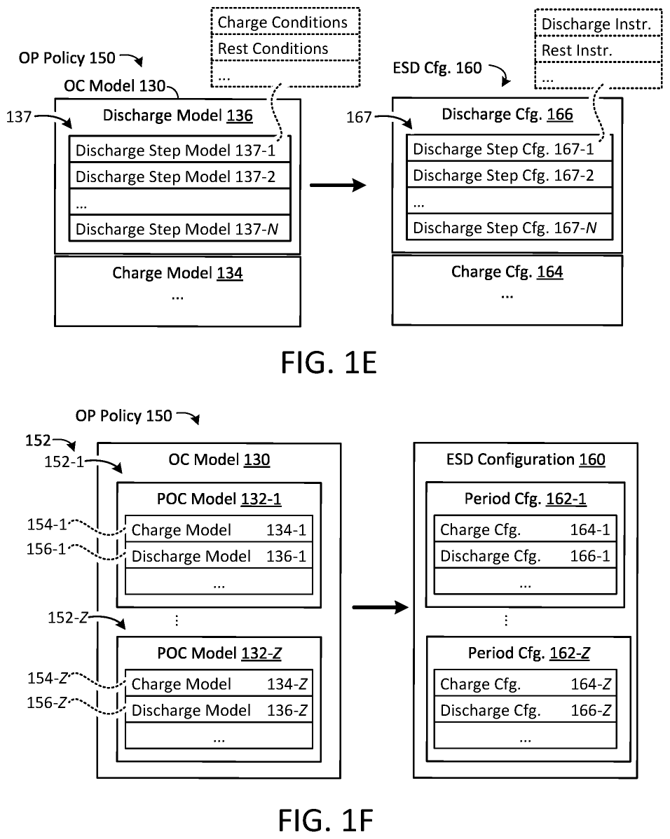

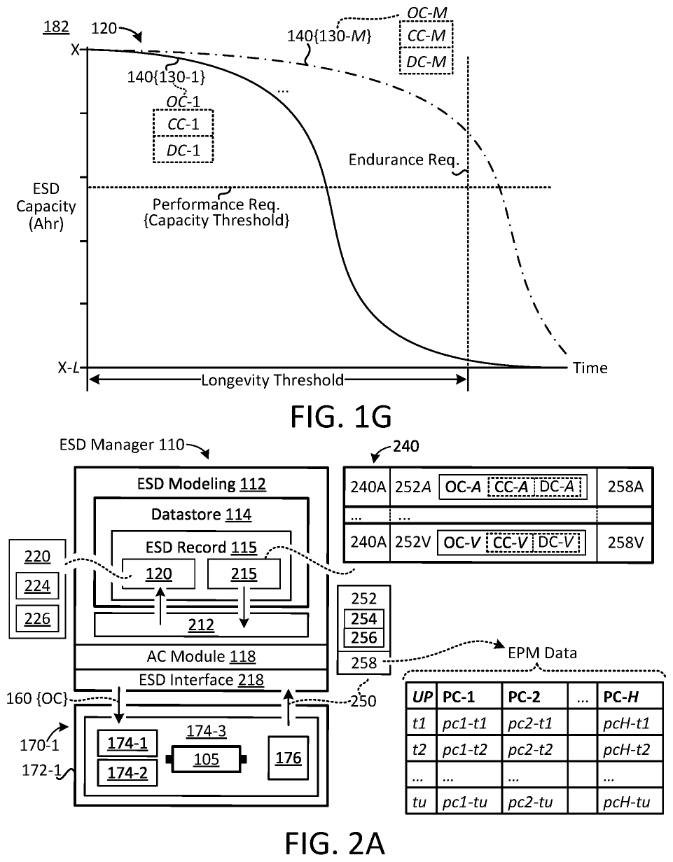

FIG. 1A illustrates an example of an operating environment 10 in which aspects of the systems and methods for ESD management disclosed herein may be practiced. The operating environment 10 may comprise a system 100 for ESD management, e.g., an ESD management system 100. The system 100 may comprise an ESD manager 110. As disclosed in further detail herein, the ESD manager 110 may be configured to manage the implementation of an application 170 by an ESD 105. Managing implementation of the application may comprise a) retrieving an aging model 120 of the ESD 105, the aging model configured to predict performance loss to be incurred by the ESD 105 under respective operating conditions and distinguish performance loss attributable to charge conditions of the ESD 105 from performance loss attributable to discharge conditions, b) utilizing the aging model 120 to determine an operation policy 150 for the ESD 105 within the application 170, the operation policy 150 configured to control aspects of the operating conditions of the ESD 105 within the application 170 such that, inter alia, performance loss predicted to be incurred by the ESD 105 is maintained at or below a threshold, and c) configuring the application 170 to operate the ESD 105 in accordance with the determined operation policy 150.

Aspects of the ESD manager 110 may comprise and/or be implemented by an apparatus 101 (e.g., an ESD management apparatus 101). The apparatus 101 may comprise and/or be implemented or embodied by a computing device 102. The computing device 102 may comprise any suitable computing means including, but not limited to: an electronic device, a computer, a general-purpose computing device, an application-specific computing device, a computing system, a mobile computing device, a smart phone, a tablet, a laptop, a server device, a distributed computing system, a cloud-based computing system, an embedded computing system, and/or the like.

The apparatus 101 may comprise and/or be coupled to computing resources 104. The computing resources 104 may comprise any suitable computing means including, but not limited to processing resources 104-1, data storage and/or retrieval (DSR) resources 104-2, human-machine interface (HMI) resources 104-5, data interface (DI) resources 104-6, and/or the like. The computing resources 104 may comprise and/or be embodied by any suitable computing means. In the FIG. 1A example, aspects of the computing resources 104 may be implemented by the computing device 102.

The processing resources 104-1 may comprise any suitable processing means. The processing resources 104-1 comprise any suitable means for processing and/or executing machine-readable instructions (e.g., code, machine code, assembly code, source code, interpretable code, script, and/or the like), including, but not limited to: a circuit, a chip, a package, processing circuitry, logic circuitry, an integrated circuit (IC), a processor, a processing unit, a physical processor, a virtual processor (e.g., a virtual machine), an arithmetic-logic unit (ALU), a central processing unit (CPU), a general-purpose processor, a programmable logic device (PLD), a Complex Programmable Logic Device (CPLD), a Programmable Logic Array (PLA), a field programmable gate array (FPGA), an application-specific integrated circuit (ASIC), a System in Package (SiP), a System on Chip (SoC), virtual processing resources, and/or the like.

The DSR resources 104-2 may comprise any suitable means for storing, retrieving, maintaining, and/or otherwise managing data, which may include, but are not limited to: memory resources 104-3, NTS resources 104-4, and/or the like. The memory resources 104-3 may comprise any suitable memory means including, but not limited to: cache memory, volatile memory, non-volatile memory, Random-Access Memory (RAM), Dynamic RAM (DRAM), Static RAM (SRAM), Thyristor RAM (TRAM), Zero-Capacitor RAM (ZRAM), and/or the like. The NTS resources 104-4 may comprise any suitable non-transitory, persistent, and/or non-volatile storage means including, but not limited to: an NTS device, a persistent storage device, an internal storage device, an external storage device, a remote storage device, Network Attached Storage (NAS) resources, a magnetic disk drive, a hard disk drive (HDD), a magnetic disk storage device, an optical storage device, a tape storage device, a solid-state memory, Flash memory, NAND-type Flash memory, NOR-type Flash memory, Programmable Metallization Cell (PMC) memory, Silicon-Oxide-Nitride-Oxide-Silicon (SONOS) memory, Resistive RAM (RRAM) memory, Floating Junction Gate RAM (FJG RAM), ferroelectric memory (FeRAM), magnetoresistive memory (MRAM), phase change memory (PRAM), Electrically Erasable Programmable Read-Only Memory (EEPROM), a cache storage device, and/or the like.

The HMI resources 104-5 may comprise any suitable means for human-machine interaction including, but not limited to: input devices, output devices, input/output (I/O) devices, visual output devices, display devices, monitors, touch screens, a keyboard, gesture input devices, a mouse, an image capture device (e.g., a camera, scanner, and/or the like), a haptic feedback device, an audio I/O device, an audio capture device, an audio output device (e.g., a speaker), a neural interface device, and/or the like.

The DI resources 104-6 may comprise any suitable data communication and/or interface means including, but not limited to: a communication interface, a I/O interface, a device interface, a network interface, an interconnect, and/or the like. In some implementations, the data interface 104-6 may be configured to communicatively couple the apparatus 101 to a network, which may include, but is not limited to: an electronic communication network, a computer network, a wired communication network, a wireless communication network, the Internet, a virtual private network (VPN), a wide area network (WAN), a WiFi network, a public switched telephone network (PSTN), a cellular communication network, a cellular data network, an Internet Protocol (IP) network, a satellite network, a Near Field Communication (NFC) network, a Bluetooth network, a mesh network, a grid network, and/or the like.

Aspects of the ESD manager 110 (and/or portions thereof) may be embodied as hardware components, such as components of the computing device 102, computing resources 104, and/or the like. Alternatively, or in addition, aspects of the ESD manager 110 (and/or portions thereof) may be embodied as machine-readable instructions stored on or within a non-transitory storage medium, such as NTS resources 104-5 of the apparatus 101. The instructions may be configured for execution by the processing resources 104-1 of the computing device 102, which execution may configure the computing device 102 to implement operations for ESD management, as disclosed herein.

The ESD manager 110 may comprise an interface module 111. The interface module 111 may be configured for interaction with an entity, such as a process, computing system, user 12, and/or the like. The interface module 111 may comprise and/or be configured to implement any suitable interface means including, but not limited to: a user interface, a human-machine interface, a graphical user interface (GUI), a command line interface (CLI), a machine-to-machine interface, a programming interface, an application program interface (API), and/or the like.

The ESD manager 110 may further comprise an ESD modeling (ESDM) module 112. The ESDM module 112 may be configured to model aging characteristics of respective ESD 105 and/or respective types of ESD 105, e.g., ESD 105 comprising respective types of cells, cell chemistry, and/or the like. The ESDM module 112 may be configured to model temporal ESD aging characteristics of an ESD 105 by use of an aging model 120 developed for the ESD 105 (and/or a type or class of energy storage devices corresponding to the ESD 105). In some implementations, the ESDM module 112 may be configured to develop aging models 120 for respective ESD 105. The aging models 120 may be developed by, inter alia, monitoring performance degradation exhibited by ESD 105 over time and/or under specified conditions, as disclosed in further detail herein. Alternatively, or in addition, the ESDM module 112 may be configured to retrieve aging models 120 developed for respective ESD 105 from a datastore 114. The datastore 114 may comprise any suitable data storage and/or retrieval means, e.g., may comprise and/or be implemented by DTS resources 104-2, as disclosed herein. In some implementations, the ESD manager 110 may comprise and/or be configured to maintain profiles 115 for respective ESD 105 (and/or respective ESD types) within the datastore 114. As used herein, an ESD profile 115 (or profile 115) may comprise and/or refer to any suitable data comprising information pertaining to an ESD 105 (and/or ESD type). An ESD profile 115 may be maintained in any suitable format using any suitable data storage and/or retrieval technique, e.g., a database, relational database, library, and/or the like. An ESD profile 115 may comprise any suitable information pertaining to an ESD 105 including, but not limited to: ESD name, ESD model name, ESD serial number, ESD manufacturer, ESD-specific characteristics, such as rated capacity of the ESD 105, C-rate of the ESD 105, a maximum voltage (Vₘₐₓ) of the ESD 105 (and/or cells thereof), minimum voltage (Vₘᵢₙ), nominal charge rate (e.g., expressed in terms of C-rate, such as 1C), nominal discharge rate (e.g., expressed in terms of C-rate), maximum charge rate (r_{ch_max}), maximum discharge rate (r_{d_max}), cell chemistry information (e.g., cell type), materials information (e.g., information pertaining to the materials used in the anode, cathode and/or other components of the ESD 105), reference temperature(s) of the ESD (e.g., T_{ref}), age modeling data (e.g., an aging model 120, as disclosed in further detail herein), and/or the like.

The ESD profiles 115 may further comprise information pertaining to the aging characteristics of respective ESD 105 (and/or ESD types). The ESD profiles 115 may, for example, comprise aging models 120 determined for respective ESD 105 (and/or ESD types). As disclosed herein, an aging model 120 of an ESD 105 may be configured to model age-related performance degradation predicted to be incurred by the ESD 105 under specified operating conditions; the aging model 120 may be configured to predict the a) maximum extent of aging to be incurred by the ESD 105 under specified operating conditions, and/or b) the rate at which such aging will be incurred over time. In other words, the aging model 120 may be configured to quantify the impact or cost of specified operating conditions on the usable life of the ESD 105.

As used herein, the “operating conditions” of an ESD may comprise and/or refer to conditions under which the ESD 105 may be utilized in an application 170. Operating conditions may comprise and/or refer to conditions under which energy storage and/or retrieval (ESR) functions of the ESD 105 are utilized. The operating conditions of an ESD 105 may be configured to characterize and/or model ESD duty cycles comprising charge operations to store energy within the ESD 105, corresponding discharge operations, storage or rest conditions of the ESD 105, and so on. In some implementations, the ESD manager 110 may be configured to model ESD operating conditions. A specified set of ESD operating conditions may be represented, defined, described, modeled and/or otherwise expressed an operating condition model 130. As used herein, an operating condition (OC) model 130 may comprise and/or refer to data configured to characterize, describe, quantify, and/or otherwise model aspects of the operating conditions of an ESD 105. An OC model 130 may be configured to model any condition related to ESD aging, including, but not limited to: duty cycle conditions, charge conditions (e.g., charge rate, SoC, charge temperature, and/or the like), discharge conditions (e.g., discharge rate, power output, discharge temperature, and/or the like), and/or the like.

In some implementations, an OC model 130 may comprise a charge model 134, which may be configured to model charge-related operating conditions. A charge model 134 may comprise data configured to express, represent, define, describe, characterize and/or otherwise model any suitable charge-related operating conditions. For example, the charge model 134 may be configured to model charge-related aspects of a duty cycle characterized by the OC model 130, e.g., model charge conditions of charge operations of the duty cycle. The charge model 134 may be configured to model charge conditions pertaining to any aspect of the charge operations including, but not limited to: parameters of the charge operations, e.g., parameters of single-step charge operations, such as charge rate (r_{ch}), end charge voltage (V_{ch_end}), and/or the like, parameters of respective steps of multi-step charge operations, characteristics of ESD 105 charged in the charge operations (e.g., ESD-specific characteristics, such as maximum charge rate (r_{ch_max}), maximum voltage (Vₘₐₓ), and/or the like), environmental conditions, e.g., temperature during the charge operations and/or respective charge steps (T_{ch}), and/or the like.

Alternatively, or in addition, an OC model 130 may comprise a discharge model 136, which may be configured to model discharge-related ESD operating conditions. A discharge model 136 may comprise data configured to express, represent, define, describe, characterize, and/or otherwise model any suitable discharge-related operating conditions. For example, the discharge model 136 may be configured to model discharge-related aspects of a duty cycle characterized by the OC model 130, e.g., model discharge conditions of a discharge operations of the duty cycle. The discharge model 136 may be configured to model discharge conditions pertaining to any aspect of a discharge operation including, but not limited to: parameters of single-step discharge operations, such as discharge rate (r_{d}), end discharge voltage (V_{d_end}), and/or the like, parameters of respective steps of multi-step discharge operations, characteristics of ESD 105 discharged in the discharge procedures (e.g., ESD-specific characteristics, such as maximum discharge rate (r_{d_max}), minimum voltage (Vₘᵢₙ), and/or the like), environmental conditions, e.g., temperature of the ESD 105 during the discharge operation and/or respective discharge steps (T_{d}), and/or the like.

The ESD manager 110 may further comprise an analysis module 116. The analysis module 116 may be configured to utilize aging models 120 determined for respective ESD 105 (and/or ESD types) to, inter alia, manage the implementation of applications 170 by the ESD 105. As used herein, an application 170 (or ESD application 170) may comprise and/or refer to utilization of an ESD 105 by and/or within a system 172, e.g., an ESD application (ESDA) system 172. The ESDA system 172 may comprise any suitable means for utilizing one or more ESD 105, including, but not limited to: a machine, equipment, a vehicle, a tool, an electronic device, a computing device, a power management system, a battery backup system, a power distribution system, and/or the like.

In some implementations, the ESDA system 172 may comprise and/or be coupled to one or more ESD modules 174. As used herein, an ESD module 174 may comprise and/or refer to any suitable means for controlling, monitoring, operating, regulating, managing and/or otherwise interfacing with an ESD 105 including, but not limited to: a controller, an ESD controller, an integration component, an ESD integration device, an ESD management system, a battery management system (BMS), an ESD monitoring device, an ESD analysis device, ESD test equipment (e.g., a battery tester), an ESD diagnostic device, an ESD conditioning device (e.g., battery conditioning equipment), a charging device, a cell charger, a cell balancing device, and/or the like. In the FIG. 1A example, the ESDA system 172 may comprise one or more of a charge module 174-1 and/or discharge module 174-2. The charge module 174-1 may be configured to implement charge operations on the ESD 105, e.g., may comprise and/or be coupled to a charge device. The discharge module 174-2 may be configured to implement discharge operations on the ESD 105, e.g., may comprise and/or be coupled to a controller, a motor controller, an electronic speed controller (ESC), and/or the like.

The ESD application 170 may subject the ESD 105 to duty cycles, each duty cycle comprising a charge operation to store energy within the ESD 105 and corresponding discharge operation. A duty cycle may comprise configuring the charge module 174-1 to store energy within the ESD 105, configuring the discharge module 174-2 to supply power to a load 176, such as a motor, electronic device, or the like, and so on.

The ESD manager 110 may be configured to manage the implementation of an application 170 by an ESD 105. Characteristics of the application 170 may be defined by and/or within a specification 171 (or application specification 171). As used herein, a specification 171 may comprise and/or refer to machine-readable data stored and/or maintained within a machine-readable storage medium, such as DSR resources 104-2 of the computing device 102. A specification 171 may comprise any suitable information pertaining to an application 170, e.g., may comprise an application identifier, name, description, and/or the like. The specification 171 may define energy storage and/or retrieval (ESR) requirements of the application 170. The specification 171 may define performance requirements pertaining to specified ESD characteristics, e.g., thresholds, ranges, and/or other criteria pertaining to specified performance characteristics, such as ESD capacity, charge acceptance, impedance, power output, discharge current, discharge voltage, and/or the like. For example, the performance requirements may specify a minimum capacity required of ESD 105 utilized within the application 170, define power requirements of the application 170, and/or the like.

In some implementations, the specification 171 may comprise and/or define one or more endurance requirements. The endurance requirements may be configured to define aging, and/or longevity requirements of the application 170. In other words, an endurance requirement may require that performance degradation incurred by the ESD 105 be maintained below a specified threshold and/or that performance degradation be maintained below a threshold for a specified usage period. In some implementations, a performance requirement of the application 170 may comprise and/or be associated with an endurance requirement. For example, a performance requirement may specify that ESD capacity must remain above a threshold for a specified usage period.

Alternatively, or in addition, the endurance requirement(s) of an application 170 may define criteria for determining the “usable life” of an ESD 105 within the application 170. As used herein, the “usable life” of an ESD 105 may comprise and/or refer to a period during which the ESD 105 satisfies specified performance criteria, e.g., a usage period during which performance degradation incurred by the ESD 105 satisfies performance requirements of the application 170. The endurance requirement may specify a minimum usable life for ESD 105 utilized within the application 170.

As disclosed in further detail herein, the ESD manager 110 may be configured to utilize the aging model 120 of an ESD 105 to, inter alia, predict the extent and/or rate at which the ESD 105 will age under specified operating conditions. As disclosed herein, “aging” may comprise and/or refer to a process by which performance of an ESD 105 may deteriorate over time. Accordingly, the aging model 120 of an ESD 105 may be configured to predict performance degradation to be incurred by the ESD 105 under respective operating conditions as a function of time. The ESD manager 110 may utilize the aging model 120 of an ESD 105 to, inter alia, predict the usable life of the ESD 105 within an application 170. As used herein, the predicted usable life of an ESD 105 under specified operating conditions (e.g., an OC model 130) may comprise and/or refer to a period during which the aging model 120 of the ESD 105 predicts that the ESD 105 will satisfy specified performance criteria. In other words, the predicted usable life of an ESD 105 may comprise and/or refer to a period during which performance degradation predicted to be incurred by the ESD 105 remains below a threshold. The predicted usable life of an ESD 105 in an application 170 configured to utilize the ESD 105 according to specified operating conditions (per an OC model 130) may, therefore, comprise and/or refer to a period during which the ESD 105 is predicted to satisfy the requirements of the application 170 (e.g., satisfy the specification 171 of the application 170).

In some implementations, the specification 171 of an application 170 may further comprise requirements pertaining to specified ESD operations. For example, the specification 171 may comprise charge requirements pertaining to ESD charge operations. The charge requirements may pertain to any aspect of the charge operations to be performed on ESD 105 within the application 170. For example, the charge requirements may specify that the application 170 requires ESD 105 to be charged to a minimum SoC, e.g., the charge requirements may specify a minimum charge SOCₘᵢₙ, minimum end charge voltage V_{ch_end_min}, and/or the like. By way of further example, the charge requirements may limit the duration of charge operations; the charge requirements may limit the maximum duration of the charge operations, e.g., specify a charge duration threshold (D_{ch_max}) or the like. As disclosed in further detail herein, charge requirements of the application 170 may, therefore, constrain aspects of the operating policy 150 and/or corresponding charge policy 154 determined for the ESD 105 within the application 170. As disclosed in further detail herein, the charge requirements may constrain target charge conditions of a charge profile 154 determined for the ESD 105 to a minimum SoC (and/or corresponding V_{ch_end}), limit charge duration (D_{ch_max}), and/or the like.

Alternatively, or in addition, the specification 171 may comprise discharge requirements pertaining to ESD discharge operations. The discharge requirements may pertain to any aspect of the discharge operations to be performed on ESD 105 within the application 170. For example, the discharge requirements may correspond to power requirements of the application 170, e.g., may define a minimum discharge rate (r_{d_min}), maximum discharge rate (r_{d_max}), minimum discharge end voltage (Vₘᵢₙ), and/or the like. By way of further example, the discharge requirements may pertain to other discharge conditions, such as discharge temperature (T_{d}), and so on. As disclosed in further detail herein, the discharge requirements of the application 170 may, therefore, constrain aspects of the operating policy 150 and/or corresponding discharge policy 156 determined for the ESD 105 within the application 170. As disclosed in further detail herein, the discharge requirements may constrain target discharge conditions of a discharge profile 156 determined for the ESD 105 to specified discharge rates (r_{d}), discharge SoC (V_{d_end_max}), and/or the like.

Aspects of the specification 171 of an application 170 may be received, modified, designed, authored and/or otherwise configured at the ESD manager 110 by any suitable means, e.g., through and/or by use of the interface module 111, HMI resources 104-5, DI resources 104-6, an electronic communication network, and/or the like. For example, aspects of the specification 171 may be received through interaction of a user 12 with a GUI of the ESD manager 110. Alternatively, or in addition, aspects of the specification 171 may be retrieved from DSR resources 104-2 of the computing device 102, an electronic communication network, and/or the like. For example, power requirements of one or more components utilized in the application 170 (e.g., a load 176, such as a motor), may be retrieved from the datastore 114 and/or other data source, e.g., data source managed by a manufacturer or supplier of the load 176.

The analysis module 116 may be configured to manage implementation of application 170 by ESD 105. Managing the implementation of an application 170 by an ESD 105 may comprise a) utilizing the aging model 120 of the ESD 105 to determine an operation (OP) policy 150 for the ESD 105 within the application 170, and b) configuring the application 170 to utilize the ESD 105 in accordance with the OP policy 150.

The OP policy 150 may be configured to control aspects of the operating conditions of the ESD 105 within the application 170. The OP policy 150 may define “target operating conditions” for the ESD 105 within the application 170. As used herein, “target operating conditions” for an ESD 105 in an application 170 may comprise and/or refer to operating conditions under which the ESD 105 is predicted to satisfy requirements of the application 170. For example, target operating conditions may comprise and/or refer to operating conditions under which the maximum extent of performance degradation predicted to be incurred by the ESD 105 satisfies a threshold, e.g., operating conditions wherein Mₜₒₜₐₗ<M_{threshold}, where Mₜₒₜₐₗ is a quantity configured to predict the maximum extent of performance degradation predicted to be incurred by the ESD 105 under the operating conditions and M_{threshold} is configured to limit such performance degradation (e.g., per a performance requirement of the application 170), as disclosed in further detail herein. Alternatively, or in addition, target operating conditions may comprise and/or refer to operating conditions under which performance degradation incurred by the ESD 105 is predicted to remain below a threshold for a specified usage period, e.g., ψₜₒₜₐₗ(tₗ)<ψ_{threshold}, where ψₜₒₜₐₗ(t) is a function configured to model the rate at which performance degradation is predicted to be incurred by the ESD 105 over time (e.g., predict degradation to an ESD performance characteristic, such as capacity), ψ_{threshold} specifies a lower bound for the ESD performance characteristic and tₗ is a longevity threshold (e.g., per an endurance requirement of the application 170), as disclosed in further detail herein.

As disclosed herein, the OP policy 150 determined for the ESD 105 may be configured to specify target operating conditions for the ESD 105 within the application 170. Accordingly, configuring the application 170 to operate the ESD 105 in accordance with the OP policy 150 may comprise configuring the application 170 to utilize the ESD 105 such that the operating conditions of the ESD 105 within the application 170 correspond with the target operating conditions of the OP policy 150.

Configuring the application 170 to utilize the ESD 105 in accordance with the OP policy 150 may comprise generating an ESD configuration (ESD CFG) 160. The ESD CFG 160 may be configured to control utilization of the ESD 105 by application components such that the operating conditions of the ESD 105 in the application 170 correspond with the target operating conditions of the OP policy 150. The ESD CFG 160 may comprise any suitable means for controlling, regulating, advising, limiting, and/or otherwise managing ESD operations implemented by and/or within the application 170 (operations implemented by the ESDA system 172 and/or components thereof, such as the ESD module 174 or the like), which may include, but are not limited to: machine-readable data, configuration data, firmware, instructions, machine-readable instructions, code, machine-readable code, computer-readable code, a script, settings, parameters, limits, thresholds, and/or the like.

The ESD CFG 160 may comprise a charge configuration 164 configured to manage aspects of charge operations to be performed on the ESD 105 in the application 170, e.g., manage charge operations implemented by a charge module 174-1 of the application 170. The charge configuration 164 may be configured to cause the charge module 174-1 to implement charge operations in accordance with the charge policy 154 determined for the ESD 105. In other words, the charge configuration 164 may be configured to cause the charge module 164-1 to implement charge operations having charge conditions corresponding to the target charge conditions of the OP policy 150. The charge configuration 164 may comprise any suitable means for controlling, regulating, advising, limiting, and/or otherwise managing aspects of a charge operation including, but not limited to: charge configuration data, charge commands, firmware, instructions, machine-readable code, computer-readable code, charge settings, charge parameters, charge thresholds, charge rate, end voltage (e.g., target voltage for the ESD 105 in the charge operation), and/or the like. The charge configuration 164 may be configured such that charge conditions of the ESD 105 in the application 170 correspond with the target charge conditions (and/or target charge model 134) of the OP policy 150 determined by the analysis module 116, e.g., target charge conditions of the charge policy 154.

Alternatively, or in addition, the ESD CFG 160 may comprise a discharge configuration 166 configured to manage aspects of discharge operations to be performed on the ESD 105 in the application 170, e.g., manage aspects of discharge operations implemented by a discharge module 174-2 of the application 170. The discharge configuration 166 may be configured to cause the discharge module 174-2 to implement discharge operations in accordance with the discharge policy 156 determined for the ESD 105. In other words, the discharge configuration 166 may be configured to cause the discharge module 164-2 to implement discharge operations having discharge conditions corresponding to the target discharge conditions of the OP policy 150. The discharge configuration 166 may comprise any suitable means for managing a discharge operation, including, but not limited to: discharge configuration data, discharge commands, firmware, instructions, machine-readable code, computer-readable code, discharge settings, discharge parameters, discharge thresholds (e.g., specify a maximum discharge rate for the ESD 105), and/or the like. The discharge configuration 166 may be configured such that discharge conditions of the ESD 105 in the application 170 correspond with the target discharge conditions (and/or target discharge model 134) of the OP policy 150 determined by the analysis module 116, e.g., target discharge conditions of the discharge policy 154.

As disclosed herein, the ESD manager 120 may be configured predict ESD performance degradation by use of, inter alia, ESD aging models 120. The aging model 120 of an ESD 105 may be configured to a) predict an extent of performance degradation to be incurred by an ESD 105 under specified operating conditions, and/or b) predict the rate at which such performance degradation will be incurred by the ESD 105 over time.

In some implementations, the aging model 120 may predict the maximum extent of age-related degradation to be incurred by the ESD 105 under specified operating conditions as, Mₜₒₜₐₗ=M_{oc}+M_{bl}, where Mₜₒₜₐₗ represents the total or full extent of performance degradation predicted to be incurred by the ESD 105 under the specified operating conditions (e.g., a specified OC model 130), which may comprise a sum of the maximum extent of performance degradation attributable operating-condition-related aging (ORA) mechanisms (M_{oc}) and a baseline performance degradation quantity (M_{bl}). The M_{bl} quantity may be configured to model performance degradation attributable to non-ORA mechanisms, e.g., model performance degradation attributable to aging mechanisms that are independent of and/or unrelated to ESD operating conditions. The M_{oc} quantity for an ESD 105 under a specified set of operating conditions (OCₖ) may be modeled as M_{oc}=M_{OC}⁰f_{SoC}(OCₖ), where M_{OC}⁰ is the theoretical maximum extent of performance degradation that can be attributed to ESD operating conditions and f_{SoC}(OCₖ) is a function configured to model the extent of performance degradation predicted to be incurred by the ESD 105 under a specified set of operating conditions (OCₖ). In other words, M_{OC}⁰ may comprise a kinetic and thermodynamic term quantifying the theoretical maximum extent of aging predicted to emerge over abundant time (e.g., years) under a range of operating conditions, whereas Moe represents the maximum extent of aging predicted to occur under a specified set of operating conditions.

By way of further illustration, FIG. 1B comprises a plot 180 depicting an aging model 120. The aging model 120 may be configured to predict capacity loss to be incurred by the ESD 105 under specified operating conditions (e.g., operating conditions of an OC model 130). In the FIG. 1B example, the aging model 120 may predict that a capacity of the ESD 105 will fall from X Ahr to X-L Ahr under the specified operating conditions, where a capacity loss of L Ahr represents the Mₜₒₜₐₗ quantity predicted for the OC model 130. Therefore, when the ESD 105 exhibits a capacity of about X Ahr, the ESD 105 has incurred about 0% of Mₜₒₜₐₗ, and when the ESD 105 falls to a capacity of about X-L Ahr, the ESD 105 has incurred about 100% of Mₜₒₜₐₗ. As illustrated in FIG. 1B, about 90% of Mₜₒₜₐₗ is attributable operating conditions of the ESD 105 (e.g., M_{OC} is about 0.9 Mₜₒₜₐₗ) and about 10% is attributable to baseline aging (M_{bl}).

As disclosed in further detail herein, the Mₒₚ quantity may comprise a sum of performance degradation attributable to a plurality of aging mechanisms, e.g., Mₒₚ=ΣⱼMⱼ, where Mⱼ represents the maximum extent of performance degradation attributable to respective aging mechanisms. The aging model 120 may be configured to model performance degradation attributable to any suitable aging mechanism and/or conditions including, but not limited to: charge-related aging (CRA) mechanisms (e.g., charge conditions), discharge-related aging (DRA) mechanisms (e.g., discharge conditions), and so on. For example, the Mₒₚ quantity predicted for a specified set of operating conditions may be modeled as Mₒₚ=M_{ch}+M_{d}, where M_{ch} is a quantity configured to predict the maximum extent of performance degradation attributable to CRA mechanisms (e.g., charge conditions) and M_{d} is a quantity configured to predict the maximum extent of performance degradation attributable to CRA mechanisms (e.g., discharge conditions).

In some implementations, the aging model 120 may be further configured to distinguish aging attributable to ESD charge conditions (e.g., CRA mechanisms) from aging attributable to ESD discharge conditions (e.g., DRA mechanisms). FIG. 1C illustrates another example of an aging model 120. The plot 181 of the FIG. 1C example, illustrates an aging model 120 configured to predict performance degradation attributable to charge conditions (M_{ch}) and discharge conditions (M_{d}) under specified operating conditions (e.g., an OC model 130). As in the FIG. 1B example, the aging model 120 may predict a drop in ESD capacity from about X Ahr to about X-L Ahr, e.g., predict an Mₜₒₜₐₗ of about L Ahr. The aging model 120 may be further configured to predict the relative contributions of respective aging mechanisms. In the FIG. 1B example, the aging model 120 may predict that about 60% of Mₜₒₜₐₗ is attributable to charge conditions (e.g., M_{ch}≅0.6 Mₜₒₜₐₗ or 0.6 L Ahr) and about 30% is attributable to discharge conditions (e.g., M_{d}≅0.3 Mₜₒₜₐₗ or 0.3 L Ahr). The aging model 120 may, therefore, indicate that the charge conditions of the OC model 130 are a more significant source of aging that the discharge conditions, e.g., the charge conditions are more strenuous than the discharge conditions.

The aging model 120 may be further configured to model the rate at which the maximum extent of age-related performance degradation (M_{Total}) predicted for a specified set of operating conditions will be incurred by the ESD 105 over time, e.g., model an age-related degradation rate (ψₜₒₜₐₗ) and/or model a rate of age-related degradation attributable to respective operating conditions (ψ_{OP}). The aging model 120 may be further configured to model the rate of respective aging mechanisms. As disclosed in further detail herein, the aging model 120 may model ψₜₒₜₐₗ as a combination of CRA rate (ψ_{ch}) and a DRA rate (ψ_{d}).

As disclosed herein, in some implementations, the ESD manager 110 may be configured to develop aging models 120 adapted to model charge-related aging and/or distinguish performance degradation attributable to charge-related aging mechanisms (e.g., charge conditions) from performance degradation attributable to other, non-charge-related aging (NCR) aging mechanisms. For example, the aging model 120 developed for an ESD 105 may be configured to distinguish the maximum extent and/or rate of charge-related aging incurred under respective operating conditions (M_{ch} and/or ψ_{ch}) from the maximum extent and/or rate of performance degradation attributable to NCR aging mechanisms, e.g., M_{ncr} and/or ψ_{ncr}. The aging model 120 may be configured to model the M_{ch} quantity as a fraction or percent of an M_{ch}^{o} quantity determined for the ESD 105. The M_{ch}^{o} quantity may represent a maximum extent of performance loss attributable to charge conditions, e.g., may represent a theoretical maximum space wherein additional performance loss (aging) can occur due to the collective charge conditions. The M_{ch}^{o} term may be expressed as a fraction or percent of the total extent of performance loss incurred by the ESD 105 over time (Mₜₒₜₐₗ); e.g., M_{ch}^{o}=1−{M_{ncr}}, or M_{ch}^{o}=100%−{M_{ncr}}, where M_{ncr} represents a fraction or percentage of total performance loss (Mₜₒₜₐₗ) attributable to non-charge-related aging mechanisms, such as discharge-related aging (M_{d}), baseline or non-ORA mechanisms (M_{bl}), and/or the like, as disclosed herein. While 100% is used as a maximum amount of allowable performance loss, in real terms the extent of performance degradation incurred by the ESD 105 will likely be less due to thermodynamic processes that limit the extent of the reactions involved in the CRA mechanisms of the ESD 105.

Alternatively, or in addition, the ESD manager 110 may be configured to develop aging models 120 adapted to model aging attributable to DRA mechanisms and/or distinguish discharge-related aging from other, non-discharge-related (NDR) aging. For example, the aging model 120 of an ESD 105 may be configured to predict the extent of performance degradation to be incurred by the ESD 105 due to DRA mechanisms (M_{d}) under respective operating conditions and/or model the rate at which M_{d} will be incurred by the ESD 105 over time (ψ_{d}). The aging model 120 may be further configured to distinguish discharge-related aging from NDR aging, e.g., distinguish (M_{d} and/or ψ_{d}) from the maximum extent and/or rate of performance degradation attributable to NDR aging mechanisms (M_{ndr} and/or ψ_{ndr}). The aging model 120 may be configured to model the M_{d}^{o} quantity as a fraction or percent of an M_{d}^{o} quantity determined for the ESD 105. The M_{d}^{o} quantity may represent a maximum extent of performance loss attributable to discharge conditions, as disclosed herein. The M_{d}^{o} term may be expressed as a fraction or percent of the total extent of performance loss incurred by the ESD 105 over time (Mₜₒₜₐₗ); e.g., M_{d}^{o}=1−{M_{ndr}}, or M_{d}^{o}=100%−{M_{ndr}}, where M_{ndr} represents a fraction or percentage of total performance loss (Mₜₒₜₐₗ) attributable to non-discharge-related aging mechanisms, such as charge-related aging (M_{ch}), baseline or non-ORA mechanisms (M_{bl}), and/or the like, as disclosed herein. Again, although 100% is used as a maximum amount of allowable performance loss, in real terms the extent of performance degradation incurred by the ESD 105 will likely be less due to thermodynamic processes that limit the extent of the reactions of the DRA mechanisms of the ESD 105.

Alternatively, or in addition, the ESD manager 110 may be configured to develop aging models 120 configured to model age-related degradation attributable to multiple aging mechanisms, e.g., model charge-related aging, discharge-related aging, and/or the like. The aging model 120 may be configured to distinguish charge-related aging from NCR aging (e.g., discharge-related aging) and/or distinguish discharge-related aging from NDR aging (e.g., charge-related aging). In other words, the aging model 120 may be configured to model the extent of age-related degradation to be incurred by the ESD 105 under specified operating conditions (Mₜₒₜₐₗ or M_{OC}) as combination of: a) M_{ch} attributable to charge-related degradation (e.g., charge conditions) and b) M_{d} attributable to discharge-related degradation (e.g., discharge conditions). The aging model 120 may be further configured to model the rate at which the predicted extent the age-related degradation will be incurred over time as a combination of: a) ψ_{ch} attributable to charge-related degradation (e.g., charge conditions) and b) ψ_{d} attributable to discharge-related degradation (e.g., discharge conditions). The aging model 120 may, therefore, be configured to model temporal characteristics of a plurality of aging mechanisms, e.g., model total or overall temporal aging ψₜₒₜₐₗ as ψ_{ch}+ψ_{d}.

As disclosed herein, the M_{ch} quantity determined for an ESD 105 under operating conditions specified by an OC model 130 may define an upper bound of charge-related performance degradation predicted to be incurred by the ESD 105 over time. The ESD manager 110 may be configured to predict the M_{ch} quantity for a specified charge conditions (e.g., charge operations of an OC model 130), as follows:

$${M}_{c h} = {M}_{c h}^{o} {f}_{ch \_ SoC} [ 1 - exp ( - {{α}_{c h} ( \frac{2 {r}_{c h}}{{r}_{ch \_ max}} )}^{\frac{1}{{b}_{ch}}} ) ] \qquad Eq . 1$$

$${f}_{ch \_ SoC} = \frac{{b}_{c h}}{2} ( 1 + {( {c}_{c h} * {d}_{c h} )}^{\frac{1}{2}} ) \qquad Eq . 2$$

$${b}_{c h} = \frac{( {V}_{max} - {V}_{min} )}{\frac{1}{2} ( {V}_{max} + {V}_{min} )} {( \frac{{V}_{ch \_ end} - {V}_{min}}{{V}_{max} - {V}_{ch \_ end} + {Δ V}_{pol}} )}^{\frac{1}{{V}_{c h}}} \qquad Eq . 3$$

$${c}_{c h} = \frac{( {V}_{ch \_ end} - {V}_{ch \_ start} )}{( {V}_{ch \_ end} - {V}_{min} )} \qquad Eq . 4$$

$${d}_{c h} = \frac{{V}_{ch \_ end}}{{V}_{max}} \qquad Eq . 5$$

$${α}_{c h} = {f}_{T} ( \frac{{T}_{ref}}{{T}_{c h}} ) \qquad Eq . 6$$

As illustrated in Eq. 1-6, the extent of CRA predicted to be incurred by the ESD 105 under an OC model 130 (M_{ch}) may be derived from characteristics of the ESD 105 and/or charge conditions of the OC model 130 (e.g., discharge model 134), such as: an M_{ch}^{o} quantity determined for the ESD 105, the charge rate (r_{ch}) of the modeled charge operation (e.g., expressed in terms of ESD capacity, such as a C-rate or the like), a maximum charge rate (r_{ch_max}) of the ESD 105, a maximum voltage (Vₘₐₓ) of the ESD 105, a minimum voltage of the ESD 105 (Vₘᵢₙ), a start voltage (V_{ch_start}) of the modeled charge operation (e.g., a voltage of the ESD 105 and/or respective cells at a start of the modeled charge operation), an target or end voltage (V_{ch_end}) of the modeled charge operation, a polarization offset parameter (ΔVₚₒₗ) determined for the ESD 105 (e.g., a value on the order of 0.01V, which may be a function of aging of the type of cells comprising the ESD 105), and a material and temperature parameter α_{ch}. The α_{ch} term may be a function of the temperature of the ESD 105 in the modeled charge operation (T_{ch}) and a reference temperature of the ESD 105 (T_{ref}), which may correspond to materials used to construct components of the specified ESD 105, such as the anode, or the like.

Parameters such as maximum charge rate (r_{ch_max}), maximum voltage (Vₘₐₓ), minimum voltage (Vₘᵢₙ), polarization offset parameter (ΔVₚₒₗ), and reference temperature (T_{ref}) may comprise and/or be derived from characteristics of the ESD 105, e.g., may comprise and/or be derived from ESD-specific characteristics. In some implementations, ESD-specific characteristics for respective ESD 105 (and/or ESD types) may be retrieved and/or maintained within the datastore 114, e.g., may be maintained within respective ESD profiles 115, as disclosed herein. Alternatively, or in addition, ESD-specific characteristics may be retrieved from manufacturer guidelines, determined based on ESD characteristics (e.g., cell chemistry, materials comprising respective components of the ESD 105, such as the anode, cathode, and/or the like), may be learned through testing and experience, and/or the like.

The M_{ch}^{o} quantity determined for the ESD 105 may be configured to quantify the maximum net theoretical extent of ESD aging that can be attributed to CRA mechanisms of the ESD 105. In other words, the M_{ch}^{o} term may comprise an ESD-specific value quantifying the theoretical maximum extent of charge-related aging to be incurred over abundant time (e.g., years) under a range of charge conditions. By contrast, the M_{ch} quantity determined for an OC model 130 may be configured to quantify the maximum extent of CRA predicted to be incurred by the ESD 105 under a specified set of charge conditions (e.g., charge conditions of the OC model 130). For example, M_{ch}(OC) may represent the maximum extent of performance degradation predicted to be incurred by the ESD 105 under operating conditions (OC), which may be expressed as a percentage or fraction of M_{ch}^{o}.

In some implementations, parameters of the aging model 120 may be expressed in terms of voltage potential. For example, the b_{ch}, c_{ch}, and d_{ch} parameters of Eq. 1-6 may represent a difference between the initial voltage of the ESD 105 (V_{ch_start}) and the target, end voltage (V_{ch_end}) of the ESD 105 in the modeled charge operation. The disclosure is not limited in this regard, however. In some implementations, the aging model 120 may be configured to express these types of parameters as scaled SoC quantities rather than voltage potentials. For example, scaled SoC quantities, e.g., scaled SoC quantities between 0 and 1, may be utilized to derive the b_{ch}, c_{ch}, and d_{ch} term in place of V_{ch_start}, V_{ch_end}, and/or the like. Conversions between voltage and equivalent SoC quantities (voltage to SoC conversions) may be unique to respective ESD 105 (and/or ESD types). A voltage to SoC conversion may specify any suitable relationship between voltage and SoC (or vice versa), including, but not limited to a proportional relationship, a linear relationship, an exponential relationship, a non-linear relationship, and/or the like.

In some examples, the ESD manager 110 may be configured to determine whether to express the b_{ch}, c_{ch}, d_{ch} and/or other parameters of the aging model 120 of an ESD 105 in terms of voltage, SoC, or the like based on characteristics of the ESD 105. By way of non-limiting example, lithium-ion ESD 105 having lithiated iron phosphate/graphite (LFP/Gr) chemistries may exhibit relatively flat voltage regions. In response to analyzing an ESD 105 exhibiting such flat voltage regions, the ESDM module 112 may construct an aging model 120 for the ESD 105 using b_{ch}, c_{ch}, and d_{ch} quantities expressed in terms of SoC, which may show more appreciable change and, as such, may convey more information than a model utilizing voltage quantities.

In some implementations, the ESD manager 110 may be configured to model charge operations comprising a single operation or step, e.g., as illustrated in Eq. 1-6. The disclosure is not limited in this regard, however, and could be adapted to model charge-related aging associated with other types of charge operations, including multi-step charge operations. As used herein, a multi-step charge operation may comprise and/or refer to a charge operation comprising two or more steps, each step having respective charge conditions. By way of non-limiting example, the M_{ch} quantity for a two-step charge operation may be modeled as follows:

$${M}_{ch} = {M}_{ch}^{o} \{ {{x}_{ch\_t 1} ( {f}_{SOC \_ 1} [ 1 - exp ( - {{α}_{ch \_ 1} ( \frac{2 {r}_{ch \_ 1}}{{r}_{ch\_max}} )}^{\frac{1}{{b}_{ch\_ 1}}} ) ] )}_{1} + {{x}_{ch \_ t 2} ( {f}_{{SOC}_{2}} [ 1 - exp ( - {{α}_{ch \_ 2} ( \frac{2 {r}_{ch \_ 2}}{{r}_{ch\_max} )} )}^{\frac{1}{{b}_{ch \_ 2}}} ) ] )}_{2} \} \qquad Eq . 7$$

In Eq. 7, x_{ch_t1} and x_{ch_t2} are relative time portions of the charge operation occupied by charge steps 1 and 2, respectively. Charge step 1 may comprise charging an ESD 105 from a specified start voltage V_{ch_start_1} to a target, end voltage of the step (V_{ch_end_1}), where V_{ch_start_1}<V_{ch_end_1}<V_{ch_end}. The interim voltage of the ESD 105 at the end of step 1 (V_{ch_end_1}) may be used as the value of V_{ch_start_2} for the second charge step, which may be configured to charge the ESD 105 to the target, end voltage of the charge operation (V_{ch_end}, where V_{ch_start_2}<V_{ch_end_2}≈V_{ch_end}). As disclosed herein, each step of the multi-step charge operation may utilize respective parameters and, as such, subject the ESD 105 to respective charge conditions. For example, the charging rates r_{ch_1} and r_{ch_2} may vary between charge steps 1 and 2 and so on.

The approach illustrated in Eq. 7 may be applied to model charge-related aging imposed by charge operations comprising any number of charge steps. The aging model 120 may be configured to predict the maximum extent of charge-related aging (M_{ch}) for a charge model 134 configured to model an N-step charge operation, as follows:

$${M}_{ch} = {M}_{ch}^{o} \{ {{\sum }^{N}}_{i} {{x}_{ch\_ti} ( {f}_{ch\_SoC \_i} [ 1 - exp ( - {{α}_{ch\_i} ( \frac{2 {r}_{ch\_i}}{{r}_{ch\_max}} )}^{\frac{1}{{b}_{ch\_i}}} ) ] )}_{i} \} \qquad Eq . 8$$

$${f}_{ch\_SoC \_i} = \frac{{b}_{i}}{2} ( 1 + {( {c}_{i} * {d}_{i} )}^{\frac{1}{2}} ) \qquad Eq . 9$$

$${b}_{ch\_i} = \frac{( {V}_{max} - {V}_{min} )}{\frac{1}{2} ( {V}_{max} - {V}_{min} )} {( \frac{{V}_{ch\_end \_i} - {V}_{min}}{{V}_{max} - {V}_{ch\_end \_i} + Δ {V}_{pol}} )}^{\frac{1}{{V}_{ch\_i}}} \qquad Eq . 10$$

$${c}_{ch\_i} = \frac{( {V}_{ch\_end \_i} - {V}_{ch\_start \_i} )}{( {V}_{ch\_end \_i} - {V}_{min} )} \qquad Eq . 11$$

$${d}_{ch\_i} = \frac{{V}_{ch\_end \_i}}{{V}_{max}} \qquad Eq . 12$$

$${α}_{ch\_i} = {f}_{T} ( \frac{{T}_{ref}}{{T}_{ch\_i}} ) \qquad Eq . 13$$

As illustrated in Eq. 8-13, the M_{ch} predicted for an N-step charge operation may be a function of, inter alia, the charge conditions of respective charge steps. Accordingly, the OC model 130 may specify a set of N charge conditions, each defining charge conditions for a respective charge step. For example, the charge conditions for charge step i may define: a duration of the charge step (x_{ch_ti}); a voltage of the ESD 105 (and/or respective cells of the ESD 105) cell at the start of the charge step (x_{ch_start_i}); the target or end voltage of the charge step (V_{ch_end_i}), the charge rate during the charge step (r_{ch_i}), a temperature of the ESD 105 during the discharge step (T_{ch_i}), and so on. In some implementations, SoC quantities (e.g., values between 0 and 1) may be used in place of step-specific voltage quantities, such as V_{ch_start_i} and/or V_{ch_end_i}, as disclosed herein.

The aging model 120 may be further configured to model charge-related performance degradation attributable to charge rest periods between respective charge steps (e.g., rest periods between adjacent charge operations). As used herein, a “rest period” of an ESD 105 may comprise and/or refer to a time interval wherein there is cessation of active charging and/or discharging of the ESD 105 within typical duty cycle conditions. In other words, a rest period may comprise a period during which the SoC of the ESD 105 is substantially constant, e.g., substantially no charge or discharge current is enacted to/from the ESD 105 that would alter the present-time SoC of the ESD 105. For example, a rest period may comprise and/or refer to a condition wherein the ESD 105 is placed in an open-circuit voltage (OCV) state and/or is maintained at a substantially constant SoC by application of a nominal current, e.g., a “trickle charge,” “taper charge,” or the like.

The time spent at respective SoC (and/or interim V_{ch_end_i}) during multi-step charge operations may influence the extent and/or rate of charge-related aging incurred by the ESD 105. The extent and/or rate of aging during rest periods may be independent of the cycling rate or the number of preceding charge steps. The OC model 130 for an N-step charge operation comprising rest periods may be configured to model conditions that correlate with aging during such rest periods, such as SoC, temperature, rest period duration, and so on.

In some implementations, the aging model 120 may be configured to model aging contributions of charge and rest-period conditions, which may have same and/or overlapping mechanistic outcomes. The extent of charge-related aging (M_{ch}) incurred by the ESD 105 may be modeled as a combination of: (A_{ch}) charge conditions on the ESD 105 during respective charge steps, and (B_{ch}) conditions during rest-periods between respective steps, which may reside within the same general category of aging mechanisms, e.g., charge-related aging mechanisms that impact the anode of the ESD 105. As such, the outcomes of A_{ch} and B_{ch} may not be strictly additive, but may be super-positional in part, where the greater of the two will dominate the resulting M_{ch} quantity. The ESD manager 110 may, therefore, configure the aging model 120 to avoid “double-counting” the effects of aging by two or more sets of linked conditions that contribute to the same aging mechanisms (e.g., avoid double counting aging due to charge conditions and/or corresponding rest-period conditions), as follows:

$${M}_{ch} = {M}_{ch}^{o} \{ \begin{matrix}{{x}_{ch\_t 1} ( {f}_{{ch\_SoC}_{1}} [ 1 - exp ( - {{α}_{ch \_ 1} ( \frac{2 {r}_{ch \_ 1}}{{r}_{ch\_max}} )}^{\frac{1}{{b}_{ch \_ 1}}} ) ] )}_{1} + \\ {y}_{ch\_t 3} {( {g}_{ch \_ 3} * exp ( \frac{1}{{α}_{ch \_ 3}} ( 1 - \frac{1}{{b}_{ch \_ 3}} ) ) )}_{3} + \\ {x}_{t 2} {( {f}_{{ch\_SoC}_{2}} [ 1 - exp ( - {{α}_{ch \_ 2} ( \frac{2 {r}_{ch \_ 2}}{{r}_{ch\_max}} )}^{\frac{1}{{b}_{ch \_ 2}}} ) ] )}_{2} + \\ {{y}_{ch\_t 4} ( {g}_{ch \_ 4} * exp ( \frac{1}{{α}_{ch \_ 4}} ( 1 - \frac{1}{{b}_{ch \_ 4}} ) ) )}_{4}\end{matrix} \} \qquad Eq . 14$$

In Eq. 14, the M_{ch} quantity represents the maximum extent to which a specified ESD 105 is predicted to age under multi-step charge operations comprising rest periods, e.g., aging attributable to charge conditions during respective charge steps (A_{ch}) and conditions during respective rest periods (B_{ch}). The x_{ch_t1} and x_{ch_t2} parameters are the relative time proportions of total charge time occupied by charge steps 1 and 2, respectively. The y_{ch_t3} parameter is the proportion of time spent in a rest period between charge steps 1 and 2 compared to the combined charge steps 1 and 2 (or any N number of steps). The y_{ch_t4} parameter is the proportion of time spent in a rest period after step 2 (or final charge step N) compared to the combined charge steps 1 and 2 (or any N number of steps). The parameters g_{ch_t3} and g_{ch_t4} may comprise ESD-specific parameters corresponding to the temperature-sensitivity of the materials comprising the ESD 105 (e.g., cathode and anode) in terms of aging, e.g., may comprise and/or be derived from ESD-specific characteristics defined within, inter alia, a profile 115 of the ESD 105, as disclosed herein. Elevated temperatures that might exist during the indicated rest periods would cause accelerated aging and be accounted for in the magnitude of g_{ch_t3} and g_{ch_t4} . . . g_{ch_tn}. The charge steps x_{ch_t1} . . . x_{ch_tn} may sum to unity, whereas the y_{ch_t} term may be independent but defined relative to x_{ch_t1} . . . x_{ch_tn}. By way of non-limiting example, if steps 1 and 2 were each 2 hours, and the rest period were 8 hours, the x_{ch_t1} and x_{ch_t2} terms of Eq. 14 would be 0.5, and the y_{ch_t3} term would be 4. Although Eq. 14 is defined in terms of rest periods of a two-step charge operations, the disclosure is not limited in this regard and could be adapted to incorporate aging models 120 configured to model charge operations having any number of charge steps and/or rest periods.

FIG. 1D is a schematic block diagram illustrating an example of an OC model 130 configured to model operating conditions of an N-step charge operation comprising one or more rest periods. The OC model 130 illustrated in FIG. 1D may comprise N charge step models 135, e.g., charge step models 135-1 through 135-N. The charge step models 135 may be configured model charge conditions during respective charge steps and corresponding optional rest periods (e.g., rest periods that follow and/or proceed respective charge steps).

FIG. 1D further illustrates an example of a ESD CFG 160 corresponding to the OC model 130. The ESD CFG 160 may comprise a charge configuration 164 configured to manage implementation of the N-step charge operation defined by the charge model 134. The charge configuration 164 may comprise machine-readable instructions configured cause a charging device to implement N-step charge operations in accordance with the charge model 134, e.g., configure the charge module 174-1 of an application 170 to implement N-step charge operations per the charge model 134. In some implementations, the ESD CFG 160 may further comprise a discharge configuration 166 configured to manage discharge conditions of the ESD 105, as disclosed in further detail herein.

In the FIG. 1E example, the OC model 130 may comprise N charge step models 135, which may be configured to characterize the charge and/or rest conditions of the ESD 105 during respective charge steps of the N-step charge operation of the OC model 130. For example, the charge step model 135-i may be configured to model a charge step having a specified duration (x_{ch_ti}), charge rate (r_{ch_i}), end voltage (V_{ch_end_i}), and so on. The charge step model 135-i may be further configured to model an optional rest period implemented before or after the charge step, e.g., may specify a duration (y_{ch_end_i}) of the rest period, ESD voltage during the rest period, and so on. Accordingly, in the FIG. 1D example, the charge configuration 164 may comprise N charge step configurations 155 (e.g., charge step configurations 155-1 through 155-N), each configured to cause the charge module 174-1 (or other charging device) to implement a respective step of the N-step charge operation. The charge step configurations 155 may be derived from corresponding charge step models 135. For example, the charge configuration 155-i may be configured to cause the charge module 174-1 to implement a charge step having charge and/or rest conditions specified by charge step model 135-i. The charge configuration 155-i may be configured to cause the charge module 174-1 to implement a charge operation having the duration (x_{ch_i}), charge rate (r_{ch_i}), and target charge voltage (V_{ch_i}) specified by the charge step model 135-i. The charge configuration 155-i may be further configured to cause the charge module 174-1 to implement a rest period having the duration specified by the charge step model 135-i (e.g., y_{ch_i}), and so on.

In some implementations, the aging model 120 may be further configured to model temporal characteristics of the charge-related performance degradation predicted to be incurred by the ESD 105. The aging model 120 may, for example, be configured to predict the rate at which M_{ch} will be incurred over time under specified operating conditions. The ESD manager 110 may be configured to model the extent and/or rate of ESD aging using any suitable technique. Byway of non-limiting example, the ESD manager 110 may be configured to model temporal characteristics of charge-related aging using sigmoid functions and/or sigmoid rate expressions, as illustrated below:

$${φ}_{ch} ( t ) = {M}_{ch}^{′} + 2 ( {M}_{ch} - {M}_{ch}^{′} ) [ \frac{1}{2} - \frac{1}{1 + exp ( {( {p}_{ch} t )}^{{q}_{ch}} )} ] \qquad Eq . 15$$

In Eq. 15, ψ_{ch}(t) may be configured to model a charge-related aging trend of one or more ESD performance characteristics as a function of time (t), e.g., predict degradation to ESD capacity, discharge rate, and/or the like. The M_{ch}′ parameter of Eq. 14 may quantify the extent of charge-related aging due to charging at time zero, which may be substantially 0 for newly fabricated ESD 105. Alternatively, the M_{ch}′ parameter may quantify charge-related aging of a repurposed ESD 105. As disclosed herein, the M_{ch} term may quantify the maximum extent of charge-related aging predicted to be incurred by the ESD 105 under specified charge conditions, as disclosed herein. The p_{ch} and q_{ch} terms of Eq. 15 may model the rate at which charge-related aging occurs over time (e.g., model the rate at which the ESD 105 is predicted to approach M_{ch} over time). In some examples, the p_{ch} and q_{ch} terms may model reaction rates of the ESD 105, which may correspond to the cell chemistry of the ESD 105. The p_{ch} term may correspond to an equivalent intrinsic rate constant for CRA mechanisms of the ESD 105, and the q_{ch} term may correspond to an equivalent intrinsic kinetic order of the CRA mechanisms. The p_{ch} and/or q_{ch} terms may indicate the sensitivity of the ESD 105 to specified charge conditions. As disclosed in further detail herein, in some implementations, the ESD manager 110 may be configured to learn the p_{ch} and/or q_{ch} terms for respective ESD 105 (and/or operating conditions) through, inter alia, regression analysis of ESD aging data (e.g., through testing, experience, and/or analysis).

The operating conditions of the ESD 105 in an application 170 may change over time. The operating conditions may change due to a number of different factors including, but not limited to environmental conditions (e.g., ambient temperature), operational factors (e.g., usage of the ESD 105 within the application 170, such as the use of higher than predicted charge rates, discharge rates), and so on. As disclosed herein, changes to the operating conditions of the ESD 105 may result in corresponding changes to the age-related performance degradation incurred by the ESD 105. Changes to the operating conditions of the ESD 105 may, for example, result in changes to the extent of age-related performance degradation to be incurred by the ESD 105 (e.g., Mₜₒₜₐₗ, M_{ch}, M_{d}, and/or the like) and/or the rate at which such degradation is incurred over time (ψₜₒₜₐₗ, ψ_{ch}, ψ_{d}, and/or the like).

In some implementations, the ESD manager 110 may be configured to develop aging models 120 configured to model ESD aging under changing operating conditions. The aging model 120 may be configured to predict aging incurred over a plurality of usage periods, each usage period having respective operating conditions (e.g., operating conditions characterized by a respective OC model 130). The aging model 120 of an ESD 105 may be configured to predict charge-related aging under variable charge conditions as follows:

$${φ}_{ch} ( t ) = {\sum }_{k = 1}^{Z} {M}_{ch}^{′} + 2 {( {M}_{ch\_k} - {M}_{ch}^{′} ) [ \frac{1}{2} - \frac{1}{1 + exp ( {( {p}_{ch\_k} t )}^{{q}_{ch\_k}} )} ]}_{k} \qquad Eq . 16$$

In Eq. 16, ψ_{ch}(t) is configured to model the extent and/or rate of charge-related aging incurred by the ESD 105 in each of Z usage periods. The charge conditions of respective usage periods k may be specified by respective charge models 134 and, as such, may result in respective CRA metrics, M_{ch_k}, p_{ch_k}, q_{ch_k}, and so on, which may be calculated as disclosed herein (e.g., in accordance with Eq. 1-16). The aging model 120 may, therefore, predict a cumulative performance loss (or performance degradation) to be incurred by the ESD 105 over the Z usage periods due to charge conditions of the respective usage periods.

As disclosed herein, the aging models 120 developed by the ESD manager 110 may be configured to predict performance degradation due to various ORA mechanisms, including discharge-related aging mechanisms of the ESD 105. The aging model 120 may be configured to predict the maximum extent of discharge-related aging (M_{d}) to be incurred by the ESD 105 under operating conditions of the respective OC models 130. The predicted extent of DRA predicted to be incurred under duty cycles comprising single-step discharge operations may be expressed as follows:

$${M}_{d} = {M}_{d}^{o} {f}_{d\_SoC} [ 1 - EXP ( - {{α}_{d} ( \frac{2 {r}_{d}}{{r}_{d\_max}} )}^{\frac{1}{{b}_{d}}} ) ] \qquad Eq . 17$$

$${f}_{d\_SoC} = \frac{{b}_{d}}{2} ( 1 + {( {c}_{d} * {d}_{d} )}^{\frac{1}{2}} ) \qquad Eq . 18$$

$${b}_{d} = \frac{( {V}_{max} - {V}_{min} )}{\frac{1}{2} ( {V}_{max} - {V}_{min} )} {( \frac{{V}_{d\_end} - {V}_{min}}{{V}_{max} - {V}_{d\_end} + Δ {V}_{pol}} )}^{\frac{1}{{V}_{disch}}} \qquad Eq . 19$$

$${c}_{d} = \frac{( {V}_{d\_start} - {V}_{d\_end} )}{( {V}_{d\_end} - {V}_{min} )} \qquad Eq . 20$$

$${d}_{d} = \frac{{V}_{d\_end}}{{V}_{max}} \qquad Eq . 21$$

$${α}_{d} = {f}_{T} ( \frac{{T}_{ref}}{{T}_{d}} ) \qquad Eq . 22$$

As illustrated in Eq. 17-22, the extent of DRA predicted to be incurred by the ESD 105 under an OC model 130 (M_{d}) may be derived from characteristics of the ESD 105 and/or discharge conditions of the OC model 130 (e.g., discharge model 134), such as: a discharge-related aging factor M_{d}^{o} determined for the ESD 105, discharge rate (r_{d}) of the modeled discharge conditions (e.g., expressed as a C-rate or the like), a maximum discharge rate (r_{d_max}) of the ESD 105, a maximum voltage (Vₘₐₓ) of the ESD 105, a minimum voltage (Vₘᵢₙ) of the ESD 105, a start voltage (V_{d_start}) for the modeled discharge operation (e.g., an initial voltage of the ESD 105 and/or respective cells), an end voltage (V_{d_end}) of the modeled discharge operation (e.g., voltage of the ESD 105 and/or cell(s) thereof at the end of discharge operation, where Vₘᵢₙ≤V_{d_end}<V_{d_start}), a polarization offset parameter (ΔVₚₒₗ) determined for the ESD 105, and a material and temperature parameter α_{d}. The α_{d} parameter may be a function of the temperature at which the discharge operations are to be performed (T_{d}) and a reference temperature (T_{ref}), which may correspond to materials used to construct components of the cells comprising the ESD 105, such as the anode, or the like as disclosed herein.

The maximum discharge rate (r_{d_max}), maximum voltage (Vₘₐₓ), minimum voltage (Vₘₐₓ), polarization offset parameter (ΔVₚₒₗ), and reference temperature (T_{ref}) may comprise ESD-specific parameters. As disclosed herein, ESD-specific parameters of the aging model 120 may be retrieved from and/or maintained within a datastore 114 (e.g., within a profile 115 of the ESD 105), may be derived from manufacturer guidelines, determined based on ESD characteristics, learned through testing and/or experience, and/or the like.

The M_{d}^{o} quantity determined for the ESD 105 may be configured to quantify the maximum net theoretical extent of ESD aging that can be attributed to DRA mechanisms of the ESD 105. In other words, the M_{d}^{o} term may comprise an ESD-specific value quantifying the theoretical maximum extent of discharge-related aging to be incurred over abundant time (e.g., years) under a range of discharge conditions. By contrast, the M_{d} quantity determined for an OC model 130 may be configured to quantify the maximum extent of DRA predicted to be incurred by the ESD 105 under a specified set of discharge conditions (e.g., discharge conditions of the OC model 130). For example, M_{d}(OC) may represent the maximum extent of performance degradation predicted to be incurred by the ESD 105 under operating conditions (OC), which may be expressed as a percentage or fraction of M_{d}^{o}.

In some implementations, parameters of the aging model 120 may be expressed in terms of voltage potential. For example, the parameters b_{d}, c_{d}, and d_{d} parameters of Eq. 17-22 may be based, at least in part, on ESD voltage potentials, e.g., an initial voltage of the ESD 105 (V_{d_start}) and a voltage of the ESD 105 at the end of the discharge operation (V_{d_end}). The disclosure is not limited in this regard, however. In some implementations, the aging model 120 may be configured to express these types of parameters as scaled SoC quantities rather than voltage potentials, as disclosed herein.

The ESD manager 110 may be further configured to predict the extent of DRA attributable to discharge conditions of multi-step discharge operations. The ESD manager 110 may develop aging models 120 configured to predict M_{d} for an OC model 130 configured to model a two-step discharge operation as follows:

$${M}_{d} = {M}_{d}^{o} \{ {{x}_{d\_t 1} ( {f}_{d\_SoC \_ 1} [ 1 - exp ( - {{α}_{d \_ 1} ( \frac{2 {r}_{d \_ 1}}{{r}_{d\_max}} )}^{\frac{1}{{b}_{d \_ 1}}} ) ] )}_{1} + {x}_{d\_t 2} {( {f}_{d\_SoC \_ 2} [ 1 - exp ( - {α}_{d \_ 2} {( \frac{2 {r}_{d \_ 2}}{{r}_{d\_max}} )}^{\frac{1}{{b}_{d \_ 2}}} ) ] )}_{2} \} \qquad Eq . 23$$

In Eq. 23, x_{d_t1} and x_{d_t2} are relative time portions occupied by discharge steps 1 and 2, respectively. Discharge step 1 (x_{d_t1}) may comprise discharging the ESD 105 from a specified start voltage V_{d_start} to an end voltage of the step (V_{d_end_1}), where V_{d_end}<V_{d_end_1}<V_{d_start}. The interim cell voltage at the end of the first discharge step (V_{d_1}) may be used as V_{d_start} for the second discharge step (x_{d_t2}), which may comprise discharging the ESD 105 to the end discharge voltage (V_{d_end}, where V_{d_start}>V_{d_end_1}>V_{d_end_2}≈V_{d_end}). Other discharge conditions may vary between discharge steps, e.g., the rate r_{d_1} at which the ESD 105 is discharged during the first discharge step (x_{d_t1}) may differ from the discharge rate r_{d_2} of the second discharge step (x_{d_t2}).

The approach illustrated in Eq. 23 may be applied to model discharge-related aging imposed by duty cycles (e.g., discharge conditions) comprising any suitable number of discharge steps. The aging model 120 may be configured to predict the maximum extent of discharge-related aging (M_{d}) imposed by N-step discharge operations, as follows:

$${M}_{d} = {M}_{d}^{o} \{ {{\sum }_{i}}^{N} {{x}_{d\_ti} ( {f}_{d\_SoC \_i} [ 1 - EXP ( - {{α}_{d\_i} ( \frac{2 {r}_{d\_i}}{{r}_{d\_max}} )}^{\frac{1}{{b}_{d\_i}}} ) ] )}_{i} \} \qquad Eq . 24$$

$${f}_{d\_SoC \_i} = \frac{{b}_{d\_i}}{2} ( 1 + {( {c}_{d\_i} * {d}_{d\_i} )}^{\frac{1}{2}} ) \qquad Eq . 25$$

$${b}_{d\_i} = \frac{( {V}_{max} - {V}_{min} )}{( {V}_{max} + {V}_{min} )} {( \frac{{V}_{d\_end \_i} - {V}_{min}}{{V}_{max} - {V}_{d\_end \_i} + Δ {V}_{pol}} )}^{\frac{1}{{V}_{d\_end \_i}}} \qquad Eq . 26$$

$${c}_{d\_i} = \frac{( {V}_{d\_start \_i} - {V}_{d\_end \_i} )}{( {V}_{d\_end \_i} - {V}_{min} )} \qquad Eq . 27$$

$${d}_{d\_i} = \frac{{V}_{d\_end \_i}}{{V}_{max}} \qquad Eq . 28$$

$${α}_{d\_i} = {f}_{T} ( \frac{{T}_{ref}}{{T}_{d\_i}} ) \qquad Eq . 29$$

As illustrated in Eq. 24-29, the extent of aging attributable to an N-step discharge operation (M_{d}) may be a function of the discharge conditions of respective steps. According, the corresponding OC model 130 (and/or discharge model 136) may specify a set of N discharge conditions, each defining discharge conditions for a respective discharge step. For example, the discharge conditions for a discharge step i may define: a duration of the discharge step; a voltage of the ESD 105 (and/or respective cells of the ESD 105) cell at the start of the discharge step (V_{d_start_i}); the end voltage of the discharge step (V_{d_end_i}), the discharge rate of the discharge step (r_{d_i}), a temperature of the ESD 105 during the discharge step (T_{d_i}), and so on. In some implementations, step-specific voltage quantities, such as V_{d_start_i} and/or V_{d_i} may be replaced with SoC quantities (e.g., values between 0 and 1), as disclosed herein.

In some implementations, the aging model 120 may be further configured to model age-related performance degradation attributable to multi-step discharge operations comprising one or more intervening rest periods (e.g., periods interposed between one or more discharge steps). The aging model 120 may be configured to model aging contributions of discharge and rest-period conditions, which may have same and/or overlapping mechanistic outcomes. The extent of discharge-related aging (M_{d}) incurred by the ESD 105 may be modeled as a combination of: (A_{d}) discharge conditions on the ESD 105 during respective discharge steps, and (B_{d}) conditions during rest-periods between respective discharge steps, which may reside within the same general category of aging mechanisms, e.g., discharge-related aging mechanisms that impact the anode of the ESD 105. As such, the outcomes of A_{d} and B_{d} may not be strictly additive, but may be super-positional in part, where the greater of the two will dominate the resulting M_{d} quantity. The ESD manager 110 may, therefore, configure the aging model 120 to avoid “double-counting” the effects of aging by two or more sets of linked conditions that contribute to the same aging mechanisms (e.g., avoid double counting aging due to discharge conditions and/or corresponding rest-period conditions), as follows:

$${M}_{d} = {M}_{d}^{o} \{ \begin{matrix}{x}_{d\_t 1} {( {f}_{{d\_SoC}_{1}} [ 1 - EXP ( - {{α}_{d \_ 1} ( \frac{2 {r}_{d \_ 1}}{{r}_{d\_max}} )}^{\frac{1}{{b}_{d \_ 1}}} ) ] )}_{1} + \\ {y}_{d\_t 3} {( {g}_{d \_ 3} * EXP ( \frac{1}{{α}_{d \_ 3}} ( 1 - \frac{1}{{b}_{d \_ 3}} ) ) )}_{3} + \\ {x}_{d\_t 2} {( {f}_{{d\_SoC}_{2}} [ 1 - EXP ( - {{α}_{d \_ 2} ( \frac{2 {r}_{d \_ 2}}{{r}_{disch\_max}} )}^{\frac{1}{{b}_{d \_ 2}}} ) ] )}_{2} + \\ {y}_{d\_t 4} {( {g}_{d \_ 4} * EXP ( \frac{1}{{α}_{d \_ 4}} ( 1 - \frac{1}{{b}_{d \_ 4}} ) ) )}_{4}\end{matrix} \} \qquad Eq . 30$$

In Eq. 30, the M_{d} quantity represents the maximum extent to which a specified ESD 105 is predicted to age under multi-step discharge operations comprising rest periods, e.g., aging attributable to discharge conditions during respective discharge steps (A_{d}) and conditions during respective rest periods (B_{d}). As disclosed above, the x_{d_t1} and x_{d_t2} parameters are the relative time proportions of total discharge time occupied by discharge steps 1 and 2, respectively. The y_{d_t3} parameter represents the proportion of time spent in a rest period between discharge steps 1 and 2 compared to the combined discharge steps 1 and 2 (or any N number of steps). The y_{d_t4} parameter is the proportion of time spent in a rest period after step 2 (or final charge step N) compared to the combined charge steps 1 and 2 (or any N number of steps). The parameters g_{d_3} and g_{d_4} may comprise material specific terms that reflect sensitivity of the materials comprising the ESD 105 (e.g., cathode and anode) to temperature in terms of aging mechanisms, e.g., may comprise and/or be derived from ESD-specific characteristics defined within, inter alia, a profile 115 of the ESD 105, or the like. Elevated temperatures that might exist during the indicated rest periods would cause accelerated aging and be accounted for in the magnitude of y_{d_4} and g_{d_4} . . . g_{d_n}. The discharge steps x_{d_t1} . . . x_{d_tn} may sum to unity, whereas the y_{d_t} term may be independent but defined relative to x_{d_t1} . . . x_{d_tn}. By way of non-limiting example, if steps 1 and 2 were each 2 hours, and the rest period were 8 hours, the x_{ch_t1} and x_{ch_t2} terms of Eq. 14 would be 0.5, and the y_{d_t3} term would be 4. Although Eq. 30 is defined in terms of rest periods of a two-step discharge operations, the disclosure is not limited in this regard and could be adapted to incorporate aging models 120 configured to model discharge operations having any number of discharge steps and/or rest periods.

FIG. 1E is a schematic block diagram illustrating an example of an OC model 130 configured to model operating conditions of an N-step discharge operation comprising one or more rest periods. As illustrated in FIG. 1E, the OC model 130 may comprise N discharge step models 137, e.g., discharge step models 137-1 through 137-N. The discharge step models 137 may be configured model discharge conditions during respective discharge steps and corresponding optional rest periods (e.g., rest periods that follow and/or proceed respective discharge steps).

FIG. 1E further illustrates an example of an ESD CFG 160 corresponding to the OC model 130. The ESD CFG 160 may comprise a discharge configuration 166 configured to manage implementation of the N-step discharge operation defined by the discharge model 136. The discharge configuration 166 may comprise machine-readable instructions configured cause a discharge device (e.g., an ESD controller, BMS or the like) to implement N-step discharge operations in accordance with the discharge model 136, e.g., configure the discharge module 174-2 of an application 170 to implement N-step discharge operations per the discharge model 136. In some implementations, the ESD CFG 160 may further comprise a charge configuration 164 configured to manage charge conditions of the ESD 105, as disclosed herein.

In the FIG. 1E example, the OC model 130 may comprise discharge step models 137, which may be configured to characterize the respective discharge steps of the N-step discharge operation of the OC model 130. For example, the discharge step model 137-i may be configured to model a discharge step having a specified duration (x_{d_ti}), discharge rate (r_{d_i}), discharge end voltage (V_{d_end_i}), and so on. The discharge step model 137-i may be further configured to model an optional rest period implemented before or after the discharge step, e.g., may specify a duration (y_{d_i}) of the rest period, ESD voltage during the rest period, and so on. Accordingly, in the FIG. 1E example, the discharge configuration 166 may comprise N discharge step configurations 167 (e.g., discharge step configurations 167-1 through 167-N), each configured to cause the discharge module 174-1 (or other ESD module 174) to implement a respective step of the N-step discharge operation. The discharge step configurations 167 may be derived from corresponding discharge step models 137. For example, the discharge configuration 167-i may be configured to cause the discharge module 174-1 to implement a discharge step having discharge and/or rest conditions specified by discharge step model 137-i. The discharge configuration 167-i may be configured to cause the discharge module 174-2 to implement a discharge operation having the duration (x_{d_i}), discharge rate (r_{d_i}), and/or discharge end voltage (V_{d_end_i}) specified by the discharge step model 137-i. The discharge configuration 167-i may be further configured to cause the discharge module 174-2 to implement a rest period having the duration specified by the discharge step model 137-i (e.g., y_{d_i}), and so on.

In some implementations, the aging model 120 may be further configured to model temporal characteristics of ESD discharge-related aging, e.g., predict the rate at which M_{d} may be incurred over time under specified operating conditions, as follows:

$${φ}_{d} ( t ) = {M}_{d}^{′} + 2 ( {M}_{d} - {M}_{d}^{′} ) [ \frac{1}{2} - \frac{1}{1 + exp ( {( {p}_{d} t )}^{{q}_{d}} )} ] \qquad Eq . 31$$

In Eq. 31, ψ_{d}(t) may be configured to model a discharge-related aging trend of one or more ESD performance characteristics as a function of time (t), e.g., predict degradation to ESD capacity, discharge rate, and/or the like. The M_{d}′ parameter may quantify the extent of discharge-related aging due to charging at time zero, which may be substantially 0 for newly fabricated ESD 105 (or quantify previously incurred discharge-related aging of a repurposed ESD 105). The M_{d} term may quantify the maximum extent of charge-related aging due to specified discharge conditions, as disclosed herein. The p_{d} and q_{d} terms may model the rate at which discharge-related aging occurs over time (e.g., the rate at which the ESD 105 reaches M_{ch}). In some examples, the p_{d} and q_{d} terms may model reaction rates of the DRA mechanisms of the ESD 105, which may correspond to the cell chemistry of the ESD 105. The p_{d} quantity may correspond to an equivalent intrinsic rate constant for the DRA mechanism(s) of the ESD 105, and the q_{d} term may correspond to an equivalent intrinsic kinetic order of the DRA mechanism(s). The p_{d} and/or q_{d} terms may indicate the sensitivity of the ESD 105 to specified discharge conditions. In some implementations, the ESD manager 110 may be configured to learn the p_{d} and/or q_{d} terms for respective ESD 105 (and/or operating conditions) through, inter alia, regression analysis of ESD aging data (e.g., through testing, experience, analysis, and/or the like).

As disclosed herein, the operating conditions of the ESD 105 in the application 170 may change over time. In some implementations, the ESD manager 110 may be configured to develop aging models 120 configured to model ORA under changing operating conditions, e.g., model aging over a plurality of usage periods, each having respective operating conditions (e.g., operating conditions characterized by a respective OC model 130). The aging model 120 of an ESD 105 may be configured to predict discharge-related aging under variable discharge conditions as follows:

$${φ}_{d} ( t ) = {\sum }_{k = 1}^{Z} {M}_{{d}^{′}} + 2 {( {M}_{d\_k} - {M}_{d}^{′} ) [ \frac{1}{2} - \frac{1}{1 + exp ( {( {p}_{d\_k} t )}^{{q}_{d\_k}} )} ]}_{k} \qquad Eq . 32$$

In Eq. 32, ψ_{d}(t) is configured to model the extent and/or rate of discharge-related aging incurred by the ESD 105 in each of Z usage periods. The discharge conditions of respective usage periods k may be specified by respective discharge models 136 and, as such, may result in respective discharge-related age modeling terms, M_{d_k}, p_{d_k}, q_{d_k} and so on, which may be calculated as disclosed herein (e.g., in accordance with Eq. 17-31). The aging model 120 may, therefore, predict a cumulative performance loss (or performance degradation) to be incurred by the ESD 105 over Z usage periods due to discharge conditions of the respective usage periods.

As disclosed herein, the ESD manager 110 may be configured to model the maximum extent of aging under specified operating conditions (OC), as follows:

M_{OC}=M_{OC}^{o}f_{SoC}(OC)

M_{OC}=M_{ch}(CC)+M_{d}(DC)

Mₜₒₜₐₗ=M_{OC}+M_{bl} Eq. 33

In Eq. 33, M_{OC}^{o} is a quantity indicating an upper limit aging attributable to operating conditions, which may be a combination of M_{ch}^{o} and M_{d}^{o}. The M_{ch} for a specified set of charge conditions (CC) may be modeled per Eq. 1-14 and the M_{d} for a specified set of discharge conditions (DC) may be modeled per Eq. 17-30. The ESD manager 110 may be further configured to model the rate at which performance degradation is predicted to be incurred by the ESD as:

$${φ}_{OC} ( t ) = {M}_{OC}^{′} + 2 ( {M}_{OC} - {M}_{OC}^{′} ) [ \frac{1}{2} - \frac{1}{1 + exp ( {( {p}_{OC} t )}^{{q}_{OC}}} ] \qquad Eq . 34$$

$${φ}_{OC} ( t ) = {φ}_{ch} ( t ) + {φ}_{d} ( t )$$

$${φ}_{total} ( t ) = {φ}_{OC} ( t ) + {φ}_{bl} ( t )$$

In Eq. 34, ψ_{OC}(t) may be configured to model the rate at which ORA is incurred under specified operating conditions (OC), ψ_{ch}(t) may be configured to model the rate at which CRA is incurred under charge conditions (CC), e.g., per Eq. 15-16, ψ_{d}(t) may be configured to model the rate at which DRA is incurred under discharge conditions (DC), and ψ_{bl}(t) may be configured to model the rate at which background aging is incurred by the ESD 105.

In some implementations, the ESD manager 110 may be configured to develop and/or utilize aging models 120 configured to predict age-related degradation attributable to a plurality of aging mechanisms, as illustrated in below:

$${φ}_{total} ( t ) = {\sum }_{j = 1}^{m} \{ {M}_{j}^{′} + 2 ( {M}_{j} - {M}_{j}^{′} ) [ \frac{1}{2} - \frac{1}{1 + exp ( {( {p}_{j} t )}^{{q}_{j}} )} ] \} \qquad Eq . 35$$

Eq. 35 may be configured to quantify aging behavior of m aging mechanisms, e.g., aging mechanisms j where j∈{1 . . . m}. The j aging mechanisms may include ORA mechanisms, such as CRA mechanisms (e.g., charge conditions characterized by respective charge models 134), DRA mechanisms (e.g., discharge conditions characterized by respective discharge models 136), and so on, as disclosed herein.

In some implementations, the ESD manager 110 may be configured to develop and/or utilize aging models 120 configured to predict the extent and/or rate of performance degradation attributable to charge conditions and discharge conditions (and/or distinguish CRA from DRA and vice versa). The aging model 120 of an ESD 105 may be configured to predict the extent and/or rate of performance degradation to be incurred by the ESD 15 under specified operating conditions (e.g., an OC model 130), as follows:

ψₜₒₜₐₗ(t)=Σₖ₌₁ⁿ^{₁}ψ_{ch}(t)+Σₖ₌₁ⁿ^{₂}ψ_{d}(t) Eq. 36

The ψₜₒₜₐₗ(t) function of Eq. 36 may be configured to quantify aging as a function of degradation incurred by a specified ESD performance characteristic, as disclosed herein (e.g., degreased energy storage capacity, increased impedance, and/or the like). For example, the ψₜₒₜₐₗ(t) function may be configured to predict capacity loss to be incurred by the ESD 105 over time under specified operating conditions, e.g., operating conditions characterized by respective OC models 130. The ψₜₒₜₐₗ(t) function determined for an OC model 130 may be expressed as ψₜₒₜₐₗ(OCₖ, t), where OCₖ represents the OC model 130 and/or operating conditions characterized thereby.

The ψₜₒₜₐₗ(t) function may be configured to model charge-related aging; the aging model 120 may comprise a ψ_{ch}(t) function configured to quantify total and/or composite aging attributable to charge conditions (e.g., model the cumulative impact of n₁ CRA mechanisms under specified charge conditions). The CRA mechanisms may be modeled as disclosed above (e.g., may be modeled in accordance with Eq. 1-16). The ψ_{ch}(t) function may be configured model aging attributable to any suitable charge conditions including, but not limited to charge models 134 configured to characterize: single-step charge operations, multi-step charge operations (e.g., N-step charge operations), multi-step charge operations comprising one or more intervening rest periods, charge conditions during respective usage periods, and/or the like. The ψ_{ch}(t) function for a specified set of operating conditions (OC) may be expressed as ψ_{ch}(OC, t) or ψ_{ch}(CC, t), where CC represents the charge conditions of the OC model 130 (and/or corresponding charge model 134).

Alternatively, or in addition, the ψₜₒₜₐₗ(t) function may be configured to model discharge-related aging; the aging model 120 may comprise a ψ_{d}(t) function configured to quantify total and/or composite aging attributable to discharge conditions (e.g., model the cumulative impact of n₂ DRA mechanisms under specified discharge conditions). The DRA mechanisms may be modeled as disclosed above (e.g., may be modeled in accordance with Eq. 17-32). The ψ_{d}(t) function may be configured model aging attributable to any suitable discharge conditions including, but not limited to discharge models 136 configured to characterize: single-step discharge operations, multi-step discharge operations (e.g., N-step discharge operations), multi-step discharge operations comprising one or more intervening rest periods, discharge conditions during respective usage periods, and/or the like. The ψ_{d}(t) function for a specified set of operating conditions (OC) may be expressed as ψ_{d}(OC, t) or ψ_{d}(DC, t), where DC represents the discharge conditions of the OC model 130 (and/or corresponding discharge model 136).

The ESD manager 110 may be further configured to utilize and/or develop aging models 120 configured to model age-related performance degradation of ESD 105 under variable operating conditions, e.g., usage periods having different operating conditions. The aging model 120 may be configured to model ψₜₒₜₐₗ(t) over respective usage periods, where ψₜₒₜₐₗ(t) comprises a combination of ψ_{ch}(t) and ψ_{d}(t) under charge and/or discharge conditions of the respective usage periods, e.g., as in Eq. 16 and 32, respectively. As illustrated in FIG. 1F, the analysis module 116 may be configured to determine an OP policy 150 configured to model operating conditions of respective usage periods. The OP policy 150 may, for example, comprise a plurality of period-specific OP (POP) policies 152, each configured to manage operation of the ESD 105 within the application 170 during a respective usage period per a respective period-specific OC (POC) model 132.

The OP policy 150 illustrated in the FIG. 1F example may be configured to manage operation of the ESD 105 over Z usage periods. As such, the OP policy 150 may comprise Z POP policies 152-1 through 152-Z configured to manage operation of the ESD 105 to the target operating conditions of POC models 132-1 through 132-Z, respectively. The POP policies 152-1 through 152-Z may comprise corresponding charge policies 154-1 through 154-Z and/or discharge policies 156-1 through 156-Z. The charge policies 154-1 through 154-Z may be configured to manage charge conditions of the ESD 105 during respective usage periods per charge models 134-1 through 134-Z. The discharge policies 156-1 through 156-Z may be configured to manage discharge conditions of the ESD 105 during respective usage periods per discharge models 136-1 through 136-Z.

The ESD manager 110 may be further configured to generate ESD CFG 160 corresponding to multi-period OP policies 150 (and/or multi-period OC models 130). As illustrated in the FIG. 1F example, the ESD CFG 160 may comprise Z period configurations 162. The period configurations 162-1 through 162-Z may be configured to cause the application 170 to utilize the ESD 105 in accordance with the POP polices 152-1 through 152-Z during respective usage periods. The period configurations 162A-Z may comprise charge configurations 164 and/or discharge configurations 166. The charge configurations 164-1 through 164-Z may be configured to cause the application 170 to implement charge operations on the ESD 105 in accordance with charge policies 154-1 through 154-Z, such that the charge conditions of the ESD 105 during respective usage periods correspond with the target charge conditions of charge models 134-1 through 134-Z. The discharge configurations 166-1 through 166-Z may be configured to cause the application 170 to implement discharge operations on the ESD 105 in accordance with charge policies 156-1 through 156-Z, such that the discharge conditions of the ESD 105 during respective usage periods correspond with the target discharge conditions of discharge models 136-1 through 136-Z.

Referring back to FIG. 1A, the analysis module 116 may utilize the aging model 120 developed for an ESD 105 to, inter alia, manage implementation of an application 170 by the ESD 105. The analysis module 116 may utilize the aging model 120 to a) determine an OP policy 150 under which the ESD 105 is predicted to satisfy the requirements of the application 170, and d) derive a ESD CFG 160 to configure operation of the ESD 105 within the application 170 in accordance with the OP policy 150. The analysis module 116 may utilize the aging model 120 to configure the OP policy 150 (and/or the target operating conditions thereof) such that performance degradation predicted to be incurred by the ESD 105 during operation in accordance with the OP policy 150 (and/or corresponding ESD CFG 160) is maintained below specified threshold(s), e.g., maintain Mₜₒₜₐₗ, M_{oc}, M_{ch}, and/or M_{d} below thresholds defined by the specification 171 of the application 170. Alternatively, or in addition, the analysis module 116 may utilize the aging model 120 to configure the OP policy 150 (and/or corresponding ESD CFG 160) such that the ESD 105 is predicted to satisfy performance requirements of the application 170 for a specified usage period, e.g., maintain ψₜₒₜₐₗ, ψ_{OC}, ψ_{ch}, and/or ψ_{d} below one or more thresholds for a usage period defined by an endurance requirement of the application 170.

In some implementations, determining the OP policy 150 may comprise a) evaluating respective OC models 130 to identify target operating conditions that satisfy ESR requirements of the application 170, and b) generating an ESD CFG 160 configured to manage operation of the ESD 105 within the application 170 based, at least in part, on the identified target operating conditions. The evaluating may comprise predicting performance degradation to be incurred by the ESD 105 under respective operating conditions, e.g., operating conditions configured to model respective charge conditions and/or discharge conditions. The evaluating may further comprise comparing the extent and/or rate of performance degradation predicted to be incurred by the ESD 105 under the respective operating conditions to requirements of the application 170, e.g., comparing the extent and/or rate of performance degradation predicted for respective ESD performance characteristics to corresponding requirements defined by, inter alia, the application specification 171.

In some implementations, the analysis module 116 may be configured to evaluate the extent of aging predicted to be incurred by the ESD 105 under respective operating conditions (e.g., Mₜₒₜₐₗ, M_{oc}, M_{ch}, and/or M_{d}) to identify operating conditions that are predicted to satisfy performance requirements of the application 170, e.g., operating conditions where Mₜₒₜₐₗ<M_{threshold}, wherein M_{threshold} is a threshold configured to limit the maximum extent of performance degradation incurred by the ESD 105. The analysis module 116 may be configured to determine charge conditions predicted to result in a maximum extent of charge-related aging (M_{ch}) that satisfies a threshold, e.g., determine charge conditions having CC metrics 144 where M_{ch}<M_{ch_threshold}, and M_{ch_threshold} is a threshold configured to limit the extent of charge-related aging incurred by the ESD 105. Alternatively, or in addition, the analysis module 116 may be configured to determine discharge conditions predicted to result in a maximum extent of discharge-related aging (M_{d}) that satisfies the threshold, e.g., determine discharge conditions having DC metrics 146 where M_{d}<M_{d_threshold}, and M_{d_threshold} is a threshold configured to limit the extent of discharge-related aging incurred by the ESD 105.

Alternatively, or in addition, the analysis module 116 may utilize the aging model 120 to evaluate temporal characteristics of ESD aging under specified operating conditions. The analysis module 116 may be configured to evaluate the extent and/or rate of performance degradation attributable to respective OC models 130, e.g., evaluate ψₜₒₜₐₗ, ψ_{OC}, ψ_{ch}, ψ_{d}, and/or the like. In some implementations, the analysis module 116 may be configured to evaluate the rate of aging predicted to be incurred by the ESD 105 under respective operating conditions to, inter alia, identify operating conditions that are predicted to satisfy performance requirements of the application 170 for the usage period defined by a corresponding endurance requirement (if any), e.g., operating conditions where ψₜₒₜₐₗ (tₗ)<PCᵢ, wherein tₗ is a longevity threshold and PCᵢ is a threshold configured to limit performance degradation to a specified ESD performance characteristic (e.g., performance characteristic i of the ESD 105, such as energy storage capacity or the like).

In some implementations, the analysis module 116 may be configured to utilize the aging model 120 to evaluate temporal characteristics of aging attributable to charge conditions, e.g., evaluate a ψ_{ch} function per Eq. 15 and/or 16. The analysis module 116 may evaluate OC models 130 to, inter alia, identify charge conditions (charge models 134) predicted to maintain ψ_{ch} below one or more a specified usage period, e.g., charge conditions where ψ_{ch}(tₗ)>PCᵢ or ψ_{ch}(tₗ)>PC_{ch_i}, where PC_{ch_i} is a threshold configured to limit CRA aging incurred by a specified ESD performance characteristic during a specified usage period tₗ. Alternatively, or in addition, the analysis module 116 may be configured to utilize the aging model 120 to evaluate temporal characteristics of aging attributable to discharge conditions, e.g., evaluate a ψ_{d} function per Eq. 31 and/or 32. The analysis module 116 may evaluate OC models 130 to, inter alia, identify discharge conditions (discharge models 136) predicted to maintain ψ_{d} below one or more thresholds, e.g., discharge conditions where ψ_{d}(tₗ)>PCᵢ or ψ_{d}(tₗ)>PC_{d_i}, where PC_{d_i} is a threshold configured to limit DRA aging incurred by a specified ESD performance characteristic during usage period tₗ.

In some implementations, the analysis module 116 may be configured to determine aging metrics 142 for respective operating conditions, e.g., OC models 130 and/or corresponding OP policies 150. The aging metrics 142 of an OC model 130 (and/or corresponding OP policy 150) may comprise and/or be based on the extent of performance degradation predicted to be incurred under operating conditions of the OC model 130 and/or the rate at which such performance degradation is predicted to be incurred. For example, the aging metrics 142 may comprise and/or be derived from Mₜₒₜₐₗ, M_{oc}, ψₜₒₜₐₗ(t), ψ_{OC}(t), and/or the like, as disclosed herein. The aging metrics 142 predicted for a specified set of operating conditions (and/or OC model 130) may, therefore, quantify aging attributable to the specified set of operating conditions. The aging metrics 142 may, therefore, comprise and/or be referred to as operating condition (OC) metrics, operating condition cost (OCC) metrics, or the like.

The aging metrics 142 predicted for an OC model 130 (and/or corresponding OP policy 150) may comprise and/or be derived from charge condition metrics 144 and/or discharge condition metrics 146. As used herein, charge condition (CC) metrics 144 may comprise and/or refer to data configured to quantify an extent and/or rate of ESD aging attributable to charge conditions. The CC metrics 144 of an OC model 130 may comprise and/or be based on the extent of performance degradation predicted to be incurred under the charge conditions of the OC model 130 (e.g., charge model 134) and/or the rate at which such performance degradation is predicted to be incurred. For example, CC metrics 144 may comprise and/or be derived from M_{ch}, ψ_{ch}(t), and/or the like, as disclosed herein (e.g., per one or more of Eq. 1-16). As used herein, discharge condition (DC) metrics 146 may comprise and/or refer to data configured to quantify an extent and/or rate of ESD aging attributable to discharge conditions. The DC metrics 146 of an OC model 130 may comprise and/or be based on the extent of performance degradation predicted to be incurred under the discharge conditions of the OC model 130 (e.g., discharge model 136) and/or the rate at which such performance degradation is predicted to be incurred. For example, DC metrics 146 may comprise and/or be derived from M_{d}, ψ_{d}(t), and/or the like, as disclosed herein (e.g., per one or more of Eq. 17-32). The aging metrics 142 predicted for an OC model 130 may, therefore, comprise a combination or sum of the CC metrics 144 and DC metrics 146 predicted for the OC model 130. In other words, the aging metrics 142 predicted for an OC model 130 may comprise a combination of a) the CC metrics 144 predicted for charge conditions of the OC model 130 (charge model 134 of the OC model 130) and b) the DC metrics 146 predicted for the discharge conditions of the OC model 130 (discharge model 136 of the OC model 130), e.g., may comprise and/or be derived per one or more of Eq. 33-36, as disclosed herein.

In some implementations, the analysis module 116 may be configured to evaluate one or more aging predictions 140, each aging prediction 140 configured to characterize the extent and/or rate of aging to be incurred by the ESD 105 under a respective set of operating conditions, e.g., operating conditions characterized by an OC model 130 of a respective OP policy 150. The aging prediction 140 for an OC model 130 (and/or corresponding OP policy 150) may comprise and/or be derived from aging metrics 142 determined for the OC model 130, as disclosed herein. An aging prediction 140 may comprise a prediction of the maximum extent of age-related performance degradation to be incurred by the ESD 105 over time under a specified set of operating conditions (e.g., Mₜₒₜₐₗ, M_{OC}, M_{ch}, M_{d}, and/or the like) and/or the rate that such degradation is predicted to be incurred (e.g., ψₜₒₜₐₗ, ψ_{OC}, ψ_{ch}, ψ_{d} and/or the like). The analysis module 116 may evaluate aging metrics 142 and/or aging predictions 140 determined for respective OC models 130 to, inter alia, determine operating conditions that maintain the predicted extent of age-related performance loss below a threshold and/or maintain performance loss under a threshold throughout a specified usage period.

FIG. 1G is a plot 182 illustrating further aspects of the aging models 120 disclosed herein. The plot 182 illustrates examples of aging predictions 140 generated using an aging model 120 developed for an ESD 105. In the FIG. 1G example, the aging predictions 140 may be configured to predict temporal, age-related performance degradation to the energy storage capacity of an ESD 105. In other words, the aging predictions 140 illustrated in FIG. 1G may comprise and/or be derived from a function ψₜₒₜₐₗ(t) configured to predict degradation to the energy storage capacity of the ESD 105 under specified operating conditions as a function of time.

In the FIG. 1G example, the analysis module 112 may be configured to evaluate P aging predictions 140 (e.g., aging predictions 140-1 through 140-M), which may be configured to model performance degradation predicted to be incurred to ESD capacity under operating conditions characterized by OC models 130-1 through 130-M, respectively, e.g., degradation predicted to be incurred under respective operating conditions OC-1 through OC-M. The OC models 130-1 through 130-M may comprise charge models 134 configured to characterize charge conditions CC-1 through CC-M and/or discharge models 136 configured to characterize discharge conditions DC-1 through DC-M.

The aging predictions 140 may be configured to predict a) the maximum extent of performance degradation (e.g., Mₜₒₜₐₗ) under operating conditions characterized by respective OC models 130-1 through 130-M and/or b) the rate at which such degradation is predicted to be incurred over time (e.g., ψₜₒₜₐₗ). The aging predictions 140 may be configured to predict the extent and/or rate of performance degradation attributable to respective aging mechanisms, e.g., Mₜₒₜₐₗ may comprise and/or be derived from a combination of M_{ch} and M_{d} and ψₜₒₜₐₗ may comprise and/or be derived from a combination of ψ_{ch}(t) and ψ_{d}(t), as disclosed herein. In some implementations, the aging predictions 140 may be configured to distinguish aging attributable charge conditions from aging attributable to NCR conditions, distinguish aging attributable to discharge conditions from aging attributable to NDR conditions, distinguish aging attributable to charge conditions from aging attributable to discharge conditions, and/or the like. For example, the aging predictions 140-1 through 140-M may be configured model the extent and/or rate of CRA (M_{ch} and/or ψ_{ch}) under respective OC models 130, e.g., model the impact of the charge conditions CC-1 through CC-M. Alternatively, or in addition, the aging predictions 140 may be configured model the extent and/or rate of DRA (M_{d} and/or ψ_{d}) under respective OC models 130, e.g., model the impact of the discharge conditions DC-1 through DC-M.

In the FIG. 1G example, OC models 130-1 and 130-M may be predicted to result in a similar maximum extent of performance degradation (Mₜₒₜₐₗ), e.g., may result in degradation from an initial capacity of X Ahr to a reduced capacity of about X-L Ahr. The aging model 120 may, however, predict that the operating conditions of OC model 130-1 will result in a higher degradation rate than the operating conditions of OC model 130-M. For example, the OC model 130-1 may be predicted to impose a higher impact on ORA mechanism(s) of the ESD 105 than the OC model 130-M, e.g., the operating conditions of the OC model 130-1 may be more strenuous (and/or impose more strain on the ESD 105) than operating conditions of OC model 130-M.

As disclosed herein, the analysis module 116 may evaluate the aging model 120 of the ESD 105 under different operating conditions to, inter alia, identify operating conditions that satisfy the application specification 171, e.g., satisfy ESR requirements of the application 170. Plot 182 of FIG. 1G further illustrates examples of an ESR specification 171 of an application 170, the ESR specification 171 configured to define a performance requirement and corresponding endurance requirement. The performance requirement illustrated in the FIG. 1G example may be configured to define a capacity threshold and the endurance requirement may specify a longevity threshold, e.g., define a usage period during which the energy storage capacity of the ESD 105 is required to satisfy the capacity threshold. As illustrated in FIG. 1G, the endurance requirement may be defined in terms of time, e.g., may define the longevity threshold in terms of time, such as weeks, months or the like. The disclosure is not limited in this regard, however, and could be adapted to define endurance requirements in other terms, such as duty cycle count or the like.

As illustrated in FIG. 1G, the aging prediction 140-1 fails to satisfy the application specification 171; the aging prediction 140-1 indicates that operation of the ESD 105 in accordance with the operating conditions of OC model 130-1 is predicted to result unacceptable performance degradation, e.g., the capacity of the ESD 105 is predicted to fall below the capacity threshold prior to the longevity threshold of the application 170. Accordingly, the analysis module 116 may determine that the operating conditions characterized by OC model 130-1 are unsuitable for implementation of the application 170 by the ESD 105.

By contrast, the analysis module 116 may determine that the operating conditions of OC model 130-M are suitable for implementation of the application 170 by the ESD 105, e.g., determine that the operating conditions of OC model 130-M satisfy the application specification 171. Evaluation of the aging prediction 140-M may indicate that, under the operating conditions of OC model 130-M, the ESD 105 is predicted to satisfy the performance requirements of the application 170 for the usage period specified by the corresponding endurance requirement.

Referring back to FIG. 1A, the analysis module 116 may be configured to manage implementation of applications 170 by ESD 105. Managing implementation of an application 170 by an ESD 105 may comprise, inter alia, a) retrieving an aging model 120 of the ESD 105, b) utilizing the aging model 120 to an OP policy 150 for the ESD 105, and c) generating a ESD CFG 160 to manage operation of the ESD 105 in the application 170 in accordance with the determined OC model 130. Determining the OP policy 150 target may comprise constructing an OC model 130 comprising operating conditions configured to satisfy requirements of the application 170, e.g., operating conditions under which the ESD 105 is predicted to satisfy the performance and/or endurance requirements of the ESR specification 171, as disclosed herein. In other words, the OP policy 150 may specify target operating conditions for the ESD 105 within the application 170, e.g., the OP policy 150 may comprise a charge policy 154 configured to specify target charge conditions for the ESD 105 within the application 170 and/or a discharge policy 156 configured to specify target discharge conditions for the ESD 105 within the application 170.

In response to determining the OP policy 150, the ESD manager 110 may be further configured to generate an application implementation ESD CFG 160 for the ESD 105. As disclosed herein, the ESD CFG 160 may be configured to manage operation of the ESD 105 within the application 170 such that, inter alia, operating conditions of the ESD 105 correspond with the target operating conditions of the OP policy 150 (and/or corresponding OC model 130). The ESD CFG 160 may comprise instructions and/or other data configured to manage utilization of the ESD 105. For example, the ESD CFG 160 may comprise a charge configuration 164 configured to control aspects of the charge operations to be performed on the ESD 105 within the application 170 (e.g., by a charge module 174-1 of the system 172) and/or a discharge configuration 166 configured to control aspects of the discharge operations to be performed on the ESD 105 within the application 170 (e.g., by a discharge module 174-2), as disclosed herein.

In some implementations, the ESD manager 110 may further comprise and/or be coupled to an application configuration (AC) module 118. The AC module 118 may be configured to generate, adapt, translate, and/or otherwise configure the OP policy 150 (and/or corresponding ESD CFG 160) for use within respective applications 170 and/or ESDA systems 172. The AC module 118 may be configured to generate ESD CFG 160 comprising configuration data, firmware, instructions, settings, parameters, and/or other data adapted for ESD modules 174 utilized within respective applications 170 and/or systems 172. For example, the AC module 118 may receive OP policy 150 determined for implementation of an application 170 by an ESD 105 and, in response, generate a ESD CFG 160 configured to cause ESDA system(s) 172 of the application 170 to utilize the ESD 105 in accordance with the target operating conditions of the OP policy 150. Alternatively, or in addition, the AC module 118 may receive a generalized ESD CFG 160 from the analysis module 116 and, in response, generate an application-specific ESD CFG 160 configured for respective ESDA systems 172 and/or ESD modules 174. The AC module 118 may be configured to generate ESD CFG 160 for particular types of BMS, controllers, processors, charge modules 174-1, discharge modules 174-2, and/or the like. The AC module 118 may be configured to generate, adapt, translate, and/or otherwise configure charge configurations 164 for particular types of charge modules 174-1, e.g., charge configurations 164 comprising instructions configured to manage charge operations in accordance with the charge conditions of the target OC model 130 determined for the ESD 105. Alternatively, or in addition, the AC module 118 may be configured to generate, adapt, translate, and/or otherwise configure discharge configurations 166 for particular types of discharge modules 174-2, e.g., discharge configurations 166 comprising instructions configured to manage discharge operations in accordance with the discharge conditions of the OP policy 150 determined for the ESD 105.

As disclosed herein, in some implementations, the ESD manager 110 may be configured to retrieve aging models 120 for respective ESD 105 from a datastore 114 and/or other DSR resources 104-2. Alternatively, or in addition, the ESD manager 110 may be configured to develop and/or refine ESD aging models 120.

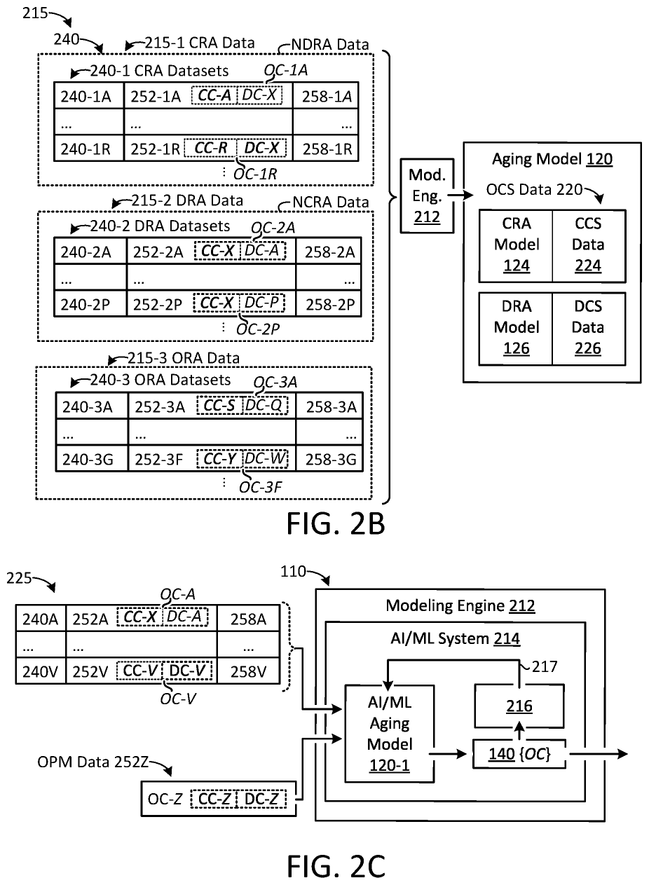

FIG. 2A is a schematic block diagram illustrating further examples of an ESD manager 110, as disclosed herein. As illustrated in FIG. 2A, the ESD manager 110 may comprise an ESDM module 112 (other aspects of the ESD manager 110 not shown to avoid obscuring details of the illustrated examples). The ESDM module 112 may be configured to retrieve aging models 120 for ESD 105 from a datastore 114, as disclosed herein. Alternatively, or in addition, the ESD module 112 may be configured to develop and/or refine ESD aging models 120.

Developing an aging model 120 for an ESD 105 (or ESD type) may comprise acquiring aging data 215 pertaining to the ESD 105. As used herein, aging data 215 may comprise and/or refer to any suitable information pertaining to ESD aging, e.g., information pertaining to performance degradation incurred by the ESD 105 over time and/or under specified operating conditions.

As illustrated in FIG. 2A, the aging data 215 of an ESD 105 may comprise one or more aging datasets 240. As used herein, an aging dataset 240 may comprise and/or refer to data pertaining to performance degradation incurred by the ESD 105 under specified operating conditions. An aging dataset 240 may be analogous to an aging prediction 140. As disclosed herein, an aging prediction 140 may predict performance loss to be incurred by an ESD 105 under specified operating conditions, whereas an aging dataset 240 may comprise measurements of performance degradation observed in the ESD 105 under the specified operating conditions.

FIG. 2A illustrates examples of aging datasets 240. As illustrated in FIG. 2A, the aging datasets 240 may comprise respective operating condition measurement and/or monitoring (OCM) data 252, which may be configured to characterize the operating conditions under which the aging datasets 240 were acquired. The OCM data 252 may comprise any suitable information pertaining to ESD operating conditions, as disclosed herein, e.g., may comprise OC model(s) 130 or the like. OCM data 252 comprise and/or refer to charge condition measurement and/or monitoring (CCM) data 254. CCM data 254 may comprise any suitable information pertaining to ESD charge conditions, as disclosed herein (e.g., may comprise a charge model 134 or the like). Alternatively, or in addition, OCM data 252 may comprise and/or refer to discharge condition measurement and/or monitoring (DCM) data 256. DCM data 256 may comprise any suitable information pertaining to ESD discharge conditions, as disclosed herein (e.g., may comprise a discharge model 136 or the like).

The aging datasets 240 may further comprise ESD performance measurement and/or monitoring (EPM) data 258. As used herein, EPM data 258 may comprise and/or refer to any suitable information pertaining to the functionality and/or performance of an ESD 105. EPM data 258 may, for example, comprise measurements of any suitable ESD performance characteristics as disclosed herein. EPM data 258 may comprise measurements of ESD performance characteristics acquired over a usage period, e.g., measurements of ESD capacity, charge acceptance, internal impedance, voltage, discharge voltage (e.g., voltage under load), and/or the like. The EPM data 258 of an aging dataset 240 may comprise measurements acquired over a specified usage period under specified operating conditions, e.g., operating conditions characterized by OPM data 252 of the aging dataset 240.

FIG. 2A illustrates an example of EPM data 258. The EPM data 258 of the FIG. 2A example may comprise measurements of ESD performance characteristics PC-1 through PC-H acquired over a usage period (UP). The EPM data 258 may comprise measurements corresponding to respective times or offsets within the usage period, e.g., measurements acquired at times t1 through tu of the usage period. In some implementations, the usage period (and/or offsets t1 through tu) may correspond to ESD usage time (e.g., weeks, months, or the like). Alternatively, or in addition, the usage period may correspond to ESD utilization, e.g., may correspond to duty cycle count, wherein t1 corresponds to M duty cycles of the ESD 105, t2 corresponds to 2M duty cycles, t3 corresponds to 3M duty cycles, and so on (e.g., tu corresponds to uM duty cycles). The example EPM data 258 illustrated in FIG. 2A comprises measurements pertaining to performance characteristic PC-1 (e.g., measurements pc1-t1 through pc1-tu), performance characteristic PC-2 (e.g., pc2-t1 through pc2-tu), performance characteristic PC-H (e.g., pcH-t1 through pcH-tu), and so on. The EPM data 258 may, therefore, reflect performance degradation incurred by respective performance characteristics PC-1 through PC-Hover the usage period, e.g., as a function of time, duty cycle, or the like.

The ESDM module 112 may be configured to acquire aging datasets 240 covering a range of ESD operating conditions. In the FIG. 2A example, the profile 115 of the ESD 105 may comprise V aging datasets 240. The aging datasets 240A-V may comprise EPM data 258A-V comprising measurements of performance degradation incurred by the ESD 105 under operating conditions OC-A through OC-V, respectively. The operating conditions OC-A through OC-V may be characterized by respective charge conditions CC-A through CC-V and/or discharge conditions DC-A through DC-V. The aging datasets 240 may, therefore, comprise data used to model and/or predict ESD performance degradation, as disclosed herein, (e.g., model and/or predict Mₜₒₜₐₗ, M_{ch}, M_{d}, ψₜₒₜₐₗ, ψ_{ch}, and/or ψ_{d} under respective operating conditions per Eq. 1-34).

In some implementations, the ESDM module 112 may be configured to retrieve aging data 215 pertaining to an ESD 105 from the datastore 114. The ESDM module 112 may be configured to maintain aging data 215 and/or other information pertaining to respective ESD 105 (and/or ESD types) within respective ESD profiles 115, as disclosed herein. The ESDM module 112 may be configured to acquire aging data 215 from any suitable source. For example, the ESDM module 112 may receive aging data 215 from ESD manufacturers, may retrieve aging data 215 acquired by other systems, and/or the like.

Alternatively, or in addition, the ESDM module 112 may be configured to acquire aging data 215 through, inter alia, monitoring and/or testing. In the FIG. 2A example, the ESDM module 112 may be configured to acquire aging data 215 by use of an ESD application 170-1. The application 170-1 may comprise an ESD evaluation system 172-1, which may comprise any suitable means for utilizing, testing, monitoring and/or otherwise evaluating an ESD 105. The evaluation system 172-1 may comprise one or more ESD modules 174, as disclosed herein. In the FIG. 2A example, the evaluation system 172-1 may comprise an ESD test module 174-3, which may include, but is not limited to: a BMS, a diagnostic device, a test device, a monitoring device, an ESD analysis device, and/or the like. The evaluation system 172-1 (and/or test module 174-3) may be configured to subject the ESD 105 to duty cycles having specified operating conditions.

The evaluation system 172-1 may comprise means for controlling the operating conditions of the ESD 105 in accordance with a ESD CFG 160 generated by the ESD manager 110. For example, the ESDM module 112 utilize the AC module 118 to, inter alia, generate ESD CFG 160 configured to subject the ESD 105 to a range of operating conditions, e.g., subject the ESD 105 to a range of charge conditions, discharge conditions, and so on. The ESD CFG 160 may comprise respective charge configurations 164 configured to cause the evaluation system 172-1 (e.g., charge module 174-1) to implement charge operations having specified charge conditions. The ESD CFG 160 may further comprise respective discharge configurations 166 configured to cause the evaluation system 172-1 (e.g., discharge module 174-2) to implement discharge operations having specified discharge conditions.

In some implementations, the ESDM module 112 may be configured to generate aging datasets 240 from, inter alia, ESD monitoring data 250. The ESD manager 110 and/or evaluation system 172-1 may be configured to capture, collect, acquire, measure, record, and/or otherwise acquire ESD monitoring data 250. As used herein, ESD monitoring data 250 may comprise and/or refer to any suitable information pertaining to the operating conditions and/or performance characteristics of an ESD 105. ESD monitoring data 250 may comprise and/or refer to OCM data 252. As disclosed herein, OCM data 252 may comprise any suitable information pertaining to the operating conditions of an ESD 105. For example, OCM data 252 may comprise information pertaining to the operating conditions of an ESD in an application 170 (e.g., application 170-1), ESDA system 172 (e.g., system 172-1), and/or the like. OCM data 252 may comprise CCM data 254 pertaining to charge conditions of the ESD 105 and/or DCM data 256 pertaining to discharge conditions of the ESD 105.

Alternatively, or in addition, ESD monitoring data 250 may comprise and/or refer to EPM data 258. As disclosed herein, EPM data 258 may comprise any suitable information pertaining the functionality and/or performance characteristics of an ESD 105. EPM data 258 may comprise measurements of ESD performance characteristics acquired over a specified usage period, e.g., at respective offsets or times during the usage period.

In some implementations, aspects of the ESDM data 250 may be acquired by components of the ESD system 172-1, such as the charge module 174-1, discharge module 174-2, test module 174-3, load 176, and/or the like. Alternatively, or in addition, the ESD manager 110 may retrieve and/or request aspects of the ESDM data 250. For example, the ESD manager 110 may comprise and/or be coupled to an ESD interface module 218, which may be configured to access ESDM data 250 (and/or other information) through a data interface of the evaluation system 172-1, such as an API or the like.

The ESDM data 250 may comprise information pertaining to charge conditions of the ESD 105 within the evaluation system 172-1 (e.g., CCM data 254). Aspects of the CCM data 254 may be captured by one or more of the charge module 174-1, test module 174-3, a monitoring device (e.g., temperature sensor, current sensor, voltage sensor, power meter, and/or the like), and/or other suitable means, e.g., other ESD module(s) 174. The CCM data 254 may comprise information pertaining to single and/or multi-step charge operations performed on the ESD 105, including, but not limited to: charge rate (r_{ch}), charge voltage (V_{ch}), charge step duration (x_{ch_t}), rest period duration (g_{ch_t} and/or y_{ch_t}), ESD temperature (T_{ch}), and so on, as disclosed herein. As disclosed herein, the evaluation system 172-1 may be configured to charge the ESD 105 in accordance with a ESD CFG 160 generated by the ESD manager 110, e.g., in accordance with a charge configuration 164. The evaluation system 172-1 may be configured to implement charge operations such that the resulting ESDM data 250 (e.g., CCM data 254) corresponds to the target charge conditions of the charge configuration 164. The ESDM data 250 (and/or corresponding aging datasets 240) may comprise information used to generate the aging model 120 of the ESD 105, e.g., model and/or predict M_{ch} quantities and/or Ψ_{ch} functions, as disclosed herein (e.g., per Eq. 1-16).

Alternatively, or in addition, the ESDM data 250 may comprise information pertaining to the discharge conditions of the ESD 105 within the (e.g., DCM data 256). The DCM data 256 may be captured by one or more of the discharge module 174-2, test module 174-3, a monitoring device (e.g., temperature sensor, current sensor, voltage sensor, power meter, and/or the like), and/or other suitable means, e.g., other ESD module(s) 174. The discharge-related ESDM data 250 may comprise information pertaining to single and/or multi-step discharge operations performed on the ESD 105, including, but not limited to: discharge rate (d_{ch}), discharge voltage (V_{d}), discharge step duration (x_{d_t}), power output, rest period duration (g_{d_t}), ESD temperature (T_{actual}), and so on, as disclosed herein. As disclosed herein, the evaluation system 172-1 may be configured to discharge the ESD 105 in accordance with a ESD CFG 160 generated by the ESD manager 110, e.g., in accordance with a discharge configuration 166. The evaluation system 172-1 may be configured to implement discharge operations such that the resulting ESDM data 250 (e.g., DCM data 256) corresponds to the target discharge conditions of the discharge configuration 166. The ESDM data 250 (and/or corresponding aging datasets 240) may comprise information used to develop and/or refine the aging model 120 of the ESD 105, e.g., model and/or predict M_{d} quantities and/or Ψ_{d} functions, as disclosed herein (e.g., per Eq. 17-32).

As used herein, ESDM data 250 may comprise and/or refer to EPM data 258. As disclosed herein, EPM data 258 may comprise any suitable information pertaining to the functionality and/or performance characteristics of an ESD 105. EPM data 258 may be acquired by any suitable means. In the FIG. 2A example, aspects of the EPM data 258 may be acquired by components of the evaluation system 172-1, such as the charge module 174-1, discharge module 174-2, test module 174-3, load 176, monitoring devices (e.g., current sensors, voltage sensors, temperature sensors, power meters, and/or the like), and/or other ESD module 174, e.g., an ESD controller, an integration component, an ESD management system, a battery management system (BMS), an ESD monitoring device, an ESD analysis device, ESD test equipment (e.g., a battery tester), an ESD diagnostic device, an ESD conditioning device (e.g., battery conditioning equipment), and/or the like. The ESDM data 250 may comprise information pertaining to any suitable performance characteristic disclosed herein, including, but not limited to: capacity, temperature rise during operation (e.g., temperature rise during charge and/or discharge operations), charge acceptance, internal impedance, voltage, voltage under load, frequency of self-discharge, and/or the like.

The ESDM module 112 may utilize the evaluation system 172-1 to acquire ESDM data 250 comprising measurements of ESD performance characteristics captured at respective offsets of a usage period (e.g., t1 through tu), the measurements quantifying performance degradation incurred by the ESD 105 under the operating conditions specified by the ESD CFG 160 (and/or corresponding OCM data 252).

The ESD manager 110 may utilize the evaluation system 172-1 to acquire aging datasets 240 configured to measure performance degradation of specified types of ESD 105 under specified operating conditions. Acquiring an aging dataset 240 may comprise a) configuring the evaluation system 172-1 to subject an ESD 105 to specified operating conditions over a specified usage period, e.g., generating a ESD CFG 160 for implementation by the evaluation system 172-1, as disclosed herein, and b) acquiring ESDM data 250 comprising measurements of one or more performance characteristics of the first ESD 105 acquired at respective offsets of the usage period, e.g., acquiring EPM data 258 and/or corresponding EPM data 252, as disclosed herein. Acquiring the aging dataset 240 may comprise configuring the evaluation system 172-1 to charge the ESD 105 under specified charge conditions (e.g., per a charge configuration 164) and/or discharge the ESD 105 under specified discharge conditions (e.g., per a discharge configuration 166).

In the FIG. 2A example, the ESDM module 112 may comprise and/or be coupled to a modeling engine 212. The modeling engine 212 may be configured to develop and/or refine aging models 120 for respective ESD 105 as disclosed herein. The modeling engine 212 may be configured to develop, refine, and/or learn aging models 120 for respective ESD 105 through, inter alia, analysis of aging data 215 pertaining to the ESD 105. In some implementations, learning an aging model 120 for an ESD 105 may comprise learning terms of Eq. 33 and/or 34, e.g., learning M_{oc}, p_{OC}, q_{OC}, and so on. Developing an aging model 120 for an ESD 105 may comprise modeling respective aging mechanisms of the ESD 105. For example, developing the aging model 120 of an ESD 105 may comprise learning parameters of Eq. 35 for respective aging mechanisms, e.g., learning Mⱼ, pⱼ, qⱼ, and so on.

In some implementations, developing the aging model 120 of an ESD 105 may comprise modeling CRA and/or DRA mechanisms of the ESD 105. The modeling engine 212 may be configured to learn a function ψ_{ch}(t) configured to model CRA mechanisms of the ESD 105 and/or a function ψ_{d}(t) configured to model DRA mechanisms of the ESD 105, as disclosed herein. Modeling CRA mechanisms of the ESD 105 may comprise learning parameters of Eq. 1-16, e.g., leaning M_{ch}^{o}, p_{ch}, q_{ch}, and/or the like. Modeling DRA mechanisms of the ESD 105 may comprise learning parameters of Eq. 17-32, e.g., learning M_{d}^{o}, p_{d}, q_{d}, and/or the like. The modeling engine 212 may be configured to learn aging models 120 through any suitable technique. By way of non-limiting example, in some implementations, the ESDM module 112 may be configured to learn aging models 120 through regression analysis of the aging data 215, through numerical methods such as function fitting (e.g., learning parameters to fit ψₜₒₜₐₗ(t), ψ_{ch}(t), and/or ψ_{d}(t) to observed EPM data), and/or the like.

In some implementations, the aging models 120 learned for respective ESD 105 may further comprise operating condition sensitivity (OCS) data 220. The OCS data 220 may be configured to quantify the degree to which ORA mechanisms of the ESD 105 are sensitive to respective operating conditions. The OCS data 220 may comprise charge condition sensitivity (CCS) data 224 and/or discharge condition sensitivity (DCS) data 226. The CCS data 224 may indicate a sensitivity of CRA mechanisms of the ESD 105 to respective charge conditions, e.g., may indicate a sensitivity of ψ_{ch} to charge rate (r_{ch}), end voltage (V_{ch}), and/or the like. The DSC data 226 may indicate a sensitivity of DRA mechanisms of the ESD 105 to respective discharge conditions, e.g., may indicate a sensitivity of ψ_{d} to discharge rate (r_{d}), discharge voltage (V_{d}), and/or the like.

As disclosed herein, in some implementations, the ESDM module 112 may be configured to model respective ESD aging mechanisms, such as CRA mechanisms, DRA mechanisms, and so on. The ESDM module 112 may be configured to acquire aging datasets 240 configured to monitor performance degradation attributable to respective aging mechanisms. FIG. 2B is a schematic block diagram illustrating examples of aging data configured to model respective ESD aging mechanisms. The ESDM module 112 may leverage such aging data to, inter alia, develop charge-related and/or discharge-related aspects of the aging model 120, as disclosed in further detail herein.

In some implementations, the ESDM module 112 may be configured to acquire charge-related aging datasets 240-1. As used herein, a charge-related aging (CRA) dataset 240-1 may comprise and/or refer to an aging dataset 240 configured to measure performance degradation attributable to charge conditions and/or distinguish charge-related aging from non-charge-related aging of the ESD 105. A CRA dataset 240-1 may comprise and/or refer to an aging dataset 240 acquired under nominal discharge conditions. As used herein, “nominal” discharge conditions may comprise and/or refer to discharge conditions predicted to result in nominal discharge-related aging, e.g., discharge operations performed at discharge rates of C₁ or lower, nominal V_{d_end}−V_{d_start} differentials, nominal SoC ranges, nominal discharge temperatures (e.g., about 30° C.), and so on. Nominal discharge conditions may comprise and/or refer to operating conditions predicted to result in discharge-related performance degradation that satisfies a threshold (M_{d_nominal}), e.g., discharge conditions configured such that M_{d}≤M_{d_nominal}. Accordingly, a CRA dataset 240-1 may comprise and/or be referred to as nominal-discharge-related aging (NDRA) data and/or an NDRA dataset 240.

The ESDM module 112 may be configured to acquire CRA datasets 240-1 that cover a plurality of charge conditions. In the FIG. 2B example, the aging data 215 acquired by the ESDM module 112 may comprise R CRA datasets 240-1. The CRA datasets 240-1A through 240-1R may comprise respective EPM data 258 (EPM data 258-1A through 258-1R) acquired under operating conditions OC-1A through OC-1R (as indicated by respective OCM data 252-1A through 252-1R). The CRA datasets 240-1A through 240-1R may be acquired under a plurality of different charge conditions (CC-A through CC-R) and a substantially constant set of nominal discharge conditions (DC-X). Accordingly, the CRA datasets 240-1A through 240-1R may indicate the extent and/or rate of aging incurred by the ESD 105 attributable to charge conditions, e.g., charge conditions CC-A through CC-R.

As disclosed herein, CRA datasets 240-1 may be configured to model CRA mechanisms of the ESD 105 and/or distinguish performance degradation attributable to charge conditions from aging attributable to other, non-charge-related conditions (e.g., distinguish aging attributable to charge conditions from aging attributable to discharge conditions). Performance degradation observed in the CRA datasets 240-1 of an ESD 105 may indicate a fraction and/or percentage of performance degradation attributable to CRA mechanisms of the ESD 105. For example, the maximum extent of performance degradation observed across the CRA datasets 240-1A through 240-1R may be used to estimate M_{ch}^{o} for the ESD 105 and/or other parameters of Eq. 1-16.

The ESDM module 112 may retrieve CRA datasets 240-1 from a datastore 114, as disclosed herein. Alternatively, or in addition, the ESDM module 112 may be configured to acquire CRA datasets 240-1 by use of an evaluation system 172-1 or the like. Acquiring a CRA dataset 240-1 configured to model CRA performance degradation incurred by an ESD 105 under specified charge conditions may comprise, inter alia: a) configuring the evaluation system 172-1 to subject the ESD 105 to charge operations having specified charge conditions over a specified usage period, e.g., charge operations implemented per a specified charge configuration 164, b) configuring the evaluation system 172-1 to subject the ESD 105 to nominal discharge operations over the usage period, e.g., discharge operations configured to subject the ESD 105 to nominal discharge conditions per a nominal discharge configuration 166 determined for the ESD 105, and c) acquiring ESDM data 250 comprising measurements of one or more ESD performance characteristics at respective offsets within the usage period.

The modeling engine 212 may leverage CRA datasets 240-1 to, inter alia, model charge-related aspects of the aging model 120. For example, the modeling engine 212 utilize CRA datasets 240-1 (and/or other non-charge-related aging data, such as DRA datasets 240-2) to learn a charge-related aspects of the aging model 120, e.g., learn a CRA model 124 of the ESD 105. Learning the CRA model 124 may comprise learning parameters of Eq. 1-16, e.g., learning M_{ch}^{o}, p_{ch}, q_{ch}, and/or the like. In some implementations, the modeling engine 212 may be further configured to utilize non-charge-related aging (NCRA) data to develop and/or refine the CRA model 124. The modeling engine 212 may, for example, compare aging incurred by the ESD 105 under respective charge conditions (e.g., CC-A through CC-R) to aging incurred under nominal charge conditions (e.g., CC-X, as disclosed in further detail herein) to, inter alia, estimate M_{ch}^{o} of the ESD 105. Alternatively, or in addition, the modeling engine 212 may be configured to learn charge-related aspects of the aging model 120 (e.g., learn a CRA model 124) through and/or by use of AI/ML techniques, as disclosed in further detail herein.

In some implementations, the ESDM module 112 may be further configured to acquire discharge-related aging datasets 240-2. As used herein, a discharge-related aging (DRA) dataset 240-2 may comprise and/or refer to an aging dataset 240 configured to measure performance degradation attributable to discharge conditions. In other words, a DRA dataset 240-2 may comprise and/or refer to an aging dataset 240 acquired under nominal charge conditions. As used herein, nominal charge conditions may comprise and/or refer to charge conditions predicted to result in nominal charge-related aging, e.g., charge operations performed at charge rates of C₁ or lower, nominal voltage and/or SoC differentials, nominal charge temperatures (e.g., about 30° C.), and so on. Nominal charge conditions may comprise and/or refer to charge conditions predicted to result in charge-related performance degradation that satisfies a threshold (M_{ch_nominal}), e.g., charge conditions such that M_{ch}≤M_{ch_nominal}. Accordingly, a DRA dataset 240-2 may comprise and/or be referred to as nominal-charge-related aging (NCRA) data and/or an NCRA dataset 240.

The ESDM module 112 may be configured to acquire DRA datasets 240-2 configured to model a plurality of discharge conditions. In the FIG. 2B example, the aging data 215 acquired by the ESDM module 112 may comprise P DRA datasets 240-2. The DRA datasets 240-2A through 240-2P may comprise respective EPM data 258 (EPM data 258-2A through 258-2P) acquired under operating conditions OC-2A through OC-2P (as indicated by respective OCM data 252-2A through 252-2P). More specifically, DRA datasets 240-2A through 240-2P may be acquired under a plurality of different discharge conditions (DC-A through DC-Q) and a substantially constant set of nominal charge conditions (CC-X). Accordingly, the DRA datasets 240-2A through 240-2P may indicate the extent and/or rate of DRA aging incurred by the ESD 105 attributable to discharge conditions, e.g., discharge conditions DC-A through DC-Q.

As disclosed herein, DRA datasets 240-2 may be configured to model DRA mechanisms of the ESD 105 and/or distinguish performance degradation attributable to discharge conditions from aging attributable to other, NDR conditions (e.g., distinguish aging attributable to discharge conditions from aging attributable to charge conditions). Performance degradation observed in DRA datasets 240-2 may indicate a fraction and/or percentage of performance degradation attributable to DRA mechanisms of the ESD 105. For example, the maximum extent of performance degradation observed across the DRA datasets 240-2A through 240-2P may be used to estimate M_{d}^{o} and/or other parameters of Eq. 17-32.

The ESDM module 112 may retrieve DRA datasets 240-2 from a datastore 114, as disclosed herein. Alternatively, or in addition, the ESDM module 112 may be configured to acquire DRA datasets 240-2 by use of an evaluation system 172-1 or the like. Acquiring a DRA dataset 240-2 configured to model DRA performance degradation incurred by an ESD 105 under specified discharge conditions may comprise, inter alia: a) configuring the evaluation system 172-1 to subject the ESD 105 to nominal charge operations over a specified usage period, e.g., charge operations configured to subject the ESD 105 to nominal charge conditions per a nominal charge configuration 164 determined for the ESD 105, b) configuring the evaluation system 172-1 to subject the ESD 105 to discharge operations having specified discharge conditions over the usage period, e.g., discharge operations implemented according to a specified discharge configuration 166, and c) acquiring ESDM data 250 comprising measurements of one or more ESD performance characteristics at respective offsets within the usage period.

The modeling engine 212 may leverage DRA datasets 240-2 to, inter alia, model discharge-related aspects of the aging model 120. For example, the modeling engine 212 may utilize DRA datasets 240-2 (and/or other NDRA data, such as CRA datasets 240-1) to learn a discharge-related aging (DRA) model 126 of the ESD 105. Learning the DRA model 126 may comprise learning parameters of Eq. 17-32, e.g., learning M_{d}^{o}, p_{d}, q_{d}, and/or the like. Alternatively, or in addition, the modeling engine 212 may be configured to learn discharge-related aspects of the aging model 120 (e.g., learn a DRA model 126) through and/or by use of AI/ML techniques, as disclosed in further detail herein.

Although particular examples of aging datasets 240 as described herein (e.g., CRA datasets 240-1, DRA datasets 240-2 and the like), the disclosure is not limited in this regard and could be adapted to utilize any suitable type of aging data 215 pertaining to any suitable range of ESD operating conditions. As illustrated in FIG. 2B, in some implementations, the ESDM module 112 may be configured to acquire one or more operating-condition-related aging datasets 240-3. As used herein, an operating-condition-related aging (ORA) dataset 240-3 may comprise and/or refer to an aging dataset 240 configured to measure performance degradation incurred by an ESD 105 under specified charge conditions and/or discharge condition. In other words, ORA data (e.g., an ORA dataset 240-3) may comprise and/or refer to aging data 215 captured under arbitrary charge conditions and/or discharge conditions. Accordingly, ORA datasets 240-3 may be configured to quantify performance degradation incurred due to a plurality of ESD aging mechanisms, e.g., quantify performance degradation attributable to charge conditions (e.g., CRA mechanisms of the ESD 105), discharge conditions (e.g., DRA mechanisms of the ESD 105), and so on. In the FIG. 2B example, the aging data 215 comprises G ORA datasets 240-3. The ORA datasets 240-3A through 240-3G may comprise EPM data 258-3A through 258-3G configured to measure performance degradation incurred by the ESD 105 under operating conditions OC-3A through OC-3G (as indicated by respective OCM data 252-3A through 252-3G), e.g., charge conditions CC-S through CC-Y and discharge conditions DC-Q through DC-W, respectively.

The modeling engine 212 may be further configured to construct an aging model 120 for the ESD 105 from, inter alia, models developed for respective aging mechanisms. The modeling engine 212 may derive the aging model 120 from one or more of the CRA model 124 and the DRA model 126 learned for the ESD 105. For example, the modeling engine 212 may derive the aging model 120 by, inter alia, combining the CRA model 124 and DRA model 126 per one or more of Eq. 33-36, e.g., determine an aging model ψₜₒₜₐₗ(t)=ψ_{ch}(t)+ψ_{d}(d), where ψ_{ch}(t) is a function configured to model CRA mechanisms of the ESD 105 and ψ_{d}(t) is a function configured to model DRA mechanisms of the ESD 105, as disclosed herein.

Alternatively, or in addition, the modeling engine 212 may be configured to learn aging models 120 through artificial intelligence and/or machine-learning (AI/ML) techniques. FIG. 2C is a schematic block diagram of another example of an ESD manger 110. In the FIG. 2C example, the modeling engine 212 of the ESD manager 110 may comprise and/or be coupled to an AI/ML system 214. The AI/ML system 214 many comprise any suitable AI/ML means, including, but not limited to: a supervised learning AI/ML architecture, an unsupervised AI/ML architecture, a reinforcement AI/ML architecture, a deep learning AI/ML architecture, an artificial neural network (ANN), a convolutional neural network (CNN), a recurrent or recursive neural network (RNN), an AI/ML sorting architecture, an AI/ML clustering architecture, a generative model, and/or the like. The AI/ML system 214 may comprise and/or be configured to learn an AI/ML aging model 120-1 configured to, inter alia, predict performance degradation to be incurred by an ESD 105 under specified operating conditions. For example, the AI/ML system 214 may be configured to learn an AI/ML aging model 120-1 comprising a machine-learned function(s) ψₜₒₜₐₗ(t), ψ_{ch}(t), ψ_{d}(t), and/or the like, as disclosed herein.

In some implementations, the AI/ML system 214 may comprise a training module 216. The training module 216 may be configured to learn AI/ML aging models 120-1 for respective ESD 105 (and/or ESD types). The training module 216 may be configured to implement any suitable AI/ML technique. In the non-limiting example of FIG. 2C, the training module 216 may be configured to learn AI/ML aging models 120-1 through supervised machine learning. Learning an AI/ML aging model 120-1 for an ESD 105 (and/or ESD type) may comprise, inter alia, a) initializing the AI/ML aging model 120-1 (e.g., initializing one or more AI/ML components, such as ANN, CNN, RNN, and/or the like), b) causing the AI/ML aging model 120-1 to process training data 225, c) evaluating aging predictions 140 generated by the AI/ML aging model 120-1 in response to the training data 225, and d) refining the AI/ML aging model 120-1 based on the evaluating.

The AI/ML aging model 120-1 may be trained by use of, inter alia, training data 225. The training data 225 may comprise, inter alia, aging data 215 as disclosed herein. For example, the training data 225 may comprise a plurality of aging datasets 240. The training data 225 may comprise any suitable aging datasets 240 including, but not limited to, CRA datasets 240-1, DRA datasets 240-2, ORA datasets 240-3, and/or the like. As disclosed herein, the aging datasets 240 may be configured to quantify ESD performance degradation incurred by an ESD 105 over a usage period under specified operating conditions. The aging datasets 240 may comprise EPM data 258 comprising measurements of one or more ESD performance characteristics acquired over the usage period, e.g., measurements acquired at respective times, offsets, or the like. The aging datasets 240 may further comprise OPM data 252 configured to characterize the operating conditions of the ESD 105 during the usage period. In the FIG. 2C example, the modeling engine 212 may be configured to learn the AI/ML aging model 120-1 by use of training data 225 comprising aging datasets 240A-V. As illustrated in FIG. 2C, the aging datasets 240A-V may comprise EPM data 258A-V acquired under operating conditions characterized by respective OPM data 252A-V, e.g., operating conditions OC-A through OC-V, corresponding to charge conditions CC-A through CC-V and/or discharge conditions DC-A through DC-V.

The AI/ML aging model 120-1 may be configured to generate aging predictions 140 in response to the training data 225. The AI/ML aging model 120-1 may be configured to generate aging predictions 140 in response to OPM data 252 of respective aging datasets 240, e.g., in response to OC models 130, charge models 134, discharge models 136, and/or other means for characterizing ESD operating conditions. For example, the aging prediction 140 generated by the AI/ML aging model 120-1 in response to the aging dataset 240A may be configured to predict aging incurred by the ESD 105 under operating conditions OC-A, e.g., charge conditions CC-A, discharge conditions DC-A. In other words, the AI/ML aging model 120-1 may be configured to generate an aging prediction 140 in response to OPM data 252A. The aging prediction 140 may comprise and/or be derived from aging metrics 142 predicted for the of aging dataset 240A (operating conditions OC-A), such as Mₜₒₜₐₗ, M_{oc}, ψₜₒₜₐₗ(t), ψ_{OC}(t), and/or the like. In some implementations, the aging prediction 140 may comprise and/or be derived from CC metrics 144 predicted for charge conditions (CC-A) of the aging dataset 240A, such as M_{ch}, ψ_{ch}(t), and/or the like. Alternatively, or in addition, the aging prediction 136 may comprise and/or be derived from discharge metrics 146 predicted for discharge conditions (DC-A) of the aging dataset 240A, such as M_{d}, ψ_{d}(t), and/or the like.

Evaluating the aging prediction 140 determined for a specified set of operating conditions may comprise comparing the aging prediction 140 to known aging data associated with the operating conditions. For example, evaluating the aging prediction 140 generated by the AI/ML aging model 120-1 in response to the aging dataset 240A may comprise comparing the aging prediction 140 to known aging characteristics of the ESD 105 under operating conditions OC-A. The evaluating may comprise comparing the aging prediction 140 to EPM data 258A of the aging dataset 240A. The evaluating may comprise comparing aging metrics 142 predicted for the operating conditions (OC-A) to performance degradation observed in the EPM data 258A.

The training module 216 may be configured to generate feedback data 217 in response to respective aging predictions 140. The feedback data 217 may be configured to, inter alia, quantify error between aging predictions 140 generated by the AI/ML aging model 120-1 for respective operating conditions and known EPM data 258 associated with the operating conditions. For example, the feedback data 217 generated in response to evaluation of the aging prediction 140 produced in response to aging dataset 240A (e.g., operating conditions OC-A of OPM data 252A) may quantify error between the aging prediction 140 and the EPM data 258A of the aging dataset 240A.

The training module 216 may be further configured to update and/or refine the AI/ML model 120-1 based on the feedback data 217. For example, the training module 216 may be configured to update AI/ML components of the AI/ML aging model 120-1 (e.g., ANN weights and/or the like) to, inter alia, reduce error between the aging predictions 140 generated by the AI/ML aging model 120-1 and the corresponding EPM data. The training module 216 may be configured to learn an AI/ML aging model 120-1 capable of accurately predicting aging under operating conditions characterized by the training data 225. The AI/ML aging model 120-1 may be trained over a plurality of iterations, generations, epochs, and/or the like. The trained AI/ML aging model 120-1 may then be used to generate aging predictions 140 for arbitrary operating conditions. For example, the trained AI/ML aging model 120-1 may be configured to generate an aging prediction 140 in response to OPM data 252Z configured to characterize arbitrary operating conditions (OC-Z) such as an OC model 130 of the like, the operating conditions (OC-Z) comprising arbitrary charge conditions (CC-Z) and/or arbitrary discharge conditions (DC-Z) that may not be covered in the training data 225.

Although examples of techniques for learning aging models 120 are described herein, the disclosure is not limited in this regard and could be adapted to utilize any suitable modeling technique. For example, the modeling engine 212 may learn ESD aging trends using any suitable function, e.g., exponential functions, exponential decay functions, sigmoid expressions, sigmoid rate expressions, polynomials, a spline, and/or the like. Alternatively, or in addition, the modeling engine 212 may learn AI/ML aging models 120-1 comprising any suitable AI/ML architecture through any suitable AI/ML technique.

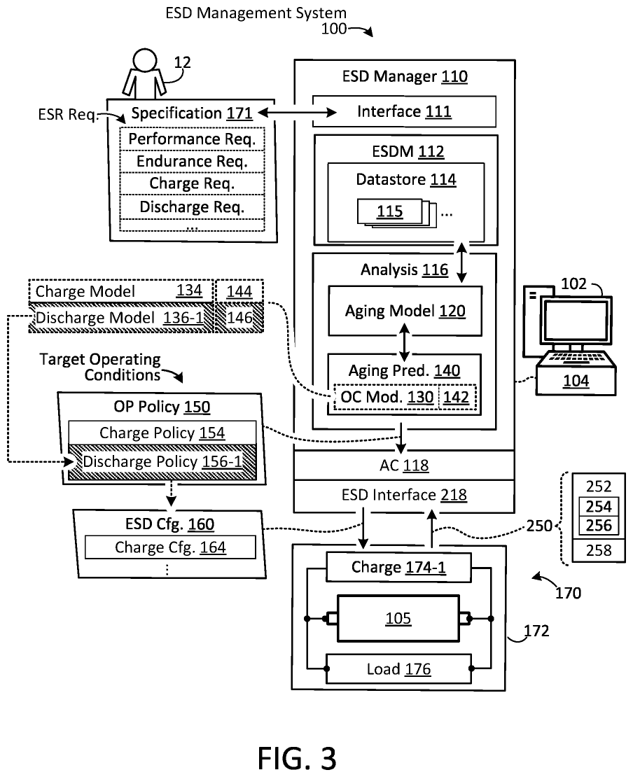

FIG. 3 is a schematic block diagram illustrating another example of an ESD management system 100 comprising an ESD manager 110. Aspects of the ESD manager 110 may be embodied and/or implemented by computing resources 104 of a computing device 102, as disclosed herein.

In the FIG. 3 example, the ESD manager 110 may be configured to manage implementation of an application 170 by an ESD 105 (and/or a particular ESD type, as disclosed herein). The application 170 may comprise and/or be embodied by a system 172 comprising one or more ESD modules 174. The system 172 may, for example, comprise a charge module 174-1 configured to implement ESD charge operations.

The ESD manager 110 may be configured to control aspects of the charge conditions of ESD 105 within the application 170, e.g., control aspects of charge operations implemented by the charge module 174-1. In the FIG. 3 example, the ESD manager 110 may be configured to treat ESD discharge conditions as constants or constraints as opposed to a variable that can be adjusted. For example, ESD discharge conditions may be managed by the application 170, e.g., discharge operations may be managed by ESD module(s) 134 and/or other components of the ESDA system 172 (not shown in FIG. 3 to avoid obscuring details of the illustrated examples).

As disclosed herein, the ESD manager 110 may be configured to manage implementation of the application 170 by an ESD 105 (and/or ESD 105 of a specified ESD type). The ESD manager 110 may be configured to determine an OP policy 150 configured to manage utilization of the ESD 105 within the application 170.

In the FIG. 3 example, the OP policy 150 may be configured to incorporate a discharge model 136-1. The discharge model 136-1 may be configured to characterize predicted discharge conditions of the ESD 105 within the application 170. The discharge model 136-1 may, therefore, comprise and/or be referred to as a fixed, predetermined, and/or predicted discharge model 136-1. The ESD manager 110 may derive aspects of the discharge model 136-1 from the specification 171 of the application 170. For example, aspects of the discharge model 136-1 may be derived from ESR requirements of the application 170, such as discharge requirements (e.g., minimum discharge rate (r_{d_max}), predicted discharge temperature (T_{d}), and/or the like), performance requirements, and/or the like. In some implementations, aspects of the discharge model 136-1 may be derived from characteristics of the application 170 and/or ESDA system 172. For example, the ESD manager 110 may be configured to determine aspects of the discharge model 136-1 based, at least in part, on power requirements of one or more components of the application 170, such as the load 176 and/or other ESD modules 134. Alternatively, or in addition, aspects of the predicted discharge model 136-1 may be received from a user 12, e.g., through user interaction with a GUI managed by the interface module 111. In some implementations, the ESD manager 110 may be configured to estimate aspects of the discharge model 136-1. For example, the ESD manager 110 may configure the discharge model 136-1 in accordance with nominal and/or default discharge conditions of the ESD 105 and/or application 170. In some implementations, the ESD manager 110 may be configured to determine and/or revise the predicted discharge conditions (e.g., discharge model 136-1) based on ESDM data 250, as disclosed in further detail herein.

As disclosed herein, in the FIG. 3 example, the analysis module 116 may treat the discharge model 136-1 as a constant or constraint. The analysis module 116 may be further configured to incorporate the discharge model 136-1 into the OP policy 150 determined for the ESD 105. In other words, the OP policy 150 determined for the ESD 105 may be configured to model and/or incorporate the predicted discharge conditions of the ESD 105 within the application 170 (and corresponding discharge-related aging metrics 146). As illustrated in FIG. 3, the OP policy 150 may comprise a discharge policy 156-1, the discharge policy 156-1 comprising and/or derived from the discharge model 136-1.

Determining the OP policy 150 for the ESD 105 may comprise configuring charge-related aspects of the OP policy 150 (e.g., the charge policy 154) to satisfy requirements of the application 170, while treating discharge-related aspects of the OP policy 150 as constraints (e.g., the discharge policy 156-1 and/or corresponding discharge conditions). The analysis module 116 may be configured to generate, evaluate, and/or modify candidate charge policies 154 to determine target operating conditions predicted to satisfy the ESR requirements of the application 170 (and/or satisfy other objectives, such as charge requirements of the application 170, as disclosed herein).

In the example illustrated in FIG. 3, managing implementation of the application 170 by an ESD 105 (and/or ESD 105 of a particular type) may comprise: a) retrieving an aging model 120 for the ESD 105, b) determining an OP policy 150 specifying target operating conditions for the ESD 105, the OP policy 150 comprising a charge policy 154 determined by the analysis module 116 and a discharge policy 156 corresponding to the predicted discharge conditions of the ESD 105 within the application 170, and c) generating an ESD CFG 160 configured to cause the application 170 to utilize the ESD 105 in accordance with the OP policy 150. The ESD CFG 160 may be configured to cause the application 170 to utilize the ESD 105 under operating conditions corresponding to the target operating conditions of the OP policy 150. As illustrated in the FIG. 3 example, the ESD CFG 160 may comprise a charge configuration 164 configured to control aspects of the charge operations performed by the charge module 174-1. In some implementations, the ESD CFG 160 may not include a discharge configuration 166, e.g., since discharge conditions of the ESD 105 may be managed by the application 170. The charge policy 154 determined by the ESD manager 110 may specify parameters and/or settings of charge operations to be performed on the ESD 105 within the application 170. The charge configuration 164 generated by the AC module 118 may be configured to cause ESD modules 174 of the application 170 (e.g., charge module 174-1) to implement charge operations in accordance with the target charge conditions of the charge policy 154, as disclosed herein, e.g., may comprise instructions, commands, configuration data, parameters, and/or other information to manage aspects of charge operations performed on the ESD 105 within the system 172.

The charge policy 154 (and/or target charge conditions and corresponding charge configuration 164) may comprise and/or correspond to any suitable type of charge operation including, but not limited to: single-step charge operations (e.g., single-step charge operations having an M_{ch} modeled per Eq. 1-6), two-step charge operations (e.g., two-step charge operations having an M_{ch} modeled per Eq. 7), multi-step charge operations (e.g., N-step charge operations having an M_{ch} modeled per Eq. 8-13), multi-step charge operations with intervening rest periods (e.g., N-step charge operations with optional rest periods having an M_{ch} modeled per Eq. 14), period-specific charge operations, and/or the like.

In the FIG. 3 example, determining the OP policy 150 (charge policy 154) may comprise determining target charge conditions that satisfy requirements of the application 170, e.g., satisfy requirements defined within a specification 171 of the application 170 or the like. Determining the target charge conditions may comprise designing an OC model 130 having charge conditions (e.g., a charge model 134) under which the ESD 105 is predicted to satisfy performance requirements of the application 170. The analysis module 112 may configure the target charge conditions to produce CC metrics (e.g., Mₜₒₜₐₗ or M_{ch}) that satisfy a specified threshold (M_{threshold}), e.g., determine a charge model 134 and/or charge conditions where Mₜₒₜₐₗ<M_{threshold} and/or where M_{ch}<M_{threshold}.

In some implementations, the target charge conditions may be determined based on default or nominal discharge conditions, such as nominal or baseline discharge conditions, e.g., a nominal discharge rate (r_{d}) of about C₁, nominal starting voltage (V_{d_start}), nominal discharge voltage (V_{d}), nominal temperature (T_{d}), and so on. For example, the target charge conditions may be configured such that, M_{ch}+M_{d_nom}<M_{threshold}, where M_{d_nom} is a prediction of performance degradation attributable to default or nominal discharge conditions.

Alternatively, the target charge conditions may be determined based on a specified set of predetermined or fixed discharge conditions, such as discharge conditions corresponding to discharge requirements of the application 170, as disclosed herein. The analysis module 116 may configure the OC models 130 used to determine target charge conditions for the ESD 105 in accordance with the predicted discharge conditions of the ESD 105 within the application 170. In other words, the OC models 130 evaluated by the analysis module 116 may be configured to model fixed, predetermined, and/or predicted discharge conditions of the ESD 105 as opposed to nominal or default discharge conditions. The analysis module 116 may be configured to determine target charge conditions wherein M_{ch}+M_{d_req}≤M_{threshold}, where M_{d_req} is the extent of performance degradation predicted to be incurred due to the discharge requirements of the application 170 (e.g., per the predicted discharge conditions of the ESD 105 within the application as characterized by the discharge model 136-1).

Alternatively, or in addition, the analysis module 112 may configure the target charge conditions such that performance degradation incurred by a specified performance characteristic of the ESD 105 is predicted to remain above a threshold for a specified usage period, e.g., target charge conditions wherein ψₜₒₜₐₗ(tₗ)<ψ_{threshold} and/or ψ_{ch}(tₗ)<ψ_{threshold}, where ψ_{threshold} is a performance requirement defined for the specified performance characteristic and tₗ is the corresponding endurance requirement. In some implementations, the target charge conditions may be determined based on a specified set of discharge conditions, such as nominal or baseline discharge conditions, as disclosed herein. For example, the analysis module 116 may configure the target charge conditions such that ψ_{ch}(tₗ)+ψ_{d_nom}(tₗ)<ψ_{threshold}, where ψ_{d_nom} is a function configured to model performance degradation under nominal and/or default discharge conditions. Alternatively, the target charge conditions may be determined based, at least in part, on discharge requirements of the application 170, as disclosed herein. The target discharge conditions may be configured such that ψ_{ch}(tₗ)+ψ_{d_req}(tₗ)<ψ_{threshold}, where ψ_{d_req} is a function configured to model performance degradation incurred by the ESD 105 under discharge conditions corresponding to the discharge requirements of the application 170 (e.g., discharge model 136-1).

As disclosed herein, the analysis module 116 may be further configured to determine OP policies 150 comprising target operating conditions that satisfy performance and other types of requirements, such as charge requirements, discharge requirements, and/or the like. In the FIG. 3 example, the analysis module 116 may configure the charge policy 154 to, inter alia, satisfy charge requirements of the application 170. For example, the specification 171 may require that ESD 105 be charged to an SoC of at least 80% in charge operations having a maximum duration of T_{ch_max}, or the like, and the analysis module 116 configure the charge policy 154 to satisfies the charge requirements, e.g., constrain the charge policy 154 to charge conditions having an end SoC of at least 80% (and/or corresponding end charge voltage V_{ch_end}).

Determining the OP policy 150 (charge policy 154 in the FIG. 3 example) may comprise evaluating one or more aging predictions 140, each aging prediction 140 configured to model performance degradation attributable to a specified OC model 130 (e.g., a set of charge conditions and/or discharge conditions). In some implementations, determining the charge policy 154 may comprise iteratively evaluating and/or modifying OC models 130 until termination criteria are satisfied. The termination criteria may comprise an iteration limit, suitability criteria (e.g., terminate in response to identifying target charge conditions that satisfy the ESR specification 171), optimization criteria (e.g., terminate in response to identifying optimal charge conditions per an objective function, as disclosed in further detail herein), and/or the like.

In some implementations, the analysis module 116 may be configured to determine target charge conditions using, inter alia, an optimization procedure, as disclosed in further detail herein. The analysis module 116 may be configured to evaluate aging predictions 140 corresponding to any suitable type of charge operation. The analysis module 116 may be further configured to maintain information pertaining to the aging predictions 140 determined for respective operating conditions within the datastore 114 and/or other DSR resources 104-2, e.g., within ESD profiles 115, as disclosed herein. The ESD profiles 115 may comprise ESD-specific characteristics of respective ESD 105 (and/or ESD types), such as ESD capacity (C), maximum voltage (Vₘₐₓ), minimum voltage (Vₘᵢₙ), maximum charge rate (r_{ch_max}), maximum discharge rate (r_{d}ma, reference temperature (T_{ref}), polarization offset (ΔVₚₒₗ), and/or the like. The ESD profiles 115 may further comprise information pertaining to ESD aging characteristics, such as aging models 120, aging predictions 140 and/or aging metrics 142 determined for ESD 105 under specified operating conditions, aging data 215 (e.g., aging datasets 240), and/or the like.

Table 1 shows examples of aging predictions 140 (and/or aging metrics 142) determined for an ESD 105 across a range of operating conditions. The M_{ch} quantities of Table 1 may be based, at least in part, on ESD-specific characteristics, Vₘᵢₙ=3.0V, Vₘₐₓ=4.2V, M_{ch}^{o}=0.3, r_{ch_max}=2, and so on. The M_{ch} quantities of the aging predictions 140 illustrated in Table 1 may be configured to estimate and/or predict the extent of ESD aging attributable to charge conditions CC_A through CC_G under substantially constant discharge conditions (e.g., nominal discharge conditions DC-X, as disclosed herein).

TABLE 1

| Case | Vₛₜₐᵣₜ | V_{ch} | r_{ch} | b | c | d | f_{SoC} | M_{ch} | % of M_{ch}^{o} |
|---|---|---|---|---|---|---|---|---|---|
| A | 3.0 | 3.7 | 1 | 0.38 | 1 | 0.881 | 0.368 | 0.07 | 23 |
| B | 3.0 | 4.2 | 1 | 1 | 1 | 1 | 1 | 0.19 | 63 |
| C | 3.7 | 4.2 | 1 | 1 | 0.420 | 1 | 0.823 | 0.156 | 52 |
| D | 3.7 | 4.1 | 2 | 0.59 | 0.364 | 0.976 | 0.471 | 0.136 | 45 |
| E | 3.3 | 4.2 | 2 | 1 | 0.75 | 1 | 0.933 | 0.242 | 81 |
| F | 3.7 | 4.2 | 2 | 1 | 0.42 | 1 | 0.823 | 0.213 | 71 |
| G* | — | 4.2 | — | — | — | — | — | 0.15 | 33 |

The M_{ch} quantities of Table 1 may be configured to model charge operations performed at a determined temperature (e.g., where the α_{ch} parameter is about 1). The disclosure is not limited in this regard, however. The ESD manager 110 may be configured to generate aging predictions 140 configured to model charge operations performed at respective charge temperatures T_{ch}, such as higher charge temperatures (e.g., where T_{ch}>T_{ref} resulting in α_{ch} parameters less than one per Eq. 3 and/or 10), lower charge temperatures (e.g., where T_{ch}<T_{ref} resulting in α_{ch} parameters greater than one), and so on. The charge conditions CC_G may be configured to predict CRA incurred during charge rest periods, as disclosed herein; the parameter g for predicting aging during such rest periods per Eq. 14 may be 0.5.

The aging model 120 may be configured to quantify the relative impact of respective charge conditions on CRA mechanisms of the ESD 105. For example, the aging model 120 (and/or corresponding aging predictions 140) may indicate a degree to which the charge rate (r_{ch}), end charge voltage (V_{ch_end}), and/or other charge conditions impact the extent of CRA incurred by the ESD 105 and/or the rate at which such aging is incurred over time.

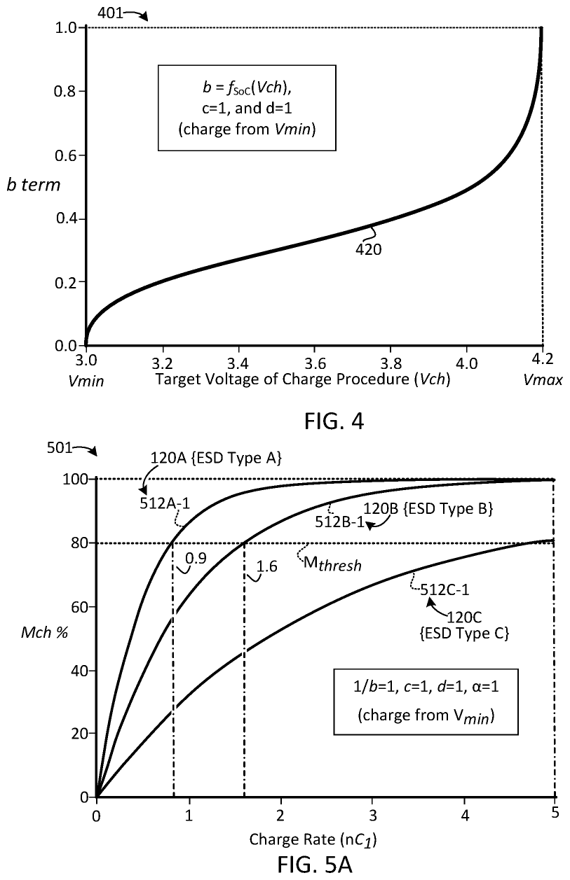

FIG. 4 comprises a plot 401 illustrating examples of an aging model 12 configured to model relationships between charge rate and CRA incurred by the ESD 105. The plot line 412 illustrates the impact of the end voltage (V_{ch_end}) charge condition on the b_{ch} term used to predict M_{ch} (e.g., per Eq. 1-6, 8-13, or the like). The plot 401 may be generated by use of the aging model 120 determined for the ESD 105 of Table 1 (e.g., an ESD 105 having a Vₘₐₓ of 4.2v and Vₘᵢₙ of 3.0v). The b_{ch} term of the aging model 120 (e.g., Eq. 3 and/or 10) may be expressed as a function of end charge voltage (V_{ch_end} represented by variable x_{ch}), as illustrated in Eq. 37 below:

$${b}_{ch} ( {x}_{ch} ) = \frac{( 4.2 - 3. )}{\frac{1}{2} ( 4.2 + 3. )} {( \frac{{x}_{ch} - 3.}{4.2 - {x}_{ch} + 0.01} )}^{\frac{1}{{x}_{ch}}} \qquad Eq . 37$$

The ESD manager 110 may use information pertaining to the illustrated relationships between M_{ch} and V_{ch_end} (and/or V_{ch_start}−V_{ch_end}) to, inter alia, determine target charge conditions for the ESD 105. For example, the analysis module 116 may utilize such relationships to configure target charge conditions that satisfy requirements of the application 170, e.g., result in M_{ch}<M_{threshold}, ψ_{ch}(tₗ)≤ψ_{threshold}, and/or the like.

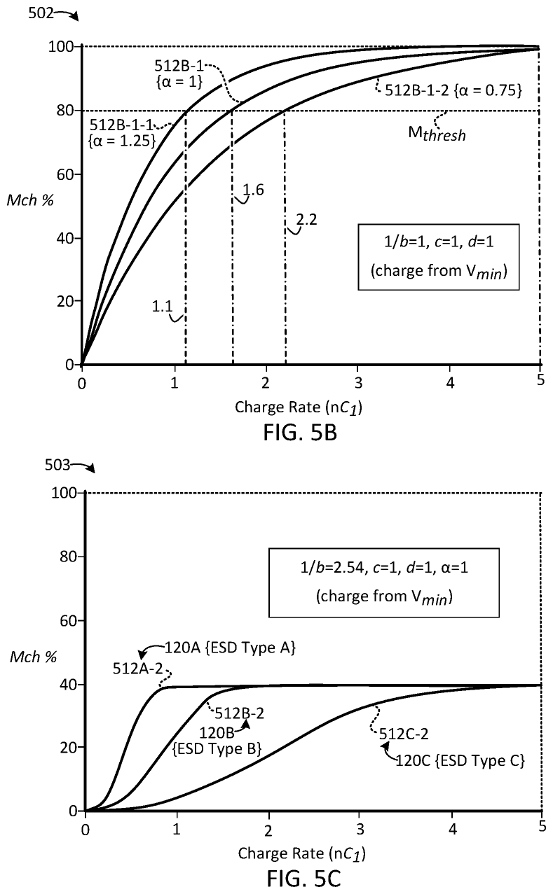

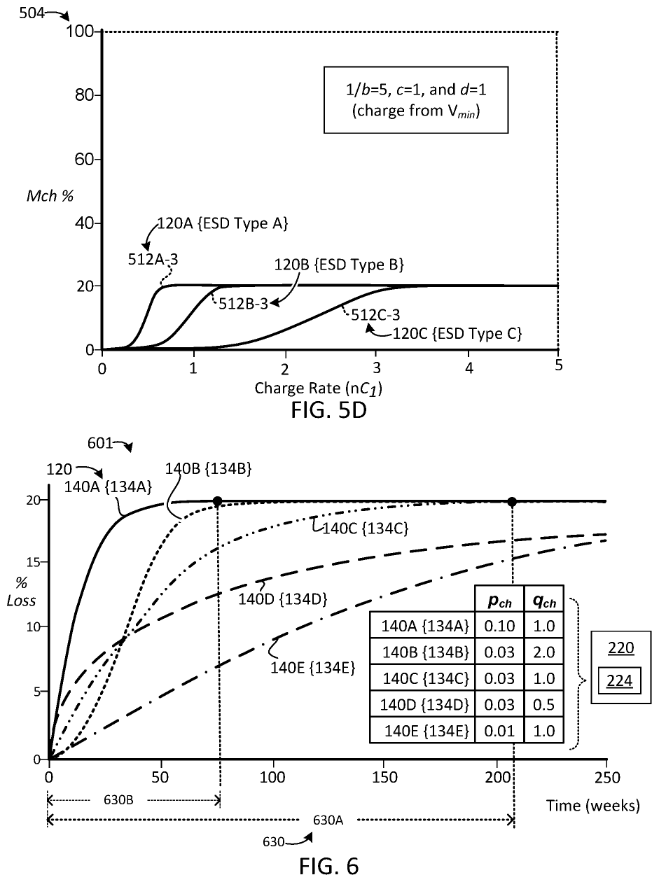

The aging models 120 disclosed herein may be configured to model the impact of any suitable operating conditions. FIG. 5A comprises a plot 501 illustrating examples of aging models 120 developed for different types of ESD 105, e.g., ESD 105 having different ESD-specific characteristics. The aging models 120A-C may be configured to model age-related performance degradation incurred by ESD types A-C, respectively. ESD types A-C may have substantially the same energy storage capacity (C) but may differ with respect to maximum charge rate (r_{ch_max}); the aging model 120A be configured to model ESD type A having a maximum charge rate of 1C, aging model 120B may be configured to model ESD type B having a maximum charge rate of 2C, and aging model 120C may be configured to model ESD type C having a maximum charge rate of 5C.

FIG. 5A further illustrates M_{ch} as a function of charge rate (rₕ) for ESD types A-C, wherein other charge conditions are characterized by parameters 1/b_{ch}=1, c_{ch}=1, d_{ch}=1, α_{ch}=1, e.g., per Eq. 1-6 and/or 8-13. Plot lines 512A-1 through 512C-1 illustrate the predicted impact of charge rates (r_{ch}) up to about 5C. As illustrated in FIG. 5A, ESD 105 having lower maximum charge rates may be more sensitive to charge rate than ESD 105 having higher maximum charge rates, e.g., may incur larger extents of CRA under higher charge rates than ESD 105 having higher maximum charge rates.

The analysis module 116 may utilize relationships between charge conditions and ESD aging of the disclosed aging models 120 to, inter alia, configure target operating conditions for respective ESD 105. For example, the analysis module 116 may utilize the information illustrated in plot 501 to determine target charge conditions predicted to satisfy the performance requirements of an application 170. In the FIG. 5A example, the ESR specification 133 of the application 170 may define an M_{threshold} of about 80%. The analysis module 116 may configure target charge conditions for ESD types A-C to satisfy this threshold; target charge conditions for ESD type A may limit r_{ch} to about 0.9C, target charge conditions for ESD type B may limit r_{ch} to about 1.6C and the target charge conditions for ESD type C may limit r_{ch} to about 5C (where other charge conditions are such that 1/b_{ch}=1, c_{ch}=1, d_{ch}=1, α_{ch}=1).

FIG. 5B is a plot 502 illustrating further examples of aging models 120 as disclosed herein. FIG. 5B illustrates the impact of charge temperature (T_{ch}) on aging incurred by ESD 105 of ESD type B (r_{ch_max}=2C) across a range of charge rates, e.g., from 0 to about 5C as in the FIG. 5A example. Plotline 512B-1 illustrates M_{ch} for ESD type B at charge temperatures (T_{ch}) where α_{ch}=1, plotline 512B-1-1 illustrates the impact of lower charge temperatures (T_{ch}) on ESD 105 of ESD type B (e.g., T_{ch} where α_{ch} is about 1.25), and plotline 512B-1-2 illustrates the impact of higher charge temperatures (e.g., T_{ch} where α_{ch} is about 0.75) and other ESD operating conditions are substantially constant (e.g., 1/b_{ch}=1, c_{ch}=1, d_{ch}=1, and so on).

In the temperature range illustrated in the FIG. 5B example, lower charge temperatures may result in increased performance degradation as a function of charge rate (r_{ch}). The analysis module 116 may utilize such relationships to, inter alia, determine target operating conditions for ESD 105, as disclosed herein. In the non-limiting example above (an application 170 having an M_{threshold} of about 80%), the analysis module 116 may utilize the aging model 120 developed for ESD type B to limit r_{ch} to lower charge rates (e.g., about 1.1C) under operating conditions comprising lower charge temperatures (e.g., where α_{ch} is about 1.25), limit r_{ch} to about 1.6C under nominal charge temperatures (e.g., where α_{ch} is about 1.0 as in the FIG. 5A example), limit r_{ch} to about 2.2C under higher charge temperatures (e.g., where α_{ch} is about 0.75), and so on.

As disclosed herein, the aging models 120 of the ESD manager 110 may be configured to predict the impact of any suitable operating condition(s) on ESD aging. FIGS. 5C and 5D illustrate examples of aging models 120 configured to model the impact of end charge voltage and/or SoC (V_{ch_end} and/or SoC_{ch_end}) on ESD aging over a range of charge rates (r_{ch}). More specifically, FIGS. 5C and 5D illustrate the impact of lower end charge voltages; FIG. 5C models charge operations where V_{ch_end} is such that 1/b_{ch}=2.54 (e.g., per Eq. 3 and/or 10) and FIG. 5D models charge operations where V_{ch_end} is such that 1/b_{ch}=5, as opposed to the higher end charge voltages of FIGS. 5A and 5B, e.g., V_{ch_end} of about Vₘₐₓ such that 1/b_{ch}=1.

In plot 503 of FIG. 5C, plotlines 512A-2 through 512C-2 predict the extent of CRA to be incurred by ESD 105 of respective ESD types A-C under charge operations having end charge voltages where 1/b_{ch}=2.54 at charge rates (r_{ch}) from 0 to about 5C₁ (and other charge conditions are substantially constant such that c=1, d=1, α=1, and so on). As illustrated in FIG. 5C, charge conditions with end charge voltages (V_{ch_end}) configured such that 1/b_{ch}=2.54 may limit the extent of CRA incurred by ESD types A-C to about 40% of M_{ch} (as opposed to 80% to 100% of M_{ch} under charge conditions with higher V_{ch_end} values such that 1/b_{ch}=1, as illustrated in FIGS. 5A and 5B). As further illustrated in FIG. 5C, ESD 105 having lower r_{ch_max} values may incur the maximum extent of M_{ch} (e.g., about 40% M_{ch}) at lower charge rates (r_{ch}) than ESD 105 having higher r_{ch_max} characteristics. According to aging models 120A-C, ESD 105 of ESD type A may incur 40% of M_{ch} at charge rates (r_{ch}) of about 0.9C and higher, ESD 105 of ESD type B may incur 40% of M_{ch} at charge rates (r_{ch}) of about 1.8 C and higher, and ESD 105 of ESD type C may incur 40% of M_{ch} at charge rates (r_{ch}) of about 4.6C and higher (where other charge conditions are substantially constant and configured such that c_{ch}=1, d_{ch}=1, α_{ch}=1, and so on).

In plot 504 of FIG. 5D, plotlines 512A-3 through 512C-3 predict the extent of CRA predicted to be incurred by ESD 105 of respective ESD types A-C under charge operations having lower end charge voltages V_{ch_end}. As illustrated in FIG. 5D, the aging models 120A-C may predict that charge conditions with end charge voltages (V_{ch_end}) configured such that 1/b_{ch}=5 may limit the extent of CRA incurred by ESD 105 of respective ESD types A-C to about 20% of M_{ch}. ESD 105 having lower maximum charge rates (r_{ch_max}) may incur the maximum 20% of M_{ch} at lower charge rates (r_{ch}); ESD 105 of ESD type A may incur 20% of M_{ch} at r_{ch} of about 0.5C₁ and above, ESD 105 of ESD type B may incur 20% of M_{ch} at r_{ch} of about 1.2C and above, and ESD 105 of ESD type C may incur 20% of M_{ch} at r_{ch} of about 3.1C and above (where other charge conditions are substantially constant and configured such that c_{ch}=1, d_{ch}=1, α_{ch}=1, and so on).

The analysis module 116 may utilize the relationships illustrated in FIGS. 5C and 5D to configure target charge conditions for ESD 105, as disclosed herein. For example, the analysis module 116 may utilize relationships between M_{ch} and charge conditions (e.g., end charge voltage (V_{ch_end}), charge rate (r_{ch}), ESD-specific maximum charge rate (r_{ch_max}), and so on) of the disclosed ESD aging models 120 to, inter alia, configure target operating conditions (e.g., target charge conditions) predicted to satisfy ESR requirements of applications 170. For example, the analysis module 116 may utilize aging model 120 (e.g., aging models 120A-C) to predict M_{ch}% to be incurred by ESD 105 of respective ESD types (e.g., ESD types A-C as illustrated in FIGS. 5A-5D), as a function of end charge voltage (V_{ch_end} and/or b_{ch}) and charge rate (r_{ch}), as follows:

$${M}_{ch} \% ( {b}_{ch} , {x}_{ch} ) = 100 * {b}_{ch} ( 1 - exp ( - {α}_{ch} {( \frac{2 {x}_{ch}}{{V}_{ch\_max}} )}^{\frac{1}{{b}_{ch}}} ) ) \qquad Eq . 38$$

In Eq. 38, end charge voltage may be represented by variable x_{ch}, charge rate (r_{ch}) may be expressed in terms of C₁ (e.g., may be expressed as a factor of the ESD-specific C₁ parameter, nC₁), and 100 is a placeholder for the maximum extent of M_{ch}, which may be based on Mₜₒₜₐₗ and/or M_{ch}^{o}, as disclosed herein.

Referring back to FIG. 3, the ESD manager 110 may be configured to maintain information pertaining to M_{ch} % as a function of charge rate (r_{ch}) for respective ESD 105 and/or ESD types in respective ESD profiles 115, e.g., within aging models 120 determined for respective ESD types. The ESD manager 110 may be further configured to evaluate operating conditions (e.g., charge conditions) based on M_{ch} % characteristics determined for respective ESD 105, e.g., based on M_{ch}% characteristics of the ESD 105 under respective operating conditions, as disclosed herein). The ESD manager 110 may utilize the M_{ch}% characteristics of the aging models 120 to, inter alia, determine target operating conditions an ESD 105 in an application 170. For example, the ESD manager 110 may utilize the M_{ch}% characteristics of the ESD aging model 120 to determine target charge conditions predicted to result in a maximum extent of M_{ch} that satisfies the ESR requirements of an application 170, e.g., predicted to result in M_{ch}≤M_{threshold}.

As disclosed herein, in some implementations, the ESD manager 110 may comprise aging models 120 configured to predict the rate at which charge-related aging will be incurred by an ESD 105 under specified operating conditions. The analysis module 116 may utilize such aging models 120 to, inter alia, determine target charge conditions that maintain performance degradation predicted to be incurred by the ESD 105 below a threshold for a specified usage period, e.g., configure target charge conditions for the ESD 105 such that ψ_{ch}(tₗ)≤ψ_{threshold}, as disclosed herein. Aging predictions 140 for respective charge conditions may be generated by use of a ψ_{ch}(t) function learned for the ESD 105, e.g., per Eq. 15, Eq. 16, or the like.

FIG. 6 comprises a plot 601 illustrating another example of an aging model 120. More specifically, the plot 601 illustrates examples of aging predictions 140 determined by use of an aging model 120 of an ESD 105. The aging predictions 140 may be configured to predict the extent and/or rate of performance loss incurred by the ESD 105 under respective charge models 134. The analysis module 116 may be configured to evaluate aging predictions 140 to, inter alia, determine target charge conditions for the ESD 105 within an application 170, e.g., determine target charge conditions that satisfy performance and/or endurance requirements of the application 170, as disclosed herein.

FIG. 6 illustrates examples of aging predictions 140A-E configured to predict performance degradation to ESD capacity attributable to charge models 134A-E, respectively. The aging model 120 may predict that the theoretical extent of capacity loss attributable to the charge conditions is about 20%, e.g., M_{ch} determined for charge models 134A-E is about 20%. The aging predictions 140A-E may predict the rate at which the ESD 105 will approach 20% capacity loss over a usage period of about 250 weeks under respective charge models 134A-E.

As disclosed herein, the aging model 120 may be configured model CRA mechanisms of an ESD 105 using a function, such as the ψ_{ch}(t) function of Eq. 15, e.g., p_{ch}, q_{ch} and/or other terms of the ψ_{ch}(t) function learned for the ESD 105 may be configured to model chemical reaction rates involved in charge-related aging. As illustrated in FIG. 6, parameters of the ψ_{ch}(t) functions comprising aging predictions 140A-E may be adjusted for precise rendering of aging trends learned and/or predicted for respective charge models 134A-E. For example, the aging prediction 140A may model CRA incurred under charge model 134A by a function ψ_{ch_A}(t) comprising parameters p_{ch}=0.10 and q_{ch}=1.0, the aging prediction 140B may model CRA incurred under charge model 134B by a function ψ_{ch_B}(t) comprising parameters p_{ch}=0.03 and q_{ch}=2.0, the aging prediction 140C may model CRA incurred under charge model 134C by a function ψ_{ch_C}(t) comprising parameters p_{ch}=0.03 and q_{ch}=1.0, the aging prediction 140D may model CRA incurred under charge model 134D by a function ψ_{ch_D}(t) comprising parameters p_{ch}=0.03 and q_{ch}=0.5, and the aging prediction 140E may model CRA incurred under charge model 134E by a function ψ_{ch_E}(t) comprising parameters p_{ch}=0.01 and q_{ch}=1.0.

The ESD manager 110 may utilize the aging model 120 to diagnose specific causes of charge-related aging. The ESD manager 110 may, for example, determine OCS data 220 configured to, inter alia, quantify the influence of respective operating conditions on ESD aging. For example, the ESD manager 110 may be configured to derive charge condition sensitivity (CCS) data 224 from charge-related aging predictions 140 (and/or corresponding aging data 215). As disclosed herein, CCS data 224 may comprise and/or refer to data configured to quantify the influence of respective charge conditions on ESD aging. In the FIG. 6 example, the ESD manager 110 may compare ψ_{ch}(t) determined for respective charge models 134A-E (e.g., p_{ch} and/or q_{ch}) and determine the influence of respective charge conditions based on the comparing.

By way of non-limiting example, the ESD manager 110 may determine that a) the charge model 134A corresponds to higher SoC than other charge models 134B-E (e.g., higher V_{ch_end} levels), and that b) the charge rate (r_{ch}) of charge model 134E corresponds to the same or similar charge rates (r_{ch}) as other charge conditions 134A-D. Based on the foregoing, the ESD manager 110 may determine that the CRA mechanisms of the ESD 105 have a higher sensitivity to SoC (V_{ch_end}) and a lower sensitivity to charge rate (r_{ch}), e.g., the ψ_{ch}(t) determined for the ESD 105 may be more sensitive to V_{ch} than r_{ch}. The analysis module 116 may utilize CCS data 224 of the aging model 120 to, inter alia, generate target charge conditions for the ESD 105. In the non-limiting example above, the analysis module 116 may utilize CCS data 224 to determine that modifying V_{ch} is likely to result in more significant improvements to ESD performance degradation rate than modifications to charge rate (r_{ch}).

As disclosed above, the ESD manager 110 may evaluate aging predictions 140 to, inter alia, determine target charge conditions that satisfy the ESR requirements of an application, e.g., target charge conditions configured such that M_{ch}≤M_{threshold}, M_{ch}+M_{d}≤M_{threshold}, ψ_{ch}(tₗ)≤ψ_{threshold}, ψ_{ch}(tₗ)+ψ_{d}(tₗ)≤ψ_{threshold}, and/or the like, where M_{ch} and ψ_{ch}(t) predict the extent and/or rate of performance degradation attributable to the target charge conditions and M_{d} and ψ_{d}(t) predict the extent and/or rate of performance degradation attributable to discharge conditions (e.g., discharge conditions per discharge requirements of the application 170).

In the FIG. 6 example, the ESD manager 110 may evaluate the aging predictions 140A-E to determine target charge conditions capable of satisfying performance and/or endurance requirements of an application 170. The ESD manager 110 may be configured to determine target charge conditions predicted to satisfy a usage guarantee 630. FIG. 6 illustrates examples of usage guarantees 630, including a first usage guarantee 630A and a second usage guarantee 630B. The first usage guarantee 630A may require ESD capacity loss to remain below 20% for at least 208 weeks (per a performance requirement and corresponding endurance requirement). The ESD manager 110 may evaluate the aging predictions 140A-E to, inter alia, determine target charge conditions that satisfy the first usage guarantee 630A. As illustrated in FIG. 6, the ESD manager 110 may determine that charge conditions of the charge models 134D and 134E satisfy the first usage guarantee 630A and that charge models 134A-C fail to satisfy the first usage guarantee 630A (e.g., the ESD 105 is predicted to reach 20% capacity degradation before 208 weeks under charge models 134A-C).

In another example, the ESD manager 110 may be configured to determine target charge conditions that satisfy a second usage guarantee 630B that only requires capacity degradation to remain below 20% for 18 months (about 78 weeks). The ESD manager 110 may determine that charge models 134B-E satisfy the second usage guarantee 630B. The ESD manager 110 may derive target charge conditions from charge model 134B, which may provide faster charge times while satisfying the less stringent 18-month endurance requirement, e.g., faster charge times as compared to other suitable charge models 134C-E.

The ESD manager 110 may be further configured to leverage aging models 120 to select ESD 105 (and/or ESD types) for applications 170. ESD types may be selected based, at least in part, on requirements of the applications 170 and OCS data 220 determined for respective types of ESD 105. For example, the ESD manager 110 may be configured to match OCS data 220 determined for respective ESD types with OP requirements of respective applications 170. By way of non-limiting example, a first application 170 may comprise charge requirements specifying that ESD 105 be charged to a high SoC (and/or high V_{ch_end}). The ESD manager 110 may select ESD 105 for the first application 170 having OCS data 220 (and/or CCS data 224) indicating low sensitivity to SoC (and/or V_{ch_end}). By contrast, the ESD manager 110 may determine that ESD 105 that are more sensitive to SoC (and/or V_{ch_end}), such as ESD 105 of the FIG. 6 example, may be unsuitable for the first application 170, since such ESD 105 would likely incur higher levels of CRA than other types of ESD 105. By way of further example, the ESD manager 110 may select an ESD 105 for a second application 170 having different charge requirements. The charge requirements of the second application 170 may require that ESD 105 be charged at higher rates (e.g., higher r_{ch} values such as 3C₁ or more) but allow for lower SoC levels (e.g., SoC as low as about 50%). The ESD manager 110 may select ESD 105 for the second application 170 determined to have lower sensitivity to charge rate (r_{ch}), regardless of whether such ESD 105 are sensitive to SoC (and/or V_{ch_end}). For example, the ESD manager 110 may select the ESD 105 of the FIG. 6 example for the second application 170, since the OCS data 220 (and/or CCS data 224) determined for the ESD 105 indicate a low sensitivity to charge rate (r_{ch}). Although particular examples of the use of OCS data 220 to select ESD 105 for applications 170 are described herein, the disclosure is not limited in this regard and could be adapted to select ESD 105 for particular applications 170 based on any suitable criteria, aging modeling information, and/or the like.

Referring back to FIG. 3, as disclosed herein, the operating conditions of an ESD 105 in an application 170 may change over time. The operating conditions of an ESD 105 may change due to various factors including, but not limited to: environmental conditions (e.g., ambient temperature), operational considerations (e.g., utilization of the ESD 105 in the application 170), changing application requirements (e.g., changing power requirements, changing SoC requirements, and/or the like), and so on. Changes to the operating conditions of an ESD 105 may result in corresponding changes to the extent and/or rate of performance degradation incurred by the ESD 105, e.g., changes to aging metrics 142 such as M_{ch}, M_{d}, Mₜₒₜₐₗ, ψ_{ch}(t), ψ_{d}(t), ψₜₒₜₐₗ(t), and/or the like. As disclosed herein, the ESD manager 110 may be configured to develop aging models 120 configured to predict ESD aging over a plurality of periods, each period having respective operating conditions. The aging models 120 may be configured to predict ESD aging over a plurality of usage periods k, each usage period having respective operating conditions; aging attributable to the charge conditions in respective usage periods may be modeled per Eq. 16 and aging attributable to the discharge conditions in respective usage periods may be modeled per Eq. 32.

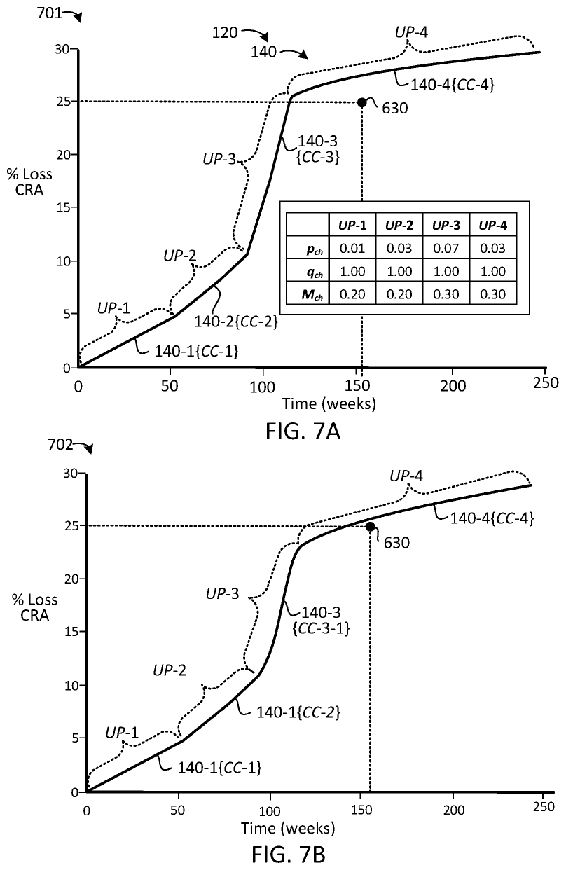

FIG. 7A comprises a plot 701 illustrating an example of an aging model 120 configured to predict ESD aging over a plurality of usage periods (UP), as disclosed herein. The aging model 120 of the FIG. 7A example may be configured to model CRA as a percentage of M_{ch}^{o} (about 30% in the FIG. 7A example).

Plot 701 illustrates a multi-period aging prediction 140 configured to predict cumulative performance degradation over usage periods UP-1 through UP-4, each usage period having respective operating conditions. As illustrated in FIG. 7A, usage period UP-1 (week 0 to about week 52) may correspond to charge conditions (CC-1) resulting in CC metrics M_{ch}=0.20 and ψ_{ch}(t) function having parameters p_{ch}=0.01 and q_{ch}=1.0; usage period UP-2 (about week 53 to about week 100) may correspond to charge conditions (CC-2) resulting in CC metrics M_{ch}=0.20 and ψ_{ch}(t) function having parameters p_{ch}=0.03 and q_{ch}=1.0; usage period UP-3 (about week 101 to about week 125) may correspond to charge conditions (CC-3) resulting in CC metrics M_{ch}=0.30 and ψ_{ch}(t) function having parameters p_{ch}=0.07 and q_{ch}=1.0; and usage period UP-4 (about week 126 to about week 250) may correspond to charge conditions (CC-4) resulting in CC metrics M_{ch}=0.30 and ψ_{ch}(t) function having parameters p_{ch}=0.03 and q_{ch}=1.0.

The ESD manager 110 may use multi-period aging prediction 140 to manage ESD charge conditions. The ESD manager 110 may identify usage periods predicted to result in high levels of charge-related performance loss. As disclosed herein, high levels of CRA may result in shortened useful life, or even failure if allowed to continue during the aging timeline. The ESD manager 110 may use the disclosed multi-period aging predictions 140 to detect and/or mitigate the effects of adverse charging conditions. In the FIG. 7A example, the ESD manager 110 may detect that usage period UP-3 produces unacceptably high CRA and, in response, modify the charge conditions CC-3. By way of non-limiting example, the usage period UP-3 may correspond to cold temperatures, which may increase charge-related aging of the ESD 105 (per the cell chemistry of the ESD 105 as quantified by the α_{ch} parameter disclosed herein). In response, the ESD manager 110 may reduce charge rates (r_{ch}) and/or end charge levels (V_{ch_end}) of CC-3 to, inter alia, reduce CRA incurred during usage period UP-3. Detecting the high levels of performance loss may comprise evaluating M_{ch} and/or ψ_{ch} determined for the charge conditions of respective usage periods. The detecting may further comprise evaluating the rate of change of ψ_{ch}(t) during respective usage periods. The ESD manager 110 may evaluate a derivative and/or second order derivative of the aging model 120 (and/or continuous approximation thereof). Alternatively, or in addition, the ESD manager 110 may be configured to evaluate derivatives during respective usage periods (the aging prediction 140 being continuous within respective usage periods UP-1 through UP-4).

The ESD manager 110 may be further configured to manage charge operations to satisfy application requirements. For example, the ESD manager 110 may configure charge conditions to satisfy a usage guarantee 630. In the FIG. 7A example, the ESD manager 110 may determine that the charge conditions during usage periods UP-1 through UP-4 fail to satisfy a usage guarantee 630 that ESD performance degradation remain below 25% for at least 3 years (156 weeks). In response, the ESD manager 110 may determine modified charge conditions for one or more of the usage periods, the modified charge conditions configured to satisfy the usage guarantee 630. In plot 702 of FIG. 7B, the ESD manager 110 may determine modified charge conditions (CC-3-1) for UP-3, the modified charge conditions (CC-3-1) configured to reduce the extent and/or rate of CRA, thereby enabling the ESD 105 to satisfy the usage guarantee 630. Determining the modified charge conditions (CC-3-1) may comprise modifying one or more charge parameters, such as charge rate (r_{ch}), charge SoC, end voltage (V_{ch}), and/or the like, as disclosed herein. Alternatively, or in addition, determining the modified charge conditions (CC-3-1) may comprise converting a single-step charge operation to a multi-step charge operation, modifying steps of a multi-step charge operation, including intervening rest periods between charge steps, and/or the like.

Referring back to FIG. 3, the ESD manager 110 may be configured to manage implementation of an application 170 by an ESD 105 by a) determining an OP policy 150 comprising a charge policy 154 predicted to satisfy requirements of the application 170 under predicted discharge conditions of the application 170, b) generating a charge configuration 164 corresponding to the target charge conditions, and c) configuring the application 170 (e.g., charge module 174-1) to implement the charge configuration 164.

In some implementations, the analysis module 116 may be configured to determine an “optimal” OP policy 150 and/or target operating conditions for the ESD 105. As used herein, an “optimal” OP policy 150 and/or target operating conditions for an ESD 105 in an application 170 may comprise and/or refer to an OP policy 150 and/or target operating conditions that a) satisfy ESR requirements of the application 170 at b) a minimal cost and/or maximum utility, according to criteria defined for the application 170. By way of non-limiting example, optimal target operating conditions for an application 170 prioritizing ESD longevity may comprise operating conditions that minimize the extent and/or rate of aging incurred by the ESD 105 (minimal aging metrics 142), while satisfying ESR requirements of the application 170, e.g., charge requirements, discharge requirements, and so on. In another non-limiting example, optimal operating conditions for an application 170 prioritizing fast charge times may comprise operating conditions that result in a shortest charge duration (D_{ch}) while satisfying usage guarantees 630 of the application 170, e.g., maintaining performance loss below a threshold for a specified usage period. Accordingly, in some implementations, the analysis module 116 may be configured to determine target operating conditions (e.g., target charge conditions in the FIG. 3 example) through and/or by use of an optimization algorithm or technique, as disclosed in further detail herein.

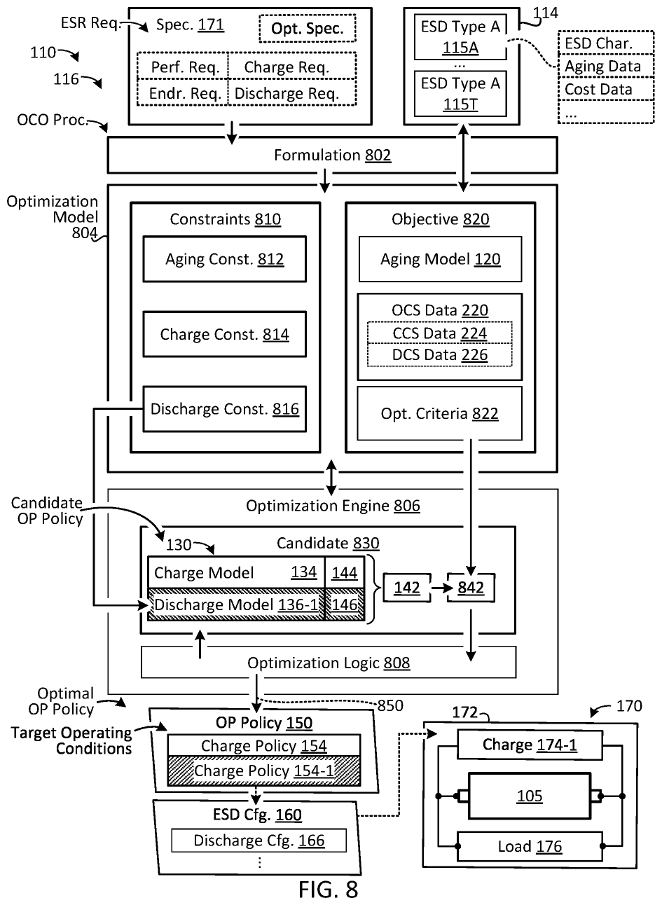

FIG. 8 is a schematic block diagram illustrating another example of an ESD manager 110. The ESD manager 110 may comprise an analysis module 116 configured to, inter alia, manage implementation of an application 170 by an ESD 105 (and/or ESD 105 of a particular type), as disclosed herein.

In the FIG. 8 example, the ESD manager 110 may be configured to control aspects of the charge conditions of ESD 105 within the application 170, e.g., control aspects of the charge operations implemented by charge module(s) 174-1 of the application 170. As in the FIG. 3 example, the ESD manager 110 may be configured to treat ESD discharge conditions of the application 170 as constants and/or constraints. The ESD manager 110 may comprise a discharge model 136-1 configured to characterize default, nominal, and/or predicted discharge conditions of the ESD 105 within the application 170, as disclosed herein.

The analysis module 116 may be configured to determine an OP policy 150 for the ESD 105 within the application 170. In the FIG. 8 example, the OP policy 150 may comprise a discharge policy 156-1 configured to model predicted discharge conditions of the ESD 105 within the application 170 as disclosed herein, e.g., per discharge model 136-1. According to the FIG. 8 example, determining the OP policy 150, may comprise determining a charge policy 154 that satisfies requirements of the application 170 under the predicted ESD discharge conditions of the application 170. For example, the charge policy 154 may be required to result in aging metrics 132 that satisfy one or more thresholds, e.g., specify target charge conditions wherein M_{ch}>M_{ch_threshold} and/or Mₜₒₜₐₗ>M_{threshold}, where Mₜₒₜₐₗ=M_{ch}+M_{d_req} and M_{d_req} is the extent of DRA predicted for the discharge model 136-1. Alternatively, or in addition, the charge policy 154 may be required to satisfy a usage guarantee 630. The charge policy 154 may be required to result in aging metrics 132 that maintain performance degradation predicted to be incurred by the ESD 105 below a threshold for a longevity threshold (tₗ), e.g., target charge conditions wherein ψ_{ch}(tₗ)≤ψ_{ch_threshold} and/or ψₜₒₜₐₗ(tₗ)≤ψ_{threshold}, where ψₜₒₜₐₗ(t)=ψ_{ch}(t)+ψ_{d_req}(t) and ψ_{d_req}(t) is a function configured to predict DRA incurred under discharge conditions of the discharge model 136-1.

The charge policy 154 may be further configured to satisfy other constraints, such as constraints corresponding to charge requirements of the application 170; charge requirements of the application 170 may constrain aspects of the charge policy 154 to specified ranges and/or values. For example, the charge requirements may specify that the application 170 requires ESD 105 to be charged to at least 80% SoC (and/or equivalent V_{ch_end}) and the analysis module 116 may constrain the charge policy 154 accordingly, e.g., may constrain target charge conditions of the charge policy 154 to V_{ch_end} corresponding to 80% SoC or higher. By way of further example, the application 170 may limit the duration of charge operations, e.g., may specify a maximum charge duration (D_{ch_max}). The duration of a single-step charge operation may be a function of charge rate (r_{ch}), start voltage (V_{ch_start}), end voltage (V_{ch_end}), and ESD capacity. The analysis module 116 may configure charge policies 154 determined for single-step charge operations such that the charge rate (r_{ch}), start voltage (V_{ch_start}), and/or end voltage (V_{ch_end}) satisfy the maximum charge duration constraint (D_{ch_max}). The duration of N-step charge operations may be a function of the duration of respective charge steps i (x_{ch_ti}) and/or optional, intervening rest periods (y_{ch_ti}). The analysis module 116 may configure charge policies 154 determined for N-step charge operations to satisfy the maximum charge duration constraint (D_{ch_max}).

In some implementations, the analysis module 116 may be configured to determine OP policies 154 (charge policies 154 in the FIG. 8 example) through, inter alia, implementation of an operating condition optimization (OCO) procedure. The OCO procedure may comprise determining optimal OP policies 154 (and/or optimal operating conditions) for ESD 105 in respective applications 170. As disclosed herein, an optimal OP policy 150 (and/or optimal ESD operating conditions) may comprise and/or refer to an OP policy 150 (and/or target operating conditions) that satisfy specified optimization criteria 822.

In the FIG. 8 example, the analysis module 116 may comprise a formulation module 802. The formulation module 802 may be configured to generate, construct, formulate, and/or otherwise manage an optimization model 804 of the OCO procedure. The optimization model 804 may comprise and/or be derived from characteristics of the application 170 and/or ESD 105. The formulation module 802 may be configured to retrieve information pertaining to the application 170, ESD 105, and/or respective ESD types from any suitable source, e.g., DTS resources 104-2 of the ESD manager 110, a user 12, user interaction with a GUI of the interface module 111, and/or the like. The formulation module 802 may be configured to retrieve information pertaining to the application 170 from, inter alia, a specification 171 of the application 170, as disclosed herein. The formulation module 802 may be further configured to retrieve information pertaining to the ESD 105 (and/or respective ESD types) from a datastore 114, e.g., from ESD profiles 115, or the like.

As illustrated in FIG. 8, the formulation module 802 may be configured to determine constraints 810 of the OCO procedure. The constraints 810 may be configured to constrain aspects of the OP policy 150 determined for the ESD 105 through the OCO procedure. In the FIG. 8 example, the constraints 810 may be configured to constrain aspects of the charge policy 154 determined for the ESD 105. The optimization model 804 may comprise any suitable constraints 810 pertaining to any suitable aspect of the target operating conditions and/or corresponding aging metrics 142, including, but not limited to: aging constraints 812, charge constraints 814, discharge constraints 816, and/or the like.

The aging constraints 812 may be derived from, inter alia, ESR requirements of the application 170. The aging constraints 812 may comprise and/or be derived from performance requirements, performance requirements and corresponding endurance requirements, usage guarantees 630, and/or the like. For example, the aging constraints 812 may require the OP policy 150 to maintain ESD performance degradation below a threshold for a specified usage period. The aging constraints 812 may be configured to limit the extent of aging predicted to be incurred by the ESD 105 and/or the rate at which such aging is predicted to be incurred under the target operating conditions. For example, the aging constraints 812 may be configured to constrain aging metrics 132 of the target operating conditions, e.g., constrain Mₜₒₜₐₗ, M_{ch}, ψₜₒₜₐₗ(tₗ), ψ_{ch}(tₗ), aging metrics 142, CC metrics 144, and/or the like, as disclosed herein.

The formulation module 802 may be further configured to determine charge constraints 814. The charge constraints 814 may be based on and/or derived from charge requirements of the application 170, as disclosed herein. The charge constraints 814 may, for example, constrain target charge conditions of the charge policy 154 to specified values and/or ranges, e.g., constrain end charge voltage (V_{ch_end}) to an SoC of 80% or higher, constrain charge conditions to satisfy a maximum charge duration (D_{ch_max}), and/or the like.

The formulation module 802 may be further configured to determine discharge constraints 816 of the OCO procedure. The discharge constraints 816 may be based on and/or derived from discharge requirements of the application 170, as disclosed herein. In the FIG. 8 example, the discharge constraints 816 may correspond to a predicted discharge model 136-1 determined for the application 170, as disclosed herein. Discharge conditions of the discharge model 136-1 may be treated as fixed constants and/or constraints within the optimization model 804. In the FIG. 8 example, the discharge constraints 816 may be configured to prevent modification of the discharge model 136-1, e.g., may require that the OP policy 150 incorporate the discharge model 136-1, as illustrated in FIG. 8.

The formulation module 802 may be further configured to construct an objective model 820 of the OCO procedure. The objective model 820 may comprise means for evaluating the cost and/or utility of respective candidates 830. More specifically, the objective model 820 may comprise means for evaluating the cost and/or utility of the OP policies 150 (and/or target operating conditions) of respective candidates 830. As disclosed in further detail herein, a candidate 830 may comprise and/or refer to a potential solution to the OCO procedure. In other words, a candidate 830 may comprise an OP policy 150 (and/or candidate OC model 130 specifying target operating conditions) that satisfies the constraints 810 of the OCO procedure.

The objective model 820 may comprise an aging model 120 of the ESD 105. The analysis module 116 may utilize the aging model 120 to evaluate aging characteristics of respective candidates 830. The analysis module 116 may utilize the aging model 120 to, inter alia, determine aging predictions 140 for respective candidates 830, determine aging metrics 142 for respective candidates 830 (e.g., determine aging metrics 142 for OP policies 150 of respective candidates 830), and so on. Determining aging metrics 142 of a candidate 830 may comprise determining CC metrics 144 for the charge policy 154 of the candidate 830 and/or determining DC metrics 146 for the predicted discharge conditions of the discharge model 136-1, and so on.

The objective model 820 may further comprise optimization criteria 822. The optimization criteria 822 may comprise means for quantifying the cost and/or utility of respective candidates 830. For example, the optimization criteria 822 may be configured to maximize and/or minimize one or more aspects of the OP policy 150 (and/or target operating conditions), aging metrics 142, and/or the like. The optimization criteria 822 may be configured in accordance with requirements and/or priorities of the application 170.

In the FIG. 8 example, the optimization criteria 822 may comprise means for determining cost metrics 842 for respective candidates 830. The OCO procedure may, therefore, comprise determining an OP policy 150 that satisfies requirements of the application 170 (per the constraints 810 of the OCO procedure) while minimizing the cost metric 842 (per the objective model 820).

The cost metrics 842 of a candidate 830 may be based, at least in part, on aging metrics 142 predicted for the candidate 830, e.g., per the aging model 120. In the FIG. 8 example, the cost metrics 842 may be proportional to one or more of Mₜₒₜₐₗ, M_{ch}, ψₜₒₜₐₗ(t), ψ_{ch}(t), and/or the like. Alternatively, or in addition, the cost metric 842 may be configured to incorporate characteristics of the target operating conditions, such as charge SoC (e.g., may prefer target operating conditions where ESD 105 are charged to higher SoC levels), charge duration (e.g., may prefer target operating conditions resulting in lower charge duration), and/or the like.

In a first non-limiting example, the optimization criteria 822 may be configured to minimize the extent and/or rate of aging incurred by the ESD 105. For example, the optimization criteria 822 may weight aging metrics 132 more heavily than other factors incorporated in the cost metric 842. According to optimization criteria 822 of the first non-limiting example, the OCO procedure may be configured to determine target operating conditions that result in minimal Mₜₒₜₐₗ and/or ψₜₒₜₐₗ(t) while satisfying the constraints 810 of the optimization model 804. The optimization criteria 822 of the first non-limiting example may, therefore, prioritize longevity over performance, e.g., may result in lower charge SoC, longer charge duration, and/or the like.

In a second non-limiting example, the optimization criteria 822 may be configured to minimize a specified aspect of the operating conditions, such as charge duration. According to such optimization criteria 822, the OCO procedure may be configured to determine target operating conditions that result in minimal charge duration (D_{ch}) while satisfying the constraints 802 of the optimization model 804. The optimization criteria 822 of the second non-limiting example may, therefore, prioritize charge performance over ESD longevity, e.g., may result in shorter charge times but higher levels of charge-related aging.

In a third non-limiting example, the optimization criteria 822 may be configured to assign weights to respective operating condition parameters and/or aging metrics 132. For example, the optimization criteria 822 may be configured to assign costs to selected operating conditions, such as charge SoC, charge duration, charge rate, and/or the like. For example, the optimization criteria 822 may define a cost function that is inversely proportional to charge SoC, such that candidates 830 having operating conditions specifying lower charge SoC are assigned higher cost metrics 842 than candidates 830 having operating conditions specifying higher charge SoC. The optimization criteria 822 may be further configured to assign and/or weight costs assigned to specified aging metrics 132, such as Mₜₒₜₐₗ, M_{ch}, ψₜₒₜₐₗ, ψ_{ch}, or the like. Therefore, under optimization criteria 822 of the third non-limiting example, the OCO procedure may be configured to determine target operating conditions that balance selected operating conditions against specified aging metrics 142.

Although particular examples of optimization criteria 822 are described herein, the disclosure is not limited in this regard and could be adapted to utilize any suitable criteria pertaining to any suitable aspect of the optimization model 804, e.g., any suitable characteristic of an OC model 130, operating conditions, aging metrics 142, and/or the like.

In the FIG. 8 example, the analysis module 116 may further comprise an optimization engine 806. The optimization engine 806 may be configured to determine an optimal OC policy 150 for the ESD 105 in accordance with the optimization criteria 822. The optimization engine 806 may be configured to generate and/or evaluate candidates 830. As disclosed herein, a candidate 830 may comprise and/or refer to a potential solution to the optimization problem characterized by the optimization model 804. In other words, a candidate 830 may comprise and/or refer to an OP policy 150 that satisfies a) aging constraints 812 determined for the application 170, e.g., satisfies performance and/or endurance requirements of the application 170, as disclosed herein, b) charge constraints 814 of the application 170, e.g., comprises a charge policy 154 that satisfies charge requirements of the application 170, as disclosed herein, and c) discharge constraints 816 of the application 170, e.g., comprises and/or incorporates a discharge model 136-1 configured to model predicted discharge conditions of the ESD 105 within the application 170, as disclosed herein.

The candidates 830 may comprise respective aging metrics 142. The aging metrics 142 may be configured to predict aging to be incurred by the ESD 105 under the OP policies 150 of the respective candidates 830. In the FIG. 8 example, the aging metrics 142 may be configured to predict aging under the target operating conditions of respective OP policies 150, e.g., under charge conditions of the charge policies 154 of respective candidates 830 and/or the predicted discharge conditions of the discharge model 136-1. As illustrated in FIG. 8, aging metrics 142 of a candidate 830 may comprise and/or be derived from CC metrics 144 of the charge model 134 of the candidate 830 and/or DC metrics 146 of the discharge model 136-1. The aging metrics 142 may be determined by use of the aging model 120 of the ESD 105, as disclosed herein.

The candidates 830 may further comprise cost metrics 842. As disclosed herein, the cost metrics 842 of a candidate 830 may be determined by applying the optimization criteria 822 of the optimization model 804 to the candidate 830. As disclosed herein, the cost metrics 842 may be based on the aging metrics 142 and/or OP policy 150 of the candidate 830. In the FIG. 8 example, the cost metrics 842 may be a function of one or more target charge conditions of the charge policy 154, such as charge SoC (SoC_{ch_end}), end charge voltage (V_{ch_end}), charge rate (r_{ch}), charge duration (D_{ch}), and/or the like. Alternatively, or in addition, in the FIG. 8 example, the cost metrics 842 may be a function of specified aspects of the aging metrics 142, such as predicted aging extent (e.g., Mₜₒₜₐₗ and/or M_{ch}), predicted aging rate (e.g., ψₜₒₜₐₗ(t) and/or ψ_{ch}(t)), and/or the like.

The optimization engine 806 may be configured to generate and/or evaluate candidates 830 according to optimization logic 808. The optimization logic 808 may be configured to implement any suitable optimization algorithm, including, but not limited to: a bracketing algorithm, a logical descent algorithm, a first-order optimization algorithm (e.g., gradient descent, momentum, stochastic optimization, stochastic gradient descent), a second-order optimization algorithm (e.g., Newton's Method, Quasi-Newton Method, Secant Method, and/or the like), a non-differential objective function algorithm, a direct optimization algorithm, a stochastic algorithm, a population algorithm, and/or the like.

The optimization engine 806 may be configured to generate candidates 830 based, at least in part, on the optimization model 804. The optimization engine 806 may be configured to generate candidates 830 comprising OC models 130 that satisfy the constraints 810 of the objective model 804, e.g., satisfy aging constraints 812, charge constraints 814, discharge constraints 816, and so on, as disclosed herein.

In some implementations, the optimization engine 806 may be configured to iteratively generate, evaluate, and/or modify candidates 830, e.g., iteratively modify aspects of the operating conditions of respective candidates 830. The candidates 830 may be modified to improve the cost metrics 842 thereof, e.g., reduce aging metrics 142, improve specified aspects of the operating conditions, and so on per the optimization criteria 822 of the OCO procedure. The optimization engine 806 may be configured to modify OC model 130 of the candidates 830 based, at least in part, on OCS data 220 determined for the ESD 105. As disclosed herein, the OCS data 220 may quantity the sensitivity of the aging model 120 (and/or resulting aging metrics 132) to respective operating conditions. The OCS data 220 may comprise CCS data 224 configured to quantify the impact of respective charge conditions on CC metrics 144, DCS data 226 configured to quantity the impact of respective discharge conditions on DC metrics 146, and so on. The optimization engine 806 may utilize the OCS data 220 to modify the operating conditions of a candidate 830 such that the operating conditions satisfy the constraints 810 of the OCO procedure while improving the cost metrics 842 of the candidate 830. For example, the OCS data 220 may indicate that CRA mechanisms of the ESD 105 are more sensitive to charge rate (r_{ch}) than end charge voltage (V_{ch_end}) and, as such, may modify a candidate 830 to improve the aging metrics 142 thereof by, inter alia, reducing charge rate (r_{ch}) rather than end charge voltage (V_{ch_end}).

The optimization engine 806 may be configured to iteratively generate, evaluate, and/or modify candidates 830 until one or more termination criteria of the optimization logic 808 are satisfied. The termination criteria may be determined by the algorithm implemented by the optimization logic 808. For example, the optimization logic 808 may terminate the OCO procedure in response to generating a locally and/or globally optimal candidate 830. Alternatively, or in addition, the termination criteria may comprise an iteration limit, optimization threshold, and/or like.

Terminating the OCO procedure may comprise generating an output or solution 850. The solution 850 may comprise and/or be derived from an “optimal” candidate 830 of the OCO procedure. The “optimal” candidate 830 may comprise and/or refer to the candidate 830 that minimizes the cost metrics 842 of the optimization model 804 (per the optimization criteria 822), while satisfying the constraints 810 of the optimization model 804. In other words, solution 850 of the OCO procedure may comprise an OP policy 150 (set of target operating conditions) that satisfy the aging constraints 812, charge constraints 814, and discharge constraints 816 of the application 170 at minimal cost per the optimization criteria 822 of the application 170. In some implementations, the optimal candidate 830 may comprise the candidate 830 that triggered termination of the OCO procedure. Alternatively, or in addition, the optimal solution may be selected from a plurality of candidates 830 evaluated by the optimization engine 806. The selection may be based on, inter alia, cost metrics 842 of the candidates 830, e.g., may comprise the candidate 830 having the lowest cost metrics 842, greatest utility metrics, and/or the like.

As illustrated in FIG. 8, the solution 850 of the OCO procedure may comprise an OP policy 150 comprising an optimal charge policy 154 determined for the ESD 105. In the FIG. 8 example, the solution 850 may not include a discharge policy 156 (e.g., since discharge conditions may be treated as fixed constants or constraints in the FIG. 8 example). Alternatively, the OP policy 150 determined by the analysis module 116 may comprise a discharge policy 156-1 configured to model the predicted discharge conditions of the ESD 105 within the application 170 per the discharge model 136-1, as disclosed herein.

As illustrated in FIGS. 3 and 8, the ESD manager 110 may be configured to generate a ESD CFG 160 corresponding to the OP policy 150 determined for the ESD 105. The ESD CFG 160 may comprise a charge configuration 164 configured to control charge operations implemented by the charge module 174-1 of the application 170. The charge configuration 164 may be configured to cause the charge module 174-1 to implement charge operations having charge conditions corresponding to the determined target charge conditions, as disclosed herein. In some implementations, the ESD CFG 160 may include a discharge configuration 166 corresponding to the predicted ESD discharge conditions within the application 170. Alternatively, the discharge configuration 166 may be omitted, as illustrated in the FIG. 8 example.

Referring to FIG. 3, in some implementations, the ESD manager 110 may be further configured to acquire, retrieve, request, and/or otherwise receive ESDM data 250. In the FIG. 3 example, the ESDM data 250 may comprise information pertaining to the operating conditions and/or performance of the ESD 105 within the application 170. The ESD manager 110 may be configured to detect “prediction deviations” pertaining to an ESD 105 and/or application 170 and, in response, modify OP policy 150 and/or corresponding ESD CFG 160 of the ESD 105 within the application 170.

As used herein, a “prediction deviation” may comprise and/or refer to an operating condition (OC) deviation. An OC deviation may comprise and/or refer to deviation between the target operating conditions determined for an ESD 105 within an application 170 (e.g., target operating conditions used to derive the operation ESD CFG 160 for the ESD 105 as disclosed herein) and the actual, observed operating conditions of the ESD 105 within the application 170. The ESD manager 110 may be configured to detect OC deviations. Detecting an OC deviation may comprise a) receiving ESDM data 250 pertaining to the application 170, the ESDM data 250 comprising OCM data 252, b) comparing operating conditions of the OCM data 252 to the target operating conditions determined for the ESD 105 and c) detecting an OC deviation based on the comparing.

In response to detecting an OC deviation, the ESD manager 110 may be configured to generate aging metrics 142 and/or an aging prediction 140 for the OCM data 252. The ESD manager 110 may be further configured to determine whether the OCM data 252 satisfies the ESR requirements of the application 170, e.g., determine whether Mₜₒₜₐₗ, M_{ch}, M_{d}, ψₜₒₜₐₗ(t), ψ_{ch}(t), and/or ψ_{d}(t) predicted for the observed operating conditions of the OCM data 252 satisfy performance and/or endurance requirements of the application 170. The ESD manager 110 may be further configured to generate a revised or modified OP policy 150 for the ESD 105 incorporate aspects of the observed operating conditions.

In the FIG. 3 example, the ESD manager 110 may be configured to manage aspects of the charge conditions of the ESD 105 within the application 170, e.g., discharge conditions may be managed internally. The ESD manager 110 may detect an OC deviation between the predicted discharge conditions of the ESD 105 within the application 170 (e.g., discharge model 136-1) and the actual, observed discharge conditions of the ESD 105 within the application 170. In response, the ESD manager 110 may be configured to generate a modified OP policy 150 for the ESD 105 that incorporates the actual, observed discharge conditions of the OCM data 252. The ESD manager 110 may be configured to a) update the discharge model 136-1 and/or discharge requirements of the specification 171 per the OCM data 252, and b) determine a revised OP policy 150 that incorporate the updated discharge conditions, as disclosed herein. For example, the ESD manager 110 may be configured to determine an optimal OP policy 150 incorporating the updated discharge model 136-1, as illustrated in FIG. 8. The ESD manager 110 may be further configured to generate a revised, updated ESD CFG 160 and/or configure the application 170 to implement charge operations in accordance with the revised ESD CFG 160, as disclosed herein.

In some examples, the revised ESD CFG 160 may be configured to preserve the usable life of the ESD 105, e.g., ensure that the ESD 105 satisfies usage guarantees 630 of the application 170 or the like. For example, the OCM data 252 may indicate that the actual, observed discharge conditions of the ESD 105 are more strenuous that the predicted discharge conditions used to generate the initial charge configuration 164. Accordingly, the actual extent and/or rate of DRA incurred by the ESD 105 may be higher than predicted. In response, the ESD manager 110 may modify the OP policy 150 of the ESD 105 to, inter alia, reduce CRA incurred by the ESD 105 to offset the increased degree of DRA predicted under the revised discharge conditions. Alternatively, the revised ESD CFG 160 may be configured to improve one or more performance characteristics. For example, the OCM data 252 may indicate that the observed discharge conditions of the ESD 105 are less strenuous than those of the original discharge model 136-1 and, as such, the ESD manager 110 may utilize more strenuous charge conditions while satisfying ESR requirements of the application 170, e.g., reduce charge duration (D_{ch}), increase end charge voltage (V_{ch_end}), and/or the like.

The prediction deviations detected by the ESD manager 110 may further comprise and/or refer to aging deviations. As used herein, an aging deviation may comprise and/or refer to deviation between aging predicted to be incurred under the target operating conditions (and/or ESD CFG 160) determined for the ESD 105 and performance degradation observed in the ESDM data 250. The ESD manager 110 may be configured to detect aging deviations. Detecting an aging deviation may comprise a) receiving ESDM data 250 pertaining to the ESD 105, the ESDM data 250 comprising EPM data 258, b) comparing aging metrics 142 and/or an aging prediction 140 determined for the ESD 105 under the OP policy 150 with the EPM data 258, and c) detecting an aging deviation based on the comparing.

As disclosed herein, the aging metrics 142 and/or aging prediction 140 of the OP policy 150 may predict the extent of aging to be incurred by the ESD 105 under the target operating conditions thereof and/or the rate at which such aging is predicted to be incurred, e.g., may comprise an Mₜₒₜₐₗ quantity and/or ψₜₒₜₐₗ(t) functions, as disclosed herein. The EPM data 258 may comprise measurements of one or more ESD performance characteristics. The ESD manager 110 may compare the extent and/or rate of performance degradation predicted under the OP policy 150 to measurements of the EPM data 258 to determine whether actual, observed performance degradation incurred by the ESD 105 corresponds to the aging prediction 140. For example, the ESD manager 110 may detect an aging deviation in response to comparing EPM data 258 acquired at respective usage times to corresponding aging predictions 140; the ESD manager 110 ay detect an aging deviation in response to determining that a difference, distance, and/or other error between the EPM data 258 and aging prediction 140 exceeds a threshold.

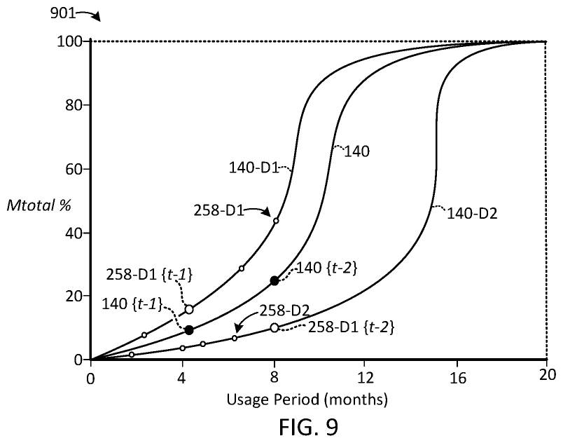

The ESD manager 110 may be further configured to modify and/or update the target operating conditions and/or ESD CFG 160 of the ESD 105 in response to detecting an aging deviation. FIG. 9 comprises a plot 901 illustrating examples of aging predictions 140. The plot 901 includes an aging prediction 140 corresponding to the target operating conditions determined for the ESD 105. The aging prediction 140 may be configured to predict performance loss as a percentage of a maximum extent of performance loss attributable to the target operating conditions determined for the ESD 105, e.g., percentage of Mₜₒₜₐₗ, or the like. In the FIG. 9 example, the aging prediction 140 may be configured to predict performance loss over a 20-month usage period.

The ESD manager 110 may be configured to detect an aging deviation by, inter alia, comparing EPM data 258 captured at respective usage times to the aging prediction 140. The ESD manager 110 may detect an aging deviation in response to determining that a difference, distance, and/or other error between the EPM data 258 and aging prediction exceeds a threshold, e.g., may detect an aging deviation |Obsₜ_{ᵢ}−ψₜₒₜₐₗ(tᵢ)|>Δ_{threshold}, where Obsₜ_{ᵢ} comprises a measurement of observed performance degradation acquired at a specified usage time (tᵢ), ψₜₒₜₐₗ(tᵢ) is predicted performance degradation under the target operating conditions at the specified usage time (tᵢ), and Δ_{threshold} is a aging deviation detection threshold.

In the FIG. 9 example, the ESD manager 110 may detect an aging prediction pertaining to the first ESD 105 in response to comparing a measurement of performance degradation incurred by the first ESD 105 a usage time t−1 to predicted performance degradation at usage time t−1; the aging deviation may be detected in response to comparing the measurement of EPM data 258-D1 {t−1} to the corresponding aging prediction 140 {t−1}, e.g., ψₜₒₜₐₗ(t₁). The ESD manager 110 may be further configured to determine that the first ESD 105 is aging more quickly than predicted based on the comparing, e.g., since aging observed in the first ESD 105 at usage time t−1 is greater than the corresponding aging prediction 140.

As further illustrated in FIG. 9, the ESD manager 110 may detect an aging deviation pertaining to the second ESD 105 in response to comparing a measurement of performance degradation incurred by the second ESD 105 a usage time t−2 to predicted performance degradation at usage time t−2; the aging deviation may be detected in response to comparing the measurement of EPM data 258-D2 {t−2} to the corresponding aging prediction 140 {t−2}, e.g., ψₜₒₜₐₗ(t₂). The ESD manager 110 may be further configured to determine that the first ESD 105 is aging more slowly than predicted based on the comparing, e.g., since aging observed in the second ESD 105 at usage time t−2 is less than the corresponding aging prediction 140.

Alternatively, or in addition, the ESD manager 110 may be configured to derive aging predictions 140 from the EPM data 258 and detect aging deviations by, inter alia, comparing the observed aging predictions 140 to the aging prediction 140 determined for the target operating conditions. In the FIG. 9 example, the ESD manager 110 (and/or ESDM module 112) may be configured to derive an aging prediction 140-D1 for the first ESD 105 from ESD data 258-D1 and derive an aging prediction 140-D2 for the second ESD 105 from ESD data 258-D2. As illustrated in FIG. 9, the aging predictions 140-D1 and 140-D2 may be derived from EPM data 258 acquired over the first eight months of the usage period, e.g., the aging prediction 140-D1 may be derived from first EPM data 258-D1 pertaining to a first ESD 105 and the aging prediction 140-D1 may be derived from second EPM data 258-D2 pertaining to a second ESD 105. The aging predictions 140-D1 and 140-D2 may be generated by, inter alia, fitting measurements of the EPM data 258-D1 and 258-D2 to the aging model 120 of the ESD 105, as disclosed herein, e.g., fitting measurements to a ψₜₒₜₐₗ(t) function learned for the ESD 105, as disclosed herein.

As illustrated in FIG. 9, the aging prediction 140-D1 may indicate that the first ESD 105 is aging more quickly than predicted, e.g., per the aging prediction 140. An ESD 105 may incur a greater (or lesser) degree of aging due to various factors, such as manufacturing variations between ESD 105 of a particular type, defects, damage, operating conditions (e.g., OC deviations, as disclosed herein), and/or the like. In response to the aging prediction 140-D1, the ESD manager 110 may be configured to generate a modified OP policy 150 (and/or corresponding ESD CFG 160) for the first ESD 105. In the FIG. 3 example, the modified OP policy 150 (and/or corresponding ESD CFG 160) may be configured to reduce the extent and/or rate of CRA incurred by the first ESD 105. The ESD manager 110 may be configured to modify target charge conditions in the charge policy 154 of the modified OP policy 150 such that the resulting aging metrics 142 and/or aging prediction 140 satisfy ESR requirements of the application 170, e.g., maintain performance degradation incurred by the first ESD 105 at or below one or more thresholds for a specified usage period.

As further illustrated in FIG. 9, the aging prediction 140-D2 may indicate that the second ESD 105 is aging more slowly than predicted. In response, the ESD manager 110 may determine a modified OP policy 150 (and/or corresponding ESD CFG 160) for the second ESD 105. In the FIG. 3 example, the charge policy 154 of the revised OP policy 150 may be configured to improve aspects of the charge conditions, e.g., may comprise modifications configured to increase charge SoC, reduce charge duration, and/or the like while satisfying the performance and/or endurance requirements of the application 170, as disclosed herein.

Referring back to FIG. 3, as disclosed herein, the ESD manager 110 may be configured to manage implementation of applications 170 by ESD 105. Managing implementation of an application 170 by an ESD 105 may comprise utilizing an aging model 120 of the ESD 105 to determine target operating conditions for the ESD 105, the target operating conditions configured to maintain performance degradation predicted to be incurred by the ESD 105 below a threshold for a specified usage period.

As disclosed herein, the ESD manager 110 may be configured to determine OP policies 150 configured to satisfy the requirements of an application 170. In some implementations, the ESD manager 110 may be further configured to determine OP policies 150 configured to enable secondary utilization of ESD 105. As used herein, secondary utilization may comprise and/or refer to utilization of an ESD 105 in multiple applications 170. For example, an ESD 105 may be utilized in a first, primary application 170 and, upon completion of the usage period of the primary application 170, be utilized in a secondary application 170. The usage period of the secondary application 170 may, therefore, extend the effective usage period of the ESD 105, e.g., the effective usage period of the ESD 105 may include the usage period of the primary application 170 followed by the usage period of the secondary application 170. The ESD manager 110 may be configured to determine OP policies 150 for ESD 105 that are predicted to satisfy requirements of a primary application 170 and the requirements of a secondary application 170. In other words, the ESD manager 110 may be configured to determine OP policies 150 predicted to a) satisfy requirements of the primary application 170 for the usage period of the primary application 170 and b) satisfy requirements of a secondary application 170 for an extended, secondary usage period that extends beyond the primary usage period. For example, the OP policy 150 may be configured such that the ESD 105 is predicted to satisfy requirements of the secondary application 170 for an extended secondary usage period, the secondary usage period extending the usage period of the primary application by the usage period of the secondary application 170. The ESD manager 110 may be configured to predict performance degradation during the usage period of the primary application 170 based on an OP policy 150 (and/or target operating conditions) determined for the primary application 170, as disclosed herein.

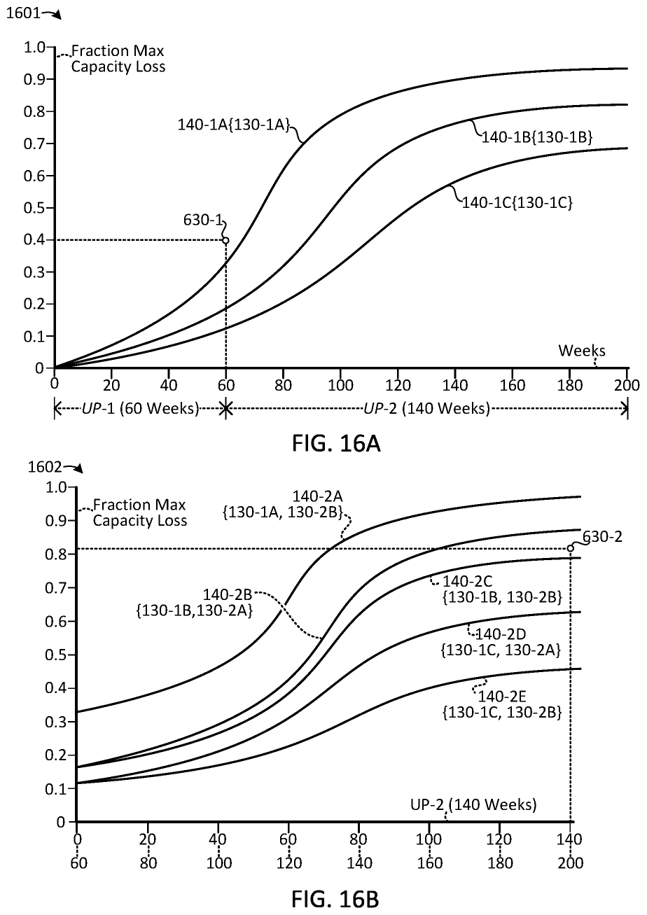

In the examples illustrated in FIGS. 3 and 8, the ESD manager 110 may determine a first OP policy 150 (a first charge policy 154) configured to manage operation of the ESD 105 within the primary application 170 (e.g., over the usage period of the primary application) and a second OP policy 150 (a second charge policy 154) configured to manage operation of the ESD 105 within the secondary application 170 (e.g., over the secondary usage period). The first charge policy 154 may be configured to satisfy requirements of the primary application 170 as disclosed herein. The first charge policy 154 and the second charge policy 154 may be further configured to satisfy requirements of the secondary application 170 over the secondary usage period. For example, the ESD manager 110 may be configured to predict performance degradation during the secondary usage period based on a) cumulative performance degradation incurred under the primary OP policy 154 (and predicted discharge conditions of the primary application 170) during the primary usage period, and b) performance degradation predicted to be incurred under the second OP policy 150 (and predicted discharge conditions of the secondary application 170). For example, the ESD manager 110 may model performance degradation of the ESD 105 using a multi-period aging model 120 as illustrated in FIGS. 7A and 7B. Alternatively, or in addition, the ESD manager 110 may determine multi-application OP policies 150 as illustrated in FIGS. 16A and 16B, as disclosed in further detail herein.

In some implementations, the analysis module 116 may be configured to manage implementation of applications 170 by specified ESD 105 and/or ESD 105 of a specified ESD type. Accordingly, in some implementations, the “search space” of the analysis module 116 may be limited to a single ESD type, e.g., a “single-type search space.” A single-type search space for determining an OP policy 150 may be constrained by the characteristics and/or capabilities of a single type of ESD 105. For example, the “single-type search space” for an ESD 105 of ESD type A may be constrained to ESD-specific characteristics of ESD type A such as e.g., maximum voltage (Vₘₐₓ), minimum voltage (Vₘᵢₙ), ESD capacity (C, which may determine other ESD characteristics, such as C₁ rates), maximum charge rate (r_{ch_max}, e.g., in terms of ESD capacity and/or C₁ rate), maximum discharge rate (r_{d_max}, e.g., in terms of ESD capacity and/or C₁ rate), reference temperature (T_{ref}, which may limit the range of temperatures in which the ESD 105 may be used), and so on. Moreover, the single-type search space may be further characterized by ESD-specific aging characteristics, such as the aging model 120 determined for ESD type A, OCS data 220 determined for ESD type A, and so on.

Alternatively, in some implementations, the ESD manager 110 may be configured to determine OP policies 150 for applications 170 capable of utilizing a plurality of different ESD types. The ESD manager 110 may be configured to determine OP policies 150 within a “multi-type search space” corresponding to a plurality of ESD types. The multi-type search space may comprise ESD-specific characteristics, capabilities, and/or aging models of a plurality of ESD types. Therefore, in some implementations, managing implementation of an application 170 by an ESD 105 may comprise a) selecting an ESD type for the application 170, b) determining an OP policy 150 for the ESD 105 of the determined ESD type within the application 170 (e.g., determining a charge policy 154 for the selected ESD type), and c) configuring the application 170 to utilize the ESD 105 in accordance with the determined OP policy 150. In the examples illustrated in FIGS. 3 and 8, the ESD manager 110 may be configured to evaluate charge policies 154 for ESD 105 of respective ESD types under predicted discharge conditions of the application 170.

Selecting the ESD type for the application 170 may comprise comparing requirements of the application 170 to ESD-specific characteristics, capabilities, and/or aging models 120 of respective ESD types. In the examples illustrated in FIGS. 3 and 8, the ESD manager 110 may be configured to determine the ESD type for the application 170 based, at least in part, on a comparison between ESD-specific characteristics of respective ESD types and charge requirements of the application 170. For example, the ESD manager 110 may determine the ESD type for the application 170 based, at least in part, on OCS data 220 determined for respective ESD types. By way of non-limiting example, the application 170 may comprise charge requirements specifying relatively high charge rates (r_{ch}) and/or a relatively short maximum charge duration (D_{ch}) and relatively low charge SoC requirements. In response, the ESD manager 110 may select ESD type(s) having a low sensitivity to charge rate (r_{ch}) regardless of whether such ESD type(s) are sensitive to charge SoC.

Alternatively, or in addition, the ESD manager 110 may select the ESD type and/or determine the ESD policy 150 for the selected ESD type in an OCO procedure, as disclosed herein. As illustrated in FIG. 8, in some implementations, the formulation module 802 may be configured to construct optimization models 804 corresponding to multiple ESD types. The formulation module 802 may be configured to retrieve ESD-specific information pertaining to respective ESD types from the datastore 114 or the like, e.g., from respective ESD profiles 115, as disclosed herein. For example, the formulation module 802 may be configured to construct a search space for the OCO procedure corresponding to T ESD types, e.g., ESD types A through T as illustrated in FIG. 8. The OCO procedure may comprise searching the multi-type search space for an optimal solution 850, the optimal solution comprising an optimal OP policy 150 determined for an optimal ESD type for the application 170. In some implementations, the cost metrics 842 determined for respective candidates 830 may incorporate information pertaining to the cost of ESD 105 of respective ESD types. The optimal solution 850 may, therefore, balance characteristics respective ESD types against costs associated with the respective ESD types.

In some implementations, the OCO procedure may be further configured to determine optimal OP policies 150 for secondary utilization of ESD 105. For example, the optimization criteria 822 of the OCO procedure may be configured to weight the utility of ESD 105 capable of use in a secondary application 170 higher than ESD 105 incapable of such secondary use (and/or assign inversely proportional weights to the cost metrics 842). The OCO procedure may, therefore, select ESD types that may have higher costs than other ESD types, but are capable of secondary use.

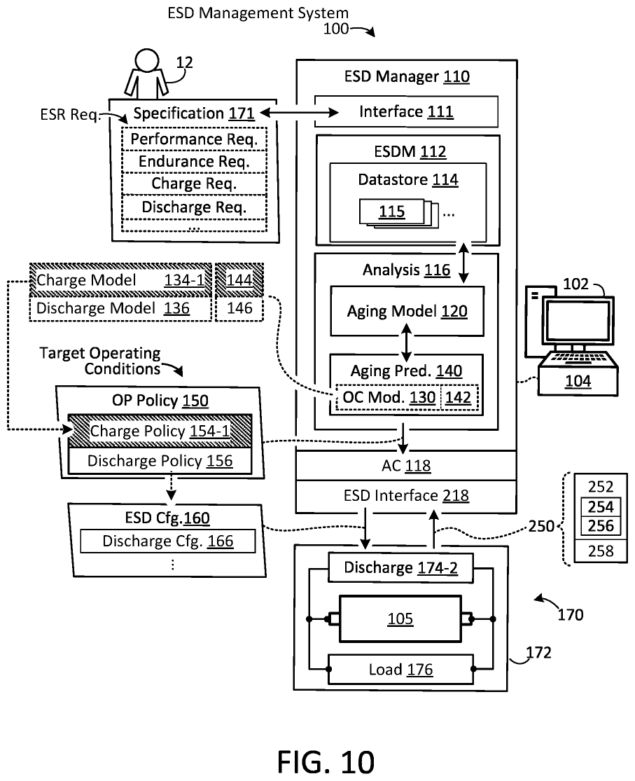

FIG. 10 is a schematic block diagram illustrating another example of a system for managing ESD 105, as disclosed herein. In the FIG. 10 example, the ESD manager 110 may be configured to manage implementation of an application 170 by an ESD 105 (and/or ESD 105 of a particular type, model, or the like). The application 170 may comprise and/or be embodied by a system 172 comprising one or more ESD modules 174. The system 172 may, for example, comprise a discharge module 174-2 configured to implement ESD discharge operations.

The ESD manager 110 may be configured to control aspects of ESD discharge conditions within the application 170, e.g., control aspects of discharge operations implemented by the discharge module 174-2 or the like. In the FIG. 10 example, the ESD manager 110 may be configured to treat ESD charge conditions as constants as opposed to variables that can be adjusted in the target operating conditions. For example, ESD charge conditions may be managed by the application 170, e.g., charge operations may be managed by ESD module(s) 134 and/or other components of the ESDA system 172 (not shown in FIG. 10 to avoid obscuring details of the illustrated examples).

As disclosed herein, the ESD manager 110 may be configured to manage implementation of the application 170 by an ESD 105 (and/or ESD 105 of a specified ESD type). The ESD manager 110 may be configured to determine an OP policy 150 configured to manage utilization of the ESD 105 within the application 170.

In the FIG. 10 example, OP policy 150 may be configured to incorporate a charge model 134-1. The charge model 134-1 may be configured to characterize predicted charge conditions of the ESD 105 within the application 170. The charge model 134-1 may, therefore, comprise and/or be referred to as a fixed, predetermined, and/or predicted charge model 134-1. The ESD manager 110 may derive aspects of the charge model 134-1 from the specification 171 of the application 170. For example, aspects of the charge model 134-1 may be derived from ESR requirements of the application 170, such as charge requirements (e.g., minimum charge SoC and/or end charge voltage (V_{ch_end}), predicted charge temperature (T_{d}), and/or the like), performance requirements, and/or the like. In some implementations, aspects of the charge model 134-1 may be derived from characteristics of the application 170 and/or ESDA system 172. For example, the ESD manager 110 may be configured to determine aspects of the charge model 136-1 based, at least in part, on SoC and/or capacity requirements of the application 170. Alternatively, or in addition, aspects of the predicted charge model 134-1 may be received from a user 12, e.g., through user interaction with a GUI managed by the interface module 111. In some implementations, the ESD manager 110 may be configured to estimate aspects of the charge model 134-1. For example, the ESD manager 110 may configure the charge model 134-1 in accordance with nominal and/or default charge conditions of the ESD 105 and/or application 170, e.g., charge rate (r_{ch}) of about C₁, and so on. In some implementations, the ESD manager 110 may be configured to determine and/or revise the charge conditions (e.g., charge model 134-1) based on ESDM data 250, as disclosed in further detail herein.

As disclosed herein, in the FIG. 10 example, the analysis module 116 may treat the charge model 134-1 as a constant or constraint. The analysis module 116 may be further configured to incorporate the charge model 134-1 into the OP policy 150 determined for the ESD 105. In other words, the OP policy 150 determined for the ESD 105 may be configured to model and/or incorporate the predicted charge conditions of the ESD 105 within the application 170 (and corresponding charge-related aging metrics 144). As illustrated in FIG. 10, the OP policy 150 may comprise a charge policy 154-1, the charge policy 156-1 comprising and/or derived from the charge model 136-1.

In the FIG. 10 example, determining the OP policy 150 for the ESD 105 may comprise configuring discharge-related aspects of the OP policy 150 (e.g., the discharge policy 156) to satisfy requirements of the application 170, while treating charge-related aspects of the OP policy 150 as constraints (e.g., the charge policy 154-1 and/or corresponding charge conditions). The analysis module 116 may be configured to generate, evaluate, and/or modify candidate discharge policies 156 to determine target operating conditions predicted to satisfy the ESR requirements of the application 170 (and/or satisfy other objectives, such as charge requirements of the application 170, as disclosed herein).

In the example illustrated in FIG. 10, managing implementation of the application 170 by an ESD 105 (and/or ESD 105 of a particular type) may comprise: a) retrieving an aging model 120 for the ESD 105, b) determining an OP policy 150 specifying target operating conditions for the ESD 105, the OP policy 150 comprising a discharge policy 156 determined by the analysis module 116 and a charge policy 154-1 corresponding to the predicted charge conditions of the ESD 105 within the application 170, and c) generating an ESD CFG 160 configured to cause the application 170 to utilize the ESD 105 in accordance with the OP policy 150. The ESD CFG 160 may be configured to cause the application 170 to utilize the ESD 105 under operating conditions corresponding to the target operating conditions of the OP policy 150. As illustrated in the FIG. 10 example, the ESD CFG 160 may comprise a discharge configuration 166 configured to control aspects of the discharge operations performed by the discharge module 174-2. In some implementations, the ESD CFG 160 may not include a charge configuration 164, e.g., since charge conditions of the ESD 105 may be managed by the application 170. The discharge policy 156 determined by the ESD manager 110 may specify parameters and/or settings of discharge operations to be performed on the ESD 105 within the application 170. The discharge configuration 166 generated by the AC module 118 may be configured to cause ESD modules 174 of the application 170 (e.g., discharge module 174-2) to implement discharge operations in accordance with the target discharge conditions of the discharge policy 156, as disclosed herein, e.g., may comprise instructions, commands, configuration data, parameters, and/or other information to manage aspects of charge operations performed on the ESD 105 within the system 172.

The discharge policy 156 (and/or target discharge conditions an corresponding discharge configuration 166) may comprise and/or correspond to any suitable type of discharge operation including, but not limited to: single-step discharge operations (e.g., single-step discharge operations having an M_{d} modeled per Eq. 17-22), two-step discharge operations (e.g., two-step discharge operations having an M_{d} modeled per Eq. 23), multi-step discharge operations (e.g., N-step discharge operations having an M_{d} modeled per Eq. 24-29), multi-step discharge operations with intervening rest periods (e.g., N-step discharge operations with optional rest periods having an M_{d} modeled per Eq. 30), period-specific discharge operations, and/or the like.

In the FIG. 10 example, determining the OP policy 150 (discharge policy 156) may comprise determining target discharge conditions that satisfy requirements of the application 170, e.g., satisfy requirements defined within a specification 171 of the application 170 or the like. Determining the target discharge conditions may comprise designing an OC model 130 having discharge conditions (e.g., a discharge model 136) under which the ESD 105 is predicted to satisfy performance requirements of the application 170. The analysis module 112 may configure the target discharge conditions to produce DC metrics 146 (e.g., Mₜₒₜₐₗ and/or M_{d}) that satisfy a specified threshold (M_{threshold}), e.g., determine a discharge model 136 and/or discharge conditions where Mₜₒₜₐₗ<M_{threshold} and/or where M_{d}<M_{threshold}.

In some implementations, the target discharge conditions may be determined based on default or nominal charge conditions, such as nominal or baseline charge conditions, e.g., a nominal charge rate (ch) of about C₁, nominal starting voltage (V_{ch_start}), nominal charge SoC and/or end voltage (V_{ch_end}), nominal temperature (T_{d}), and so on. For example, the target discharge conditions may be configured such that, M_{d}+M_{ch_nom}<M_{threshold}, where M_{ch_nom} is a prediction of performance degradation attributable to default or nominal charge conditions.

Alternatively, the target discharge conditions may be determined based on a predicted charge conditions of the ESD 105 within the application 170, as disclosed herein. The analysis module 116 may configure the OC models 130 used to determine target discharge conditions for the ESD 105 in accordance with the predicted charge condition, as opposed to nominal or default charge conditions. The analysis module 116 may be configured to determine target discharge conditions wherein M_{d}+M_{ch_req}≤M_{threshold}, where M_{ch_req} is the extent of performance degradation predicted to be incurred due to the charge requirements of the application 170 (e.g., per the predicted charge conditions of the ESD 105 in the application 170 as characterized by the charge model 134-1).

Alternatively, or in addition, the analysis module 112 may configure the target discharge conditions such that performance degradation incurred by a specified performance characteristic of the ESD 105 is predicted to remain above a threshold for a specified usage period, e.g., target discharge conditions wherein ψₜₒₜₐₗ(tₗ)<ψ_{threshold} and/or ψ_{d}(tₗ)<ψ_{threshold}, where ψ_{threshold} is a performance requirement defined for the specified performance characteristic and tₗ is the corresponding endurance requirement. In some implementations, the target discharge conditions may be determined based on a specified set of discharge conditions, such as nominal or baseline discharge conditions, as disclosed herein. For example, the analysis module 116 may configure the target charge conditions such that ψ_{d}(tₗ)+ψ_{ch_nom}(tₗ)<ψ_{threshold}, where ψ_{ch_nom} is a function configured to model performance degradation under nominal and/or default charge conditions. Alternatively, the target discharge conditions may be determined based, at least in part, on charge requirements of the application 170, as disclosed herein. The target discharge conditions may be configured such that ψ_{d}(tₗ)+ψ_{ch_req}(tₗ)<ψ_{threshold}, where ψ_{ch_req} is a function configured to model performance degradation incurred by the ESD 105 under charge conditions corresponding to the charge requirements of the application 170 (e.g., charge model 134-1).

As disclosed herein, the analysis module 116 may be further configured to determine OP policies 150 comprising target operating conditions that satisfy performance and other types of requirements, such as charge requirements, discharge requirements, and/or the like. In the FIG. 10 example, the analysis module 116 may configure the discharge policy 156 to, inter alia, satisfy discharge requirements of the application 170. For example, the specification 171 may require that discharge operations be capable of producing a minimum amount of power (e.g., Pwrₘᵢₙ), and the analysis module 116 may configure the discharge policy 156 to satisfy the discharge requirements, e.g., constrain the discharge policy 156 to discharge conditions having discharge rate (r_{d}) and/or parameters configured to satisfy the minimum power threshold (Pwrₘᵢₙ).

Determining the OP policy 150 (discharge policy 156 in the FIG. 10 example) may comprise evaluating one or more aging predictions 140, each aging prediction 140 configured to model performance degradation attributable to a specified OC model 130 (e.g., a set of charge conditions and/or discharge conditions). In some implementations, determining the discharge policy 156 may comprise iteratively evaluating and/or modifying OC models 130 until termination criteria are satisfied. For example, the analysis module 116 may be configured to determine target discharge conditions through, inter alia, an OCO procedure, as disclosed herein. The analysis module 116 may be configured to evaluate aging predictions 140 corresponding to any suitable type of discharge operation. The analysis module 116 may be further configured to maintain information pertaining to the aging predictions 140 determined for respective operating conditions within the datastore 114 and/or other DSR resources 104-2, e.g., within ESD profiles 115. As disclosed herein, the ESD manager 110 may be configured to maintain ESD-specific information, such as ESD-specific parameters (e.g., r_{ch_max}, r_{d_max}, Vₘᵢₙ, Vₘₐₓ, T_{ref}, ΔVₚₒₗ, and/or the like) within ESD profiles 115. The ESD profiles 115 may further comprise age-related data pertaining to respective ESD 105 (and/or ESD types), such as aging models 120, aging data 215 (e.g., aging datasets 240), aging predictions 140 for respective operating conditions, aging metrics 142 under respective operating conditions, and/or the like.

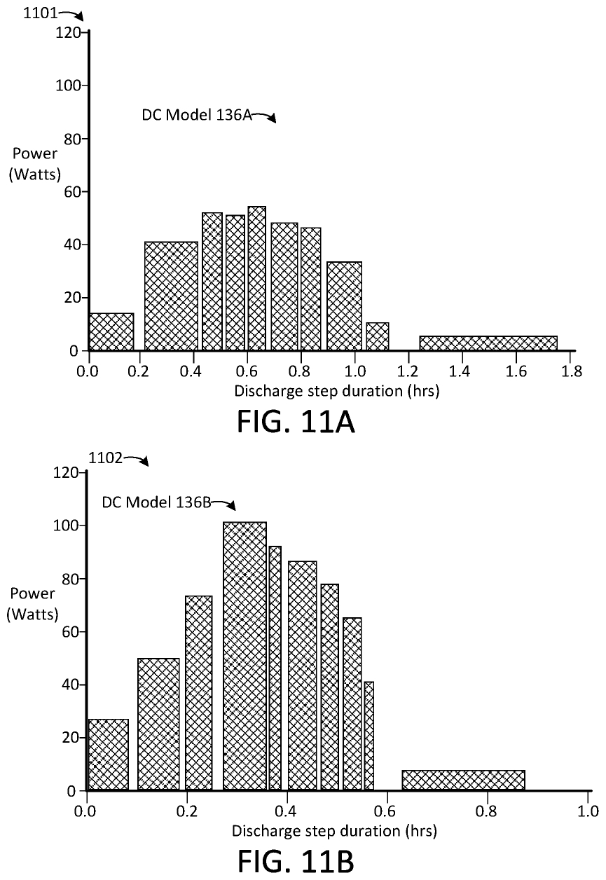

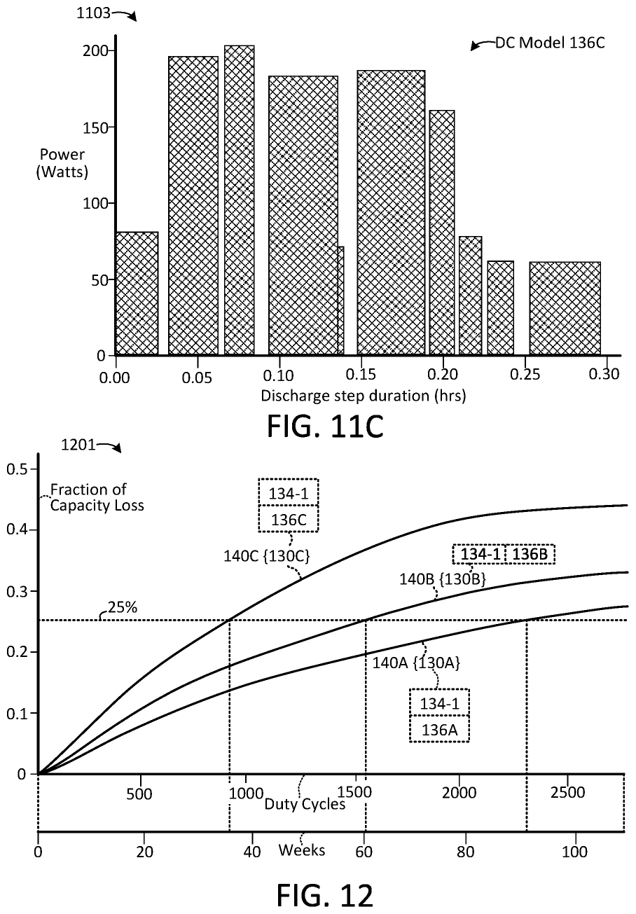

FIGS. 11A-11C comprise plots illustrating examples of discharge conditions, as disclosed herein. The discharge models 136A-C illustrated in FIGS. 11A-11C may be configured to model the discharge conditions of respective multi-step discharge operations, each discharge operation configured to discharge the ESD 105 from a start voltage (V_{d_start}) of about Vₘₐₓ to an end voltage (V_{d_end}) of about Vₘᵢₙ. The discharge models 136A-C may comprise discharge step models 137 configured to model ESD discharge conditions during respective discharge steps and/or inter-step rest periods, e.g., rest periods of about 1.5 minutes. The discharge models 136A-C may comprise respective discharge step models 137, each having discharge step i having a respective duration (x_{d_ti}) and discharge rate (d_{d_i}, resulting in a respective output power. The discharge model 136A illustrated in plot 1101 of FIG. 11A may be configured to model a multi-step discharge operation having a maximum power output of about 50 W, the discharge model 136B illustrated in plot 1102 of FIG. 11B may be configured to model a multi-step discharge operation having a maximum power output of about 100 W, and the discharge model 136C illustrated in plot 1103 of FIG. 11C may be configured to model a multi-step discharge operation having a maximum power output of about 200 W. The duration of the discharge operation (and/or discharge steps) of the discharge model 136A may be longer the duration of discharge model 136B, which may be longer than discharge model 136C, e.g., D_{d_A}>D_{d_B}>D_{d_C}, where D_{d_i} is a duration of the discharge operation characterized by discharge models 136A-C, respectively. Similarly, discharge rates of the discharge model 136A may be lower than the discharge rates of discharge model 136B, which may be lower than the discharge rates of discharge model 136C, e.g., r_{d_A}<r_{d_B}<r_{d_C}, where r_{d_i} is the discharge rate (and/or average step discharge rate) of discharge models 136A-C, respectively. Although not illustrated in FIGS. 11A-C, temperature and/or temperature rise incurred under discharge model 136C may be higher than discharge model 136B, which may be higher than discharge model 136A due to, inter alia, ohmic-related loses, e.g., internal resistance.

The ESD manager 110 may be configured to develop an aging model 120 for the ESD 105, as disclosed herein. The aging model 120 may be configured to predict the extent and/or rate of performance loss to be incurred by the ESD 105 under operating conditions corresponding to respective discharge models 136A-C. FIG. 12 comprises a plot 1201 illustrating an example of an aging model 120. The plot 1201 comprises aging predictions 140A-C. The aging predictions 140A-C may be configured to predict capacity loss incurred by the ESD 105 under respective OC models 130A-C, e.g., as a fraction of the maximum theoretical extent of capacity loss attributable to ESD operating conditions.

The aging predictions 140A-C illustrated in FIG. 12 may be configured to predict performance loss as a function of duty cycle, e.g., may predict capacity loss incurred from duty cycle 0 to over 2500 under the operating conditions of respective OC models 130A-C. Alternatively, or in addition, the aging predictions 140A-C may be configured to predict performance loss as a function of time. The aging model 120 may be configured to convert duty cycle to time (and vice versa). As illustrated in FIG. 12, the aging model 120 may predict about 5 duty cycles per day or about 25 duty cycles per week.

The aging predictions 140A-C may be configured to capacity loss under operating conditions of OC models 130A-C, respectively. In the FIG. 12 example, the OC models 130A-C may comprise the same charge model 134-1. The charge model 134-1 may comprise nominal or default ESD charge conditions. Alternatively, the charge model 134-1 may be configured to model predicted charge conditions of the ESD 105 within the application 170, as disclosed herein. Accordingly, differences between the aging predictions 140A-C may be attributable to differences between the discharge conditions of discharge models 136A-C.

As illustrated in FIG. 12, more aggressive discharge conditions may result in increased aging rates. The ESD 105 may age more quickly under discharge model 136C (200 W) than under discharge model 136B (100 W) or 136A (50 W), and may age more quickly under discharge model 136B (100 W) than under discharge model 136A (50 W).

The analysis module 116 may utilize the aging predictions 140A-C to determine target operating conditions for the ESD 105 in the application 170. The analysis module 116 may determine target operating conditions predicted to maintain performance degradation under a threshold for a specified usage period. In the FIG. 12 example, the analysis module 116 may be configured to determined target operating conditions that maintain capacity loss under 25% for a usage period of about 1500 duty cycles (or about 60 weeks). Under OC model 130C (discharge model 136C), the ESD 105 is predicted to reach 25% capacity loss by about 950 duty cycles (about 38 weeks). The analysis module 116 may, therefore, determine that the OC model 130C fails to satisfy the ESR requirements of the application 170. By contrast, the less aggressive discharge conditions of discharge models 136A and 136B (e.g., OC models 130A and 130B) may satisfy the ESR requirements of the application 170. As illustrated in FIG. 12, the ESD 105 may be predicted to reach 25% capacity loss at about 1525 duty cycles (about 61 weeks) under discharge model 136B and at about 2250 duty cycles (about 90 weeks) under discharge model 136A.

Referring back to FIG. 10, as disclosed herein, the operating conditions of an ESD 105 in an application 170 may change over time. Changes to the operating conditions of an ESD 105 may result in corresponding changes to the extent and/or rate of performance degradation incurred by the ESD 105, e.g., changes to aging metrics 142 such as M_{ch}, M_{d}, Mₜₒₜₐₗ, ψ_{ch}(t), ψ_{d}(t), ψₜₒₜₐₗ(t), and/or the like. As disclosed herein, the ESD manager 110 may be configured to develop aging models 120 configured to predict ESD aging over a plurality of periods, each period having respective operating conditions. The aging models 120 may be configured to predict ESD aging over a plurality of usage periods k, each usage period having respective operating conditions; aging attributable to the charge conditions in respective usage periods may be modeled per Eq. 16 and aging attributable to the discharge conditions in respective usage periods may be modeled per Eq. 32. In the FIG. 10 example, the analysis module 16 may be configured to determine target operating conditions (e.g., target discharge conditions under predicted charge conditions) for respective usage periods such that cumulative aging incurred by the ESD 105 over the plurality of usage periods is maintained at or below one or more thresholds, e.g., as described above in conjunction with FIGS. 7A and 7B.

As disclosed herein, in the FIG. 10 example, the ESD manager 110 may be configured to manage implementation of an application 170 by an ESD 105 by a) determining an OP policy 150 comprising a discharge policy 156 predicted to satisfy requirements of the application 170 under predicted charge conditions of the application 170, b) generating a discharge configuration 166 corresponding to the target discharge conditions, and c) configuring the application 170 (e.g., discharge module 174-2) to implement discharge operations in accordance with the discharge configuration 166. In some implementations, the analysis module 116 may be configured to determine an optimal OC policy 150 (and/or discharge policy 156) for the ESD 105 within the application 170. The optimal OP policy 150 may be determined in an OCO procedure, as disclosed herein.

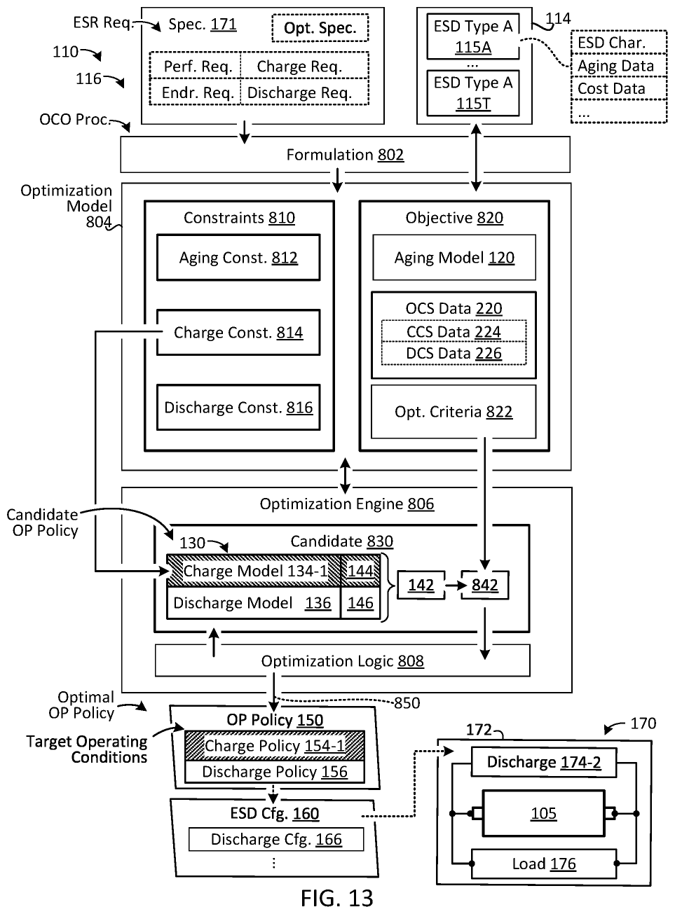

FIG. 13 is a schematic block diagram illustrating another example of an ESD manager 110. The ESD manager 110 may comprise an analysis module 116 configured to, inter alia, manage implementation of an application 170 by an ESD 105 (and/or ESD 105 of a particular type), as disclosed herein. In the FIG. 13 example, the ESD manager 110 may be configured to control aspects of the discharge conditions of ESD 105 within the application 170, e.g., control aspects of the discharge operations implemented by discharge module(s) 174-2 of the application 170. As in the FIG. 10 example, the ESD manager 110 may be configured to treat ESD charge conditions of the application 170 as constants and/or constraints. The ESD manager 110 may comprise a charge model 134-1 configured to characterize default, nominal, and/or predicted charge conditions of the ESD 105 within the application 170, as disclosed herein.

The analysis module 116 may be configured to determine an OP policy 150 for the ESD 105 within the application 170. In the FIG. 13 example, the OP policy 150 may comprise a charge policy 154-1 configured to model predicted charge conditions of the ESD 105 within the application 170 as disclosed herein, e.g., per charge model 134-1. According to the FIG. 13 example, determining the OP policy 150, may comprise determining a discharge policy 156 that satisfies requirements of the application 170 under the predicted ESD charge conditions of the application 170. For example, the discharge policy 156 may be required to result in aging metrics 132 that satisfy one or more thresholds, e.g., specify target discharge conditions wherein M_{d}>M_{d_threshold} and/or Mₜₒₜₐₗ>M_{threshold}, where Mₜₒₜₐₗ=M_{d}+M_{ch_req} and M_{ch_req} is the extent of CRA predicted for the charge model 134-1. Alternatively, or in addition, the discharge policy 156 may be required to satisfy a usage guarantee 630. The discharge policy 156 may be required to result in aging metrics 132 that maintain performance degradation predicted to be incurred by the ESD 105 below a threshold for a longevity threshold (tₗ), e.g., target discharge conditions wherein ψ_{d}(tₗ)<ψ_{threshold} and/or ψₜₒₜₐₗ(tₗ)≤ψ_{threshold}, where ψₜₒₜₐₗ(t)=ψ_{d}(t)+ψ_{ch_req}(t) and ψ_{ch_req}(t) is a function configured to predict DRA incurred the charge model 134-1.

The discharge policy 156 may be further configured to satisfy other constraints, such as constraints corresponding to discharge requirements of the application 170; discharge requirements of the application 170 may constrain aspects of the discharge policy 156 to specified ranges and/or values. For example, the discharge requirements may specify that the application 170 requires ESD 105 to produce at least a minimum amount of power (Pwrₘᵢₙ) and the analysis module 116 may constrain the discharge policy 156 accordingly, e.g., may constrain discharge policy 156 to target discharge conditions having discharge rates (r_{d}) and/or other parameter values that satisfy the minimum power discharge requirement of the application 170 (Pwrₘᵢₙ).

In some implementations, the analysis module 116 may be configured to determine OP policies 150 through, inter alia, an OCO procedure. In the FIG. 10 example, the analysis module 116 may comprise a formulation module 802. As disclosed herein, the formulation module 802 may be configured to generate, construct, formulate, and/or otherwise manage an optimization model 804 of the OCO procedure. The optimization model 804 may comprise and/or be derived from characteristics of the application 170 and/or ESD 105. The optimization model 804 may comprise constraints 810. As disclosed herein, the constraints 810 may be configured to constrain aspects of the OP policy 150 determined for the ESD 105 through the OCO procedure. More specifically, in the FIG. 13 example, the constraints 810 may be configured to constrain aspects of the discharge policy 156 determined for the ESD 105. The initialization model 804 may be configured to determine aging constraints 812, charge constraints 814, discharge constraints 816, and/or the like.

The aging constraints 812 may comprise and/or be derived from ESR requirements of the application 170, such as performance requirements, performance requirements and corresponding endurance requirements, usage guarantees 630, and/or the like. For example, the aging constraints 812 may require the OP policy 150 to maintain ESD performance degradation below a threshold for a specified usage period. The aging constraints 812 may be configured to limit the extent of aging predicted to be incurred by the ESD 105 and/or the rate at which such aging is incurred under the target operating conditions, e.g., constrain Mₜₒₜₐₗ, M_{d}, ψₜₒₜₐₗ(tₗ), ψ_{d}(tₗ), aging metrics 142, DC metrics 146 and/or the like, as disclosed herein.

The formulation module 802 may be further configured to determine charge constraints 814 of the OCO procedure. The charge constraints 814 may be based on and/or derived from charge requirements of the application 170, as disclosed herein. In the FIG. 13 example, the charge constraints 814 may correspond to a predicted charge model 134-1 determined for the application 170, as disclosed herein. Charge conditions of the charge model 134-1 may be treated as constants and/or constraints within the optimization model 804. In the FIG. 13 example, the charge constraints 814 may be configured to prevent modification of the charge model 134-1, e.g., may require the OP policy 150 to incorporate the charge model 134-1, as illustrated in FIG. 13.

The formulation module 802 may be further configured to determine discharge constraints 816. The discharge constraints 816 may be based on and/or derived from discharge requirements of the application 170, as disclosed herein. The discharge constraints 816 may, for example, constrain ESD discharge conditions to specified values and/or ranges, e.g., require target discharge conditions to satisfy a minimum power threshold (Pwrₘᵢₙ) or the like, as disclosed herein.

The formulation module 802 may be further configured to construct an objective model 820 of the OCO procedure. The objective model 820 may comprise means for evaluating the cost and/or utility of respective candidates 830. As disclosed herein, a candidate 830 may comprise and/or refer to a potential solution to the OCO procedure. In other words, a candidate 830 may comprise operating conditions (an OC model 122) that satisfies the constraints 810 of the OCO procedure.

The objective model 820 may comprise an aging model 120 of the ESD 105. The analysis module 116 may utilize the aging model 120 to evaluate aging characteristics of respective candidates 830. As disclosed herein, the analysis module 116 may utilize the aging model 120 to determine aging predictions 140 for respective candidates 830, determine aging metrics 242 for respective candidates 830 (e.g., determine aging metrics 242 for the OP policies 150 of respective candidates 830), and so on. Determining aging metrics 242 of a candidate 830 may comprise determining CC metrics 144 for the predicted charge conditions of the charge model 134-1, determining DC metrics 146 for the discharge policy 154 (and/or target discharge conditions) of the OP policy 150 of the candidate 830, and so on.

The objective model 820 may further comprise optimization criteria 822. As disclosed herein, the optimization criteria 822 may comprise means for quantifying the cost and/or utility of respective candidates 830. In the FIG. 13 example, the optimization criteria 822 may be configured to determine cost metrics 842 for respective candidates 830. The cost metric 842 of a candidate 830 may be based, at least in part, on aging metrics 142 predicted for the candidate 830. In the FIG. 13 example, the cost metrics 842 may be proportional to one or more of Mₜₒₜₐₗ, M_{d}, ψₜₒₜₐₗ(t), ψ_{d}(t), and/or the like. Alternatively, or in addition, the cost metric 842 may be configured to incorporate characteristics of the target operating conditions, such as discharge rate (e.g., may prefer target operating conditions where ESD 105 can output higher power levels) or the like. The optimization criteria 822 may be configured to assign weights to specified aspects of the aging metrics 142 and/or operating conditions, as disclosed herein.

In the FIG. 13 example, the analysis module 116 may further comprise an optimization engine 806. The optimization engine 806 may be configured to determine an optimal OP policy 150 for the ESD 105 in accordance with the optimization criteria 822. The optimization engine 806 may be configured to generate and/or evaluate candidates 830. As disclosed herein, a candidate 830 may comprise and/or refer to a potential solution to the optimization problem characterized by the optimization model 804. In other words, a candidate 830 may comprise and/or refer to an OP policy 150 that satisfies the constraints 810 of the optimization model 804. In the FIG. 13 example, a candidate 830 may comprise and/or refer to an OP policy 150 that satisfies a) aging constraints 812 determined for the application 170, e.g., satisfies performance and/or endurance requirements of the application 170, as disclosed herein, b) charge constraints 814 of the application 170, e.g., comprises and/or incorporates a charge model 136-1 configured to model predicted charge conditions of the ESD 105 within the application 170, as disclosed herein, and c) discharge constraints 816 of the application 170, e.g., comprises a discharge policy 156 that satisfies discharge requirements of the application 170, as disclosed herein.

The candidates 830 may comprise respective aging metrics 142. The aging metrics 142 may be configured to predict aging to be incurred by the ESD 105 under the OP policies 150 of the respective candidates 830. In the FIG. 13 example, the aging metrics 142 may be configured to predict aging under the target operating conditions of respective OP policies 150, e.g., under discharge conditions of the discharge policies 156 of respective candidates 830 and/or the predicted charge conditions of the discharge model 136-1. The aging metrics 142 may be determined by use of the aging model 120 of the ESD 105, as disclosed herein.

The candidates 830 may further comprise cost metrics 842. As disclosed herein, the cost metrics 842 may be a function of the aging metrics 142 and/or OP policy 150 of the candidate 830. In the FIG. 13 example, the cost metrics 842 may be a function of one or more target discharge conditions of the discharge policy 156, such as discharge rate (r_{d}), maximum power output (Pwrₘₐₓ), and/or the like. Alternatively, or in addition, in the FIG. 13 example, the cost metrics 842 may be a function of specified aspects of the aging metrics 142, such as predicted aging extent (e.g., Mₜₒₜₐₗ and/or M_{d}), predicted aging rate (e.g., ψₜₒₜₐₗ(t) and/or ψ_{d}(t)), and/or the like.

The optimization engine 806 may be configured to generate and/or evaluate candidates 830 according to optimization logic 808. The optimization logic 808 may be configured to implement any suitable optimization algorithm. The optimization engine 806 may be configured to generate candidates 830 based, at least in part, on the optimization model 804. The optimization engine 806 may be configured to generate candidates 830 comprising OC models 130 that satisfy the constraints 810 of the objective model 804, e.g., satisfy aging constraints 812, charge constraints 814, discharge constraints 816, and so on, as disclosed herein.

In some implementations, the optimization engine 806 may be configured to iteratively generate, evaluate, and/or modify candidates 830, e.g., iteratively modify aspects of the operating conditions of respective candidates 830. The candidates 830 may be modified to improve the cost metrics 842 thereof, e.g., reduce aging metrics 142, improve specified aspects of the operating conditions, and so on per the optimization criteria 822 of the OCO procedure. The optimization engine 806 may be configured to modify OC model 130 of the candidates 830 based, at least in part, on OCS data 220 determined for the ESD 105. As disclosed herein, the OCS data 220 may quantity the sensitivity of the aging model 120 (and/or resulting aging metrics 132) to respective operating conditions. The OCS data 220 may be configured to quantify the impact of respective operating conditions on the aging model 120 and/or aging metrics 142. In the FIG. 13 example, the optimization engine 806 may utilize DCS data 226 to modify discharge conditions of respective candidates 830, e.g., to improve the cost metrics 842 of the candidates 830 while satisfying the constraints 810 of the OCO procedure.

The optimization engine 806 may be configured to iteratively generate, evaluate, and/or modify candidates 830 until one or more termination criteria of the optimization logic 808 are satisfied, as disclosed herein. Terminating the OCO procedure may comprise generating an output or solution 850. The solution 850 may comprise a set of target operating conditions for the ESD 105 within the application 170. The solution 850 may comprise and/or be derived from an optimal candidate 830 of the OCO procedure. As disclosed herein, the optimal candidate 830 may comprise and/or refer to the candidate 830 that minimizes the cost metrics 842 of the optimization model 804 (per the optimization criteria 822), while satisfying the constraints 810 of the optimization model 804.

The solution 850 of the OCO procedure may comprise an optimal OP policy 150 for the ESD 105 within the application 170, as disclosed herein. For example, the solution 850 may comprise and/or be derived from a candidate 830 that satisfies the constraints 810 determined for the application 170 at a minimal cost metric 842, e.g., per the optimization criteria 822 of the application 170.

The solution 850 of the OCO procedure may comprise an OP policy comprising an optimal discharge policy 156 determined for the ESD 105. In the FIG. 13 example, the solution 850 may not include a charge policy 154 (e.g., since charge conditions may be treated as fixed constants or constraints in the FIG. 13 example). Alternatively, the OP policy 150 determined by the analysis module 116 may comprise a charge policy 154-1 configured to model the predicted charge conditions of the ESD 105 within the application 170 per the charge model 134-1, as disclosed herein.

As illustrated in FIGS. 10 and 13, the ESD manager 110 may be configured to generate a ESD CFG 160 corresponding to the OP policy 150 determined for the ESD 105. The ESD CFG 160 may comprise a discharge configuration 166 configured to control discharge operations implemented by the discharge module 174-2 of the application 170. The discharge configuration 166 may be configured to cause the discharge module 174-2 to implement discharge operations having discharge conditions corresponding to the determined target discharge conditions, as disclosed herein. In some implementations, the ESD CFG 160 may include a charge configuration 164 corresponding to the predicted ESD charge conditions within the application 170. Alternatively, the charge configuration may be omitted, as illustrated in the FIG. 13 example.

Referring to FIG. 10, in some implementations, the ESD manager 110 may be further configured to acquire, retrieve, request, and/or otherwise receive ESDM data 250. In the FIG. 10 example, the ESDM data 250 may comprise information pertaining to the operating conditions and/or performance of the ESD 105 within the application 170. As disclosed herein, the ESD manager 110 may be configured to detect prediction deviations pertaining to an ESD 105 and/or application 170 (e.g., OC deviations, aging deviations, and/or the like) and, in response, modify the OP policy 150 and/or corresponding ESD CFG 160 of the ESD 105 within the application 170.

In the FIG. 10 example, detecting an OC deviation may comprise a) receiving ESDM data 250, the ESDM data 250 comprising OCM data 252 pertaining to the operating conditions of the ESD 105 within the application 170, b) comparing the OCM data 252 to the target operating conditions determined for the ESD 105, and c) detecting an OC deviation based on the comparing. In response to detecting an OC deviation, the ESD manager 110 may be configured to generate aging metrics 142 and/or an aging prediction 140 for the OCM data 252. The ESD manager 110 may be configured to determine whether the OCM data 252 satisfies the ESR requirements of the application 170, e.g., determine whether Mₜₒₜₐₗ, M_{ch}, M_{d}, ψₜₒₜₐₗ(t), ψ_{ch}(t), and/or ψ_{d}(t) predicted for the observed operating conditions of the OCM data 252 satisfy performance and/or endurance requirements of the application 170. The ESD manager 110 may be further configured to determine a modified OP policy 150 for the ESD 105 that incorporate aspects of the observed operating conditions, as disclosed herein.

In the FIG. 10 example, the ESD manager 110 may be configured to manage aspects of the discharge conditions of the ESD 105 within the application 170, e.g., charge conditions may be managed internally. The ESD manager 110 may detect an OC deviation between the predicted charge conditions (e.g., charge model 134-1) and the actual, observed charge conditions of the ESD 105 within the application 170. In response, the ESD manager 110 may be configured to generate a modified OP policy 150 for the ESD 105 that incorporates the actual, observed charge conditions of the OCM data 252. The ESD manager 110 may be configured to a) update the charge model 134-1 and/or charge requirements of the specification 171 per the OCM data 252, and b) determine a modified OP policy 150 that incorporates the updated charge conditions. For example, the ESD manager 110 may be configured to determine an optimal OP policy 150 under the revised charge model 134-1, as illustrated in FIG. 13. The ESD manager 110 may be further configured to generate a revised, updated ESD CFG 160 for the ESD 105 and/or configure the application 170 to implement discharge operations in accordance with the revised ESD CFG 160.

In some examples, the revised ESD CFG 160 may be configured to preserve the usable life of the ESD 105, e.g., ensure that the ESD 105 satisfies usage guarantees 630 of the application 170 or the like. For example, the OCM data 252 may indicate that the actual, observed charge conditions of the ESD 105 are more strenuous than the predicted charge conditions used to generate the initial OP policy 150. Accordingly, the actual extent and/or rate of CRA incurred by the ESD 105 may be higher than predicted. In response, the ESD manager 110 may modify discharge-related parameters of the OP policy 150 (e.g., modify the discharge policy 156), to inter alia, reduce DRA incurred by the ESD 105 to offset the increased degree of CRA predicted under the revised charge conditions. Alternatively, the revised OP policy 150 may be configured to improve one or more performance characteristics. For example, the OCM data 252 may indicate that the observed charge conditions of the ESD 105 are less strenuous than those of the original charge model 134-1 and, as such, the ESD manager 110 may utilize more strenuous discharge conditions while satisfying ESR requirements of the application 170, e.g., increase discharge rate (r_{d}), increase maximum power output (Pwrₘₐₓ), and/or the like.

The prediction deviations detected by the ESD manager 110 may further comprise and/or refer to aging deviations. As disclosed herein, an aging deviation may comprise and/or refer to deviation between aging predicted to be incurred under the OP policy 150 determined for the ESD 105 and performance degradation observed in the ESDM data 250. The ESD manager 110 may be configured to detect aging deviations. Detecting an aging deviation may comprise a) receiving ESDM data 250 pertaining to the ESD 105, the ESDM data 250 comprising EPM data 258, b) comparing aging metrics 142 and/or an aging prediction 140 determined for the target operating conditions of the ESD 105 with the EPM data 258, and c) detecting an aging deviation based on the comparing. As disclosed herein, the aging metrics 142 and/or aging prediction 140 of the OP policy 150 determined for the ESD 105 may predict the extent of aging to be incurred by the ESD 105 under the target operating conditions of the OP policy 150 and/or the rate at which such aging is predicted to be incurred, e.g., may comprise an Mₜₒₜₐₗ quantity and/or ψₜₒₜₐₗ(t) functions, as disclosed herein. The EPM data 258 may comprise measurements of one or more ESD performance characteristics. The ESD manager 110 may compare the extent and/or rate of performance degradation predicted under the OP policy 150 to measurements of the EPM data 258 to determine whether actual, observed performance degradation incurred by the ESD 105 corresponds to the aging prediction 140.

The ESD manager 110 may be further configured to modify and/or update the OP policy and/or corresponding ESD CFG 160 in response to detecting an aging deviation, as described herein in conjunction with FIG. 9. In the FIG. 10 example, the ESD manager 110 may be configured to determine a modified discharge policy 156 configured to result in reduced aging metrics 142 in response to detecting an aging deviation in which the ESD 105 is aging more quickly than predicted. Alternatively, in the FIG. 10 example, the ESD manager 110 may be configured to determine a modified discharge policy 156 configured to improve one or more discharge characteristics, e.g., maximum power output (Pwrₘₐₓ) in response to detecting an aging deviation in which the ESD 105 is aging more slowly than predicted.

As disclosed herein, the ESD manager 110 may be configured to determine OP policies 150 configured to satisfy the requirements of an application 170. In some implementations, the ESD manager 110 may be further configured to determine OP policies 150 configured to enable secondary utilization of ESD 105. For example, an ESD 105 may be utilized in a first, primary application 170 and, upon completion of the usage period of the primary application 170, be utilized in a secondary application 170. The usage period of the secondary application 170 may, therefore, extend the effective usage period of the ESD 105, e.g., the effective usage period of the ESD 105 may include the usage period of the primary application 170 followed by the usage period of the secondary application 170. The ESD manager 110 may be configured to determine OP policies 150 for ESD 105 that are predicted to satisfy requirements of a primary application 170 and the requirements of a secondary application 170. In other words, the ESD manager 110 may be configured to determine OP policies 150 predicted to a) satisfy requirements of the primary application 170 for the usage period of the primary application 170 and b) satisfy requirements of a secondary application 170 for an extended, secondary usage period that extends beyond the primary usage period. For example, the OP policy 150 may be configured such that the ESD 105 is predicted to satisfy requirements of the secondary application 170 for an extended secondary usage period, the secondary usage period extending the usage period of the primary application by the usage period of the secondary application 170. The ESD manager 110 may be configured to predict performance degradation during the usage period of the primary application 170 based on an OP policy 150 (and/or target operating conditions) determined for the primary application 170, as disclosed herein.

In the examples illustrated in FIGS. 10 and 13, the ESD manager 110 may determine a first OP policy 150 (a first discharge policy 156) configured to manage operation of the ESD 105 within the primary application 170 (e.g., over the usage period of the primary application) and a second OP policy 150 (a second discharge policy 156) configured to manage operation of the ESD 105 within the secondary application 170 (e.g., over the secondary usage period). The first charge policy 154 may be configured to satisfy requirements of the primary application 170 as disclosed herein. The first charge policy 154 and the second charge policy 154 may be further configured to satisfy requirements of the secondary application 170 over the secondary usage period. For example, the ESD manager 110 may be configured to predict performance degradation during the secondary usage period based on a) cumulative performance degradation incurred under the primary OP policy 154 (and predicted discharge conditions of the primary application 170) during the primary usage period, and b) performance degradation predicted to be incurred under the second OP policy 150 (and predicted discharge conditions of the secondary application 170). For example, the ESD manager 110 may model performance degradation of the ESD 150 using a multi-period aging model 120 as illustrated in FIGS. 7A and 7B. Alternatively, or in addition, the ESD manager 110 may determine multi-application OP policies 150 as illustrated in FIGS. 16A and 16B, as disclosed in further detail herein.

In some implementations, the analysis module 116 may be configured to manage implementation of applications 170 by specified ESD 105 and/or ESD 105 of a specified ESD type. In other words, in some implementations, the search space of the analysis module 116 (and/or OCO procedure of FIG. 13) may be limited to a single ESD type.

Alternatively, in some implementations, the ESD manager 110 may be configured to determine OP policies 150 for applications 170 capable of utilizing a plurality of different ESD types. In other words, the ESD manager 110 may be configured to determine OP policies 150 within a multi-type search space corresponding to a plurality of ESD types. Therefore, in some implementations, managing implementation of an application 170 by an ESD 105 may comprise a) selecting an ESD type for the application 170, b) determining an OP policy 150 for the ESD 105 of the determined ESD type within the application 170 (e.g., determining a discharge policy 156 for the selected ESD type), and c) configuring the application 170 to utilize the ESD 105 in accordance with the determined OP policy 150. In the examples illustrated in FIGS. 10 and 13, the ESD manager 110 may be configured to evaluate discharge policies 156 for ESD 105 of respective ESD types under predicted charge conditions of the application 170.

Selecting the ESD type for the application 170 may comprise comparing requirements of the application 170 to ESD-specific characteristics, capabilities, and/or aging models 120 of respective ESD types. In the examples illustrated in FIGS. 10 and 13, the ESD manager 110 may be configured to determine the ESD type for the application 170 based, at least in part, on a comparison between ESD-specific characteristics of respective ESD types and discharge requirements of the application 170. The ESD manager 110 may, for example, select ESD types based, at least in part, on OCS data 220 determined for respective ESD types. By way of non-limiting example, the application 170 may comprise discharge requirements specifying a relatively high minimum discharge power (Pwrₘᵢₙ) over relatively short durations and/or limited SoC ranges. In response, the ESD manager 110 may select ESD type(s) having a low sensitivity to discharge rate (r_{d}) regardless of whether such ESD type(s) are sensitive to discharge duration and/or discharge SoC.

Alternatively, or in addition, the ESD manager 110 may select the ESD type and/or determine the ESD policy 150 for the selected ESD type in an OCO procedure, as disclosed herein. As illustrated in FIG. 13, in some implementations, the formulation module 802 may be configured to construct optimization models 804 corresponding to multiple ESD types. The formulation module 802 may be configured to retrieve ESD-specific information pertaining to respective ESD types from the datastore 114 or the like, e.g., from respective ESD profiles 115, as disclosed herein. For example, the formulation module 802 may be configured to construct a search space for the OCO procedure corresponding to T ESD types, e.g., ESD types A through T as illustrated in FIG. 13. The OCO procedure may comprise searching the multi-type search space for an optimal solution 850, the optimal solution comprising an optimal OP policy 150 determined for an optimal ESD type for the application 170. In some implementations, the cost metrics 842 determined for respective candidates 830 may incorporate information pertaining to the cost of ESD 105 of respective ESD types. The optimal solution 850 may, therefore, balance characteristics respective ESD types against costs associated with the respective ESD types.

In some implementations, the OCO procedure may be further configured to determine optimal OP policies 150 for secondary utilization of ESD 105. For example, the optimization criteria 822 of the OCO procedure may be configured to weight the utility of ESD 105 capable of use in a secondary application 170 higher than ESD 105 incapable of such secondary use (and/or assign inversely proportional weights to the cost metrics 842). The OCO procedure may, therefore, select ESD types that may have higher costs than other ESD types, but are capable of secondary use.

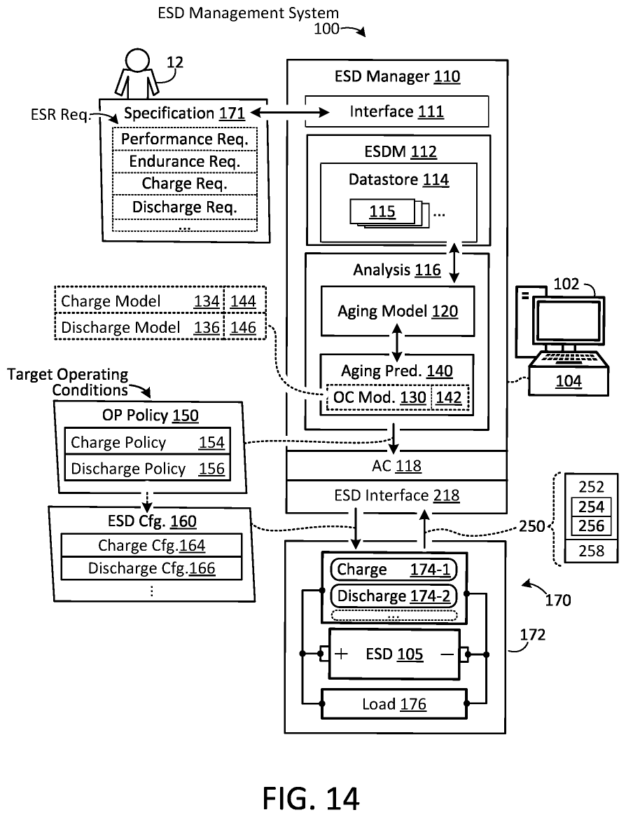

FIG. 14 is a schematic block diagram illustrating another example of a system for managing ESD 105, as disclosed herein. In the FIG. 14 example, the ESD manager 110 may be configured to manage implementation of an application 170 by an ESD 105 (and/or ESD 105 of a particular type, model, or the like). The application 170 may comprise and/or be embodied by a system 172 comprising one or more ESD modules 174. The system 172 may, for example, comprise a charge module 174-1, discharge module 174-2, load 176, and so on.

In the FIG. 14 example, the ESD manager 110 may be configured to control aspects of the charge conditions and/or discharge conditions of ESD 105 within the application 170. For example, the ESD manager 110 may be configured to control aspects of charge operations performed on the ESD 105 within the application 170 (e.g., by a charge module 134-1 and/or the like) and/or control aspects of discharge operations performed on the ESD 105 within the application 170 (e.g., by a discharge module 134-2 and/or the like).

The ESD manager 110 may be configured to manage implementation of the application 170; the ESD manager 110 may be configured to a) receive, revise, and/or generate a specification 171 configured to define requirements of the application 170, b) retrieve an aging model 120 of the ESD 105, c) determine an OP policy 150 for the ESD 105 within the application 170 by use of the aging model 120, the OP policy 150 configured to satisfy the requirements of the application 170, and d) derive an ESD CFG 160 from the OP policy 150, the ESD CFG 160 configured to cause the application 170 to subject the ESD 105 to operating conditions corresponding to the target operating conditions of the OP policy 150. The ESD manager 110 may further comprise an ESD interface module 218 adapted to, inter alia, configure the application 170 (and/or ESD modules 174 thereof) to implement the ESD CFG 160.

In the FIG. 14 example, the OP policy 150 determined for the ESD 105 may comprise a charge policy 154 and discharge policy 156. In other words, the target operating conditions of the OP policy 150 may comprise target charge conditions and target discharge conditions. The ESD CFG 160 derived from the OP policy 150 may comprise a charge configuration 164 configured to control aspects of the charge operations implemented on the ESD 105 by the charge module 174-1 (and thereby control the charge conditions of the ESD 105) and a discharge configuration 166 configured to control aspects of the discharge operations implemented on the ESD 105 by the discharge module 174-2 (and thereby control the discharge conditions of the ESD 105).

The charge policy 154 (and/or corresponding charge configuration 164) may comprise and/or correspond to any suitable type of charge operation including, but not limited to: single-step charge operations, two-step charge operations, multi-step charge operations, multi-step charge operations with intervening rest periods, period-specific charge operations, and/or the like. The discharge policy 156 (and/or corresponding discharge configuration 166) may comprise and/or correspond to any suitable type of discharge operation including, but not limited to: single-step discharge operations, two-step discharge operations, multi-step discharge operations, multi-step discharge operations with intervening rest periods, period-specific discharge operations, and/or the like.

As disclosed herein, the ESD manager 110 may be configured to determine an OP policy 150 under which the ESD 105 is predicted to satisfy requirements of the application 170, which may include, but are not limited to: performance requirements, performance requirements and corresponding endurance requirements, usage guarantees 630, charge requirements, discharge requirements, and so on. For example, the analysis module 116 may be configured the determine an OP policy 150 specifying target operating conditions predicted to maintain performance degradation incurred by the ESD 105 below a threshold for a specified usage period, e.g., maintain Mₜₒₜₐₗ, M_{ch}, M_{d}, ψₜₒₜₐₗ(t), ψ_{ch}(t), and/or ψ_{d}(t) below one or more thresholds. The analysis module 116 may be configured to determine OP policies 150 configured to maintain performance degradation incurred by a specified performance characteristic below a threshold for a specified usage period, e.g., maintain ψₜₒₜₐₗ(tₗ)>ψ_{threshold}, as disclosed herein.

The analysis module 116 may further configured to determine OP policies 150 that satisfy other, operational requirements of the application 170. The analysis module 116 may be configured to determine OP polices 150 that that satisfy performance requirements of the application, the OP policies 150 comprising a) charge policies 154 configured to satisfy charge requirements of the application 170 and/or b) discharge policies 156 that satisfy discharge requirements of the application 170.

As disclosed herein, determining an OP policy 150 for the ESD 105 may comprise evaluating one or more aging predictions 140, each aging prediction 140 configured to model performance degradation predicted to be incurred by the ESD 105 under the target operating conditions of the OP policy 150. The aging prediction 140 of an OP policy 150 may comprise CC metrics 144 configured to predict aging attributable the target discharge conditions of the OP policy 150 (e.g., per the charge policy 154 thereof) and DC metrics 146 configured to predict aging attributable to the target discharge conditions of the OP policy 150 (e.g., per the discharge policy 156 thereof).

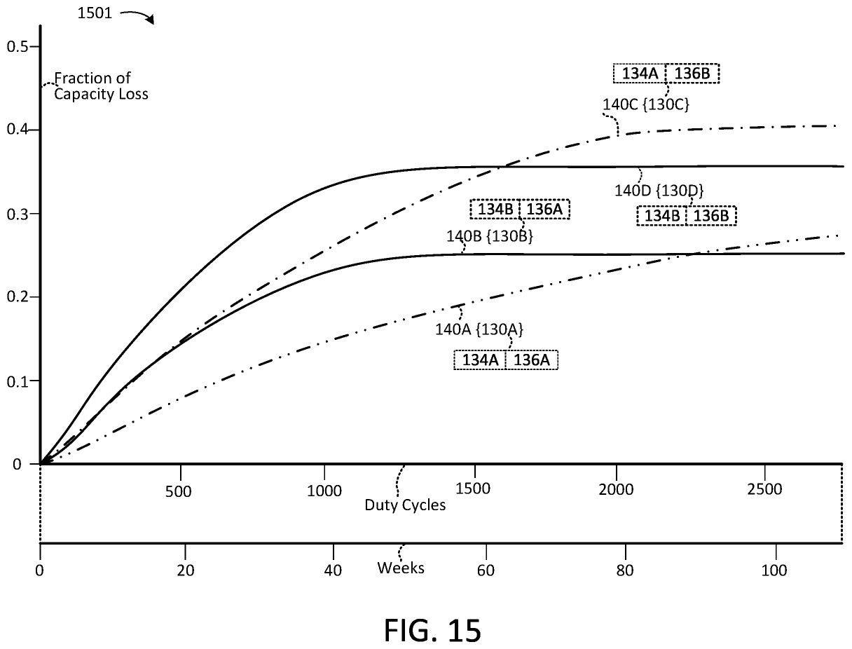

FIG. 15 comprises a plot 1501 illustrating further examples of aging predictions 140. The aging predictions 140-1A through 140-1D may be configured to predict performance degradation incurred by the ESD 105 under respective OC models 130. The aging predictions 140-1A through 140-1D may be configured to model performance degradation under operating conditions comprising respective combinations of charge models 134A, 134B, and discharge models 136A and 136B. The charge model 134A may comprise “mild” charge conditions having relatively low CC metrics 144 (e.g., charge rate of about 1C) and the discharge model 136-1A may “mild” discharge conditions having relatively low DC metrics 146 (e.g., maximum discharge rate of about 50 Amps). By contrast, the charge model 134B may comprise “aggressive” charge conditions having relatively high CC metrics 144 (e.g., charge rate of about 4C) and the discharge model 136B may comprise “aggressive” discharge conditions having relatively high DC metrics 146 (e.g., maximum discharge rate of about 200 Amps). The OC models 140A-D of aging predictions 140A-D may be configured per Table 2 below:

TABLE 2

| OC Model | Charge Conditions | Discharge Conditions |
|---|---|---|
| 130A | Mild Charge | Mild Discharge |
| | Model 134A | Model 134A |
| 130B | Aggressive Charge | Mild Discharge |
| | Model 134B | Model 134A |
| 130C | Mild Charge | Aggressive Discharge |
| | Model 134B | Model 134B |
| 130D | Aggressive Charge | Aggressive Discharge |
| | Model 134B | Model 134B |

As illustrated in FIG. 15, the aggressive charge model 134B of aging predictions 140B and 140D may result in increased aging rates early in the usage period as compared to the mild charge models 134A of aging predictions 140A and 140C, e.g., high aging rate until about duty cycle 1050 (and/or week 42). The ESD manager 110 may utilize the aging predictions 140A-D to, inter alia, determine an OP policy 150 for the ESD 105 that satisfies the ESR requirements of the application 170, as disclosed herein. The ESD manager 110 may be further configured to leverage the aging model 120 to evaluate other aging predictions 140 configured to model ESD aging under other operating conditions, e.g., arbitrary combinations of charge conditions and discharge conditions.

Referring back to FIG. 14, as disclosed herein, the operating conditions of an ESD 105 in an application 170 may change over time. Changes to the operating conditions of an ESD 105 may result in corresponding changes to the extent and/or rate of performance degradation incurred by the ESD 105, e.g., changes to aging metrics 142 such as M_{ch}, M_{d}, Mₜₒₜₐₗ, ψ_{ch}(t), ψ_{d}(t), ψₜₒₜₐₗ(t), and/or the like. The ESD manager 110 may be configured to develop aging models 120 configured to predict ESD aging over a plurality of periods, each period having respective operating conditions. The aging models 120 may be configured to predict ESD aging over a plurality of usage periods k, each usage period having respective operating conditions; aging attributable to the charge conditions in respective usage periods may be modeled per Eq. 16 and aging attributable to the discharge conditions in respective usage periods may be modeled per Eq. 32. In the FIG. 14 example, the analysis module 16 may be configured to determine OP policies 150 comprising respective charge policies 154 and/or discharge policies 156 for respective usage periods such that cumulative aging incurred by the ESD 105 over the plurality of usage periods is maintained at or below one or more thresholds, e.g., as described above in conjunction with FIGS. 7A and 7B.

As disclosed herein, the ESD manager 110 may be configured to determine OP policies 150 configured to satisfy the requirements of an application 170. In some implementations, the ESD manager 110 may be further configured to determine OP policies 150 configured to enable secondary utilization of ESD 105. For example, an ESD 105 may be utilized in a first, primary application 170 and, upon completion of the usage period of the primary application 170, be utilized in a secondary application 170. The usage period of the secondary application 170 may, therefore, extend the effective usage period of the ESD 105, e.g., the effective usage period of the ESD 105 may include the usage period of the primary application 170 followed by the usage period of the secondary application 170. The ESD manager 110 may be configured to determine OP policies 150 for ESD 105 that are predicted to satisfy requirements of a primary application 170 and the requirements of a secondary application 170. In other words, the ESD manager 110 may be configured to determine OP policies 150 predicted to a) satisfy requirements of the primary application 170 for the usage period of the primary application 170 and b) satisfy requirements of a secondary application 170 for an extended, secondary usage period that extends beyond the primary usage period. For example, the OP policy 150 may be configured such that the ESD 105 is predicted to satisfy requirements of the secondary application 170 for an extended secondary usage period, the secondary usage period extending the usage period of the primary application by the usage period of the secondary application 170. The ESD manager 110 may be configured to predict performance degradation during the usage period of the primary application 170 based on an OP policy 150 (and/or target operating conditions) determined for the primary application 170, as disclosed herein.

In the examples illustrated in FIGS. 10 and 13, the ESD manager 110 may determine a first OP policy 150 (a first discharge policy 156) configured to manage operation of the ESD 105 within the primary application 170 (e.g., over the usage period of the primary application) and a second OP policy 150 (a second discharge policy 156) configured to manage operation of the ESD 105 within the secondary application 170 (e.g., over the secondary usage period). The first charge policy 154 may be configured to satisfy requirements of the primary application 170 as disclosed herein. The first charge policy 154 and the second charge policy 154 may be further configured to satisfy requirements of the secondary application 170 over the secondary usage period. For example, the ESD manager 110 may be configured to predict performance degradation during the secondary usage period based on a) cumulative performance degradation incurred under the primary OP policy 154 (and predicted discharge conditions of the primary application 170) during the primary usage period, and b) performance degradation predicted to be incurred under the second OP policy 150 (and predicted discharge conditions of the secondary application 170).

FIG. 16A comprises a plot 1601 illustrating examples of OP policies 150 determined for implementation of an application 170 by an ESD 105 (e.g., a primary application 170). In the FIG. 16A example, the ESD manager 110 may be configured to evaluate OC aging predictions 140-1A through 140-1C, which may be configured to predict aging to be incurred by the ESD 105 under OC policies 150 corresponding to OC models 130-1A through 130-1C, respectively. As illustrated in FIG. 16A, each of the OC models 130-1A through 130-1C may satisfy the usage guarantee 630-1 of the application 170 (the primary usage guarantee 630-1), which may require that performance loss incurred by the ESD 105 remain under 40% of Mₜₒₜₐₗ for a 60-week usage period.

As illustrated in FIG. 16A, the OC model 130-1A may be predicted to result in a higher degree of aging than OC model 130-1B, which may be predicted to result in a higher degree of aging than OC model 130-1C. In other words, the OC model 130-1A may be more strenuous than OC models 130-1B and 130-1C, and the OC model 130-1C may be less strenuous than OC models 130-1A and 130-1B. Although the OP policies 150 of OC models 130-1A through 130-1C may satisfy requirements of the primary application 170, the ESD manager 110 may be further configured to determine an OP policy 150 that satisfies requirements of both the primary application 170 and a secondary application 170.

FIG. 16B comprises a plot 1602 illustrating examples of multi-application aging predictions 140 configured to predict cumulative aging incurred by the ESD 105 during a primary usage period of the primary application 170 and a secondary usage period of the secondary application 170. More specifically, the ESD manager 140 may be configured to evaluate aging predictions 140 corresponding to respective combinations of OP policies 150, including a primary OP policy 150 (primary OC model 130) configured to control operating conditions of the ESD 105 within the primary application 170 (e.g., during the primary usage period) and a secondary OP policy 150 (secondary OC model 130) configured to control operating conditions of the ESD 105 within the secondary application 170 (e.g., during the secondary usage period, extending the primary usage period).

In the FIG. 16B example, the ESD manager 110 may be configured to evaluate aging predictions 140 corresponding to combinations of primary OC models 130-1A through 130-1C and secondary OC models 130-2A through 130-2B. The secondary OC model 130-2A may be predicted to result in a higher degree of aging than OC model 130-2B, e.g., the OC model 130-2A may be more strenuous than OC model 130-2B.

The aging predictions 140-2A through 140-2E may incorporate aging incurred during the primary usage period, e.g., aging predicted per ψₜₒₜₐₗ(tₚ), where tₚ is the primary usage period (about 60 weeks in the examples illustrated in FIGS. 16A-16B). As illustrated in FIG. 16B, the aging prediction 140-2A based on the most strenuous primary OC model 130-1A may incorporate cumulative aging of about 0.33 Mₜₒₜₐₗ, the aging predictions 140-2B and 140-2C based on primary OC model 130-1B may incorporate cumulative aging of about 0.78 Mₜₒₜₐₗ, and the aging predictions 140-2D and 140-2E based on the least strenuous primary OC model 130-1C may incorporate cumulative aging of about 0.12 Mₜₒₜₐₗ. The aging predictions 140-2A through 140-2E further illustrate aging incurred by the ESD 105 over the secondary usage period (about 140 weeks) resulting in an effective usage period (across the primary application 170 and secondary application 170) of about 200 weeks.

Based on the aging predictions 140-2A, the ESD manager 110 may determine that the primary OC model 130-1A fails to satisfy the requirements of the secondary application 170 under either secondary OC model 130-2A or 130-2B (since the aging prediction 140-2A utilizing the less strenuous OC model 130-2B fails to satisfy the secondary usage guarantee 630-2). The ESD manager 110 may further determine that the combination of primary OC model 130-2B and the less strenuous secondary OC model 130-2B satisfies the secondary usage guarantee 630-2, but the combination of primary OC model 130-2B and secondary OC model 130-2A fails to satisfy the secondary usage guarantee 630-2. FIG. 16B further illustrates that, under the least strenuous OC model 130-1C, the secondary usage requirement 630-2 is satisfied under either secondary OC model 130-2A of OC model 130-2B.

As illustrated in FIGS. 16A and 16B, the ESD manager 110 may be configured to determine multi-application OP policies 150 configured to satisfy requirements of a primary application 170 and a secondary application 170. The ESD manger 110 may configure a multi-application OP policy 150 to a) maintain performance loss predicted to be incurred by the ESD 105 under a threshold of the primary application 170 for a primary usage period (usage period of the primary application 170) and b) maintain performance loss predicted to be incurred by the ESD 105 under a threshold of the secondary application 170 for a secondary usage period extending beyond primary usage period. The ESD manager 110 may be configured to predict cumulative aging incurred by the ESD 105 using a multi-period aging model 120 and/or multi-period aging predictions 140, as illustrated in FIGS. 7A and 7B. Cumulative aging incurred by the ESD 105 over multiple periods may be modeled in accordance with Eq. 16 and/or 32, e.g., cumulative aging attributable to charge conditions may be modeled per Eq. 16 and cumulative aging attributable to discharge conditions may be modeled per Eq. 32. In contrast to a multi-period OP policy 150 that may be required to satisfy the requirements of a specified application 170, the ESD manager 110 may configure multi-application OP policies 150 to satisfy requirements of multiple applications. As illustrated in FIGS. 16A and 16B, the ESD manager 110 may configure a multi-application OP policy 150 for the ESD 105 to a) satisfy requirements of the primary application 170, e.g., maintain performance loss under a threshold of the primary application 170 during the primary usage period, and b) satisfy requirements of the secondary application 170, e.g., maintain performance loss under a threshold of the secondary application 170 during a secondary usage period extending beyond the primary usage period. As illustrated above, satisfying requirements of the secondary application may require modifications to the OP policy 150 utilized during the primary usage period, e.g., to reduce aging incurred by the ESD 105 during the primary usage period.

Referring back to FIG. 14, in some implementations, the ESD manager 110 may be configured to determine OP policies 150 for ESD 105 within respective applications 170 by, inter alia, evaluating aging predictions 140 to identify target operating conditions that satisfy requirements of the application 170. The ESD manager 110 may be configured to determine multi-application OC policies 150 configured to satisfy requirements of a primary application 170 over a specified usage period and requirements of a secondary application 170 over a secondary usage period extending beyond the specified usage period as illustrated in FIGS. 16A and 16B. In some implementations, the ESD manager 110 may be configured to determine optimal OC policies 150 through an OCO procedure, as disclosed herein.

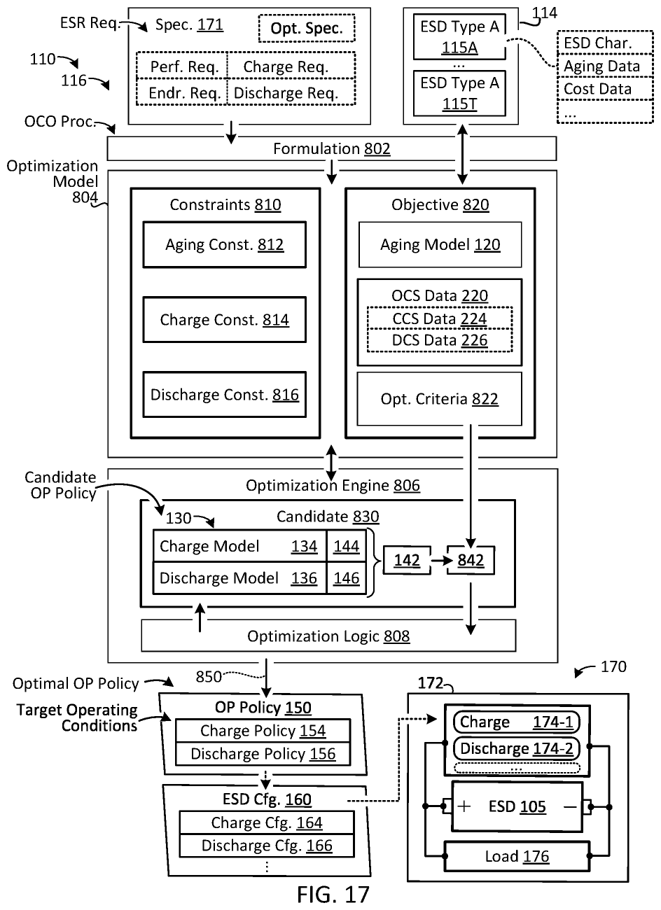

FIG. 17 is a schematic block diagram illustrating another example of an ESD manager 110. The ESD manager 110 may comprise an analysis module 116 configured to, inter alia, manage implementation of an application 170 by an ESD 105 (and/or ESD 105 of a particular type), as disclosed herein. In the FIG. 17 example, the ESD manager 110 may be configured to control aspects of the charge conditions and/or discharge conditions of the ESD 105 within the application 170.

The analysis module 116 may be configured to determine an OP policy 150 for the ESD 105 that satisfies ESR requirements of the application 170. The analysis module 116 may be configured to determine an OP policy 150 having aging metrics 142 that satisfy one or more thresholds, as disclosed herein, e.g., an OP policy 150 wherein Mₜₒₜₐₗ>M_{threshold}, M_{ch}+M_{d}>M_{threshold}, ψₜₒₜₐₗ(tₗ)≤ψ_{threshold}, ψ_{ch}(tₗ)+ψ_{d}(tₗ)≤ψ_{threshold}, and/or the like.

The analysis module 116 may configure the OP policy 150 to satisfy other requirements, such as charge requirements, discharge requirements and/or the like. As disclosed herein, charge requirements of the application 170 may constrain charge-related aspects of the OP policy 150 (e.g., constrain aspects of the charge policy 154) and the discharge requirements of the application 170 may constrain discharge-related aspects of the OP policy 150 (e.g., constrain aspects of the discharge policy 156).

In some implementations, the analysis module 116 may be configured to determine the OP policy 150 for the ESD 105 through an OCO procedure. The analysis module 116 may comprise a formulation module 802, which, as disclosed herein, may be configured to generate, construct, formulate, and/or otherwise manage an optimization model 804 of the OCO procedure. The optimization model 804 may comprise and/or be derived from characteristics of the application 170 and/or ESD 105. The constraints 810 of the optimization model 804 may comprise and/or be derived from requirements of the application 170. For example, aging constraints 812 may be derived from ESR requirements of the application 170, e.g., performance requirements, performance requirements and corresponding endurance requirements, usage guarantees 630 and/or the like.

The formulation module 802 may be further configured to determine charge constraints 814 and/or discharge constraints 816. The charge constraints 814 may be based on and/or derived from charge requirements of the application 170 and the discharge constraints 816 may be based on and/or derived from discharge requirements of the application 170, as disclosed herein. In contrast to the examples illustrated in FIGS. 8 and 13, in the FIG. 17 example, the analysis module 116 may treat both the charge conditions and discharge conditions as variables that can be adapted and/or modified in the OCO procedure, as opposed to fixed constants and/or constraints.

The formulation module 802 may be further configured to construct an objective model 820 for the OCO procedure. The objective model 820 may comprise means for evaluating the cost and/or utility of respective candidates 830. The objective model 820 may comprise an aging model 120 of the ESD 105. The analysis module 116 may utilize the aging model 120 to, inter alia, determine aging metrics 142 for respective candidates 830, e.g., determine aging metrics 142 for the OP policies 150 of respective candidates 830. The analysis module 116 may utilize the aging model 120 to determine CC metrics 134 for the charge policies 154 (and/or charge models 134) of respective candidates 830, determine DC metrics 146 for the discharge policies 156 (and/or discharge models 136) of respective candidates 830, and so on.

The objective model 820 may further comprise optimization criteria 822. In the FIG. 17 example, the optimization criteria 822 may be configured to determine cost metrics 842 for respective candidates 830. The cost metrics 842 of a candidate 830 may be based, at least in part, on aging metrics 142 predicted for the candidate 830. In the FIG. 17 example, the cost metrics 842 may be proportional to one or more of Mₜₒₜₐₗ, M_{cn}, M_{d}, ψₜₒₜₐₗ(t), ψ_{ch}(t), ψ_{d}(t), and/or the like. For example, the optimization criteria 822 may be configured to select candidates 830 that satisfy the constraints 810 of the optimization model 804 at a lowest aging cost, e.g., lowest extent and/or rate of ESD aging per the aging metrics 142 thereof.

Alternatively, or in addition, the cost metrics 842 may be configured to incorporate characteristics of the charge and/or discharge conditions of the OP policies 150 of respective candidates 830, such as charge rate (r_{ch}), charge SoC, end charge voltage (V_{ch_end}), charge duration (D_{ch}), discharge rate (r_{d}), maximum discharge power (Pwrₘₐₓ), and/or the like. For example, the optimization criteria 822 may be configured to prefer charge policies 154 having shorter charge durations (D_{ch}), prefer discharge policies 156 higher maximum discharge power (Pwrₘₐₓ), and/or the like. In some implementations, the optimization criteria 822 may be configured to assign weights and/or preferences to specified aspects of the aging metrics 142, operating conditions, and/or the like. The optimization criteria 822 may, therefore be configured to balance performance considerations against ESD aging, while ensuring that requirements of the application 170 are satisfied.

The analysis module 116 may further comprise an optimization engine 806. The optimization engine 806 may be configured to determine an optimal OP policy 150 for the ESD 105 within the application 170, as disclosed herein. The optimization engine 806 may be configured to generate and/or evaluate candidates 830. The candidates 830 may comprise respective aging metrics 142, which may be determined by use of the aging model 120, as disclosed herein. The candidates 830 may further comprise cost metrics 842, which may be a function of the aging metrics 142 and/or specified aspects of the OC model 130 of respective candidates 830.

The optimization engine 806 may be configured to generate and/or evaluate candidates 830 according to optimization logic 808. The optimization logic 808 may be configured to implement any suitable optimization algorithm. The optimization engine 806 may be configured to generate candidates 830 based, at least in part, on the optimization model 804. The optimization engine 806 may be configured to generate candidates 830 comprising OP policies 150 that satisfy the constraints 810 of the objective model 804, e.g., satisfy aging constraints 812, charge constraints 814, discharge constraints 816, and so on, as disclosed herein.

In some implementations, the optimization engine 806 may be configured to iteratively generate, evaluate, and/or modify candidates 830, e.g., iteratively modify aspects of the operating conditions of respective candidates 830. The candidates 830 may be modified to improve the cost metrics 842 thereof, e.g., reduce aging metrics 142, improve specified aspects of the operating conditions, and so on per the optimization criteria 822 of the OCO procedure. The optimization engine 806 may be configured to modify OC model 130 of the candidates 830 based, at least in part, on OCS data 220 determined for the ESD 105. The optimization engine 806 may modify charge conditions of respective candidates 830 based, at least in part, on CCS data 224 determined for the ESD 105 and/or may modify discharge conditions of respective candidates 830 based, at least in part, on DCS data 226 determined for the ESD 105.

The optimization engine 806 may be configured to iteratively generate, evaluate, and/or modify candidates 830 until one or more termination criteria of the optimization logic 808 are satisfied, as disclosed herein. Terminating the OCO procedure may comprise generating an output or solution 850. As disclosed herein, the solution 850 may comprise an optimal OP policy 150 determined for the ESD 105 within the application 170. The solution 850 may comprise and/or be derived from an optimal candidate 830 of the OCO procedure. As disclosed herein, the optimal candidate 830 may comprise and/or refer to the candidate 830 that minimizes the cost metrics 842 of the optimization model 804 (per the optimization criteria 822), while satisfying the constraints 810 of the optimization model 804.

As disclosed herein, the solution 850 of the OCO procedure illustrated in FIG. 17 may comprise an OP policy 150 comprising a charge policy 154 and discharge policy 156. In other words, in the FIG. 17 example, the solution 850 may specify both target charge conditions and target discharge conditions for the ESD 105 within the application 170. As illustrated in FIGS. 14 and 16, the ESD manager 110 may be configured to generate a ESD CFG 160 corresponding to the determined OP policy 150. The ESD CFG 160 may comprise both a charge configuration 164 and a discharge configuration 166. The charge configuration 164 may be configured to control charge operations within the application 170 (and thereby control charge conditions of the ESD 105 within the application 170). The discharge configuration 166 may be configured to control discharge operations within the application 170 (and thereby control discharge conditions of the ESD 105 within the application 170).

Referring back to FIG. 14, in some implementations, the ESD manager 110 may be further configured to acquire, retrieve, request, and/or otherwise receive ESDM data 250. In the FIG. 14 example, the ESDM data 250 may comprise information pertaining to the operating conditions and/or performance of the ESD 105 within the application 170. As disclosed herein, the ESD manager 110 may be configured to detect prediction deviations pertaining to an ESD 105 and/or application 170 (e.g., OC deviations, aging deviations, and/or the like) and, in response, modify the target operating conditions and/or ESD CFG 160 of the ESD 105 within the application 170.

In the FIG. 14 example, detecting an OC deviation may comprise a) receiving ESDM data 250, the ESDM data 250 comprising OCM data 252 pertaining to the operating conditions of the ESD 105 within the application 170, b) comparing the OCM data 252 to the target operating conditions determined for the ESD 105, and c) detecting an OC deviation based on the comparing. In response to detecting an OC deviation, the ESD manager 110 may be configured to generate aging metrics 142 and/or an aging prediction 140 for the OCM data 252. The ESD manager 110 may be configured to determine whether the OCM data 252 satisfies the ESR requirements of the application 170, e.g., determine whether Mₜₒₜₐₗ, M_{ch}, M_{d}, ψₜₒₜₐₗ(t), ψ_{ch}(t), and/or ψ_{d}(t) predicted for the observed operating conditions of the OCM data 252 satisfy performance and/or endurance requirements of the application 170. The ESD manager 110 may be further configured to determine a modified OP policy 150 for the ESD 105 that incorporates aspects of the observed operating conditions, as disclosed herein.

In the FIG. 14 example, the ESD manager 110 may be configured to manage aspects of both the charge conditions and discharge conditions of the ESD 105 within the application 170. The ESD manager 110 may detect an OC deviation between the target discharge conditions determined for the ESD 105 (per the discharge policy 156) and the actual, observed discharge conditions of the ESD 105 within the application 170. In response, the ESD manager 110 may be configured to generate a modified OP policy 150 for the ESD 105 that incorporates the actual, observed discharge conditions of ESD 105 per the OCM data 252. For example, the ESD manager 110 may treat the observed discharge conditions as fixed constants and/or constraints to determine a modified charge policy 154 for the ESD 105, as in the examples illustrated in FIGS. 3 and 8.

Alternatively, or in addition, the ESD manager 110 may detect an OC deviation between the target charge conditions determined for the ESD 105 (per the charge policy 154) and the actual, observed charge conditions of the ESD 105 within the application 170. In response, the ESD manager 110 may be configured to generate a modified OP policy 150 for the ESD 105 that incorporates the actual, observed charge conditions of the ESD 105 per the OCM data 252. For example, the ESD manager 110 may treat the observed charge conditions as fixed constants and/or constraints to determine a modified discharge policy 156 for the ESD 105 as in the examples illustrated in FIGS. 10 and 13.

The prediction deviations detected by the ESD manager 110 may further comprise and/or refer to aging deviations. The ESD manager 110 may be configured to detect aging deviations; detecting an aging deviation may comprise a) receiving ESDM data 250 pertaining to the ESD 105, the ESDM data 250 comprising EPM data 258, b) comparing aging metrics 142 and/or an aging prediction 140 of the OP policy 150 determined for the ESD 105 with the EPM data 258, and c) detecting an aging deviation based on the comparing.

As disclosed herein, the aging metrics 142 and/or aging prediction 140 of the OP policy 150 may predict the extent of aging to be incurred by the ESD 105 under the target operating conditions of the OP policy 150 and/or the rate at which such aging is predicted to be incurred, e.g., may comprise an Mₜₒₜₐₗ quantity and/or ψₜₒₜₐₗ(t) functions, as disclosed herein. The EPM data 258 may comprise measurements of one or more ESD performance characteristics. The ESD manager 110 may compare the extent and/or rate of performance degradation predicted under the OP policy 150 to measurements of the EPM data 258 to determine whether actual, observed performance degradation incurred by the ESD 105 corresponds to the aging prediction 140.

The ESD manager 110 may be further configured to modify and/or update the OP policy 150 of the ESD 105 (and/or corresponding ESD CFG 160) in response to detecting an aging deviation, as described herein in conjunction with FIG. 9. In the FIG. 17 example, the ESD manager 110 may be configured to determine a modified OP policy 150 (and/or a corresponding ESD CFG 160) configured to result in reduced aging metrics 142 in response to detecting an aging deviation in which the ESD 105 is aging more quickly than predicted. The modified OP policy 150 may be configured to reduce CRA and/or DRA predicted to be incurred by the ESD 105. The modified OP policy 150 may comprise modifications to one or more of the charge policy 154 (e.g., target charge conditions and corresponding charge configuration 164) and/or discharge policy 155 (e.g., target discharge conditions and corresponding discharge configuration 166). Alternatively, in the FIG. 17 example, the ESD manager 110 may be configured to determine a modified OP policy 150 (and/or a corresponding ESD CFG 160) configured to improve charge and/or discharge performance (e.g., reduce charge duration (D_{ch}), increase charge SoC, increase maximum discharge power (Pwrₘₐₓ, and/or the like), in response to detecting an aging deviation in which the ESD 105 is aging more slowly than predicted.

In some implementations, the analysis module 116 may be configured to manage implementation of applications 170 by specified ESD 105 and/or ESD 105 of a specified ESD type. In other words, in some implementations, the search space of the analysis module 116 (and/or OCO procedure of FIG. 17) may be limited to a single ESD type.

Alternatively, in some implementations, the ESD manager 110 may be configured to determine OP policies 150 for applications 170 capable of utilizing a plurality of different ESD types. In some implementations, managing implementation of an application 170 by an ESD 105 may comprise a) selecting an ESD type for the application 170, b) determining an OP policy 150 for the ESD 105 of the determined ESD type within the application 170, and c) configuring the application 170 to utilize the ESD 105 in accordance with the determined OP policy 150. In the examples illustrated in FIGS. 14 and 17, the ESD manager 110 may be configured to evaluate OP policies 150 for ESD 105 of respective ESD types, the OP policies 150 comprising respective charge policies 154 and discharge policies 156.

Selecting the ESD type for the application 170 may comprise comparing requirements of the application 170 to ESD-specific characteristics, capabilities, and/or aging models 120 of respective ESD types. In the examples illustrated in FIGS. 14 and 17, the ESD manager 110 may be configured to determine the ESD type for the application 170 based, at least in part, on a comparison between ESD-specific characteristics of respective ESD types and charge and/or discharge requirements of the application 170. The ESD manager 110 may, for example, select ESD types based, at least in part, on OCS data 220 determined for respective ESD types. By way of non-limiting example, the application 170 may comprise charge requirements specifying relatively high charge rates (r_{ch}) and relatively low charge voltages (V_{ch_end}) and/or discharge requirements specifying relatively high minimum discharge power (Pwrₘᵢₙ) over relatively short durations and/or limited SoC ranges. In response, the ESD manager 110 may select ESD type(s) having a low sensitivity to charge rate (r_{ch}) and/or discharge rate (r_{d}) regardless of whether such ESD type(s) are sensitive to charge voltage (V_{ch_end}), discharge duration and/or discharge SoC.

Alternatively, or in addition, the ESD manager 110 may select the ESD type and/or determine the ESD policy 150 for the selected ESD type in an OCO procedure, as disclosed herein. As illustrated in FIG. 17, in some implementations, the formulation module 802 may be configured to construct optimization models 804 corresponding to multiple ESD types. The formulation module 802 may be configured to retrieve ESD-specific information pertaining to respective ESD types from the datastore 114 or the like, e.g., from respective ESD profiles 115, as disclosed herein. For example, the formulation module 802 may be configured to construct a search space for the OCO procedure corresponding to T ESD types, e.g., ESD types A through T as illustrated in FIG. 17. The OCO procedure may comprise searching the multi-type search space for an optimal solution 850, the optimal solution comprising an optimal OP policy 150 determined for an optimal ESD type for the application 170. In some implementations, the cost metrics 842 determined for respective candidates 830 may incorporate information pertaining to the cost of ESD 105 of respective ESD types. The optimal solution 850 may, therefore, balance characteristics respective ESD types against costs associated with the respective ESD types.

In some implementations, the OCO procedure may be further configured to determine optimal OP policies 150 for secondary utilization of ESD 105. For example, the optimization criteria 822 of the OCO procedure may be configured to weight the utility of ESD 105 capable of use in a secondary application 170 higher than ESD 105 incapable of such secondary use (and/or assign inversely proportional weights to the cost metrics 842). The OCO procedure may, therefore, select ESD types that may have higher costs than other ESD types, but are capable of secondary use.

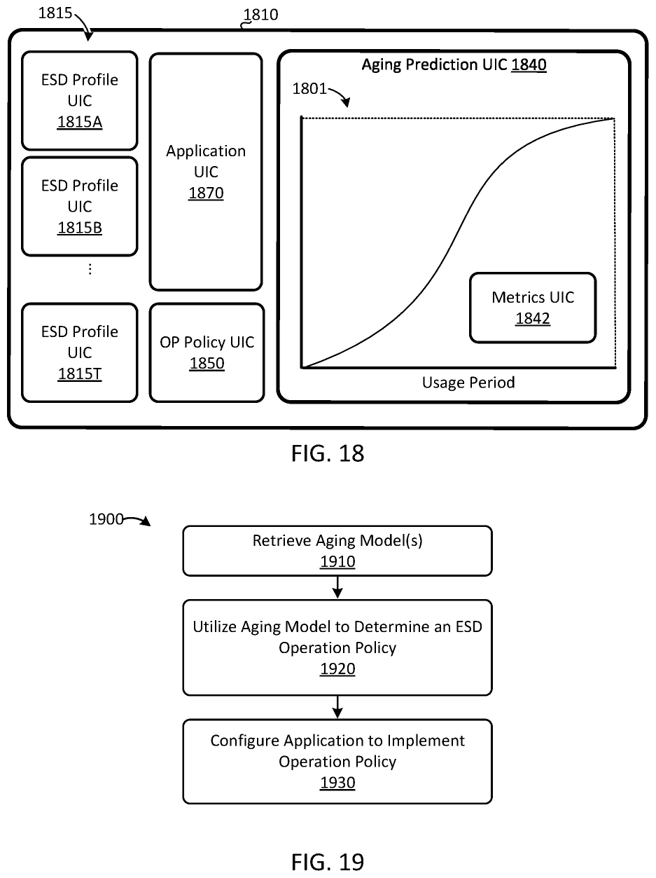

FIG. 18 is a schematic block diagram illustrating an example of a design interface 1810 of the disclosed ESD management system 100. The design interface 1810 may comprise user interface components (UIC) configured for display on HMI resources 104-5 of a computing device 102, as disclosed herein.

The design interface 1810 may comprise ESD profile UIC 1815, the ESD profile UIC 1815 may be configured to display information pertaining to respective ESD types. For example, the ESD profile UIC 1815A-T may be configured to display information pertaining to ESD types A through T. The ESD profile UIC 1815 may be configured to display aspects of respective ESD profiles 115, such as ESD-specific characteristics of respective ESD types, OCS data 220 determined for respective ESD types, cost information pertaining to respective ESD types, and/or the like.

The design interface 1810 may further comprise an application UIC 1870. The application UIC 1870 may be configured to display information pertaining to an application 170. For example, the application UIC 1870 may be configured to display aspects of a specification 171 of the application 170. Alternatively, or in addition, the application UIC 1870 may be configured to enable a user 12 to define, modify, and/or otherwise manage aspects of the application specification 171, such as ESR requirements of the application 170 (e.g., performance requirements, endurance requirements, usage period, and/or the like), OP requirements (e.g., charge requirements, discharge requirements, and/or the like), and so on. the application UIC 1870 may be further configured to display information pertaining to optimization criteria 822 of the application 170 and/or receive input pertaining to the optimization criteria 822 from a user 12.

The design interface 1810 may further comprise an OP policy UIC 1850. The OP policy UIC 1850 may be configured to display information pertaining to an OP policy 150 determined for the application 170. The OP policy 150 may specify an ESD 105 (and/or ESD type) to utilize within the application 170 and/or target operating conditions of the ESD 105 within the application 170. The OP policy UIC 1850 may be configured to receive user input pertaining to aspects of the OP policy 150. For example, the OP policy UIC 1850 may be configured to receive user selection of an ESD type and/or aspects of specified target operating conditions. Alternatively, or in addition, aspects of the OP policy displayed within the OP policy UIC 1850 may be determined by the ESD manager 110, as disclosed herein. For example, the ESD manager 110 may populate the OP policy IOC 1850 with an optimal ESD type and/or OP policy 150 determined for the application 170, as disclosed herein.

In some implementations, the design interface 1810 may further comprise an aging prediction UIC 1840. The aging prediction UIC 1840 may be configured to display information pertaining to aging predictions 140, as disclosed herein. For example, the aging prediction UIC 1840 may be configured to display information pertaining to an aging prediction 140 determined for the OP policy 150 displayed within the OP policy UIC 1850, e.g., an aging prediction 140 determined for target operating conditions of the OP policy 150. The aging prediction UIC 1840 may further comprise a plot 1801 configured to graphically represent aspects of the aging prediction 140. For example, the plot 1801 may be configured to display performance loss predicted to be incurred by the ESD 105 during operation according to the OP policy 150 of the OP policy UIC 1850 over a specified usage period. The aging prediction UIC 1840 may further comprise a metrics UIC 1842 configured to display information pertaining metrics of the OP policy 150, such as aging metrics 142, CC metrics 144, DC metrics 144, cost metrics 842, and/or the like. Accordingly, the design interface 1810 may provide a user 12 with an easy to interpret graphical representation of the impact of respective OP policies 150 on aging incurred by ESD 105 utilized in respective applications 170. The user 12 may leverage the design interface 1810 to, inter alia, define application requirements (e.g., define application specifications 171), determine and/or refine OP policies 1590 for respective applications 170, and/or the like.

FIG. 19 comprises a flow diagram illustrating an example of a method 1900 for managing an ESD 105. The operations or steps of method 1900 and/or the other methods disclosed herein may be embodied and/or implemented by any suitable means including, but not limited to: the ESD manager 110, hardware components, a computing device 102, computing resources 104, and/or the like. Alternatively, aspects of the method 1900 and/or other methods disclosed herein may be embodied and/or implemented by computer-readable code, executable code, one or more libraries, computer-readable instructions stored on a non-transitory storage medium (e.g., non-transitory storage 106) configured to cause a computing device (e.g., computing device 101) and/or processor (e.g., processor 102) to implement the disclosed functionality, and/or the like.

The flowchart of FIG. 19 illustrates an example of a method 1900 for managing implementation of an application 170 by an ESD 105, as disclosed herein. At 1910, the ESD manager 110 may be configured to retrieve an aging model 120 for the ESD 105 (and/or ESD type) to be utilized within the application 170. The aging model 120 may be configured to predict performance loss to be incurred by the ESD 105 under respective operating conditions and distinguish the performance loss attributable to respective ESD aging mechanisms, e.g., distinguish charge-related aging from discharge related aging (and/or vice versa), as disclosed herein.

At 1920, the ESD manager 110 may be configured to utilize the aging model 120 to determine an OP policy 150 for the ESD 105 within the application 170, the OP policy 150 configured such that performance loss predicted to be incurred by the ESD 105 satisfies one or more requirements of the application 170. The one or more requirements of the application 170 may comprise performance requirements, performance requirements and corresponding endurance requirements, charge requirements, discharge requirements, and/or the like, as disclosed herein.

At 1920, the ESD manager 110 may utilize the aging model 120 to predict the extent and/or rate of aging to be incurred by the ESD 105 under specified operating conditions. For example, the ESD manager 110 may be configured to evaluate one or more aging predictions 140, as disclosed herein. The ESD manager 110 may determine aging predictions 140 and/or aging metrics 142 for respective operating conditions by use of the aging model 120, as disclosed herein.

The OP policy 150 may comprise a charge policy 154 configured to manage aspects of charge operations to be performed on the ESD 105 within the application 170. The charge policy 154 may, for example, specify target charge conditions for the ESD 105 within the application 170 (per a charge model 134 or the like). The charge policy 154 may correspond to any suitable type of charge operation including, but not limited to: single-step charge operations, multi-step charge operations, multi-step charge operations comprising intervening rest periods, and/or the like. The ESD manager 110 may be configured to model CRA attributable to such charge operations as disclosed herein. At 1920, ESD manager 110 may utilize the aging model 120 to predict the extent and/or rate of charge-related aging to be incurred by the ESD 105 under the OP policy 150 in accordance with one or more of Eq. 1-13.

Alternatively, or in addition, the OP policy 150 may comprise a discharge policy 156 configured to manage aspects of discharge operations to be performed on the ESD 105 within the application 170. The discharge policy 156 may, for example, specify target discharge conditions for the ESD 105 within the application 170 (per a discharge model 136 or the like). The discharge policy 156 may correspond to any suitable type of discharge operation including, but not limited to: single-step discharge operations, multi-step discharge operations, multi-step discharge operations comprising intervening rest periods, and/or the like. The ESD manager 110 may be configured to model CRA attributable to such discharge operations as disclosed herein. At 1920, ESD manager 110 may utilize the aging model 120 to predict extent and/or rate of discharge-related aging to be incurred by the ESD 105 under the OP policy 150 in accordance with one or more of Eq. 17-32.

In some implementations, the ESD manager 110 may utilize the aging model 120 to predict the extent and/or rate of aging attributable to a plurality of aging mechanisms. For example, the ESD manager 110 may be configured to predict aging under the OP model 150 as a combination of charge-related aging and discharge-related aging. For example, the ESD manager 110 may utilize the aging model 120 to predict aging incurred by the ESD 105 under the OP model 150 in accordance with one or more of Eq. 33-36, which may incorporate charge-related aging per Eq. 1-13 and/or discharge-related aging per Eq. 17-32.

As disclosed herein, at 1920, the ESD manager 110 may be configured to utilize the aging model 120 to determine an OP policy 150 for the ESD 105 within the application 170, the OP policy 150 configured such that performance loss predicted to be incurred by the ESD 105 satisfies one or more requirements of the application 170. For example, the ESD manager 110 may be configured the determine an OP policy 150 specifying target operating conditions configured to maintain performance degradation predicted to be incurred by the ESD 105 below a threshold, or the like.

In a first non-limiting example, at 1920, the ESD manager 110 may be configured to determine an OP policy 150 comprising target operating conditions configured to maintain a maximum extent of performance degradation predicted to be incurred by the ESD 105 under a threshold. At 1920, the ESD manager 110 may utilize the aging model 120 to determine an OP policy 150 having aging metrics 142 wherein Mₜₒₜₐₗ, M_{OP}, M_{ch}, and/or M_{d} is below a threshold, e.g., Mₜₒₜₐₗ≤M_{threshold}, M_{OP}≤M_{threshold}, M_{ch}+M_{d}≤M_{threshold}, and/or the like. Alternatively, or in addition, the ESD manager 110 may be configured to determine an OP policy 150 having CC metrics 144 that satisfy a CRA threshold and/or DC metrics 146 that satisfy a DRA threshold, e.g., OC policy 150 comprising a charge policy 154 wherein M_{ch}≤M_{ch_threshold} and/or a discharge policy 156 wherein M_{d}≤M_{d_threshold}.

In a second non-limiting example, at 1920, the ESD manager 110 may be configured to determine an OP policy 150 configured to maintain performance loss predicted to be incurred by the ESD 105 under a threshold for a specified usage period. At 1920, the ESD manager 110 may utilize the aging model 120 to determine an OP policy 150 having aging metrics 142 wherein ψₜₒₜₐₗ(tₗ)≤ψ_{threshold}, ψ_{OC}(tₗ)≤ψ_{threshold}, ψ_{ch}(tₗ)+ψ_{d}(tₗ)≤ψ_{threshold}, and/or the like, wherein ψ_{threshold} is configured to limit performance loss incurred by a designated performance characteristic of the ESD 105 (e.g., capacity) and t₁ specifies the usage period of the application 170.

In a third non-limiting example, at 1920, the ESD manager 110 may be configured to determine an OP policy 150 covering multiple usage periods, each usage period having respective target operating conditions (e.g., a respective charge policy 154 and/or discharge policy 156). At 1920, the ESD manager 110 may be configured to determine an OP policy 150 configured to manage operation of the ESD 105 according to changing requirements of the application 170, as disclosed herein in conjunction with Eq. 16, 32, FIG. 1F, and FIGS. 7A-7B. For example, as illustrated in FIG. 1F, the ESD manager 110 may determine an OP policy 150 comprising a plurality of period-specific OP policies 152, each period-specific OP policy 152 specifying target operating conditions for the ESD 105 during a respective usage period. The ESD manager 110 may configure the multi-period OP policy 150 such that cumulative performance loss incurred over the usage periods is maintained below a threshold. The ESD manager 110 may predict cumulative CRA and/or DRA incurred over the plurality of usage periods per Eq. 16 and/or 32 of the aging model 120, as disclosed herein.

In a fourth non-limiting example, at 1920, the ESD manager 110 may be configured to determine an OP policy 150 configured to enable secondary use of the ESD 105. The ESD manager 110 may be configured to determine an OP policy 150 that satisfies a) requirements of the application 170 and b) satisfies requirements of a secondary application 170. For example, the ESD manager 110 may configure the OP policy 150 to a) maintain performance loss predicted to be incurred by the ESD 105 under a threshold of the application 170 for a usage period of the application 170 (a first or primary usage period) and b) maintain performance loss predicted to be incurred by the ESD 105 under a threshold of the secondary application 170 for a secondary usage period extending beyond the usage period of the application 170. The ESD manager 110 may be configured to determine a multi-period OP policy 150 as in the third non-limiting example above, the multi-period OP policy 150 comprising a first period-specific OP policy 150 configured to manage operation of the ESD 105 within the application 170 (during the usage period of the application 170) and a second period-specific OP policy 150 configured to manage operation of the ESD 105 within the secondary application 170 (during the secondary usage period extending beyond the usage period of the application 170). In contrast to the third non-limiting example above, the ESD manager 110 may further configure the period-specific OP policy 150 to satisfy requirements of the secondary application 170, which may comprise configuring aspects of the first period-specific OC policy 150 to, inter alia, manage aging incurred during the first usage period. For example, the ESD manager 110 may determine a multi-application OP policy 150 for the ESD 105 at 1920, as disclosed in herein (e.g., in conjunction with FIGS. 16A and 16B).

At 1920, the ESD module 110 may be further configured to determine an OP policy 150 that satisfies other, operational requirements of the application 170. The ESD manager 110 may be configured to determine an OP policy 150 for the ESD 105 that a) satisfies performance and/or endurance requirements of the application 170 (e.g., maintain predicted performance loss below a threshold for a specified usage period) while also b) satisfying charge requirements of the application 170, discharge requirements of the application 170, and/or the like. As disclosed herein, the charge and/or discharge requirements may constrain aspects of the target operating conditions of the OP policy 150, e.g., charge requirements may constrain aspects of the target charge conditions of the charge policy 154 of the OP policy, discharge requirements may constrain aspects of the target discharge conditions of the discharge policy 156 of the OP policy 150, and so on.

For example, at 1920, the ESD manager 110 may utilize the aging model 120 to determine an OP policy 150 for the ESD 105 that satisfies charge requirements of the application 170 while also satisfying a usage guarantee 630; at 1920, the ESD manager 110 may determine an OP policy 150 that a) satisfies charge requirement(s) such as a minimum charge rate (r_{ch}) and/or maximum charge duration (D_{ch}), while also b) maintaining performance loss predicted to be incurred by the ESD 105 under a threshold for a specified usage period. Alternatively, or in addition, the ESD manager 110 may determine an OP policy 150 for the ESD 105 that satisfies discharge requirement(s) of the application 170 while also satisfying the usage guarantee 630; at 1920, the ESD manager 110 may determine an OP policy 150 that a) satisfies a discharge requirement such as a minimum power output (Pwrₘᵢₙ), while also b) maintaining performance loss predicted to be incurred by the ESD 105 under a threshold for a specified usage period. In some implementations, the ESD manager 110 may be configured to determine an OP policy 150 that satisfies charge and discharge requirements while also satisfying the usage guarantee 630; at 1920, the ESD manager 110 may determine an OP policy 150 that a) satisfies charge requirement(s) of the application 170, e.g., maximum charge duration (D_{ch}), b) satisfies discharge requirement(s) of the application 1780, e.g., minimum discharge power (Pwrₘᵢₙ), while c) maintaining performance loss predicted to be incurred by the ESD 105 under a threshold for a specified usage period.

In some implementations, determining an OP policy 150 for the ESD 105 at 1920 may comprise evaluating one or more aging predictions 140, each aging prediction 140 configured to model performance degradation predicted to be incurred by the ESD 105 under a specified set of operating conditions (e.g., candidate operating conditions) and/or a respective candidate OP policy 150. The aging prediction 140 of a candidate OP policy 150 may comprise CC metrics 144 configured to predict aging attributable the target charge conditions of the OP policy 150 (e.g., per the charge policy 154 and/or corresponding charge model 134 thereof) and DC metrics 146 configured to predict aging attributable to the target discharge conditions of the OP policy 150 (e.g., per the discharge policy 156 and/or discharge model 136 thereof).

The ESD manager 110 may be configured to generate, evaluate, and/or modify candidate OP policies 150 to, inter alia, identify candidate OP policies 150 that satisfy requirements of the application 170, as disclosed herein. Determining the OP policy 150 at 1920 may comprise iteratively modifying aspects of one or more candidate OP polices 150 to satisfy performance and/or endurance requirements of the application 170, satisfy OP requirements of the application 170 (e.g., satisfy charge and/or discharge requirements), and/or the like. At 1920, the ESD manager 110 may utilize the aging model 120 to a) determine a candidate OP policy 150 for the ESD 105, the candidate OP policy 150 comprising a candidate charge policy 154 and a candidate discharge policy 156, b) evaluate aging predicted to be incurred by the ESD 105 under the candidate OP policy 150, the evaluating comprising predicting charge-related aging to be incurred by the ESD under target charge conditions of the candidate charge policy 154 and/or predicting discharge-related aging to be incurred by the ESD 105 under target discharge conditions of the candidate discharge policy 156, and c) modifying the candidate OP policy 150 based on the evaluating, the modifying based on one or more of an aging prediction 140 determined for the candidate OP policy 150, aging metrics 142 of the candidate OP policy 150, OCS data 220 determined for the ESD 105, charge requirement(s) of the application 170, discharge requirement(s) of the application 170, and/or the like.

As disclosed herein, in some implementations, the ESD manager 110 may be configured to modify selected aspects of a candidate OP policy 150 based on OCS data 220. As disclosed herein, the OCS data 220 of an ESD 105 may be configured to indicate the relative sensitivity of the aging model 120 of the ESD 105 to respective operating conditions. For example, the OCS data 220 may comprise CCS data 224 configured to indicate the sensitivity of CRA mechanisms of the ESD 105 to respective charge conditions and/or DCS data 226 configured to indicate the sensitivity of CRA mechanisms of the ESD 105 to respective discharge conditions. At 1920, the ESD manager 110 may be configured to modify candidate OP policies 150 in accordance with the OCS data 220. For example, the ESD manager 110 may be configured to modify a candidate OP policy 150 to reduce the aging metrics 142 thereof and, in response, may modify aspects of the candidate OP policy 150 likely to produce significant reductions to the aging metrics 142, e.g., operating conditions identified as high sensitivity per the OCS data 220. Alternatively, or in addition, the ESD manager 110 may be configured to modify the candidate OP policy 150 to satisfy a charge and/or discharge requirement of the application 170 and may select aspects of the candidate OP policy 150 to modify operating conditions that are unlikely to result in significant increases to the aging metrics 142, e.g., operating conditions identified as low sensitivity per the aging metrics 142.

In some implementations, the ESD manager 110 may determine the OP policy 150 at 1920 through an OCO procedure, as disclosed herein (e.g., an OCO procedure as illustrated in FIGS. 8, 13, and/or 17). As disclosed herein, the OCO procedure may comprise constructing an optimization model 804 comprising constraints 810 and an objective model 820. The optimization model 804 may comprise aging constraints 812, which may comprise and/or be derived from performance and/or endurance requirements of the application 170 (e.g., usage guarantees 630), charge constraints 814, which may comprise and/or be derived from charge requirements of the application 170, discharge constraints 816, which may comprise and/or be derived from discharge requirements of the application 170, and so on. The optimization model 804 may further comprise means for evaluating the cost and/or utility of respective candidates 830. The objective model 820 may comprise means for quantifying the utility and/or cost of respective candidates 830. The objective model 820 may comprise means for determining aging predictions 140 and/or aging metrics 142 for respective candidates, e.g., may comprise and/or incorporate an aging model 120 of the ESD 105 and/or aging models 120 determined for respective ESD types. The objective model 820 may further comprise optimization criteria 822. As disclosed herein, the optimization criteria 822 may reflect preferences and/or priorities of the application 170, e.g., weight and/or balance any suitable optimization factors including, but not limited to: ESD longevity, ESD performance (e.g., charge performance, discharge performance, and/or the like), monetary cost, secondary use, and/or the like. The ESD manager 110 may be configured to iteratively generate, evaluate, and/or modify candidates 830 in accordance with optimization logic 808 (and/or an optimization engine 806). The solution 850 of the OCO procedure may comprise an optimal OP policy 150 that a) satisfies requirements of the application 170, e.g., satisfies the constraints 810 determined for the application 170, b) at a lowest cost, e.g., per cost metrics 842 determined in accordance with, inter alia, optimization criteria 822 of the application 170.

In some implementations, the ESD manager 110 may be configured to determine an OP policy 150 for a specified type of ESD 105. In other words, the ESD manager 110 may be constrained to a single ESD type, e.g., may be limited to a single-type search space, as disclosed herein. Alternatively, in some implementations, the ESD manager 110 may be configured to determine an OP policy 150 for one of a plurality of ESD 105. Determining the OP policy 150 at 1920 may comprise a) selecting an ESD type for the application 170, and d) determining an OP policy 150 for ESD 105 of the selected ESD type. The ESD type may be selected based on ESD-specific characteristics. For example, the ESD manager 110 may select the ESD type based on OCS data 220 determined for respective ESD types, as disclosed herein in conjunction with FIGS. 5A-5D. Alternatively, or in addition, the ESD manger 110 may be configured to determine the OP policy 150 through an OCO procedure comprising a multi-type search space, as disclosed herein. For example, at 1910, the ESD manager 110 may be configured to retrieve aging models 120 for a plurality of ESD type(s), such as ESD types A through T (e.g., as illustrated in FIGS. 8, 13, and/or 17). The ESD manager 110 may determine the OP policy 150 through an OCO procedure comprising an optimization model 804 covering multiple ESD types, e.g., ESD types A through T as illustrated in FIGS. 8, 13, and 17. The OCO procedure may comprise iteratively generating, evaluating, and/or modifying candidates 830 comprising OP policies 150 determined for ESD 105 of respective ESD types. The solution 850 of the OCO procedure may, therefore, comprise determining an optimal OP policy 150 for an optimal ESD type, e.g., an ESD type capable of satisfying requirements of the application 170 at a lowest cost per the optimization criteria 822 of the application 170.

At 1930, the ESD manager 110 may configure the application 170 to implement the OP policy 150 determined at 1920. Configuring the application 170 to implement the OP policy 150 may comprise configuring components of the application 170 to utilize the ESD 105 in accordance with the OP policy 150. At 1930, the ESD manager 110 may be configured to generate an ESD CFG 160 corresponding the OP policy 150 determined at 1920. As disclosed herein, the ESD CFG 160 may be configured to control utilization of the ESD 105 by components of the application 170 such that the operating conditions of the ESD 105 within the application 170 correspond with the target operating conditions of the OP policy 150. The ESD CFG 160 may comprise any suitable means for controlling, regulating, advising, limiting, and/or otherwise managing ESD operations implemented by and/or within the application 170 (operations implemented by the ESDA system 172 and/or components thereof, such as ESD module(s) 174 or the like), which may include, but are not limited to: machine-readable data, configuration data, firmware, instructions, machine-readable instructions, code, machine-readable code, computer-readable code, a script, settings, parameters, limits, thresholds, and/or the like.

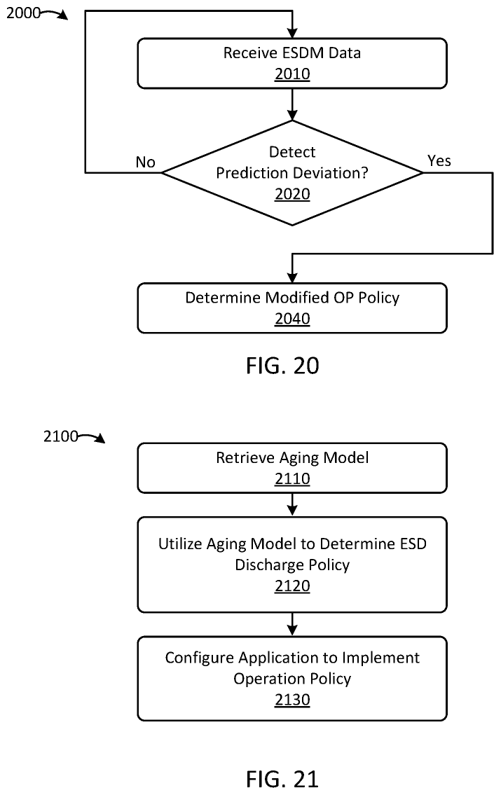

FIG. 20 comprises a flow diagram illustrating an example of a method 2000 for managing ESD prediction deviations. In the FIG. 20 example, the ESD manager 110 may receive ESDM data 250 pertaining to an ESD 105 and/or application 170 at 2010. The ESD manager 110 may receive the ESDM data 250 in response to determining an OP policy 150 for the ESD 105 and/or configuring the application 170 to operate the ESD 105 in accordance with the OP policy 150.

As disclosed herein, ESDM data 250 may comprise and/or refer to any suitable information pertaining to the operating conditions and/or performance characteristics of an ESD 105. In some implementations, the ESDM data 250 received at 2010 may comprise OCM data 252 pertaining to the operating conditions of the ESD 105 within the application 170, e.g., may comprise CCM data 254 pertaining to charge conditions of the ESD 105, DCM data 256 pertaining to discharge conditions of the ESD 105, and/or the like. Alternatively, or in addition, the ESDM data 250 received at 2010 may comprise EPM data 258, which may comprise measurements of ESD performance characteristics acquired at respective usage times.

In some implementations, the ESD manager 110 may be configured to retrieve and/or request aspects of the ESDM data 250 at 2010. For example, the ESD manager 110 may comprise and/or be coupled to an ESD interface module 218, which may be configured to access ESDM data 250 (and/or other information) through a data interface of the application 170 (and/or corresponding ESDA system 172), such as an API or the like. Alternatively, or in addition, ESD manager 110 may receive the ESDM data 250 from another source, e.g., may retrieve the ESDM data 250 from DSR resources 104-2 of the computing device 102, receive ESDM data 250 through the network, receive ESD data 250 acquired by the application 170 (e.g., the application 170 may be configured to push ESDM data 250 to the ESD manager 110), receive ESDM data 250 from an ESD module 174 of the application 170, such as a BMS, and/or the like.

At 2020, the ESD manager 110 may determine whether the ESDM data 252 is indicative of a prediction deviation. At 2020, the ESD manager 110 may be configured to detect a prediction deviation corresponding to one or more of an aging deviation and an operating condition (OC) deviation, as disclosed herein (e.g., as described in conjunction with FIG. 9). For example, the ESD manager 110 may be configured to detect a prediction deviation in response to detecting one or more of: a deviation between performance loss predicted to be incurred by the ESD 105 under the OP policy 150 determined for the ESD 105 and measured performance loss observed in the ESD 105 within the application 170 (per EPM data 258 data received at 2010), and a deviation between target operating conditions of the OP policy 105 and measured operating conditions of the ESD within the application 170 (per OCM data 252 received at 2010).

If a prediction deviation is detected at 2020, the flow may continue at 2030; otherwise, the flow may continue at 2010 when additional ESDM data 250 are received.

At 2030, the ESD manager 110 may be configured to determine a modified OP policy 150 for the ESD 105. The modified OP policy 150 may be determined in accordance with method 1900 disclosed above. Alternatively, or in addition, the modified OP policy 150 may incorporate the aging deviation detected at 2020, e.g., may incorporate the increased or decreased extent and/or rate of aging observed in the ESD 105 per the EPM data 258. Alternatively, the modified OP policy 150 may incorporate the observed operating conditions of the ESD 105 within the application 170. For example, the ESD manager 110 may determine the modified OP policy 150 wherein aspects of the target operating conditions (e.g., charge conditions and/or discharge conditions) are treated as constants or constraints, as disclosed herein. At 2030, the ESD manager 110 may be further configured to configure the application 170 to implement the modified OP policy 150, as disclosed herein.

FIG. 21 comprises a flowchart illustrating another example of a method for managing implementation of an application 170 by an ESD 105. As illustrated in FIG. 21, at 2110, the ESD manager 110 may be configured to retrieve an aging model 120 for the ESD 105 (and/or ESD type) to be utilized within the application 170. The aging model 120 retrieved at 2110 may be configured to predict discharge-related performance loss to be incurred by the ESD 105 under respective discharge conditions and distinguish the discharge-related performance loss from charge-related performance loss (and/or vice versa).

At 2120, the ESD manager 110 may be configured to utilize the aging model 120 to determine an OP policy 150 for the ESD 105 within the application 170, the OP policy 150 configured such that performance loss predicted to be incurred by the ESD 105 satisfies one or more requirements of the application 170.

In the FIG. 21 example, the ESD manager 110 may be configured to manage aspects of the discharge conditions of the ESD 105 within the application 170. The ESD manager 110 may be further configured to model known, predetermined, and/or predicted ESD charge conditions within the application 170, e.g., charge conditions may be managed internally within the application 170. The ESD manager 110 may determine an OP policy 150 that incorporates charge-related aging predicted to be incurred under the predicted charge conditions, e.g., may incorporate a charge model 134-1 predicted to result in CRA modeled by CC metrics 144. Accordingly, in the FIG. 21 example, the ESD manager 110 may be configured to utilize the aging model 120 to determine an OP policy 150 for the ESD 105 within the application 170, the OP policy 150 comprising a discharge policy 156 specifying target discharge conditions for the ESD 105 within the application 170, the OP policy 150 configured such that performance loss predicted to be incurred by the ESD satisfies one or more requirements of the application 170. In other words, the OP policy 150 may be configured such that a) performance loss attributable to the target discharge conditions of the discharge policy 156 determined at 2120 and b) performance loss attributable to predicted ESD charge conditions within the application 170 satisfy the one or more requirements of the application 170, e.g., maintain performance loss below a threshold for a specified usage period.

In a first non-limiting example, at 2120, the ESD manager 110 may be configured to determine an OP policy 150 (e.g., a discharge policy 156) comprising target operating conditions configured to maintain a maximum extent of performance degradation predicted to be incurred by the ESD 105 under a threshold. At 2120, the ESD manager 110 may utilize the aging model 120 to determine an OP policy 150 having aging metrics 142 wherein M_{d}+M_{ch_req}≤M_{threshold}, where M_{ch_req} is the extent of performance loss incurred under the predicted ESD discharge conditions of the application 170.

In a second non-limiting example, at 2120, the ESD manager 110 may be configured to determine an OP policy 150 (discharge policy 156) configured to maintain performance loss predicted to be incurred by the ESD 105 under a threshold for a specified usage period. At 2120, the ESD manager 110 may utilize the aging model 120 to determine an OP policy 150 having aging metrics 142 wherein ψ_{d}(tₗ)+ψ_{ch_req}(tₗ)≤ψ_{threshold}, wherein ψ_{threshold} is configured to limit performance loss incurred by a designated performance characteristic of the ESD 105 (e.g., capacity), ψ_{d} is a function configured to model performance loss attributable to the target discharge conditions of the discharge policy 156 determined at 2120, ψ_{ch_req} is a function configured to model performance loss attributable to the predicted ESD charge conditions of the application 170, and t₁ corresponds to the usage period of the application 170.

In a third non-limiting example, at 2120, the ESD manager 110 may be configured to determine an OP policy 150 covering multiple usage periods, each usage period having respective target operating conditions (e.g., a respective discharge policy 156). At 2120, the ESD manager 110 may be configured to determine an OP policy 150 configured to manage operation of the ESD 105 according to changing requirements of the application 170, as disclosed herein in conjunction with Eq. 16, 32, FIG. 1F, and FIGS. 7A-7B. For example, as illustrated in FIG. 1F, the ESD manager 110 may determine an OP policy 150 comprising a plurality of period-specific OP policies 152, each period-specific OP policy 152 specifying target operating conditions (target discharge conditions) for the ESD 105 during a respective usage period (and/or respective predicted charge conditions). The ESD manager 110 may configure the multi-period OP policy 150 (configure discharge polices 156 of respective periods) such that cumulative performance loss incurred over the usage periods is maintained below a threshold. The ESD manager 110 may predict cumulative CRA and/or DRA incurred over the plurality of usage periods per Eq. 16 and/or 32 of the aging model 120, as disclosed herein.

In a fourth non-limiting example, at 2120, the ESD manager 110 may be configured to determine an OP policy 150 configured to enable secondary use of the ESD 105. The ESD manager 110 may be configured to determine an OP policy 150 (discharge policy 156) that satisfies a) requirements of the application 170 and b) satisfies requirements of a secondary application 170. For example, the ESD manager 110 may configure the OP policy 150 to a) maintain performance loss predicted to be incurred by the ESD 105 under a threshold of the application 170 for a usage period of the application 170 (a first or primary usage period) and b) maintain performance loss predicted to be incurred by the ESD 105 under a threshold of the secondary application 170 for a secondary usage period extending beyond the usage period of the application 170. For example, the ESD manager 110 may determine a multi-application OP policy 150 for the ESD 105 at 2120, as disclosed in herein (e.g., in conjunction with FIGS. 16A and 16B). The multi-application OP policy 150 incorporating predicted ESD charge conditions (and/or a predicted charge models 134-1) of the primary and/or secondary applications 170.

At 2120, the ESD module 110 may be further configured to determine an OP policy 150 that satisfies other, operational requirements of the application 170. The ESD manager 110 may be configured to determine an OP policy 150 for the ESD 105 that a) satisfies performance and/or endurance requirements of the application 170 (e.g., maintain predicted performance loss below a threshold for a specified usage period) while also b) satisfying discharge requirements of the application 170. In the FIG. 21 example, charge requirements, if any, may be incorporated through the predicted ESD charge conditions of the application 170. For example, at 2120, the ESD manager 110 may utilize the aging model 120 to determine an OP policy 150 for the ESD 105 (a discharge policy 156) that satisfies discharge requirements of the application 170 while also satisfying a usage guarantee 630; at 2120, the ESD manager 110 may determine a discharge policy 156 that a) satisfies a discharge requirement such as a minimum power output (Pwrₘᵢₙ), while also b) maintaining performance loss predicted to be incurred by the ESD 105 under a threshold for a specified usage period.

In some implementations, determining the OP policy 150 for the ESD 105 at 2120 may comprise evaluating one or more aging predictions 140, each aging prediction 140 configured to model performance degradation predicted to be incurred by the ESD 105 under a specified set of operating conditions (e.g., candidate operating conditions) and/or a respective candidate OP policy 150. The aging prediction 140 of a candidate OP policy 150 may comprise CC metrics 144 configured to predict aging attributable the predicted ESD charge conditions of the application 170 and DC metrics 146 configured to predict aging attributable to the target discharge conditions of the OP policy 150 (e.g., per the discharge policy 156 and/or discharge model 136 thereof).

The ESD manager 110 may be configured to generate, evaluate, and/or modify candidate OP policies 150 to, inter alia, identify candidate OP policies 150 that satisfy requirements of the application 170, as disclosed herein. Determining the OP policy 150 at 2120 may comprise iteratively modifying aspects of one or more candidate OP polices 150 to satisfy performance and/or endurance requirements of the application 170, satisfy discharge requirements of the application 170, and/or the like. At 2120, the ESD manager 110 may utilize the aging model 120 to a) determine a candidate OP policy 150 for the ESD 105, the candidate OP policy 150 comprising a candidate discharge policy 156 and incorporating predicted ESD charge conditions of the application 170, b) evaluate aging predicted to be incurred by the ESD 105 under the candidate OP policy 150, the evaluating comprising predicting discharge-related aging to be incurred by the ESD under target discharge conditions of the candidate discharge policy 156 and/or CRA incurred under the predicted charge conditions, and c) modifying aspects of the candidate discharge policy 156 based on the evaluating, the modifying based on one or more of an aging prediction 140 determined for the candidate OP policy 150, aging metrics 142 of the candidate OP policy 150, OCS data 220 determined for the ESD 105, discharge requirement(s) of the application 170, and/or the like. In the FIG. 21 example, the ESD manager 110 may be configured to modify selected aspects of a candidate discharge policy 150 based on DCS data 226 indicating a sensitivity of DRA mechanisms of the ESD 105 to respective discharge conditions.

In some implementations, the ESD manager 110 may determine the OP policy 150 at 2120 through an OCO procedure, as disclosed herein (e.g., an OCO procedure as illustrated in FIG. 13). As disclosed herein, the OCO procedure may comprise constructing an optimization model 804 comprising constraints 810 and an objective model 820. The optimization model 804 may comprise aging constraints 812, which may comprise and/or be derived from performance and/or endurance requirements of the application 170 (e.g., usage guarantees 630), charge constraints 814, which may comprise and/or be derived from the predicted ESD charge conditions of the application 170, discharge constraints 816, which may comprise and/or be derived from discharge requirements of the application 170, and so on. In the FIG. 21 example, the ESD manager 110 may treat the predicted charge conditions (charge model 134-1) as fixed constants, e.g., charge constraints 814.

The optimization model 804 may further comprise means for evaluating the cost and/or utility of respective candidates 830, as disclosed herein. The objective model 820 may comprise optimization criteria 822, which may be configured to reflect preferences and/or priorities of the application 170, e.g., weight and/or balance any suitable optimization factors including, but not limited to: ESD longevity, ESD performance (e.g., charge performance, discharge performance, and/or the like), monetary cost, secondary use, and/or the like.

The ESD manager 110 may be configured to iteratively generate, evaluate, and/or modify candidates 830 in accordance with optimization logic 808 (and/or an optimization engine 806). The solution 850 of the OCO procedure may comprise an optimal OP policy 150 (optimal discharge policy 156) that satisfies requirements of the application 170 at minimal cost, under the predicted ESD charge conditions within the application 170.

In some implementations, the ESD manager 110 may be configured to determine an OP policy 150 for a specified type of ESD 105. In other words, the ESD manager 110 may be constrained to a single ESD type, e.g., may be limited to a single-type search space, as disclosed herein. Alternatively, in some implementations, the ESD manager 110 may be configured to determine an OP policy 150 for one of a plurality of ESD 105. Determining the OP policy 150 at 2120 may comprise a) selecting an ESD type for the application 170, and d) determining an OP policy 150 for ESD 105 of the selected ESD type, the OP policy 150 comprising a discharge policy 156 and incorporating predicted ESD charge conditions of the application 170. The ESD type may be selected based on ESD-specific characteristics, as disclosed herein. In the FIG. 21 example, the ESD manager 110 may select the ESD type based on DCS data 226 determined for respective ESD types. Alternatively, or in addition, the ESD manger 110 may be configured to determine the OP policy 150 through an OCO procedure comprising a multi-type search space, as disclosed herein. For example, at 2110, the ESD manager 110 may be configured to retrieve aging models 120 for a plurality of ESD type(s), such as ESD types A through T (e.g., as illustrated in FIG. 13). The solution 850 of the OCO procedure may comprise determining an optimal OP policy 150 (optimal discharge policy 156) for an optimal ESD type, e.g., an ESD type capable of satisfying requirements of the application 170, under the predicted ESD charge conditions of the application 170, at a lowest cost per the optimization criteria 822 of the application 170.

At 2130, the ESD manager 110 may configure the application 170 to implement the OP policy 150 determined at 2120. Configuring the application 170 to implement the OP policy 150 may comprise configuring components of the application 170 to utilize the ESD 105 in accordance with the OP policy 150. At 2130, the ESD manager 110 may be configured to generate an ESD CFG 160 corresponding the OP policy 150 determined at 2120. The ESD CFG 160 may comprise a discharge configuration 166. The discharge configuration 166 may comprise any suitable means for controlling, regulating, advising, limiting, and/or otherwise managing discharge operations implemented by and/or within the application 170 (operations implemented by the ESDA system 172 and/or components thereof, such as ESD module(s) 174 or the like), which may include, but are not limited to: machine-readable data, configuration data, firmware, instructions, machine-readable instructions, code, machine-readable code, computer-readable code, a script, settings, parameters, limits, thresholds, and/or the like. In some implementations, the ESD CFG 160 generated at 2130 may omit a charge configuration 164 (e.g., since charge conditions may be managed within the application 170).

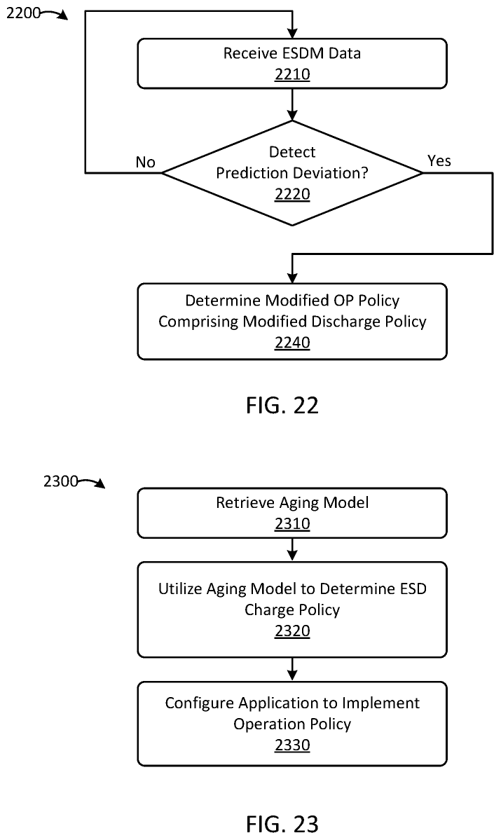

FIG. 22 comprises a flow diagram illustrating another example of a method 2200 for managing ESD prediction deviations. In the FIG. 22 example, the ESD manager 110 may receive ESDM data 250 pertaining to an ESD 105 and/or application 170 at 2210. The ESD manager 110 may receive the ESDM data 250 in response to determining an OP policy 150 for the ESD 105 and/or configuring the application 170 to operate the ESD 105 in accordance with the OP policy 150. In the FIG. 22 example, the OP policy 150 may comprise a discharge policy 156 configured to satisfy requirements of the application 170 under predicted ESD charge conditions of the application 170. For example, the OP policy 150 may be determined per method 2100 illustrated in FIG. 21.

As disclosed herein, ESDM data 250 may comprise and/or refer to any suitable information pertaining to the operating conditions and/or performance characteristics of an ESD 105. In some implementations, the ESDM data 250 received at 2210 may comprise OCM data 252 pertaining to the operating conditions of the ESD 105 within the application 170, e.g., may comprise CCM data 254 pertaining to charge conditions of the ESD 105, DCM data 256 pertaining to discharge conditions of the ESD 105, and/or the like. Alternatively, or in addition, the ESDM data 250 received at 2210 may comprise EPM data 258, which may comprise measurements of ESD performance characteristics acquired at respective usage times.

In some implementations, the ESD manager 110 may be configured to retrieve and/or request aspects of the ESDM data 250 at 2210. For example, the ESD manager 110 may comprise and/or be coupled to an ESD interface module 218, which may be configured to access ESDM data 250 (and/or other information) through a data interface of the application 170 (and/or corresponding ESDA system 172), such as an API or the like. Alternatively, or in addition, ESD manager 110 may receive the ESDM data 250 from another source, e.g., may retrieve the ESDM data 250 from DSR resources 104-2 of the computing device 102, receive ESDM data 250 through the network, receive ESD data 250 acquired by the application 170 (e.g., the application 170 may be configured to push ESDM data 250 to the ESD manager 110), receive ESDM data 250 from an ESD module 174 of the application 170, such as a BMS, and/or the like.

At 2220, the ESD manager 110 may determine whether the ESDM data 252 is indicative of a prediction deviation. At 2220, the ESD manager 110 may be configured to detect a prediction deviation corresponding to one or more of an aging deviation and an operating condition (OC) deviation, as disclosed herein (e.g., as described in conjunction with FIG. 9). For example, the ESD manager 110 may be configured to detect a prediction deviation in response to detecting one or more of: a deviation between performance loss predicted to be incurred by the ESD 105 under the OP policy 150 determined for the ESD 105 and measured performance loss observed in the ESD 105 within the application 170 (per EPM data 258 data received at 2210), and a deviation between target operating conditions of the OP policy 105 and measured operating conditions of the ESD within the application 170 (per OCM data 252 received at 2210). In other words, the ESD manager 110 may be configured to detect an aging deviation in response to detecting deviation between predicted performance degradation and observed performance degradation (per the EPM data 258). In the FIG. 22 example, the ESD manager 110 may be further configured to detect an OP deviation in response to detecting deviation between the predicted ESD charge conditions used to determine the OP policy 150 and the observed charge conditions of the ESD 105 within the application 170.

If a prediction deviation is detected at 2220, the flow may continue at 2230; otherwise, the flow may continue at 2210 when additional ESDM data 250 are received.

At 2230, the ESD manager 110 may be configured to determine a modified OP policy 150 for the ESD 105. The ESD manager 110 may be configured to determine the modified OP policy 150 in response to detection of one or more of an aging deviation and an OC deviation.

In response to detection of an aging deviation at 2220, the ESD manager 110 may be configured to determine a modified OP policy 150 that incorporates the detected aging deviation. The ESD manager 110 may attribute the aging deviation to ESD charge conditions within the application 170. The modified OP policy 150 may incorporate CRA observed within the EPM data 258, e.g., may comprise a modified discharge policy 154 configured to maintain performance loss below a threshold for a specified usage period under DRA observed within the EPM data 258.

Alternatively, in response to detection of an OC deviation at 2220, the ESD manager 110 may be configured to determine a modified OP policy 150 that incorporates the observed ESD charge conditions of the OCM data 252, which may differ from the predicted ESD charge conditions used to determine the original OP policy 150 (per method 2300 above). At 2230, the ESD manager 110 may be configured to update the predicted ESD charge conditions (and/or corresponding charge model 134-1) and determine a modified OP policy 150, the modified OP policy 150 comprising a modified discharge policy 156 configured to satisfy requirements of the application 170 under the updated, predicted ESD charge conditions of the application 170.

In some implementations, the application 170 may be configured to implement the modified OP policy 150 at 2330. In the FIG. 23 example, the ESD manager 110 may be configured to generate a modified discharge configuration 166 and/or configure the application 170 (and/or ESD module(s) 174 thereof) to implement discharge operations on the ESD 105 in accordance with the modified discharge configuration 166, as disclosed herein.

FIG. 23 comprises a flowchart illustrating another example of a method for managing implementation of an application 170 by an ESD 105. As illustrated in FIG. 23, at 2310, the ESD manager 110 may be configured to retrieve an aging model 120 for the ESD 105 (and/or ESD type) to be utilized within the application 170. The aging model 120 retrieved at 2310 may be configured to predict charge-related performance loss to be incurred by the ESD 105 under respective charge conditions and distinguish the charge-related performance loss from discharge-related performance loss (and/or vice versa).

At 2320, the ESD manager 110 may be configured to utilize the aging model 120 to determine an OP policy 150 for the ESD 105 within the application 170, the OP policy 150 configured such that performance loss predicted to be incurred by the ESD 105 satisfies one or more requirements of the application 170.

In the FIG. 23 example, the ESD manager 110 may be configured to manage aspects of the charge conditions of the ESD 105 within the application 170. The ESD manager 110 may be further configured to model known, predetermined, and/or predicted ESD discharge conditions within the application 170, e.g., discharge conditions may be managed internally within the application 170. The ESD manager 110 may determine an OP policy 150 that incorporates discharge-related aging predicted to be incurred under the predicted discharge conditions, e.g., may incorporate a discharge model 136-1 predicted to result in DRA modeled by DC metrics 146. Accordingly, in the FIG. 23 example, the ESD manager 110 may be configured to utilize the aging model 120 to determine an OP policy 150 for the ESD 105 within the application 170, the OP policy 150 comprising a charge policy 154 specifying target charge conditions for the ESD 105 within the application 170, the OP policy 150 configured such that performance loss predicted to be incurred by the ESD satisfies one or more requirements of the application 170. In other words, the OP policy 150 may be configured such that a) performance loss attributable to the target charge conditions of the charge policy 154 determined at 2320 and b) performance loss attributable to predicted EDS discharge conditions within the application 170 satisfy the one or more requirements of the application 170, e.g., maintain performance loss below a threshold for a specified usage period.

In a first non-limiting example, at 2320, the ESD manager 110 may be configured to determine an OP policy 150 (e.g., a charge policy 154) comprising target operating conditions configured to maintain a maximum extent of performance degradation predicted to be incurred by the ESD 105 under a threshold. At 2320, the ESD manager 110 may utilize the aging model 120 to determine an OP policy 150 having aging metrics 142 wherein M_{ch}+M_{d_req}≤M_{threshold}, where M_{d_req} is the extent of performance loss incurred under the predicted ESD discharge conditions of the application 170.

In a second non-limiting example, at 2320, the ESD manager 110 may be configured to determine an OP policy 150 (charge policy 156) configured to maintain performance loss predicted to be incurred by the ESD 105 under a threshold for a specified usage period. At 2320, the ESD manager 110 may utilize the aging model 120 to determine an OP policy 150 having aging metrics 142 wherein ψ_{ch}(tₗ)+ψ_{d_req}(tₗ)≤ψ_{threshold}, wherein ψ_{threshold} is configured to limit performance loss incurred by a designated performance characteristic of the ESD 105 (e.g., capacity), ψ_{ch} is a function configured to model performance loss attributable to the target charge conditions of the charge policy 154 determined at 2320, ψ_{d_req} is a function configured to model performance loss attributable to the predicted ESD discharge conditions of the application 170, and t₁ corresponds to the usage period of the application 170.

In a third non-limiting example, at 2320, the ESD manager 110 may be configured to determine an OP policy 150 covering multiple usage periods, each usage period having respective target operating conditions (e.g., a respective discharge policy 156). At 2320, the ESD manager 110 may be configured to determine an OP policy 150 configured to manage operation of the ESD 105 according to changing requirements of the application 170, as disclosed herein in conjunction with Eq. 16, 32, FIG. 1F, and FIGS. 7A-7B. For example, as illustrated in FIG. 1F, the ESD manager 110 may determine an OP policy 150 comprising a plurality of period-specific OP policies 152, each period-specific OP policy 152 specifying target operating conditions (target discharge conditions) for the ESD 105 during a respective usage period (and/or respective predicted charge conditions). The ESD manager 110 may configure the multi-period OP policy 150 (configure charge policies 154 of respective periods) such that cumulative performance loss incurred over the usage periods is maintained below a threshold. The ESD manager 110 may predict cumulative CRA and/or DRA incurred over the plurality of usage periods per Eq. 16 and/or 32 of the aging model 120, as disclosed herein.

In a fourth non-limiting example, at 2320, the ESD manager 110 may be configured to determine an OP policy 150 configured to enable secondary use of the ESD 105. The ESD manager 110 may be configured to determine an OP policy 150 (charge policy 154) that satisfies a) requirements of the application 170 and b) satisfies requirements of a secondary application 170. For example, the ESD manager 110 may configure the OP policy 150 to a) maintain performance loss predicted to be incurred by the ESD 105 under a threshold of the application 170 for a usage period of the application 170 (a first or primary usage period) and b) maintain performance loss predicted to be incurred by the ESD 105 under a threshold of the secondary application 170 for a secondary usage period extending beyond the usage period of the application 170. For example, the ESD manager 110 may determine a multi-application OP policy 150 for the ESD 105 at 2320, as disclosed in herein (e.g., in conjunction with FIGS. 16A and 16B). The multi-application OP policy 150 incorporating predicted ESD discharge conditions (and/or a predicted discharge models 136-1) of the primary and/or secondary applications 170.

At 2320, the ESD module 110 may be further configured to determine an OP policy 150 that satisfies other, operational requirements of the application 170. The ESD manager 110 may be configured to determine an OP policy 150 for the ESD 105 that a) satisfies performance and/or endurance requirements of the application 170 (e.g., maintain predicted performance loss below a threshold for a specified usage period) while also b) satisfying charge requirements of the application 170. In the FIG. 23 example, discharge requirements, if any, may be incorporated through the predicted ESD discharge conditions of the application 170. For example, at 2320, the ESD manager 110 may utilize the aging model 120 to determine an OP policy 150 for the ESD 105 (a charge policy 154) that satisfies charge requirements of the application 170 while also satisfying a usage guarantee 630; at 2320, the ESD manager 110 may determine a charge policy 156 that a) satisfies a charge requirement such as maximum charge duration (D_{ch_max}), while also b) maintaining performance loss predicted to be incurred by the ESD 105 under a threshold for a specified usage period.

In some implementations, determining the OP policy 150 for the ESD 105 at 2320 may comprise evaluating one or more aging predictions 140, each aging prediction 140 configured to model performance degradation predicted to be incurred by the ESD 105 under a specified set of operating conditions (e.g., candidate operating conditions) and/or a respective candidate OP policy 150. The aging prediction 140 of a candidate OP policy 150 may comprise CC metrics 144 configured to predict aging under target charge conditions of the candidate OP policy 150 (e.g., per the candidate charge policy 154 thereof) and DC metrics 146 configured to predict aging attributable to the predicted ESD discharge conditions of the application 170.

The ESD manager 110 may be configured to generate, evaluate, and/or modify candidate OP policies 150 to, inter alia, identify candidate OP policies 150 that satisfy requirements of the application 170, as disclosed herein. Determining the OP policy 150 at 2320 may comprise iteratively modifying aspects of one or more candidate OP polices 150 to satisfy performance and/or endurance requirements of the application 170, satisfy charge requirements of the application 170, and/or the like. At 2320, the ESD manager 110 may utilize the aging model 120 to a) determine a candidate OP policy 150 for the ESD 105, the candidate OP policy 150 comprising a candidate charge policy 154 and incorporating predicted ESD discharge conditions of the application 170, b) evaluate aging predicted to be incurred by the ESD 105 under the candidate OP policy 150, the evaluating comprising predicting charge-related aging to be incurred by the ESD under target charge conditions of the candidate charge policy 154 and/or DRA incurred under the predicted discharge conditions, and c) modifying aspects of the candidate charge policy 154 based on the evaluating, the modifying based on one or more of an aging prediction 140 determined for the candidate OP policy 150, aging metrics 142 of the candidate OP policy 150, OCS data 220 determined for the ESD 105, discharge requirement(s) of the application 170, and/or the like. In the FIG. 23 example, the ESD manager 110 may be configured to modify selected aspects of a candidate discharge policy 150 based on CCS data 224 indicating a sensitivity of CRA mechanisms of the ESD 105 to respective charge conditions.

In some implementations, the ESD manager 110 may determine the OP policy 150 at 2320 through an OCO procedure, as disclosed herein (e.g., an OCO procedure as illustrated in FIG. 8). As disclosed herein, the OCO procedure may comprise constructing an optimization model 804 comprising constraints 810 and an objective model 820. The optimization model 804 may comprise aging constraints 812, which may comprise and/or be derived from performance and/or endurance requirements of the application 170 (e.g., usage guarantees 630), charge constraints 814, which may comprise and/or be derived from charge requirements of the application 170, discharge constraints 816, which may comprise and/or be derived from the predicted ESD discharge conditions of the application 170, and so on. In the FIG. 23 example, the ESD manager 110 may treat the predicted discharge conditions (discharge model 136-1) as fixed constants, e.g., discharge constraints 816.

The optimization model 804 may further comprise means for evaluating the cost and/or utility of respective candidates 830, as disclosed herein. The objective model 820 may comprise optimization criteria 822, which may be configured to reflect preferences and/or priorities of the application 170, e.g., weight and/or balance any suitable optimization factors including, but not limited to: ESD longevity, ESD performance (e.g., charge performance, discharge performance, and/or the like), monetary cost, secondary use, and/or the like.

The ESD manager 110 may be configured to iteratively generate, evaluate, and/or modify candidates 830 in accordance with optimization logic 808 (and/or an optimization engine 806). The solution 850 of the OCO procedure may comprise an optimal OP policy 150 (optimal charge policy 154) that satisfies requirements of the application 170 at minimal cost, under the predicted ESD discharge conditions within the application 170.

In some implementations, the ESD manager 110 may be configured to determine an OP policy 150 for a specified type of ESD 105. In other words, the ESD manager 110 may be constrained to a single ESD type, e.g., may be limited to a single-type search space, as disclosed herein. Alternatively, in some implementations, the ESD manager 110 may be configured to determine an OP policy 150 for one of a plurality of ESD 105. Determining the OP policy 150 at 2320 may comprise a) selecting an ESD type for the application 170, and d) determining an OP policy 150 for ESD 105 of the selected ESD type, the OP policy 150 comprising a charge policy 154 and incorporating predicted ESD discharge conditions of the application 170. The ESD type may be selected based on ESD-specific characteristics, as disclosed herein. In the FIG. 32 example, the ESD manager 110 may select the ESD type based on CCS data 224 determined for respective ESD types. Alternatively, or in addition, the ESD manger 110 may be configured to determine the OP policy 150 through an OCO procedure comprising a multi-type search space, as disclosed herein. For example, at 2310, the ESD manager 110 may be configured to retrieve aging models 120 for a plurality of ESD type(s), such as ESD types A through T (e.g., as illustrated in FIG. 8). The solution 850 of the OCO procedure may comprise determining an optimal OP policy 150 (optimal charge policy 154) for an optimal ESD type, e.g., an ESD type capable of satisfying requirements of the application 170, under the predicted ESD discharge conditions of the application 170, at a lowest cost per the optimization criteria 822 of the application 170.

At 2330, the ESD manager 110 may configure the application 170 to implement the OP policy 150 determined at 2320. Configuring the application 170 to implement the OP policy 150 may comprise configuring components of the application 170 to utilize the ESD 105 in accordance with the OP policy 150. At 2330, the ESD manager 110 may be configured to generate an ESD CFG 160 corresponding the OP policy 150 determined at 2320. The ESD CFG 160 may comprise a charge configuration 164. The charge configuration 164 may comprise any suitable means for controlling, regulating, advising, limiting, and/or otherwise managing charge operations implemented by and/or within the application 170 (operations implemented by the ESDA system 172 and/or components thereof, such as ESD module(s) 174 or the like), which may include, but are not limited to: machine-readable data, configuration data, firmware, instructions, machine-readable instructions, code, machine-readable code, computer-readable code, a script, settings, parameters, limits, thresholds, and/or the like. In some implementations, the ESD CFG 160 generated at 2330 may omit a discharge configuration 166 (e.g., since discharge conditions may be managed within the application 170).

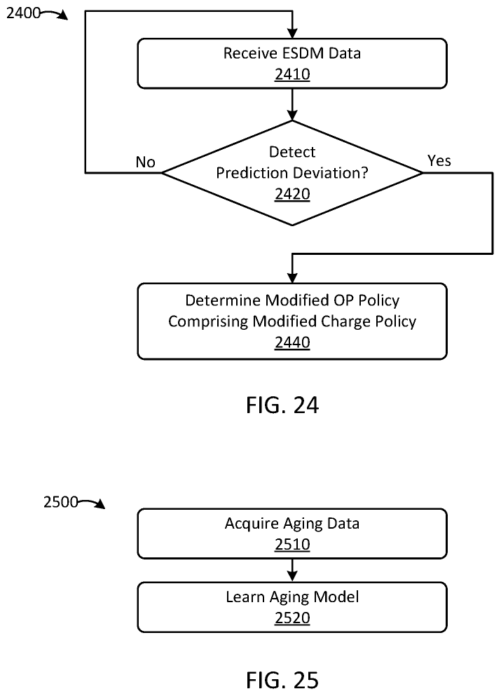

FIG. 24 comprises a flow diagram illustrating another example of a method 2400 for managing ESD prediction deviations. In the FIG. 24 example, the ESD manager 110 may receive ESDM data 250 pertaining to an ESD 105 and/or application 170 at 2410. The ESD manager 110 may receive the ESDM data 250 in response to determining an OP policy 150 for the ESD 105 and/or configuring the application 170 to operate the ESD 105 in accordance with the OP policy 150. In the FIG. 24 example, the OP policy 150 may comprise a charge policy 154 configured to satisfy requirements of the application 170 under predicted ESD discharge conditions of the application 170. For example, the OP policy 150 may be determined per method 2300 illustrated in FIG. 23.

As disclosed herein, ESDM data 250 may comprise and/or refer to any suitable information pertaining to the operating conditions and/or performance characteristics of an ESD 105. In some implementations, the ESDM data 250 received at 2410 may comprise OCM data 252 pertaining to the operating conditions of the ESD 105 within the application 170, e.g., may comprise CCM data 254 pertaining to charge conditions of the ESD 105, DCM data 256 pertaining to discharge conditions of the ESD 105, and/or the like. Alternatively, or in addition, the ESDM data 250 received at 2410 may comprise EPM data 258, which may comprise measurements of ESD performance characteristics acquired at respective usage times.

In some implementations, the ESD manager 110 may be configured to retrieve and/or request aspects of the ESDM data 250 at 2410. For example, the ESD manager 110 may comprise and/or be coupled to an ESD interface module 218, which may be configured to access ESDM data 250 (and/or other information) through a data interface of the application 170 (and/or corresponding ESDA system 172), such as an API or the like. Alternatively, or in addition, ESD manager 110 may receive the ESDM data 250 from another source, e.g., may retrieve the ESDM data 250 from DSR resources 104-2 of the computing device 102, receive ESDM data 250 through the network, receive ESD data 250 acquired by the application 170 (e.g., the application 170 may be configured to push ESDM data 250 to the ESD manager 110), receive ESDM data 250 from an ESD module 174 of the application 170, such as a BMS, and/or the like.

At 2420, the ESD manager 110 may determine whether the ESDM data 252 is indicative of a prediction deviation. At 2420, the ESD manager 110 may be configured to detect a prediction deviation corresponding to one or more of an aging deviation and an operating condition (OC) deviation, as disclosed herein (e.g., as described in conjunction with FIG. 9). For example, the ESD manager 110 may be configured to detect a prediction deviation in response to detecting one or more of: a deviation between performance loss predicted to be incurred by the ESD 105 under the OP policy 150 determined for the ESD 105 and measured performance loss observed in the ESD 105 within the application 170 (per EPM data 258 data received at 2410), and a deviation between target operating conditions of the OP policy 105 and measured operating conditions of the ESD within the application 170 (per OCM data 252 received at 2410). In other words, the ESD manager 110 may be configured to detect an aging deviation in response to detecting deviation between predicted performance degradation and observed performance degradation (per the EPM data 258). In the FIG. 24 example, the ESD manager 110 may be further configured to detect an OP deviation in response to detecting deviation between the predicted ESD discharge conditions used to determine the OP policy 150 and the observed discharge conditions of the ESD 105 within the application 170.

If a prediction deviation is detected at 2420, the flow may continue at 2430; otherwise, the flow may continue at 2410 when additional ESDM data 250 are received.

At 2430, the ESD manager 110 may be configured to determine a modified OP policy 150 for the ESD 105. The ESD manager 110 may be configured to determine the modified OP policy 150 in response to detection of one or more of an aging deviation and an OC deviation.

In response to detection of an aging deviation at 2420, the ESD manager 110 may be configured to determine a modified OP policy 150 that incorporates the detected aging deviation. The ESD manager 110 may attribute the aging deviation to ESD discharge conditions within the application 170. The modified OP policy 150 may incorporate DRA observed within the EPM data 258, e.g., may comprise a modified charge policy 154 configured to maintain performance loss below a threshold for a specified usage period under DRA observed within the EPM data 258.

Alternatively, in response to detection of an OC deviation at 2420, the ESD manager 110 may be configured to determine a modified OP policy 150 that incorporates the observed ESD discharge conditions of the OCM data 252, which may differ from the predicted ESD discharge conditions used to determine the original OP policy 150 (per method 2300 above). At 2430, the ESD manager 110 may be configured to update the predicted ESD discharge conditions (and/or corresponding discharge model 136-1) and determine a modified OP policy 150, the modified OP policy 150 comprising a modified charge policy 154 configured to satisfy requirements of the application 170 under the updated, predicted ESD discharge conditions of the application 170.

In some implementations, the application 170 may be configured to implement the modified OP policy 150 at 2330. In the FIG. 23 example, the ESD manager 110 may be configured to generate a modified charge configuration 164 and/or configure the application 170 (and/or ESD module(s) 174 thereof) to implement charge operations on the ESD 105 in accordance with the modified charge configuration 164, as disclosed herein.

FIG. 25 illustrates a flow diagram of a second example of a method 2500 for developing and/or refining an aging model 120 for an ESD 105 (and/or ESD type). At 2510, the ESD manager 110 may be configured to acquire aging data 215. The aging data 215 may comprise charge-related aging (CRA) data 215-1 configured to, inter alia, characterize charge-related aging mechanisms of the ESD 150. As illustrated in FIG. 2B, the CRA data 215-1 may comprise a plurality of CRA datasets 240-1. The CRA datasets 240-1 may comprise EPM data 248 comprising measurements pertaining to performance degradation observed in the ESD 105 at respective usage times under respective charge conditions (e.g., CC-A through CC-R) and substantially constant, nominal discharge conditions (DC-X). Accordingly, the CRA datasets 240-1 may reflect CRA incurred by the ESD 105 under specified operating conditions and may distinguish CRA from other non-CRA mechanisms, such as discharge-related aging. For example, the CRA datasets 240-1 may comprise non-discharge-related (NDR) aging data.

At 2510, the ESD manager 110 may be further configured to acquire charge-related aging (DRA) data 215-2. The DRA data 215-2 may comprise a plurality of DRA datasets 240-2. The DRA datasets 240-2 may comprise EPM data 248 comprising measurements pertaining to performance degradation observed in the ESD 105 at respective usage times under respective discharge conditions (e.g., DC-A through DC-P) and substantially constant, nominal charge conditions (CC-X). Accordingly, the DRA datasets 240-2 may reflect DRA incurred by the ESD 105 under specified operating conditions and may distinguish DRA from other non-DRA mechanisms, such as charge-related aging. For example, the DRA datasets 240-2 may comprise non-charge-related (NCR) aging data.

In some implementations, the ESD manager 110 may be further configured to acquire aging data 215 configured to characterize ESD aging under combinations of charge and/or discharge conditions. For example, the ESD manager 110 may be configured to acquire operating-condition related (OCR) datasets 240-3 comprising measurements of performance degradation observed in the ESD 150 under arbitrary charge conditions (CC-S through CC-Y) and arbitrary discharge conditions (DC-Q through DC-W).

The ESD manager 110 may acquire aging data 215 at 2510 by any suitable means. For example, the ESD manager 110 may retrieve aging data 215 from a datastore 114, e.g., from a profile 115 of the ESD 105. Alternatively, or in addition, the ESD manager 110 may be configured to acquire aging datasets 240 by use of an evaluation system 172-1, as illustrated in FIG. 2B. For example, acquiring a CRA dataset 240-1 configured to model CRA performance degradation incurred by the ESD 105 under specified charge conditions may comprise, inter alia: a) configuring the evaluation system 172-1 to subject the ESD 105 to charge operations having specified charge conditions, e.g., charge operations implemented in accordance with a specified charge configuration 164, b) configuring the evaluation system 172-1 to subject the ESD 105 to nominal discharge operations over the usage period, and c) acquiring ESDM data 250 comprising measurements of one or more ESD performance characteristics at respective offsets within the usage period.

Acquiring a DRA datasets 240-2 configured to model DRA performance degradation incurred by the ESD 105 under specified discharge conditions may comprise, inter alia: a) configuring the evaluation system 172-1 to subject the ESD 105 to discharge operations having specified discharge conditions, e.g., discharge operations implemented in accordance with a specified discharge configuration 166, b) configuring the evaluation system 172-1 to subject the ESD 105 to nominal charge operations over the usage period, and c) acquiring ESDM data 250 comprising measurements of one or more ESD performance characteristics at respective offsets within the usage period.

Acquiring ORA datasets 240-2 configured to model performance degradation under arbitrary operating conditions may comprise, inter alia: a) configuring the evaluation system 172-1 configured to subject the ESD 105 to charge operations having specified charge conditions over a specified usage period, b) configuring the evaluation system 172-1 to subject the ESD 105 to discharge operations having specified discharge conditions over the usage period, and c) acquiring ESDM data 250 comprising measurements of one or more ESD performance characteristics at respective offsets within the usage period.

At 2520, the ESD manager 110 may utilize the aging data 215 acquired at 2510 to learn aspects of an aging model 120 of the ESD 150.

At 2520, the ESD manager 110 may be configured to learn charge-related aspects of the aging model 120. For example, the ESD manager 110 may utilize CRA datasets 240-1 (and/or other non-charge-related aging data, such as DRA datasets 240-2) to learn a CRA model 124 of the ESD 105. Learning the CRA model 124 may comprise learning parameters of Eq. 1-16, e.g., learning M_{ch}^{o}, p_{ch}, q_{ch}, and/or the like. In some implementations, the ESD manager 110 may be further configured to utilize non-charge-related aging (NCRA) data to develop and/or refine the CRA model 124. The modeling engine 212 may, for example, compare aging incurred by the ESD 105 under respective charge conditions (e.g., CC-A through CC-R) to aging incurred under nominal charge conditions to, inter alia, estimate M_{ch}^{o} of the ESD 105 and/or estimate M_{ch} under respective charge conditions. Alternatively, or in addition, the ESD manager 110 may be configured to learn charge-related aspects of the aging model 120 (e.g., learn a CRA model 124) through and/or by use of AI/ML techniques, as disclosed herein.

Alternatively, or in addition, the ESD manager 110 may be configured to learn discharge-related aspects of the aging model 120 at 2520. For example, the ESD manager 110 may utilize DRA datasets 240-2 (and/or other non-discharge-related aging data, such as CRA datasets 240-1) to learn a DRA model 126 of the ESD 105. Learning the DRA model 126 may comprise learning parameters of Eq. 17-32, e.g., learning M_{d}, p_{d}, q_{d}, and/or the like. In some implementations, the ESD manager 110 may be further configured to utilize non-discharge-related aging (NDRA) data to develop and/or refine the DRA model 126. The ESD manager 110 may, for example, compare aging incurred by the ESD 105 under respective discharge conditions (e.g., DC-A through DC-P) to aging incurred under nominal discharge conditions to, inter alia, estimate M_{d}^{o} of the ESD 105 and/or estimate M_{d} under respective discharge conditions. Alternatively, or in addition, the ESD manager 110 may be configured to learn discharge-related aspects of the aging model 120 (e.g., learn a DRA model 126) through and/or by use of AI/ML techniques, as disclosed herein.

At 2520, the ESD manager 110 may be further configured to an aging model 120 for the ESD 105 from, inter alia, models developed for respective aging mechanisms. The aging model 120 may comprise and/or be derived from the CRA model 124 and the DRA model 126 learned for the ESD 105. For example, ESD manager 110 may derive the aging model 120 by, inter alia, combining the CRA model 124 and DRA model 126 per one or more of Eq. 33-36, e.g., determine an aging model ψₜₒₜₐₗ(t)=ψ_{ch}(t)+ψ_{d}(d), where ψ_{ch}(t) is a function configured to model CRA mechanisms of the ESD 105 and ψ_{d}(t) is a function configured to model DRA mechanisms of the ESD 105, as disclosed herein.

Alternatively, or in addition, in some implementations, the ESD manager 110 may be configured to learn the aging model 120 through AI/ML techniques at 2520. For example, in some implementations, the ESD manager 110 may comprise and/or be coupled to an AI/ML system 214, as illustrated in FIG. 2C. The AI/ML system 214 may comprise and/or be configured to learn an AI/ML aging model 120-1 configured to, inter alia, predict performance degradation to be incurred by an ESD 105 under specified operating conditions. For example, the AI/ML system 214 may be configured to learn an AI/ML aging model 120-1 comprising a machine-learned function(s) ψₜₒₜₐₗ(t), ψ_{ch}(t), ψ_{d}(t), and/or the like, as disclosed herein.

At 2510 the AI/ML aging model 120-1 may be learned through a training procedure. The AI/ML aging model 120-1 may be trained by use of, inter alia, training data 225. The training data 225 may comprise, inter alia, aging data 215, as disclosed herein. For example, the training data 225 may comprise a plurality of aging datasets 240. The training data 225 may comprise any suitable aging datasets 240 including, but not limited to, CRA datasets 240-1, DRA datasets 240-2, ORA datasets 240-3, and/or the like. As disclosed herein, the aging datasets 240 may be configured to quantify ESD performance degradation incurred by an ESD 105 over a usage period under specified operating conditions. The aging datasets 240 may comprise EPM data 258 comprising measurements of one or more ESD performance characteristics acquired over the usage period, e.g., measurements acquired at respective times, offsets, or the like. The aging datasets 240 may further comprise OPM data 252 configured to characterize the operating conditions of the ESD 105 during the usage period. For example, the training data 225 may comprise aging datasets 240A-V, as illustrated in FIG. 2C; the aging datasets 240A-V may comprise EPM data 258A-V acquired under operating conditions characterized by respective OPM data 252A-V, e.g., operating conditions OC-A through OC-V, corresponding to charge conditions CC-A through CC-V and/or discharge conditions DC-A through DC-V.

As disclosed herein, the AI/ML aging model 120-1 may be configured to generate aging predictions 140 in response to the training data 225. At 2520 the aging predictions 140 may be evaluated, which may comprise comparing the aging predictions 140 generated by the AI/ML aging model 120-1 for specified operating conditions to known aging characteristics of the ESD 105, e.g., performance degradation observed under the specified operating conditions. The evaluating may comprise generating feedback data 217 in response to respective aging predictions 140. The feedback data 217 may be configured to, inter alia, quantify error between aging predictions 140 generated by the AI/ML aging model 120-1 for respective operating conditions and known EPM data 258 associated with the respective operating conditions. The AI/ML aging model 120-1 may be updated to, inter alia, reduce such error. For example, the AI/ML aging model 120-1 may be trained to accurately predict the aging observed in the training data 225. The trained AI/ML aging model 120-1 may then be used to predict aging under arbitrary aging conditions.

Although examples of techniques for learning aging models 120 are described herein, the disclosure is not limited in this regard and could be adapted to utilize any suitable modeling technique. For example, at 2520 the ESD manager 110 learn ESD aging trends using any suitable function, e.g., exponential functions, exponential decay functions, sigmoid expressions, sigmoid rate expressions, polynomials, a spline, and/or the like. Alternatively, or in addition, at 2520, the ESD manager 110 may be configured to learn AI/ML aging models 120-1 comprising any suitable AI/ML architecture through any suitable AI/ML technique.

This disclosure has been made with reference to various exemplary embodiments. However, those skilled in the art will recognize that changes and modifications may be made to the exemplary embodiments without departing from the scope of the present disclosure. For example, various operational steps, as well as components for carrying out operational steps, may be implemented in alternate ways depending upon the particular application or in consideration of any number of cost functions associated with the operation of the system, e.g., one or more of the steps may be deleted, modified, or combined with other steps.

Additionally, as will be appreciated by one of ordinary skill in the art, principles of the present disclosure may be reflected in a computer program product on a computer-readable storage medium having computer-readable program code means embodied in the storage medium. Any tangible, non-transitory computer-readable storage medium may be utilized, including magnetic storage devices (hard disks, floppy disks, and the like), optical storage devices (CD-ROMs, DVDs, Blu-Ray discs, and the like), flash memory, and/or the like. These computer program instructions may be loaded onto a general-purpose computer, special purpose computer, or other programmable data processing apparatus to produce a machine, such that the instructions that execute on the computer or other programmable data processing apparatus create means for implementing the functions specified. These computer program instructions may also be stored in a computer-readable memory that can direct a computer or other programmable data processing apparatus to function in a particular manner, such that the instructions stored in the computer-readable memory produce an article of manufacture, including implementing means that implement the function specified. The computer program instructions may also be loaded onto a computer or other programmable data processing apparatus to cause a series of operational steps to be performed on the computer or other programmable apparatus to produce a computer-implemented process, such that the instructions that execute on the computer or other programmable apparatus provide steps for implementing the functions specified.

While the principles of this disclosure have been shown in various embodiments, many modifications of structure, arrangements, proportions, elements, materials, and components, which are particularly adapted for a specific environment and operating requirements, may be used without departing from the principles and scope of this disclosure. These and other changes or modifications are intended to be included within the scope of the present disclosure.

The foregoing specification has been described with reference to various embodiments. However, one of ordinary skill in the art will appreciate that various modifications and changes can be made without departing from the scope of the present disclosure. Accordingly, this disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, a required, or an essential feature or element. As used herein, the terms “comprises,” “comprising,” and any other variation thereof, are intended to cover a non-exclusive inclusion, such that a process, a method, an article, or an apparatus that comprises a list of elements does not include only those elements but may include other elements not expressly listed or inherent to such process, method, system, article, or apparatus. Also, as used herein, the terms “coupled,” “coupling,” and any other variation thereof are intended to cover a physical connection, an electrical connection, a magnetic connection, an optical connection, a communicative connection, a functional connection, and/or any other connection.

1. A method, comprising:
retrieving an aging model for an energy storage device (ESD), the aging model configured to predict discharge-related performance loss to be incurred by the ESD under respective discharge conditions and distinguish the discharge-related performance loss from charge-related performance loss;
utilizing the aging model to determine an operation policy for the ESD within an application, the operation policy comprising a discharge policy specifying target discharge conditions for the ESD within the application, the operation policy configured such that performance loss predicted to be incurred by the ESD satisfies one or more requirements of the application; and
configuring the application to implement the discharge policy.

2. The method of claim 1, wherein configuring the application to implement the discharge policy comprises generating instructions to control aspects of discharge operations implemented by a discharge module of the application such that discharge conditions of the ESD within the application correspond with the target discharge conditions of the discharge policy.

3. The method of claim 1, the method further comprising configuring the discharge policy to maintain the performance loss predicted to be incurred by the ESD under a threshold for a specified usage period.

4. The method of claim 3, the method further comprising configuring the discharge policy to maintain the performance loss predicted to be incurred by the ESD under a threshold of a secondary application for a secondary usage period extending beyond the specified usage period.

5. The method of claim 3, further comprising:
utilizing the aging model to determine predicted charge-related performance loss to be incurred by the ESD over the specified usage period;
wherein the discharge policy is configured such that a sum of the predicted charge-related performance loss and predicted discharge-related performance loss under the discharge policy satisfies the threshold for the specified usage period.

6. The method of claim 1, wherein utilizing the aging model to determine the operation policy for the ESD further comprises:
determining a charge policy of the operation policy, the charge policy pertaining to charge operations to be performed on the ESD within the application; and
configuring the operation policy such that a sum of the predicted charge-related performance loss to be incurred by the ESD under the charge policy and the predicted discharge-related performance loss to be incurred by the ESD under the discharge policy satisfies the threshold for a specified usage period.

7. The method of claim 6, wherein utilizing the aging model to determine the operation policy for the ESD further comprises configuring the operation policy to satisfy one or more of a discharge requirement of the application and a charge requirement of the application while maintaining predicted performance loss to be incurred by the ESD under the threshold for the specified usage period.

8. The method of claim 1, wherein utilizing the aging model to determine the operation policy for the ESD further comprises:
determining a candidate operation policy for the ESD, the candidate operation policy comprising a candidate discharge policy and a candidate charge policy;
evaluating aging predicted to be incurred by the ESD under the candidate operation policy, the evaluating comprising predicting discharge-related aging to be incurred by the ESD under target discharge conditions of the candidate discharge policy and predicting charge-related aging to be incurred by the ESD under target charge conditions of the candidate charge policy; and
modifying the candidate operation policy based on the evaluating, the modifying based on one or more of an aging prediction determined for the candidate policy, aging metrics of the candidate operation policy, operating condition sensitivity data determined for the ESD, a discharge constraint of the application, and a charge constraint of the application.

9. The method of claim 8, further comprising configuring the application to implement charge operations in accordance with the charge policy of the operation policy.

10. The method of claim 8, wherein utilizing the aging model to determine the operation policy for the ESD further comprises:
evaluating aging predicted to be incurred by the ESD under a plurality of candidate operation policies, each candidate operation policy comprising a respective discharge policy and respective charge policy; and
selecting the operation policy from the plurality of candidate operation policies based, at least in part, on one or more of aging predictions determined for the candidate policies, aging metrics of the candidate policies, and cost metrics of the candidate policies, the cost metrics based, at least in part, on optimization criteria of the application.

11. The method of claim 10, wherein each candidate operation policy of the plurality of operation policies comprises a same charge policy configured to model predicted charge conditions of the application, and wherein modifying respective candidate operation policies of the plurality of operation policies comprises modifying discharge policies of the respective candidate operation policies.

12. The method of claim 1, the method further comprising:
determining a modified operation policy for the ESD in response to detecting a prediction deviation, the prediction deviation comprising one or more of:
a deviation between performance loss predicted to be incurred by the ESD under the operation policy and measured performance loss observed in the ESD within the application, and
a deviation between target operating conditions of the operation policy and measured operating conditions of the ESD within the application; and
configuring the application to implement the modified operation policy.

13. The method of claim 12, wherein determining the modified operation policy comprises determining a modified discharge policy, the modified discharge policy configured to reduce discharge-related aging to be incurred by the ESD within the application.

14. The method of claim 12, further comprising detecting the prediction deviation in response to comparing predicted charge conditions of the ESD used to determine the operation policy for the ESD within the application and measured charge conditions of the ESD within the application.

15. The method of claim 1, further comprising:
retrieving aging models for a plurality of ESD types;
displaying aging predictions determined for selected ESD types of the plurality of ESD types on a graphical user interface, the aging predictions indicating performance degradation to be incurred by ESD of the selected ESD types under operating policies configured to satisfy the one or more requirements of the application; and
receiving user selection of an ESD type of the plurality of ESD types in response to the displaying.

16. An apparatus, comprising:
a processor coupled to a memory; and
an energy storage device (ESD) manager configured for operation on the processor, the ESD manager configured to:
retrieve an aging model for an ESD, the aging model configured to predict discharge-related performance loss to be incurred by the ESD under respective discharge conditions and distinguish the discharge-related performance loss from charge-related performance loss,
utilize the aging model to determine an operation policy for the ESD within an application, the operation policy comprising a discharge policy specifying target discharge conditions for the ESD within the application, the operation policy configured to maintain performance loss predicted to be incurred by the ESD under a threshold for a specified usage period, and
generate instructions configured to control aspects of discharge operations implemented by a discharge module of the application such that discharge conditions of the ESD within the application correspond with the target discharge conditions of the discharge policy.

17. The apparatus of claim 16, wherein the ESD manager is further configured to utilize the aging model to configure the operation policy to maintain the performance loss predicted to be incurred by the ESD under a threshold of a secondary application for a secondary usage period extending beyond the specified usage period.

18. The apparatus of claim 16, wherein the ESD manager is further configured to:
determine a charge policy of the operation policy, the charge policy pertaining to charge operations to be performed on the ESD within the application;
configure the operation policy such that discharge-related performance degradation predicted to be incurred by the ESD under the discharge policy and charge-related performance degradation predicted to be incurred by the ESD under the charge policy is maintained below the threshold for the specified usage period; and
configure the application to implement charge operations in accordance with the charge policy of the operation policy determined for the ESD.

19. The apparatus of claim 16, wherein the ESD manager is further configured to:
determine a modified operation policy for the ESD in response to detecting a prediction deviation, the prediction deviation comprising one or more of:
a deviation between performance loss predicted to be incurred by the ESD under the operation policy and measured performance loss observed in the ESD within the application, and
a deviation between target operating conditions of the operation policy and measured operating conditions of the ESD within the application; and
configuring the application to implement the modified operation policy.

20. The apparatus of claim 19, wherein the ESD manager is further configured to determine a modified discharge policy of the modified operation policy, the modified discharge policy configured to reduce discharge-related aging to be incurred by the ESD within the application.

21. The apparatus of claim 19, wherein the ESD manager is configured to detect the prediction deviation in response to comparing predicted charge conditions of the ESD used to determine the operation policy for the ESD within the application and measured charge conditions of the ESD within the application.

22. The apparatus of claim 16, further comprising an interface module configured to:
display aging predictions determined for selected ESD types of a plurality of ESD types on a graphical user interface, the aging predictions indicating performance degradation to be incurred by ESD of the selected ESD types under operating policies configured to satisfy one or more requirements of the application; and
receive user selection of an ESD type of the plurality of ESD types.

23. A computer-readable storage medium comprising instructions configured to cause a computing device to perform operations for managing energy storage devices, the operations comprising:
retrieving an aging model for an energy storage device (ESD), the aging model configured to predict charge-related performance loss to be incurred by the ESD under respective charge conditions and to predict discharge-related performance loss to be incurred by the ESD under respective discharge conditions;
utilizing the aging model to determine an operation policy for the ESD within an application, the operation policy comprising a discharge policy specifying target discharge conditions for the ESD within the application, the operation policy configured such that performance loss predicted to be incurred by the ESD under the operation policy is maintained below a threshold for a specified usage period; and
configuring the application to implement the discharge policy.

24. The computer-readable storage medium of claim 23, the operations further comprising configuring the discharge policy to maintain the performance loss predicted to be incurred by the ESD under a threshold of a secondary application for a secondary usage period extending beyond the specified usage period.

25. The computer-readable storage medium of claim 23, wherein utilizing the aging model to determine the operation policy for the ESD further comprises:
determining a charge policy of the operation policy, the charge policy pertaining to charge operations to be performed on the ESD within the application; and
configuring the operation policy such that a sum of predicted charge-related performance loss to be incurred by the ESD under the charge policy and predicted discharge-related performance loss to be incurred by the ESD under the discharge policy satisfies the threshold for the specified usage period.

26. The computer-readable storage medium of claim 25, wherein utilizing the aging model to determine the operation policy for the ESD further comprises configuring the operation policy to satisfy one or more of a discharge requirement of the application and a charge requirement of the application while maintaining predicted performance loss to be incurred by the ESD under the operation policy under the threshold for the specified usage period.

27. The computer-readable storage medium of claim 26, wherein utilizing the aging model to determine the operation policy for the ESD further comprises determining optimal target operating conditions for the ESD within the application, the optimal target operating conditions predicted to satisfy the requirements of the application at minimal cost metrics, the cost metrics determined in accordance with optimization criteria of the application.

28. The computer-readable storage medium of claim 27, wherein utilizing the aging model to determine the operation policy for the ESD further comprises:
determining a plurality of candidate operation policies for the ESD, the candidate operation policies comprising respective candidate charge policies and respective candidate discharge policies;
evaluating aging predicted to be incurred by the ESD under respective candidate operation policies, the evaluating comprising predicting charge-related aging to be incurred by the ESD under target charge conditions of the respective candidate charge policies and predicting discharge-related aging to be incurred by the ESD under target discharge conditions of the respective candidate discharge policies; and
modifying a candidate operation policy of the plurality of candidate operation policies based on the evaluating, the modifying based on one or more of an aging prediction determined for the candidate policy, aging metrics of the candidate operation policy, operating condition sensitivity data determined for the ESD, a charge constraint of the application, and a discharge constraint of the application.

29-56. (canceled)
